(19) United States
(12) Patent Application Publication
(10) Pub. No.: US 2016/0004156 A1
(43) Pub. Date: Jan. 7, 2016

(54) PATTERN FORMING METHOD, ACTINIC RAY-SENSITIVE OR RADIATION-SENSITIVE RESIN COMPOSITION FOR ORGANIC SOLVENT DEVELOPMENT USED THEREFOR AND METHOD OF MANUFACTURING THE SAME, METHOD OF MANUFACTURING ELECTRONIC DEVICE, AND ELECTRONIC DEVICE

(71) Applicant: FUJIFILM CORPORATION, Tokyo (JP)

(72) Inventors: Shinichi SUGIYAMA, Haibara-gun (JP); Sou KAMIMURA, Haibara-gun (JP); Akiyoshi GOTO, Haibara-gun (JP)

(73) Assignee: FUJIFILM CORPORATION, Tokyo (JP)

(21) Appl. No.: 14/853,119

(22) Filed: Sep. 14, 2015

Related U.S. Application Data
(63) Continuation of application No. PCT/JP2014/054560, filed on Feb. 25, 2014.

(30) Foreign Application Priority Data
Mar. 15, 2013 (JP) 2013-053283

(51) Int. Cl. G03F 7/038; G03F 7/32; G03F 7/20

(52) U.S. Cl. CPC G03F 7/038; G03F 7/20; G03F 7/325

(57) ABSTRACT

There is provided a pattern forming method including: (1) filtering, by using a filter, a resin solution containing (A) a resin capable of increasing its polarity by an action of an acid to decrease solubility in a developer including an organic solvent, and (C1) a solvent; (2) preparing an actinic ray-sensitive or radiation-sensitive resin composition containing the resin (A) obtained from the filtrating (1) and a solvent (C2) different from the solvent (C1); (3) filtering the actinic ray-sensitive or radiation-sensitive resin composition by using a filter; (4) forming a film by using a filtrate obtained by the filtering (3); (5) exposing the film; and (6) performing development using a developer containing an organic solvent to form a negative pattern, wherein an absolute value of the difference between solubility parameter (SP_{C1}) of the solvent (C1) and solubility parameter (SP_{DEV}) of the developer (C1), |SP_{C1}−SP_{DEV}|, is 1.00 (cal/cm³)^{1/2} or less.

### CROSS REFERENCE TO RELATED APPLICATION(S)

This is a continuation of International Application No. PCT/JP2014/054560 filed on Feb. 25, 2014, and claims priority from Japanese Patent Application No. 2013-053283 filed on Mar. 15, 2013, the entire disclosures of which are incorporated herein by reference.

### BACKGROUND

1. Technical Field

The present invention relates to a pattern forming method, an actinic ray-sensitive or radiation-sensitive resin composition for organic solvent development used therefor and method of manufacturing the same, a method of manufacturing an electronic device, and an electronic device. More specifically, the present invention relates to a pattern forming method suitable for a manufacturing process of a semiconductor such as an IC, a manufacture of a liquid crystal and a circuit board such as a thermal head, and furthermore, other lithography processes of photofabrication, an actinic ray-sensitive or radiation-sensitive resin composition for organic solvent development used therefor and method of manufacturing the same, a method of manufacturing an electronic device, and an electronic device. In particular, the present invention relates to a pattern forming method suitable for exposure in a KrF exposure apparatus, an ArF exposure apparatus and an ArF liquid immersion projection exposure apparatus which uses far-ultraviolet rays having a wavelength of 300 nm or less as a light source as well as an EUV exposure apparatus which uses an extreme-ultraviolet ray (EUV light) as a light source, an actinic ray-sensitive or radiation-sensitive resin composition for organic solvent development used therefor and a method of manufacturing the same, a method of manufacturing an electronic device, and an electronic device.

2. Background Art

Since a resist for a KrF excimer laser (248 nm) was developed, as an image forming method of a resist to complement desensitization caused by light absorption, an image forming method called chemical amplification has been used. For example, in an image forming method using positive-type chemical amplification, an acid-generating agent included in an exposed portion decomposes upon irradiation with light and generates an acid. Thereafter, in a post exposure bake (PEB), an alkali-insoluble group is changed to an alkali-soluble group by using the generated acid as a reaction catalyst. Subsequently, development is performed using an alkaline solution to remove the exposed portion, thereby forming a desired image.

Currently, ArF immersion lithography is used in a pattern forming of the tip, but the resolution that can be reached at the maximum NA water immersion lithography using a NA1.35 lens is 40 to 38 nm. Therefore, in the pattern forming of 30 nm node or less, a double patterning process (see Proc. SPIE Vol. 5992 p 557 (2005)) has been taken and many processes have been proposed as the method.

Currently, the positive-type image forming method using this chemical amplification mechanism is mainly used. For example, it is also known to form a contact hole by using this method (see International Publication No. 2008/149701 and Japanese Patent Application Laid-Open No. 2004-361629).

However, in the positive-type image forming method, an isolated line or a dot pattern can be satisfactorily formed. However, in the case of forming an isolated space (trench pattern) or a fine hole pattern, it is likely to deteriorate the shape of the pattern.

In recent years, further miniaturization of patterns has been requested. The technology in which the resist film obtained from the positive type mainly used now as well as a negative chemically amplified resist composition is developed using an organic developer has been known (see Japanese Patent Application Laid-Open No. 2008-292975).

However, in the technology in which the resist film obtained from the negative chemically amplified resist composition is developed using an organic developer, there were problems that the dissolution rate of the melting portion is low and the residue defects or bridging defects are easy to occur during pattern formation, among others, especially the residue defects is easy to occur, as compared with a conventional positive-type resist.

The present invention has been made in view of the above problems, its object is to provide a pattern forming method performing development using an organic developer which can reduce the residue defects, an actinic ray-sensitive or radiation-sensitive resin composition for organic solvent development used therefor and a method for manufacturing the same, a method of manufacturing an electronic device, and an electronic device.

The present inventors have studied intensively to solve the above-described problems and found that (i) prior to the preparation of the resist composition, a resin used in the resist composition is dissolved in a solvent which is the same as the organic developer or a solvent which has a close solubility parameter to the organic-based developer, and a solvent which is different from the solvent used for the resist composition and the resulting resin solution is filtered using a filter, (ii) after the resist composition is prepared using the filtrate in (i) the resist composition is filtered using this filter, and (iii) a resist film is formed using a filtrate in the above (ii), thereby significantly reducing the residue defects which is easy to cause particular problems in the development using the above-described organic developer. The present invention has been completed on the basis of such a finding.

### SUMMARY

The present invention has the following configuration, and the problems of the present invention are accordingly solved.

[1] A pattern forming method including:

(1) filtering, by using a filter, a resin solution containing (A) a resin capable of increasing its polarity by an action of an acid to decrease solubility in a developer including an organic solvent, and (C1) a solvent;

(2) preparing an actinic ray-sensitive or radiation-sensitive resin composition which contains the resin (A) obtained from the filtrating (1) and a solvent (C2) that is different from the solvent (C1);

(3) filtering the actinic ray-sensitive or radiation-sensitive resin composition by using a filter;

(4) forming a film by using a filtrate obtained by the filtering (3);

(5) exposing the film; and

(6) performing development using a developer containing an organic solvent to form a negative pattern,

wherein an absolute value of the difference between solubility parameter (SP_{C1}) of the solvent (C1) and solubility parameter (SP_{DEV}) of the developer (C1), |SP_{C1}−SP_{DEV}|, is 1.00 (cal/cm³)^{1/2} or less.

[2] The pattern forming method according to [1],

wherein the absolute value |SP_{C1}-SP_{DEV}| is 0.40 (cal/cm³)^{1/2} or less.

[3] The pattern forming method according to [1] or [2],

wherein the solvent (C1) and the developer are the same.

[4] The pattern forming method according to any one of [1] to [3],

wherein, when the filtering (1) is performed once, the absolute value of the difference between the solubility parameter (SP_{C1}) of the solvent (C1) and the solubility parameter (SP_{C2}) of the solvent (C2), |SP_{C1}−SP_{C2}|, is 0.40 (cal/cm³)^{1/2} or more; and

when the filtering (1) is performed twice or more, in at least one of two or more filtering (1), the absolute value of the difference between the solubility parameter (SP_{C1}) of the solvent (C1) and the solubility parameter (SP_{C2}) of the solvent (C2), |SP_{C1}−SP_{C2}|, is 0.40 (cal/cm³)^{1/2} or more.

[5] The pattern forming method according to according to any one of [1] to [4],

wherein the solvent (C1) is one or more solvents selected from the group consisting of butyl acetate, methyl amyl ketone, ethyl 3-ethoxy propionate, ethyl acetate, propyl acetate, isopropyl acetate, isobutyl acetate, pentyl acetate, isopentyl acetate, and methyl 3-methoxy propionate.

[6] The pattern forming method according to any one of [1] to [5],

wherein the resin (A) includes a repealing unit represented by Formula (AI):

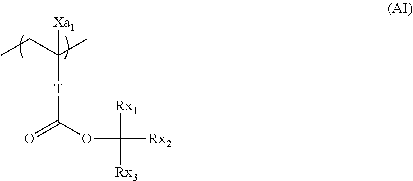

wherein in Formula (AI),

Xa₁ represents a hydrogen atom, an alkyl group, a cyano group or a halogen atom,

T represents a single bond or a divalent linking group,

each of Rx₁ to Rx₃ independently represents an alkyl group or a cycloalkyl group, and

two of Rx₁ to Rx₃ may combine with each other to form a ring structure.

[7] The pattern forming method according to any one of [1] to [6],

wherein the filter in the filtering (1) is a filter containing a polyamide-based resin filter or a polyethylene-based resin filter.

[8] The pattern forming method according to any one of [1] to [7],

wherein a pore size of the filter in the filtering (1) is 0.1 μm or less.

[9] An actinic ray-sensitive or radiation-sensitive resin composition, including:

(A) a resin capable of increasing its polarity by an action of an acid to decrease solubility in a developer including an organic solvent; and

(C2) a solvent,

wherein the resin (A) is obtained from a filtrate which is obtained by filtering, by using a filter, a resin solution containing the resin (A) and a solvent (C1) that is different from the solvent (C2).

[10] The actinic ray-sensitive or radiation-sensitive resin composition according to [9],

wherein the solvent (C1) is one or more solvents selected from the group consisting of butyl acetate, methyl amyl ketone, ethyl 3-ethoxy propionate, ethyl acetate, propyl acetate, isopropyl acetate, isobutyl acetate, pentyl acetate, isopentyl acetate, and methyl 3-methoxy propionate.

[11]A method of preparing an actinic ray-sensitive or radiation-sensitive resin composition for organic solvent development, including:

(1) filtering, by using a filter, a resin solution containing (A) a resin capable of increasing its polarity by an action of an acid to decrease the solubility in a developer including an organic solvent, and (C1) a solvent;

(2) preparing an actinic ray-sensitive or radiation-sensitive resin composition for organic solvent development, containing the resin (A) obtained from a filtrate in the filtering (1) and a solvent (C2) that is different from the solvent (C1); and

(3) filtering the actinic ray-sensitive or radiation-sensitive resin composition for organic solvent development by using a filter.

[12] The method for manufacturing an actinic ray-sensitive or radiation-sensitive resin composition for organic solvent development according to [11],

wherein the solvent (C1) is one or more solvents selected from the group consisting of butyl acetate, methyl amyl ketone, ethyl 3-ethoxy propionate, ethyl acetate, propyl acetate, isopropyl acetate, isobutyl acetate, pentyl acetate, isopentyl acetate, and methyl 3-methoxy propionate.

[13] A method of manufacturing an electronic device comprising the pattern forming method according to any one of [1] to [8].

[14] An electronic device manufactured from the method of manufacturing an electronic device according to [13].

According to the present invention, there is provided a pattern forming method performing development using an organic developer which can reduce the residue defects, an actinic ray-sensitive or radiation-sensitive resin composition for organic solvent development used therefor and a method for manufacturing the same, a method of manufacturing an electronic device, and an electronic device.

### BRIEF DESCRIPTION OF DRAWINGS

FIG. 1 is a diagram showing an example of a SEM image with residue defects.

### DETAILED DESCRIPTION OF EXEMPLARY EMBODIMENTS

Hereinafter, embodiments of the present invention will be described in detail.

In the representation of a group (atomic group) in the present specification, the representation which does not describe the substitution and unsubstitution includes a group having no substituent and a group having no substituent. For example, “an alkyl group” includes not only an alkyl group having no substituent (unsubstituted alkyl group) but also an alkyl group having a substituent (substituted alkyl group).

In the present specification, the term “actinic ray” or “radiation” refers to, for example, a bright line spectrum of a mercury lamp, a far-ultraviolet rays typified by excimer laser, an extreme-ultraviolet ray (EUV light), an X-ray, an electron bean (EB) and the like. Also, in the present invention, the term “light” refers to an actinic ray or radiation.

Further, in the present specification, unless otherwise indicated, the term “exposure” includes not only exposure with a mercury lamp, a far-ultraviolet ray typified by excimer laser, an extreme-ultraviolet ray, an X-ray, EUV light and the like, but also lithography with a particle beam such as an electron beam and an ion beam.

The pattern forming method of the present invention is a pattern forming method comprising (1) a process of filtering a resin solution containing (A) a resin capable of increasing its polarity by an action of an acid to decrease the solubility in a developer including an organic solvent, and (C1) a solvent, using a filter; (2) a process of preparing an actinic ray-sensitive or radiation-sensitive resin composition which contains the resin (A) obtained from the filtrate in the process (1) and a solvent (C2) that is different from the solvent (C1); (3) a process of filtering the actinic ray-sensitive or radiation-sensitive resin composition using a filter; (4) a process of forming a film using the filtrate obtained by the process (3); (5) a process of exposing the film; and (6) a process of performing development using a developer containing an organic solvent (hereinafter, referred to as “organic-based developer”) to form a negative pattern, wherein an absolute value of the difference between the solubility parameter (SP_{C1}) of the solvent (C1) and the solubility parameter (SP_{DEV}) of the developer, (|SP_{C1}−SP_{DEV}|), is 1.00 (cal/cm³)^{1/2} or less.

Further, a method for manufacturing the actinic ray-sensitive or radiation-sensitive resin composition for organic solvent development according to the present invention comprises:

(1) a process of filtering a resin solution containing (A) a resin capable of increasing its polarity by an action of an acid to decrease the solubility in the developer including an organic solvent, and (C1) a solvent, using a filter;

(2) a process of preparing an actinic ray-sensitive or radiation-sensitive resin composition for organic solvent development containing the resin (A) obtained from the filtrate in the process (1) and a solvent (C2) that is different from the solvent (C1); and

(3) a process of filtering the actinic ray-sensitive or radiation-sensitive resin composition for organic solvent development using a filter.

The reasons why the residue defects can be reduced in a technology of performing development using the organic-based developer by the method for manufacturing the actinic ray-sensitive or radiation-sensitive resin composition for organic solvent development and the pattern forming method are not clear, but are assumed as follows.

First, in the positive-type image forming method of performing development with an alkali developer, the exposed portion is dissolved in an alkali developer (tetramethyl ammonium hydroxide (TMAH) solution, etc.) and the unexposed portions remain, thereby forming a pattern. Accordingly, the solubility in an alkali developer of the resin after the reaction due to the exposure is important for residue detects. In contrast, in a technique for resolution using an organic-based developer, the unexposed portion is dissolved and a pattern is formed. Therefore, if any matters insoluble in the organic developer are present in the unexposed pattern, that is, the resin itself before the reaction due to the exposure, it is considered that residues defects tend to occur.

Accordingly, as in the pattern forming method according to the present invention, it is considered that a resin component is first dissolved in a solvent which is the same as the organic-based developer or a solvent which has a similar solubility parameter to the organic solvent (specifically, a solvent wherein the absolute value of the difference with the solubility parameter (SP_{DEV}) of the organic-based developer, (|SP_{C1}−SP_{DEV}|), is 1.00 (cal/cm³)^{1/2} or less and filtered with a filter to obtain a filtrate in which trace impurities are removed, and then the actinic ray-sensitive or radiation-sensitive resin composition is prepared using the resin obtained from this filtrate; as a result, the residue defects are reduced in the pattern forming method performing the development using the organic-based developer.

Also, as in the pattern forming method of the present invention, it is considered that a solvent (hereinafter, also referred to as a “resist solvent”) in the actinic ray-sensitive or radiation-sensitive resin composition is used as that is different from the solvent for pre-filtration, and the actinic ray-sensitive or radiation-sensitive resin composition is filtered with a filter and the residue defects based on the material that is soluble in a resist solvent, but insoluble or sparingly soluble in the solvent for pre-filtration are significantly reduced.

Meanwhile, when the absolute value of the difference between the solubility parameter (SP_{C1}) of the solvent (C1) and the solubility parameter (SP_{DEV}) of the organic-based developer, (|SP_{C1}−SP_{DEV}|), exceeds 1.00 (cal/cm³)^{1/2}, the components that are sparingly soluble in the developer remain as a residue and so the residue defects are easy to occur.

<Pattern Forming Method, and Method for Manufacturing the Actinic Ray-Sensitive or Radiation-Sensitive Resin Composition for Organic Solvent Development>

Hereinafter, a pattern forming method and a method for manufacturing an actinic ray-sensitive or radiation-sensitive resin composition for organic solvent development that may be used in the present invention will be described in detail.

The pattern forming method of the present invention is a pattern forming method comprising (1) a process of filtering a resin solution containing (A) a resin capable of increasing its polarity by an action of an acid to decrease the solubility in the developer including an organic solvent, and (C1) a solvent, using a filter; (2) a process of preparing an actinic ray-sensitive or radiation-sensitive resin composition containing the resin (A) obtained from the filtrate in the process (1) and a solvent (C2) that is different from the solvent (C1); (3) a process of filtering the actinic ray-sensitive or radiation-sensitive resin composition using a filter; (4) a process of forming a film using the filtrate obtained from the process (3); (5) a process of exposing the film; and (6) a process of performing development using a developer containing an organic solvent (hereinafter, referred to as an “organic-based developer”) to form a negative pattern, wherein the absolute value of the difference between the solubility parameter (SP_{C1}) of the solvent (C1) and the solubility parameter (SP_{DEV}) of the developer, (|SP_{C1}−SP_{DEV}|), is 1.00 (cal/cm³)^{1/2} or less.

Furthermore, the present invention relates to a method for manufacturing the actinic my-sensitive or radiation-sensitive resin composition for organic solvent development used in the pattern forming method will be described. Specifically, this method comprises:

(1) a process of filtering a resin solution containing (A) a resin capable of increasing its polarity by an action of an acid to decrease the solubility in the developer including an organic solvent, and a solvent (C1), using a filer;

(2) a process of preparing an actinic ray-sensitive or radiation-sensitive resin composition for organic solvent development containing the resin (A) obtained from the filtrate in the process (1) and a solvent (C2) that is different from the solvent (C1); and

(3) a process of filtering the actinic ray-sensitive or radiation-sensitive resin composition for organic solvent development using a filter.

Here, when at least one of a solvent (C1), a solvent (C2) and an organic-based developer is a mixed solvent containing two or more solvents (the concept of “solvent” is intended to include “water”), a portion of the solvent constituting the mixed solvent does not correspond to the solvent (C1), the solvent (C2) and the organic-based developer, but the entire mixed solvent corresponds to the solvent (C1), the solvent (C2) or the organic-based developer.

Also, as for the “solvent (C2) that is different from the solvent (C1)” as described above, the solvent (C1) and the solvent (C2) are considered to be different, except that the the solvent (C1) and a solvent (C2) are completely the same.

For example, when the solvent (C1) is a mixed solvent of a solvent S1 and a solvent S2 and the solvent (C2) is composed only of the solvent S1, both the solvent (C1) and the solvent (C2) contain the solvent S1 as a constitutional solvent, but they are not completely identical. Therefore, in the present invention, these are considered to be “different”.

Further, for example, when the solvent (C1) is a mixed solvent of the solvent S1 and the solvent S2 in a molar ratio of 3:7 and the solvent (C2) is a mixed solvent of the solvent S1 and the solvent S2 in a molar ratio of 5:5, both the solvent (C1) and the solvent (C2) are composed of the solvent S1 and the solvent S2, but the mass ratios are different and thus, they are not completely identical. Accordingly, in the present invention, they are considered to be “different”.

In the present invention, the solubility parameter (SP value) are those which can be obtained based on Okitsu method, specifically it can be calculated by the method described in Adhesive Handbook (3rd edition) edited by the Adhesion Society of Japan, Mizoguchi Isao, P330.

The SP value (Okitsu method) in specific compounds obtained by the above is shown below.

TABLE 1

| Name | SP value (cal/cm³)^{1/2} |
|---|---|
| Propylene glycol monomethyl ether acetate | 9.21 |
| Ethyl lactate | 12.13 |
| Butyl acetate | 8.73 |
| 2-Heptanone (methyl amyl ketone) | 8.77 |
| Ethyl-3-ethoxypropionate | 9.14 |
| Propylene glycol monomethyl ether | 11.52 |
| Methyl 3-methoxypropionate | 9.46 |
| Cyclohexanone | 10.01 |
| Ethyl acetate | 8.98 |
| Propyl acetate | 8.84 |
| Isopropyl acetate | 8.74 |
| Isobutyl acetate | 8.65 |
| Pentyl acetate | 8.65 |
| Isopentyl acetate | 8.58 |
| Methyl 3-ethoxypropionate | 9.28 |
| 3-Methoxy-1-butanol | 11.00 |
| Ethylene glycol monomethyl ether | 12.32 |
| Propylene glycol monomethyl ether propionate | 9.08 |
| γ-Butyrolactone | 10.09 |
| Water | 21.15 |

When at least one of a solvent (C1), a solvent (C2) and an organic-based developer is a mixed solvent containing two or more solvents, the solubility parameter (SP value) can be calculated by a weighted average of the SP value of respective solvent constituting the mixed solvent.

That is, for example, when a mixed solvent is composed of solvent S1, S2, . . . , Sx, . . . , Sn and the mole fraction of the mixed solvent of solvent S1, S2, . . . , Sx, . . . , Sn is m1, m2, . . . , mx, . . . , mn, respectively, the SP value of the mixed solvent (SPmix) may be calculated by the following equation.

SPmix=Σ[(m1×S1)+(m2×S2)+ . . . +(mx×Sx)+ . . . +(mn×Sn)]

The resin (A) capable of increasing its polarity by an action of an acid to decrease the solubility in a developer containing an organic solvent in process (1) will be described in detail later.

The solvent (C1) is different from the solvent (C2) in the actinic ray-sensitive or radiation-sensitive resin composition to be described in detail later, and it is not particularly limited in the pattern forming method of the present invention as long as it has the solubility parameter so that the absolute value of the difference with the solubility parameter (SP_{C2}) of the organic the developer is 1 (cal/cm³)^{1/2} or less. The solvent (C1) usually contains an organic solvent. The solvent (C1) contains preferably one or more of the organic solvent selected from the group consisting of polar solvents such as a ketone-based solvent, an ester-based solvent, an alcohol-based solvent, an amide-based solvent, and an ether-based solvent, and a hydrocarbon-based solvent.

Examples of the ketone-based solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methyl cyclohexanone, phenyl acetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate and the like.

Examples of the ester-based solvent may include methyl acetate, butyl acetate, isobutyl acetate, ethyl acetate, propyl acetate, isopropyl acetate, pentyl acetate, isopentyl acetate, amyl acetate, cyclohexyl acetate, isobutyl isobutyrate, propylene glycol monomethyl ether acetate, propylene glycol monomethyl ether propionate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, formate methyl, ethyl formate, butyl formate, propyl formate, ethyl lactate, butyl lactate, propyl lactate, methyl 3-methoxy propionate, methyl 3-ethoxypropionate, γ-butyrolactone and the like.

Examples of the alcohol-based solvent may include alcohols such as methyl alcohol, ethyl alcohol, n-propyl alcohol, isopropyl alcohol, n-butyl alcohol sec-butyl alcohol, tert-butyl alcohol, isobutyl alcohol, n-hexyl alcohol, n-heptyl alcohol, n-octyl alcohol, n-decanol, or glycol-based solvents such as 3-methoxy-1-butanol, ethylene glycol, diethylene glycol, triethylene glycol, or glycol ether-based solvents such as ethylene glycol monomethyl ether, propylene glycol monomethyl other, ethylene glycol monoethyl ether, propylene glycol monoethyl ether, diethylene glycol monomethyl ether, triethylene glycol monoethyl ether, methoxymethyl butanol and the like.

Examples of the ether-based solvents may include, in addition to the glycol ether-based solvent, dioxane, tetrahydrofuran, phenetole, anisole, dibutyl ether and the like.

Examples of the amide-based solvent may include N-methyl-2-pyrrolidone, N,N-dimethylacetamide, N,N-dimethylformamide, hexamethylphosphoric triamide, 1,3-dimethyl-2-imidazolidinone and the like.

Examples of the hydrocarbon-based solvent may include an aromatic hydrocarbon-based solvent such as toluene, xylene, or aliphatic hydrocarbon-based solvent such as pentane, hexane, octane, and decane.

More preferred specific examples include ketone-based solvents such as 1-octanone, 2-octanone, 1-nonanone, 2-nonanone, 2-heptanone (methyl amyl ketone), 4-heptanone, 2-hexanone, diisobutyl ketone, cyclohexanone, methyl cyclohexanone, ester-based solvents suc as acetic acid butyl, isobutyl acetate, ethyl acetate, propyl acetate, amyl acetate, cyclohexyl acetate, phentyl aceate, isopentyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate, propyl lactate, methyl 3-methoxy propionate, methyl 3-ethoxy propionate, γ-butyrolactone, alcohol-based solvents such as n-butyl alcohol, sec-butyl alcohol, tert-butyl alcohol, isobutyl alcohol, n-hexyl alcohol, n-heptyl alcohol, n-octyl alcohol, n-decanol, 3-methoxy-1-butanol, glycol-based solvents such as ethylene glycol, diethylene glycol, triethylene glycol, glycol ether-based solvents such as ethylene glycol monomethyl ether, propylene glycol monomethyl ether, ethylene glycol monoethyl ether, propylene glycol monoethyl other, diethylene glycol monomethyl ether, triethylene glycol monoethyl ether, methoxymethyl butanol, ether-based solvents such as anisole, phenetole, dibutyl ether, amide-based solvents such as N-methyl-2-pyrrolidone. N,N-dimethylacetamide, N,N-dimethylformamide, aromatic hydrocarbon-based solvents such as xylene, aliphatic hydrocarbon-based solvents such as octane, decane, and the like.

The solvent (C1) are more preferably one or more solvents selected from the group consisting of butyl acetate, methyl amyl ketone, ethyl 3-ethoxy propionate, ethyl acetate, propyl acetate, isopropyl acetate, isobutyl acetate, pentyl acetate, isopentyl acetate, and methyl 3-methoxy propionate.

The absolute value of the difference between the solubility parameter (SP_{C1}) of the solvent (C1) and the solubility parameter (SP_{DEV}) of the organic-based developer to be described in detail later, (|SP_{C1}−SP_{DEV}|), is 0.80 (cal/cm³)^{1/2} or less, more preferably 0.60 (cal/cm³)^{1/2} or less, still more preferably 0.40 (cal/cm³)^{1/2} or less, particularly preferably 0.20 (cal/cm³)^{1/2} or less and particularly preferably 0 (cal/cm³)^{1/2} or less.

The solvent (C1) is preferably the same as the organic-based developer. Here, “the same” mean that solvent (C1) and an organic-based developer are completely identical.

Also, the pattern forming method of the present invention may have two or more processes (1). In this case, even when the solvent (C1) in at least one process of the two or more processes (1) is the same as the organic-based developer, it is considered that “solvent (C1) is the same as the organic-based developer”.

The solvent (C1) may be composed of a single solvent or may consist of two or more solvents. Also, the solvent (C1) may contain water.

However, in order to sufficiently exert the effect of the present invention, it is preferred that the water content ratio of the whole resin solution containing the resin (A) and the solvent (C1) is 10% by mass or less, and more preferably contains substantially no water.

That is, the amount of the organic solvent for the resin solution is preferably 9% to 100% by mass, and more preferably 95% to 100% by mass, based on the total amount of the resin solution.

The content of the resin (A) based on the total amount of the resin solution in process (1) is preferably 1% to 50% by mass more preferably 3% to 30% by mass, and still more preferably 5 to 15% by mass.

The filter in the process (1) is not particularly limited, but a fluorine-based resin filter, a polyamide-based resin filter (nylon resin filter), a polyolefin-based resin filter, and the filter formed by a combination of two or more of these and the like may be exemplified.

Examples of the fluorine-based resin filter may include suitably polytetrafluoroethylene (PTFE-made filter), for example ABDIUFD3E (manufactured by Japan Pall Corporation), ABD1IUFT3EN (manufactured by Japnan Pall Corporation) and the like.

Specific examples of the polyamide-based resin filter may include nylon 6,6-made filter manufactured by Japan Pall Corporation or polyamide resin filter described in [0026] of Japanese Patent Application Laid-open No. 2010-243866 and [0019] of Japanese Patent Application Laid-open No. 2010-164980, the contents of which are incorporated herein by reference.

The polyolefin-based resin filter may include suitably polyethylene-based resin filters, and polypropylene-based resin filter.

Specific examples of polyethylene-based resin filter may include polyethylene-based resin filter manufactured by Japan Entegris Corporation, and polyethylene-based resin filter described in [0027], etc. of Japanese Patent Application Laid-open No. 2010-243866, the contents of which are incorporated herein by reference.

Specific examples of polypropylene-based resin filters include polypropylene-based resin filter described in [0027], etc. of Japanese Patent Application Laid-open No. 2010-243866, the contents of which are incorporated herein by reference.

Moreover, the filter in process (1) may be a filter made of a porous membrane having an anion exchange group or a cation exchange group.

Examples of the anion-exchange group may include anion exchange groups (basic anion exchange groups) such as quaternary ammonium groups.

Examples of the cation exchange group may include a strongly acidic cation exchange group such as a sulfonic acid, a weakly acidic cation exchange group such as a carboxyl group and the like.

Examples of the porous membrane may include a fluorine-based resin film, a polyamide-based resin film, a polyolefin-based resin layer and the like.

The filter made of a porous membrane having an anion exchange group is preferably hydrophilic, and, for example, the trade name “Ion Clean AN” (porous polyolefin film) manufactured by Japan Pall Corporation is suitably used.

The filter made of a porous membrane having a cation-exchange group is preferably hydrophilic, and, for example, the trade name “Ion Clean SL” (porous polyolefin film) manufactured by Japan Pall Corporation is preferably used.

The pore size of the filter is preferably 100 nm (0.1 μm) or less, more preferably 50 nm or less, and still more preferably 30 nm or less.

The filter may be a multi-stage filter trade by combining a plurality thereof.

The filter in process (1) is preferably a filter containing a polyamide-based resin filter or polyethylene-based resin filter.

In the filtration through a filter, as described in, for example, Japanese Patent Application Laid-Open No. 2002-62667, circulating filtration may be performed, or the filtration may be performed by connecting a plurality of kinds of filters in series or in parallel. In addition, the composition may be filtered a plurality of times. Furthermore, a deacration treatment or the like may be applied to the composition before or after filtration through a filter.

In a case where the pattern forming method of the present invention has two or more times of the process (1), the method may have two or more times of the process (1), in which the respective solvents (C1) are different. Here, “the respective solvents (C1) are different” means that in the two or more times of the process, the respective solvents (C1) are not completely identical.

If the pattern forming method of the present invention has one time of the process (1), it is preferred that the absolute value of the difference between the solubility parameter (SP_{C1}) of the solvent (C1) and the solubility parameter (SP_{C2}) of the solvent (C2), (|SP_{C1}−SP_{C2}|), is 0.40 (cal/cm³)^{1/2} or more. When the pattern forming method of the present invention has two or more times of the process (1), it is preferred that, in at least one of the two or more times of the process, the absolute value of the difference between the solubility parameter (SP_{C1}) of the solvent (C1) and the solubility parameter (SP_{C2}) of the solvent (C2), (|SP_{C1}−SP_{C2}|), is 0.40 (cal/cm³)^{1/2} or more.

The upper limit of the absolute value (|SP_{C1}−SP_{C2}|) is not particularly limited, but the absolute value (|SP_{C1}−SP_{C2}|) is generally 5.00 (cal/cm³)^{1/2}.

Furthermore, the pattern forming method of the present invention may have (0) a process of heating the resin solution provided in process (1), prior to step (1). The heating temperature in process (0) is usually from 30 to 90° C., and the heating time is usually 30 minutes to 12 hours.

The resin (A) provided in the process (2) is obtained by the filtrate in the process (1). More specifically, it is preferably obtained by mixing the filtrate with a large amount of poor solvent (more specifically, a poor solvent to the resin), re-precipitating the resin (A) and subjecting to known filtering and drying processes.

Then, the resin (A) obtained by the filtrate in the process (1), the solvent (C2) and other components which will be described in detail later, are mixed to prepare the actinic ray-sensitive or radiation-sensitive resin composition described in detail later.

The filter for obtaining the filtrate in the process (3) is not particularly limited, but those described for the filter in the process (1) can be equally used, and preferred examples are also the same. Further, specific method for filtration is also the same as those described in the process (1).

In the process (4), the film (resist film) is formed from the actinic ray-sensitive or radiation-sensitive resin composition which will be described in detail later. More specifically, a film formed by applying the actinic ray-sensitive or radiation-sensitive resin composition on the substrate is preferred. In the pattern forming method of the present invention, the process of forming a film by the actinic ray-sensitive or radiation-sensitive resin composition on a substrate may be carried out by methods which are generally known. Examples thereof may include conventionally known spin coating, spraying, roller coating, dipping and the like. It is preferred to use the spin coating method.

In the present invention, the substrate on which the film is formed is not particularly limited, and it is possible to use an inorganic substrate such as silicone, SiN, SiO₂ or SiN, a coating-type inorganic substrate such as SOG, or a substrate generally used in the process of manufacturing a semiconductor such as IC or manufacturing a liquid crystal or a circuit board such as a thermal head or in the lithography process of other photo-fabrication processes. Furthermore, if necessary, an organic antireflection film may be formed between the film and the substrate. As the antireflection film, a known organic, inorganic anti-reflection film can be appropriately used.

The pattern forming method of the present invention preferably comprises a pre-baking (PB) process between the process (4) and the process (5).

Also, the pattern forming method of the present invention preferably comprises a post-exposure baking (PEB) process between the process (5) and the process (6).

As for the heating temperature, both PB and PEB are performed at preferably 70 to 130° C. and more preferably 80 to 120° C.

The heating time is preferably 30 to 30) seconds, more preferably 30 to 180 seconds, and more preferably 30 to 90 seconds.

The heating may be performed using a means equipped with a typical exposure and development machine, or may be performed using a hot plate or the like.

By means of baking, the reaction in the exposed portion is accelerated, and thus the sensitivity or a pattern profile is improved.

The pattern forming method of the present invention may comprise plural times of the process (5).

The pattern forming method of the present invention may comprise plural times of the post-exposure heating process.

The light source wavelength used in the exposure apparatus in the process (5) is not limited, but examples thereof may include an infrared light, visible light, ultraviolet light, far ultraviolet light, an extreme-ultraviolet light, X-ray, an electron beam and the like, and the light source wavelength is preferably far ultraviolet light at a wavelength of preferably 250 nm or less, more preferably 220 nm or less, and particularly preferably from 1 nm to 200 nm. Specific examples thereof include a KrF excimer laser (248 am), an ArF excimer laser (193 n), an F₂ excimcr laser (157 nm), an X-ray, an EUV (13 nm), an electron beam and the like, and a KrF excimer laser, an ArF excimer laser, an EUV or an electron beam is preferred, and an ArF excimer laser is more preferred.

In addition, in the process (5), a liquid immersion exposure method may be applied. The immersion exposure method may be combined with a super-resolution technique such as a phase shift method, or a modified illumination method.

In the case of performing liquid immersion exposure, a process of washing the surface of the film with an aqueous chemical solution may be performed (1) before forming the film on a substrate and then performing exposure and/or (2) after the process of exposing the film through a liquid for liquid immersion but before the process of heating the film.

The liquid for liquid immersion is preferably a liquid which is transparent to light at the exposure wavelength and has a temperature coefficient of refractive index as small as possible in order to minimize the distortion of an optical image projected on the film, and particularly, when the exposure light source is an ArF excimer laser (wavelength; 193 nm), water is preferably used from the viewpoint of easy availability and easy handleability in addition to the above-described viewpoint.

When water is used, an additive (liquid) capable of decreasing the surface tension of water and increasing the interfacial activity may be added in a small ratio. It is preferred that the additive does not dissolve the resist layer on the wafer and has only a negligible effect on the optical coat at the undersurface of the lens element.

Such an additive is preferably an aliphatic alcohol having a refractive index almost equal to that of, for example, water, and specific examples thereof include methyl alcohol, ethyl alcohol, isopropyl alcohol and the like. By adding an alcohol having a refractive index almost equal to that of water, even when the alcohol component in water is evaporated and the content concentration thereof is changed, it is possible to obtain an advantage in that the change in the refractive index of the liquid as a whole may be made very small.

Meanwhile, when a substance opaque to light at 193 nm or an impurity greatly differing from water in the refractive index is incorporated, the incorporation incurs distortion of the optical image projected on the resist, and thus, the water used is preferably distilled water. Furthermore, pure water filtered through an ion exchange filter or the like may also be used.

The electrical resistance of water used as the liquid for liquid immersion is preferably 18.3 MΩcm or more, and TOC (organic concentration) is preferably 20 ppb or less and the water is preferably subjected to deacration treatment.

Further, the lithography performance may be enhanced by raising the refractive index of the liquid for liquid immersion. From this viewpoint, an additive for raising the refractive index may be added to water, or heavy water (D₂O) may be used in place of water.

The receding contact angle of the resist film formed using the actinic ray-sensitive or radiation-sensitive resin composition of the present invention is 70° or more at a temperature of 23±3° C. and a humidity of 45±5%, which is suitable for exposure via an immersion medium, preferably at 75° or more, and more preferably 75 to 85 °.

When the receding contact angle is too small, it cannot be suitably used when it is exposed to light via an immersion medium, and it is impossible to sufficiently exhibit the effect of reducing the water remaining (watermark) defects. In order to achieve the preferred receding contact angle, it is preferred to include the hydrophobic resin (HR) in the actinic ray-sensitive or radiation-sensitive composition. Alternatively, on the resist film, it is also preferred to improve the receding contact angle by forming a coating layer (so-called “top coat”) by a hydrophobic resin composition.

In the liquid immersion exposure process, the liquid for liquid immersion needs to move on a wafer following the movement of an exposure head that scans on the wafer at a high speed and forms an exposure pattern, and thus the contact angle of the liquid for liquid immersion for the resist film in a dynamic state is important, and the resist requires a performance of following the high-speed scanning of the exposure head, while a liquid droplet no longer remains.

In the process (6), examples of the organic-based developer contains preferably at least one of the organic solvents selected from the group consisting of a polar solvent such as a ketone-based solvent, an ester-based solvent, a alcohol-based solvent, an amide-based solvent, and an ether-based solvent, and a hydrocarbon-based solvent. Specific examples and preferred examples of these solvents are the same as in the above-described solvent (C1).

In particular, the organic-based developer is preferably a developer containing at least one of the organic solvents selected from the group consisting of a ketone-based solvent, an ester-based solvent, an alcohol-based solvent, an amide-based solvent and an ether-based solvent, more preferably at least one of the organic solvents selected from the group consisting of a ketone-based solvent and an ether-based solvent, and particularly preferably a developer containing butyl acetate as an ester-based solvent and methyl amine ketone (2-heptanone) as a ketone-based solvent.

The organic-based developer may consist of a single solvent or may consist of two or more solvents. Also, the organic-based developer may contain water in addition to athe organic-based solvent.

However, in order to sufficiently exhibit the effects of the present invention, the water content ratio of the entire developer is preferably less than 10% by mass, and it is more preferred that the developer contains substantially no moisture.

That is, the amount of the organic solvent used in the organic-based developer is preferably 90% by mass to 100% by mass, and preferably 95% by mass to 100% by mass, based on the total amount of the developer.

The vapor pressure of the organic-based developer is preferably 5 kPa or less, more preferably 3 kPa or less, and particularly preferably 2 kPa or less, at 20° C. By adjusting the vapor pressure of the organic-based developer to 5 kPa or less, evaporation of the developer on a substrate or in a development cup is suppressed so that temperature uniformity in the wafer plane is enhanced, and as a result, the dimensional uniformity in the wafer plane is improved.

In the organic-based developer, a surfactant may be added in an appropriate amount, if necessary.

The surfactant is not particularly limited but, for example, ionic or nonionic fluorine-based and/or silicon-based surfactant and the like may be used. Examples of the fluorine and/or silicone-based surfactants include surfactants described in Japanese Patent Application Laid-Open Nos. S62-36663. S61-226746, S61-226745. S62-170950, S63-34540. H7-230165, 1H8-62834, H9-54432, and H9-5988 and U.S. Pat. Nos. 5,405,720, 5,360,692, 5,529,881, 5,296,330, 5,436,098, 5,576,143, 5,294,511 and 5,824,451, and a nonionic surfactant is preferred. The nonionic surfactant is not particularly limited, but a fluorine-based surfactant or a silicone-based surfactant is more preferably used.

The amount of the surfatctant used is usually 0.001 to 5% by mass, preferably 0.005 to 2% by mass, and more preferably 0.01 to 0.5% by mass, based on the total amount of the developer.

In addition, the organic-based developer may be an aspect including a nitrogen-containing compound as illustrated in paragraphs [0041] to [0063] of Japanese Patent No. 5,056,974. It can be expected that such aspect improves the contrast during development and suppresses the thickness reduction.

As for the developing method, it is possible to apply, for example, a method of dipping a substrate in a bath filled with a developer for a predetermined time (a dipping method), a method of raising a developer on a substrate surface by the effect of a surface tension and keeping the substrate still for a predetermined time, thereby performing development (a puddle method), a method of spraying a developer on a substrate surface (a spray method), a method of continuously ejecting a developer on a substrate spinning at a constant speed while scanning a developer ejecting nozzle at a constant rate (a dynamic dispense method) and the like.

When the above-described various developing methods include a process of ejecting a developer toward a resist film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, and still more preferably 1 ml/sec/mm² or less. The lower limit of the flow velocity is not particularly limited, but is preferably 0.2 mL/sec/mm² or more in consideration of throughput More information on this is described in paragraphs [0022] to [0029] of Japanese Patent Application Laid-Open No. 2010-232550.

In addition, after the process of performing development using a developer including an organic solvent, a process of stopping the development while replacing the solvent with another solvent may be performed.

The pattern forming method of the present invention may further have a process of performing development using an alkali developer. In this case, the order of the process (6) and the process of performing development using an alkaline developer is not particularly limited.

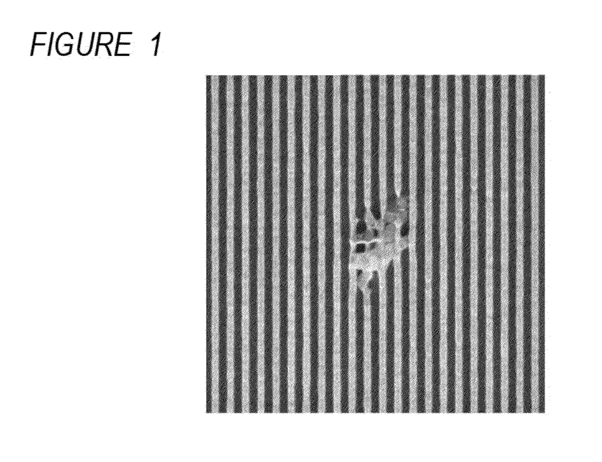

In the present invention, when the process of development using an alkaline developer is generally performed, a positive-type pattern is formed. Thus, when performing the process of development with an alkali developer in addition to the process (6), it is possible to obtain a pattern having twice the resolution of the frequency of the optical aerial image as described in FIG. 1 to FIG. 11, etc. of U.S. Pat. No. 8,227,183.

When the pattern forming method of the present invention further includes a process of performing development using an alkali developer, the available alkali developer is not particularly limited, but an aqueous solution of 2.38% by mass of tetramethylammonium hydroxide is generally used. However, those of other concentrations (for example, thinner concentration) can also be used. Furthermore, alcohols and a surfactant may be added to the alkaline aqueous solution each in an appropriate amount and the mixture may be used.

The alkali concentration of the alkali developer is usually 0.1 to 20% by mass.

The pH of the alkali developer is usually 10.0 to 15.0.

As for the rinse liquid in the rinsing treatment performed after the alkali development, pure water is used, and an appropriate amount of a surfactant may be added thereto to use the mixture.

Further, after the development treatment or rinsing treatment, a treatment of removing the developer or rinse liquid adhering on the pattern by a supercritical fluid may be performed.

It is preferred that a process of rinsing the resist using a rinse liquid is included after the process (6). The rinse liquid is not particularly limited as long as the rinse liquid does not dissolve the resist pattern, and a solution including a general organic solvent may be used. As for the rinse liquid, a rinse liquid containing at least one of the organic solvents selected from the group consisting of a hydrocarbon-based solvent, a ketone-based solvent, an ester-based solvent, an alcohol-based solvent, an amide-based solvent and an ether-based solvent is preferably used.

Specific examples of the hydrocarbon-based solvent, the ketone-based solvent, the ester-based solvent, the alcohol-based solvent, the amide-based solvent and the ether-based solvent are the same as those described above for the developer including an organic solvent.

After the process (6), a process of performing rinsing using a rinse liquid containing at least one of organic solvents selected from the group consisting of a ketone-based solvent, an ester-based solvent, an alcohol-based solvent and an amide-based solvent is more preferably performed, a process of performing rinsing using a rinse liquid containing an alcohol-based solvent or an ester-based solvent is still more preferably performed, a process of performing rinsing using a rinse liquid containing a monohydric alcohol is particularly preferably performed, and a process of performing rinsing using a rinse liquid containing a monohydric alcohol having 5 or more carbon atoms is most preferably performed.

Here, examples of the monohydric alcohol used in the rinsing process may include a straight, branched or cyclic monohydric alcohol, and specifically, it is possible to use I-hexanol, 2-hexanol, 4-methyl-2-pentanol, 1-pentanol, 3-methyl-1-butanol and the like.

A plurality of the components may be mixed, or the components may be used in mixture with an organic solvent other than those described above.

The water content ratio in the rinse liquid is preferably 10% by mass or less, more preferably 5% by mass or less, and particularly preferably 3% by mass or less. By setting the water content ratio to 10% by mass or less, good development characteristics may be obtained.

The vapor pressure of the rinse liquid used after the process of performing development using a developer including an organic solvent is preferably 0.05 kPa to 5 kPa, more preferably 0.1 kPa to 5 kPa, and most preferably 0.12 kPa to 3 kPa, at 20° C. By setting the vapor pressure of the rinse liquid to 0.05 kPa to 5 kPa, the temperature uniformity in the wafer plane is enhanced, and furthermore, swelling caused by permeation of the rinse liquid is suppressed, and as a result, the dimensional uniformity in the wafer plane is improved.

The rinse liquid may also be used by adding an appropriate amount of a surfactant thereto.

In the rinsing process, the wafer subjected to development using a developer including an organic solvent is rinsed by using the aforementioned rinse liquid including an organic solvent. The method of rinsing treatment is not particularly limited, but it is possible to apply, for example, a method of continuously ejecting a rinse liquid on a substrate spinning at a constant speed (spin coating method), a method of dipping a substrate in a bath filled with a rinse liquid for a predetermined time (dipping method), a method of spraying a rinse liquid on a substrate surface (spraying method), and the like. Among them, it is preferred that the rinsing treatment is performed by the spin coating method and after the rinsing, the substrate is spun at a rotational speed of 2,000 rpm to 4,000 rpm to remove the rinse liquid from the substrate. Furthermore, it is also preferred that a heating process (post bake) is included after the rinsing process. The developer and rinse liquid remaining between patterns and in the inside of the pattern are removed by the bake. The heating process after the rinsing process is performed at usually 40 to 160° C., and preferably 70 to 95° C. for usually 10 seconds to 3 minutes, and preferably 30 to 90 seconds.

The organic-based developer, the alkali developer and/or the rinse liquid used in the present invention are preferably those having a low content of impurities such as various particles and metal elements. In order to obtain such chemical solutions having low content of impurities, these chemical solutions are produced in a clean room, and it is preferred to reduce the content of impurities by performing filtration by various filters such as a Teflon filter, a polyolefin based filter or an ion exchange filter. As the metal elements, the metallic element concentration of Na, K, Ca, Fe, Cu, Mg, Mn, Li, Al, Cr, Ni and Zn are all preferably 10 ppm or less, and more preferably 5 ppm or less.

Also, the storage container of the developer and the rinse liquid is not particularly limited, and containers such as a polyethylene resin, a polypropylene resin, a polyethylene-propylene resin which are used for electronic materials can be properly used, but in order to reduce impurities eluted from the chemical solution, it is preferred to select a container containing a small amount of components eluted from the inner wall of the container. Such containers may include a container in which the inner wall thereof is a perfluoro resin (for example, Fluoro Pure PFA complex drum (wetted inner face; PFA resin lining) manufactured by Entegris Inc., steel drums (wetted inner face; zinc phosphate coating film) manufactured by JFE Corporation).

The pattern obtained by the pattern forming method of the present invention is generally properly used as an etching mask of a semiconductor device, but can also be used in other applications. Other applications include, for example, a guide pattern formation in the DSA (Directed Self-Assembly) (see, for example, ACS Nano Vol. 4 No. 8 Page4815-4823), used as a core material of the so-called spacer process (see, for example. Japanese Patent Application Laid-Open Nos. H 3-270227 and 2013-164509), and the like.

Further, the present invention relates to a method of manufacturing an electronic device comprising the pattern forming method of the present invention as described above, and an electronic device manufactured by this manufacturing method.

The electronic devices of the present invention is properly mounted in the electrical and electronic equipment (home appliances, OA-media-related equipment, optical equipment and communication equipment, etc.).

<Actinic Ray-Sensitive or Radiation-Sensitive Resin Composition>

Hereinafter, the actinic ray-sensitive or radiation-sensitive resin composition used in the pattern forming method of the present invention will be described.

The actinic ray-sensitive or radiation-sensitive resin composition is typically a negative-type actinic ray-sensitive or radiation-sensitive resin composition (i.e., an actinic ray-sensitive or radiation-sensitive resin composition for organic solvent development), and it is preferably a negative-type resist composition (i.e., a resist composition for organic solvent development). Also, the actinic ray-sensitive or radiation-sensitive resin composition is typically a resist composition, and preferably a chemically amplified resist composition.

More specifically, the actinic ray-sensitive or radiation-sensitive resin composition for organic solvent development according to the present invention is an actinic ray-sensitive or radiation-sensitive resin composition for organic solvent development containing (A) a resin capable of increasing its polarity by an action of an acid to decrease the solubility in the developer including an organic solvent, and (C2) a solvent, wherein the resin (A) is a resin obtained by filtering “a resin solution containing a resin (A), and a solvent (C2) that is different from the solvent (C1)” using a filter.

In the actinic ray-sensitive or radiation-sensitive resin composition for organic solvent development according to the present invention, the solvent (C1) is preferably at least one of the solvents selected from the group consisting of a butyl acetate, a methyl amyl ketone, an ethyl 3-ethoxy propionate, an ethyl acetate, a propyl acetate, an isopropyl acetate, an isobutyl acetate, a pentyl acetate, an isopentyl acetate, and a methyl 3-methoxy propionate.

[1]A resin (A) capable of increasing a polarity by the action of an acid to decrease the solubility in the developer containing an organic solvent

As the resin (A) capable of increasing a polarity by the action of an acid to decrease the solubility in the developer containing an organic solvent, which are contained in the actinic ray-sensitive or radiation-sensitive resin composition, for example, a resin having a group capable of decomposing by the action of an acid to generate a polar group (hereinafter, referred to as “acid-decomposable group”) in the main chain or side chain, or both the main chain and side chain of the resin (hereinafter, referred to as “acid-decomposable resin” or “resin (A)”) can be mentioned.

The acid-decomposable group preferably has a structure protected by a group capable of decomposing and leaving a polar group by the action of an acid.

The polar group is not particularly limited as long as it is sparingly soluble or insoluble in the organic solvent-containing developer, but acidic groups (conventionally used as a resist developer, a group capable of dissociating in 2.38% by mass of tetramethylamonium hydroxide aqueous solution) such as a phenolic hydroxyl group, a carboxyl group, a fluorinated alcohol group (preferably hexafluoroisopropanol group), a sulfonate group, a sulfonamide group, a sulfonylimide group, an (alkylsulfonyl) (alkylcarbonyl)methylene group, (alkylsulfonyl)(alkylcarbonyl)imide group, a bis(alkylcarbonyl)methylene group, bis(alkylcarbonyl)imide group, a bis(alkylsulfonyl)methylene group, bis(alkylsulfonyl)imide group, or a tris(alkylcarbonyl)methylene group, or an alcoholic hydroxyl group.

Further, the alcoholic hydroxyl group refers to a hydroxyl group other than a hydroxyl group (phenolic hydroxyl group) bonded directly to the aromatic ring as a hydroxyl group bonded to a hydrocarbon group, and excludes an aliphatic alcohol substituted with an electron withdrawing group such as a fluorine atom at α-position of the hydroxyl group (for example, fluorinated alcohol group (hexafluoroisopropanol group, etc.)). The alcoholic hydroxyl group is preferably a hydroxyl group having pKa of 12 or more and 20 or less.

Preferred examples of the polar group may include a carboxyl group, a fluorinated alcohol group (preferably, hexafluoroisopropanol group), or a sulfonic acid group.

A preferred group as the acid-decomposable group is a group substituted by a group in which a hydrogen atom in these groups is capable of leaving by the acid.

Examples of the group capable of leaving from the acid may include —C(R₃₆)(R₃₇)(R₃₈), —C(R₃₆)(R₃₇)(OR₃₉), —C(R₀₁)(R₀₂)(OR₃₉) and the like.

In the formula, each of R₃₆ to R₃₉ independently represents an alkyl group, a cycloalkyl group, an aryl group, an aralkyl group or an alkenyl group. R₃₆ and R₃₇ may be bonded to each other to form a ring.

Each of R₀₁ and R₀₂ independently represents a hydrogen atom, an alkyl group, a cycloalkyl group, an aryl group, an aralkyl group or an alkenyl group.

The alkyl group of R₃₆ to R₃₉, R₀₁ and R₀₂ is preferably an alkyl group having 1 to 8 carbon atoms, and examples thereof may include a methyl group, an ethyl group, a propyl group, a n-butyl group, a sec-butyl group, a hexyl group, an octyl group and the like.

The cycloalkyl groups of R₃₆ to R₃₉, R₀₁ and R₀₂ may be a monocyclic type or a polycyclic type. The monocyclic type is preferably a cycloalkyl group having 3 to 8 carbon atoms, and examples thereof may include a cyclopropyl group, a cyclobutyl group, a cyclopentyl group, a cyclohexyl group, a cyclooctyl group and the like. The polycyclic type is preferably a cycloalkyl group having 6 to 20 carbon atoms, and examples thereof may include an adamantyl group, a norbornyl group, an isobornyl group, a camphanyl group, a dicyclopentyl, an α-pinel group, a tricyclodecanyl group, a tetracyclododecyl group, an androstanyl group and the like. In addition, at least one carbon atom in the cycloalkyl group may be substituted with a heteroatom such as an oxygen atom.

The aryl group of R₃₆ to R₃₉, R₀₁ and R₀₂ is preferably an aryl group having 6 to 10 carbon atoms, and examples thereof may include a phenyl group, a naphthyl group, an anthryl group and the like.

The aralkyl group of R₃₆ to R₃₉, R₀₁ and R₀₂ is preferably an aralkyl group having 7 to 12 carbon atoms, and examples thereof may include a benzyl group, a phenethyl group, a naphthylmethyl group and the like.

The alkenyl group of R₃₆ to R₃₉, R₀₁ and R₀₂, is preferably an alkenyl group having 2 to 8 carbon atoms, and examples thereof may include a vinyl group, an allyl group, a butenyl group, a cyclohexenyl group and the like.

The ring formed by R₃₆ and R₃₇ bonded to each other is preferably a cycloalkyl group (monocyclic or polycyclic). The cycloalkyl group is preferably a monocyclic cycloalkyl group such as a cyclopentyl group or a cyclohexyl group, or a polycyclic cycloalkyl group such as a norbornyl group, a tetracyclodecanyl group, tetracyclododecanyl group, or an adamantyl group, more preferably a monocyclic cycloalkyl group having 5 to 6 carbon atoms, and particularly preferably a monocyclic cycloalkyl group having 5 carbon atoms.

The acid-decomposable group is preferably a cumyl ester group, an enol ester group, an acetal ester group, a tertiary alkyl ester group and the like, and more preferably a tertiary alkyl ester group.

The resin (A) preferably has a repeating unit having an acid-decomposable group.

Also, the resin (A) is a repeating unit having an acid-decomposable group, and it is preferred to have a repeating unit represented by the following general Formula (AI). Repeating unit represented by Formula (AI) generates a carboxyl group as a polar group by the action of an acid, and exhibits a high interaction by hydrogen bonding in a plurality of carboxyl groups and thus the glass transition temperature (Tg) of the resin (A) can be more improved. As a result, although a film is deposited by a CVD method around the resist pattern (in particular, high temperature CVD method), a high rectangularity of the sectional shape of the resist pattern is more hardly impaired by heat during the growth of the film. As a result, an increase in process cost can be more suppressed.

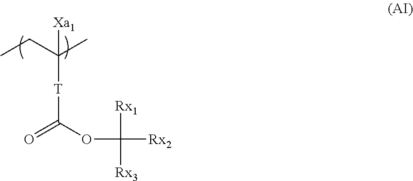

In Formula (AI),

Xa₁ represents a hydrogen atom, an alkyl group, a cyano group or a halogen atom.

T represents a single bond or a divalent linking group.

Each of Rx₁ to Rx₃ independently represents an alkyl group or a cycloalkyl group.

Two of Rx₁ to Rx₃ may be bonded to each other to form a ring structure.

The divalent linking group of T includes an alkylene group, —COO-Rt-group, —O-Rt-group, a phenylene group and the like. In the formula, Rt represents an alkylene group or a cycloalkylene group.

T represents preferably a single bond or —COO-Rt-group. Rt is preferably an alkylene group having 1 to 5 carbon atoms, and more preferably —CH₂— group, —(CH₂)₂— group or —(CH₂)₃— group. T is more preferably a single bond.

The alkyl group of Xₐ₁ may or may not have a substituent, and examples of the substituent may include a hydroxyl group, a halogen atom (preferably fluorine atom).

The alkyl group of Xₐ₁ is preferably those having 1 to 4 carbon atoms, and examples thereof may include a methyl group, an ethyl group, a propyl group, a hydroxymethyl group or a trifluoromethyl group and the like, but a methyl group is preferred.

Xₐ₁ is preferably a hydrogen atom or a methyl group.

The alkyl group of Rₓ₁, Rₓ₂ and Rₓ₃ may be straight or branched, and has preferably 1 to 4 carbon atoms, for example, a methyl group, an ethyl group, a n-propyl group, an isopropyl group, a n-butyl groups, an isobutyl group, a t-butyl group and the like.

The cycloalkyl group of Rₓ₁, Rₓ₂ and Rₓ₃ is preferably a monocyclic cycloalkyl group such as a cyclopentyl group, or a cyclohexyl group, and a polycyclic cycloalkyl group such as a norbonyl group, a tetracyclodecanyl group, a tetracyclododecanyl group, or an adamantyl group.

The ring structure formed by combining two of Rₓ₁, Rₓ₂ and Rₓ₃ with each other is preferably a monocyclic cycloalkane ring such as a cyclopentyl ring, or a cyclohexyl ring, or a polycyclic cyloalkyl group such as a norbornane ring, a tetracyclodecane rings, a tetracyclododecanyl group or an adamantane ring. A monocyclic cycloalkane ring having 5 or 6 carbon atoms is particularly preferred.

Each of Rₓ₁, Rₓ₂ and Rₓ₃ independently is preferably an alkyl group, and more preferably a straight or branched alkyl group having 1 to 4 carbon atoms.

Each of the above-described group may have a substituent, and examples of the substituent may include an alkyl group (having 1 to 4 carbon atoms), a cycloalkyl group (having 3 to 8 carbon atoms), a halogen atom, an alkoxy group (having 1 to 4 carbon atoms), a carboxyl group, an alkoxycarbonyl group (having 2 to 6 carbon atoms) and the like. The group having 8 or less carbon atoms is preferred. Among them, from the viewpoint of further improving the dissolution contrast to a developer containing an organic solvent before and after acid decomposition, a substituent having no heteroatoms such as an oxygen atom, a nitrogen atom, and a sulfur atom is preferred (for example, the group which is not an alkyl group substituted with a hydroxyl group is more preferred). A group consisting only of hydrogen and carbon atoms is more preferred, and straight or branched alkyl group or cycloalkyl group are especially preferred.

Specific examples of the repeating unit represented by Formula (at) are shown below, but the present invention is not limited to these specific examples

In the specific examples, Rx represents a hydrogen atom, CH₃, CF₃, or CH₂OH. Rxa and Rxb represent an alkyl group having 1 to 4 carbon atoms, respectively. Xa₁ represents a hydrogen atom, CH₃, CF₃ or CH₂OH. Z represents a substituent other than the polar group, if a plurality of Z's is present, the plurality of Z's may be same or different, p represents 0 or a positive integer. Specific examples and preferred examples of Z are the same as specific examples and preferred examples of the substituent which may be possessed by each group, such as Rx₁ to Rx₃.

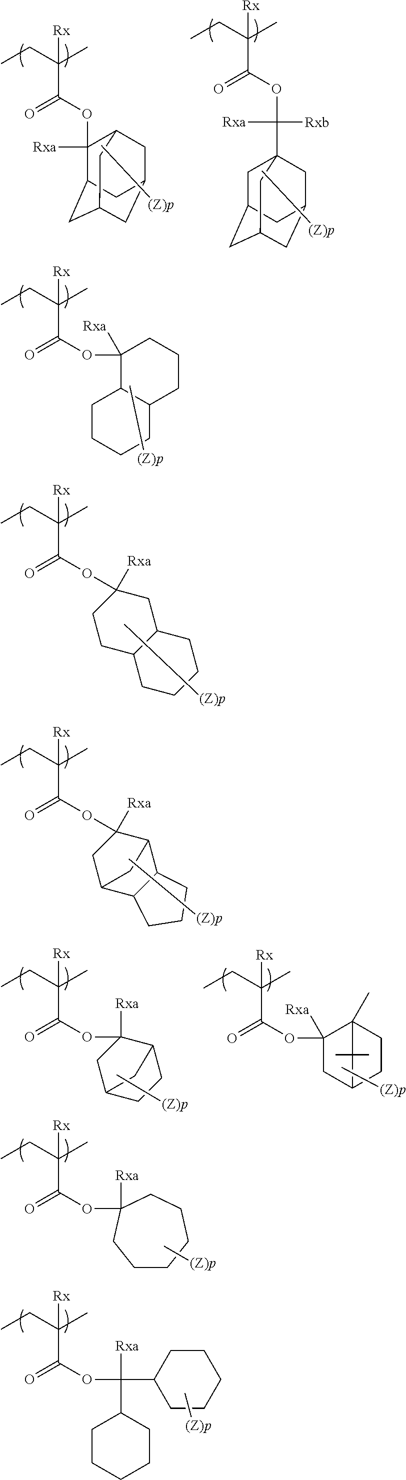

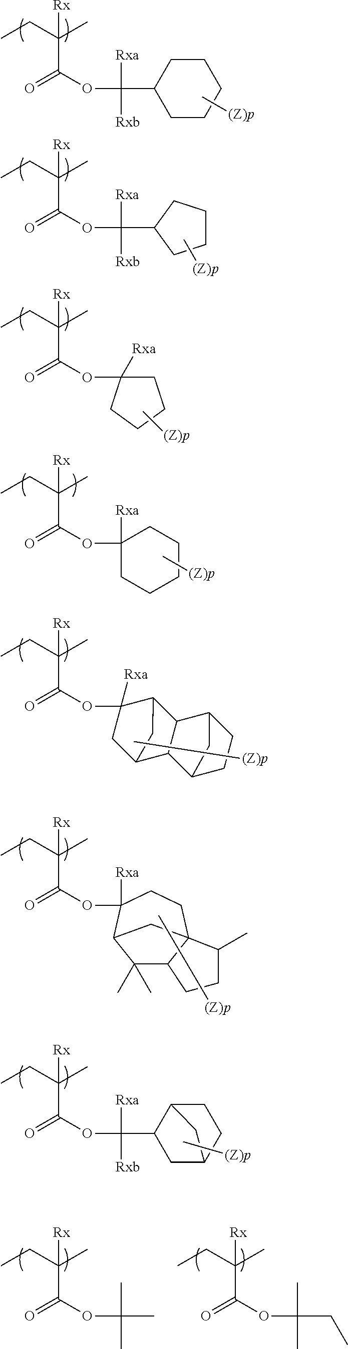

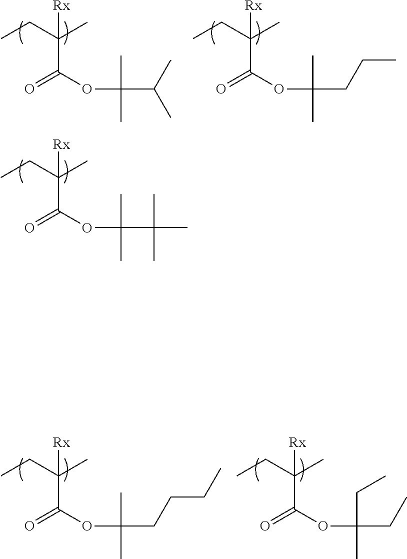

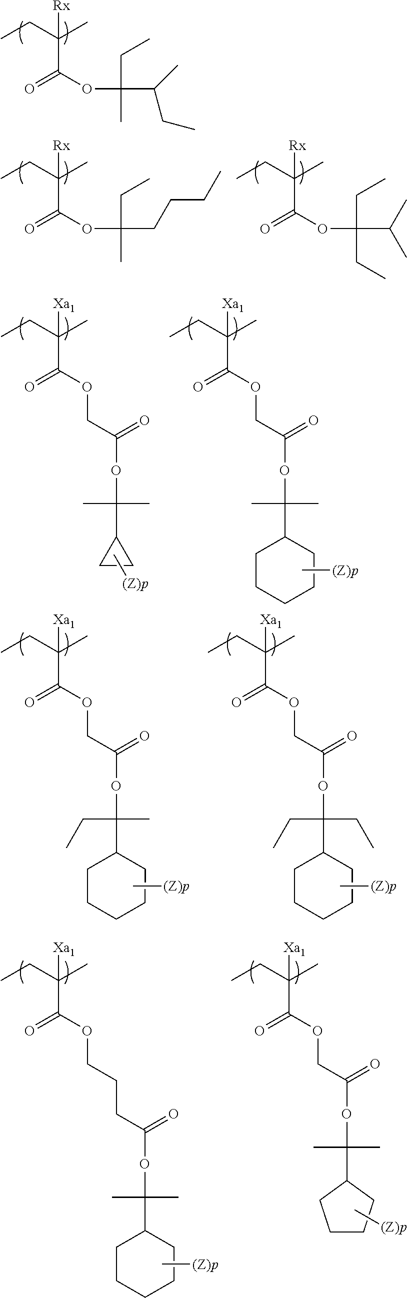

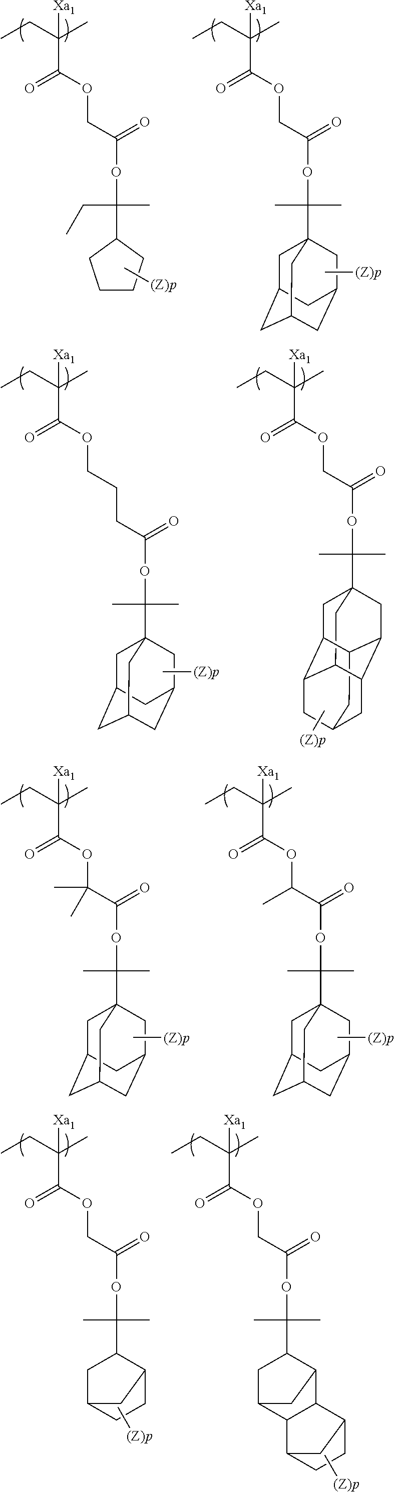

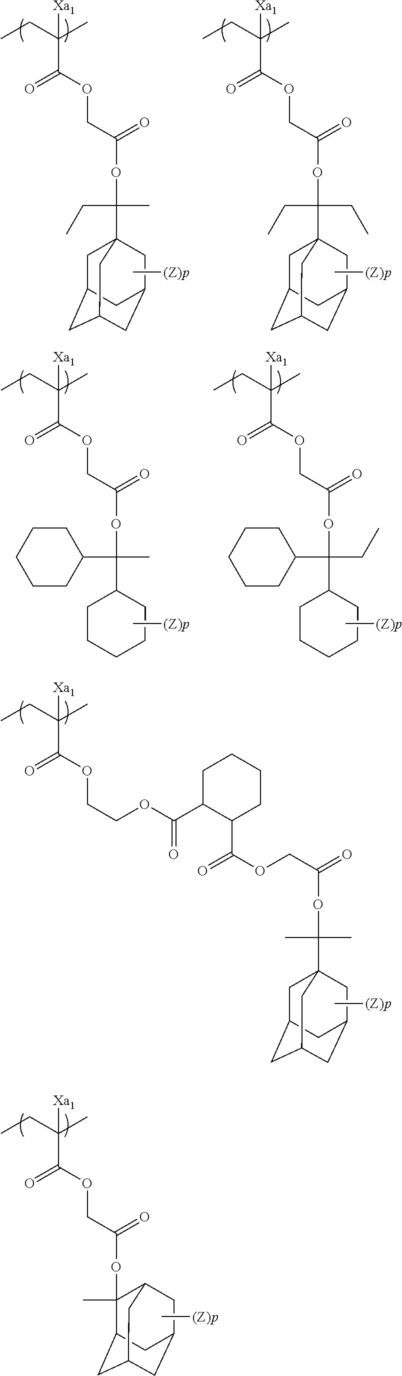

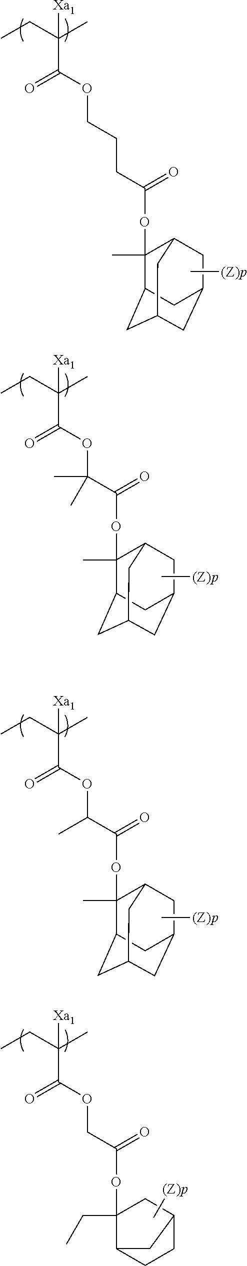

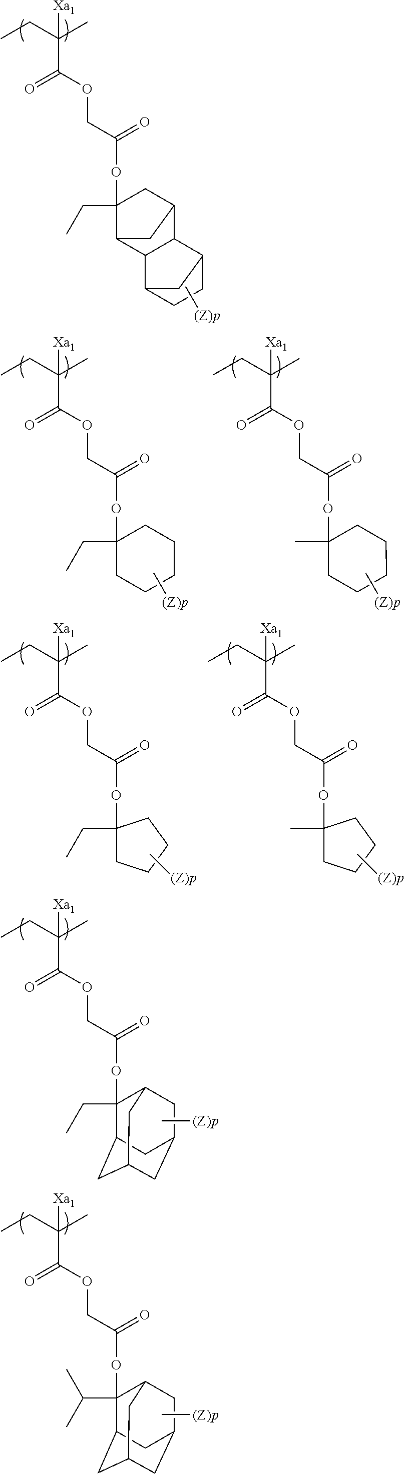

Further, the resin (A) preferably has a repeating unit represented by the following Formula (IV) as the repeating unit having an acid-decomposable group.

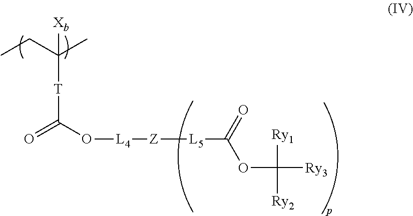

In Formula (IV), X_{b} represents a hydrogen atom, an alkyl group, a cyano group or a halogen atom.

Each of R_{y1} to R_{y3} independently represents an alkyl group or a cycloalkyl group. Two of R_{y1} to R_{y3} may combine with each other to form a ring.

Z represents a linking group having a polycyclic hydrocarbon structure that may have a heteroatom as a (p+1)-valent ring member. Z may be an atomic group constituting a polycyclic, and preferably the group having no ester bond (in other words, Z is a ring constituting the polycyclic, and preferably does not contain a lactone ring).

Each of L₄ and L₅ independently represents a single bond or a divalent linking group.

p represents an integer of 1 to 3.

When p is 2 or 3, each of L₅, R_{y1}, R_{y2} and R_{y3} may be the same as or different from every other of L₅, R_{y1}, R_{y2} and R_{y3}.

The alkyl group of X_{b} may have a substituent, and examples of the substituent may include a hydroxyl group, a halogen atom (preferably fluorine atom).

The alkyl group of X_{b} is preferably those having 1 to 4 carbon atoms, and examples thereof may include a methyl group, an ethyl group, a propyl group, a hydroxymethyl group or a trifluoromethyl group and the like, but a methyl group is preferred.

X_{b}, is preferably a hydrogen atom or a methyl group.

Specific examples and preferred examples of the alkyl group and cycloalkyl group of R_{y1} to R_{y3} are the same as the specific examples and preferred examples of the alkyl group and cycloalkyl group of Rₓ₁ to Rₓ₃ in the above-described Formula (AI).

Specific examples and preferred examples of the ring structure formed by combining two of R_{y1} to R_{y3} with each other are the same as the specific examples and preferred examples of the ring structure formed by combining two of Rₓ₁ to Rₓ₃ with each other in the Formula (AI).

Each of R_{y1} to R_{y3} independently is preferably an alkyl group, and more preferably a straight or branched alkyl group having 1 to 4 carbon atoms. Also, the total carbon number of straight or branched alkyl group as R_{y1} to R_{y3} is preferably 5 or less.

R_{y1} to R_{y3} may further have a substituent, and examples of such substituents are the same as those exemplified as substituents which may be possessed by R_{y1} to R_{y3} in Formula (AI).

A linking group having a polycyclic hydrocarbon structure of Z include a ring-aggregated hydrocarbon ring group and a crosslinked cyclic hydrocarbon ring group, and examples thereof may include a group formed by subtracting arbitrary (p+1) hydrogen atoms from a ring-aggregated hydrocarbon ring and a group formed by subtracting arbitrary (p+1) hydrogen atoms from a crosslinked cyclic hydrocarbon ring.

The linking group having a polycyclic hydrocarbon structure represented by Z may have a substituent. Examples of the substituent which may be possessed by Z may include a substituent such as an alkyl group, a hydroxyl group, a cyano group, a keto group (an alkylcarbonyl group and the like), an acyloxy group, —COOR, —CON(R)₂, —SO₂R, —SO₃R, and —SO₂N(R)₂. Here, R represents a hydrogen atom, an alkyl group, a cycloalkyl group or an aryl group.

An alkyl group, an alkylcarbonyl group, an acyloxy group, —COOR, —CON(R)₂, —SO₂R, —SO₃R and —SO₂N(R)₂ as the substituent, which may be possessed by Z, may further have a substituent, and examples of the further substituent may include a halogen atom (preferably, a fluorine atom).

In the linking group having a polycyclic hydrocarbon structure represented by Z, the carbon constituting the polycyclic ring (the carbon contributing to ring formation) may be carbonyl carbon. Further, as described above, the polycyclic ring may have, as a ring member, a heteroatom such as an oxygen atom and a sulfur atom. As described above, Z does not contain an ester bond as an atomic group which constitutes a polycyclic ring.

Examples of the linking group represented by L₄ and L₅ may include —COO—, —OCO—, —CONH—, —NHCO—, —CO—, —O—, —S—, —SO—, —SO₂—, an alkylene group (preferably having from 1 to 6 carbon atoms), a cycloalkylene group (preferably having 3 to 10 carbon atoms), an alkenylene group (preferably having 2 to 6 carbon atoms), a linking group formed by combining a plurality of these groups and the like, and a linking group having a total carbon number of 12 or less is preferred.

L₄ is preferably a single bond, an alkylene group, —COO—, —OCO—, —CONH—, —NHCO—, -alkylene group-COO—, -alkylene group-OCO—, -alkylene group-CONH—, -alkylene group-NHCO—, —CO—, —O—, —SO₂— and -alkylene group-O—, and more preferably a single bond, an alkylene group, -alkylene group-COO— or -alkylene group-O—.

L₅ is preferably a single bond, an alkylene group, —COO—, —OCO—, —CONH—, —NHCO—, —COO— alkylene group-, —OCO-alkylene group-, —CONH-alkylene group-, —NHCO-alkylene group-, —CO—, —SO₂—, —O-alkylene group- and —O-cycloalkylene group-, and more preferably a single bond, an alkylene group, —COO-alkylene group- —O-alkylene group- or —O— cycloalkylene group-.

In the above-described method, the bonding hand “—” at the left end means to be connected to the ester bond on the main chain side in La and connected to Z in L₅, and the bonding hand “—” at the right end means to be bonded to Z in L₄ and bonded to the ester bond connected to the group represented by (Ry₁)(Ry₂)(Ry₃)C— in L₅.

Meanwhile, L₄ and L₅ may be bonded to the same atom constituting the polycyclic ring in Z.

p is preferably 1 or 2, and more preferably 1.

Hereinafter, specific examples of the repeating unit represented by Formula (IV) will be shown, but the present invention is not limited thereto. In the following specific example, Xa represents a hydrogen atom, an alkyl group, a cyano group or a halogen atom.

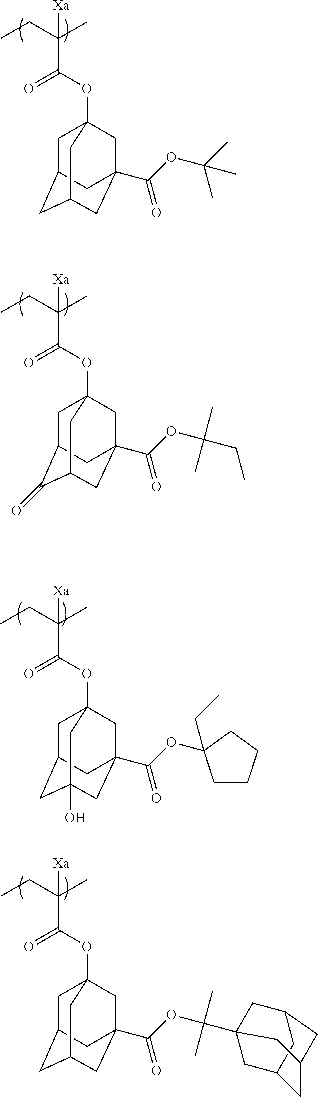

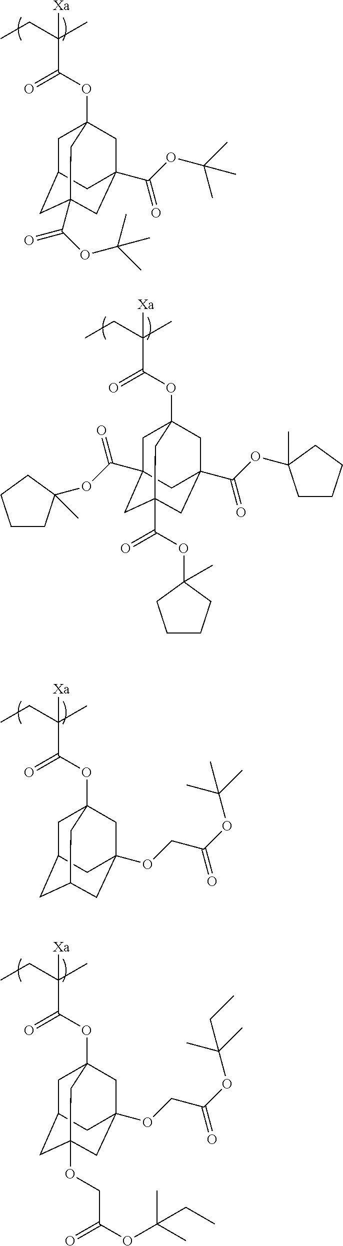

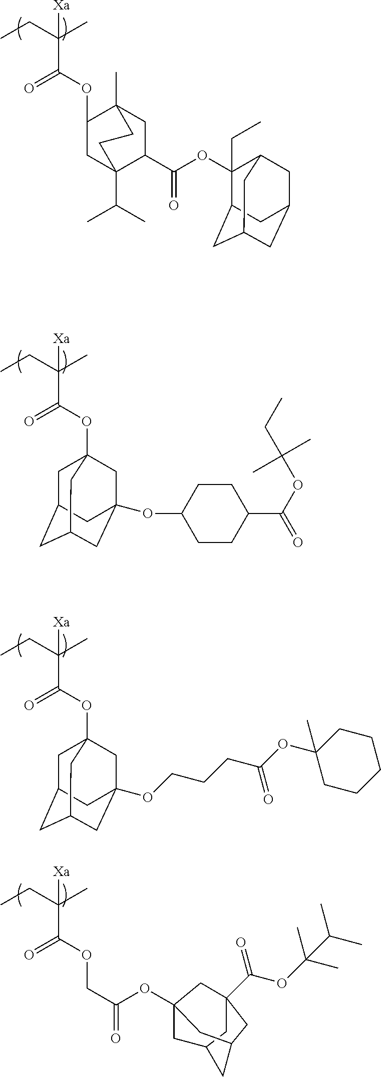

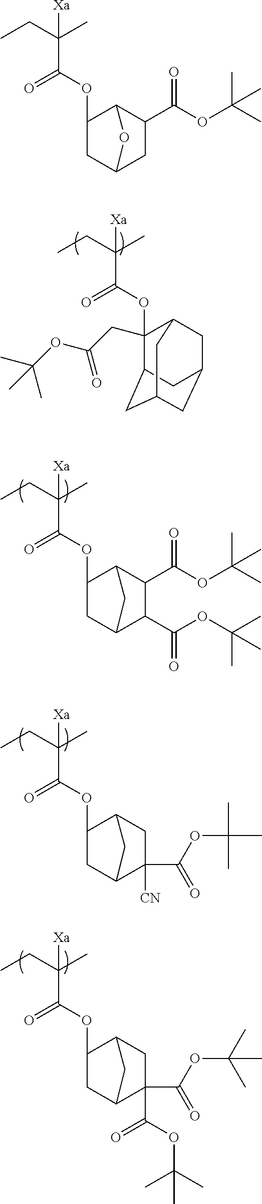

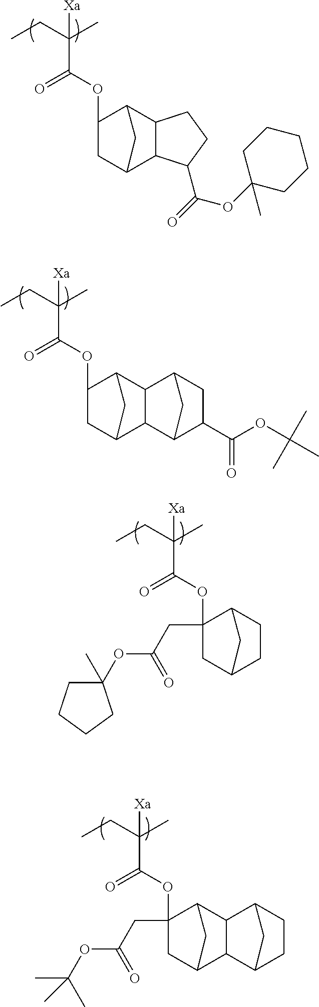

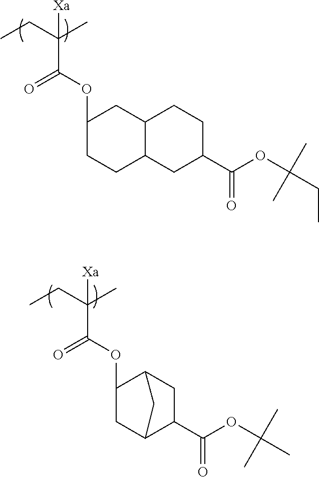

In addition, the resin (A) is the repeating unit having an acid-decomposable group, and may have a repeating unit capable of decomposing by the action of an acid to produce an alcoholic hydroxyl group as represented below.

In the following specific examples, Xa₁ represents a hydrogen atom, CH₃, CF₃ or CH₂OH.

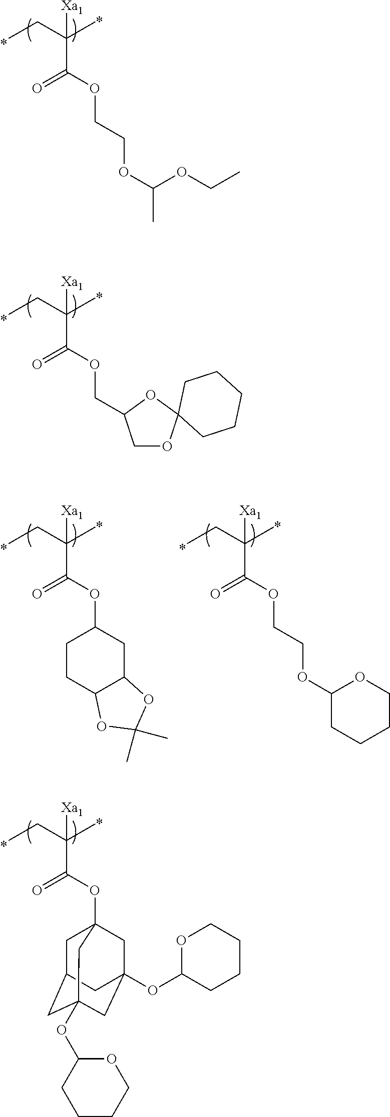

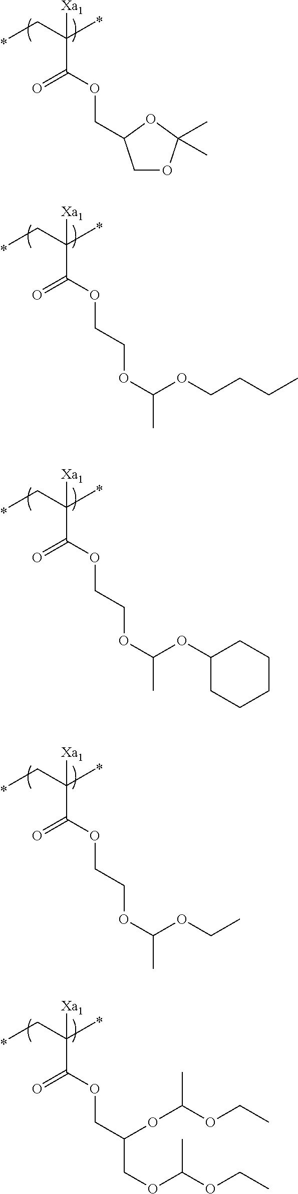

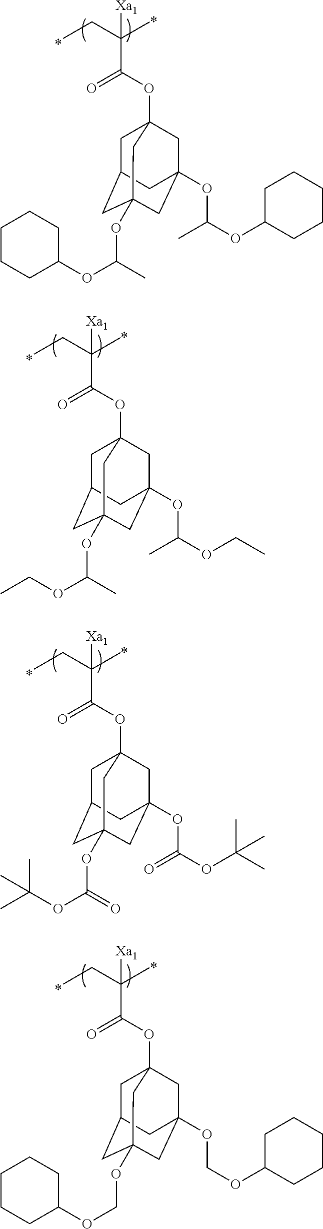

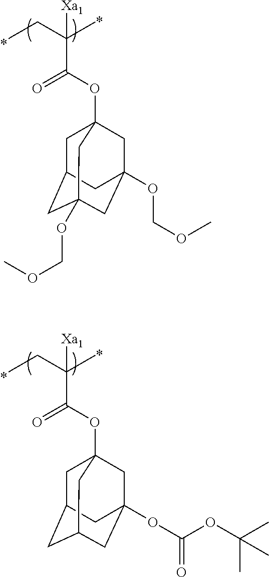

The repeating unit having an acid-decomposable group may be used either alone or in combination of two or more thereof.

Examples of the repeating unit which used in combination of two or more may include the combination as described below, or a combination of a repeating unit represented by the following Formula (AI) and a repeating unit capable of decomposing by the action of an acid to produce an alcoholic hydroxyl group, and the like. Further, in the following Formula, each R independently represents a hydrogen atom or a methyl group.

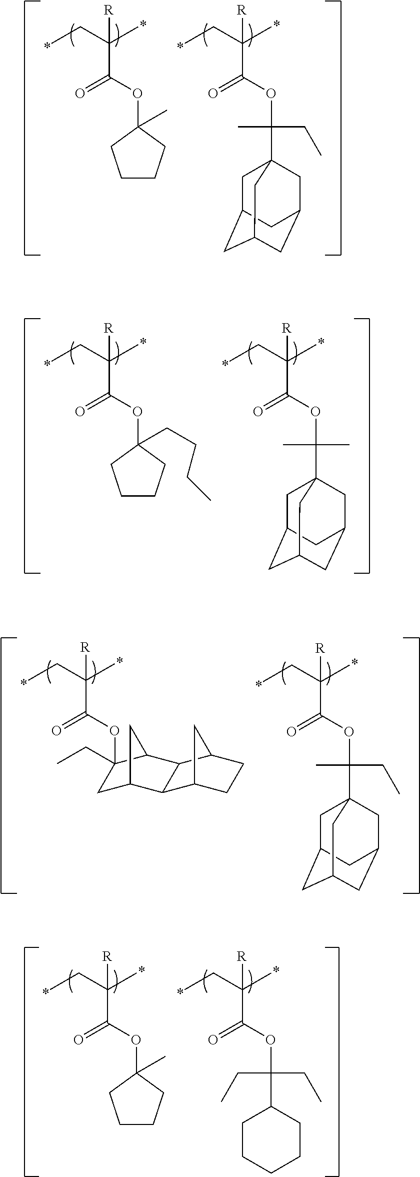

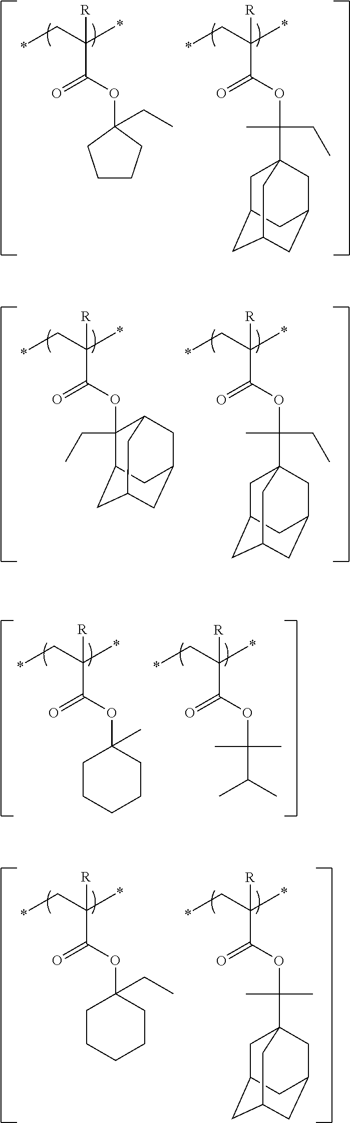

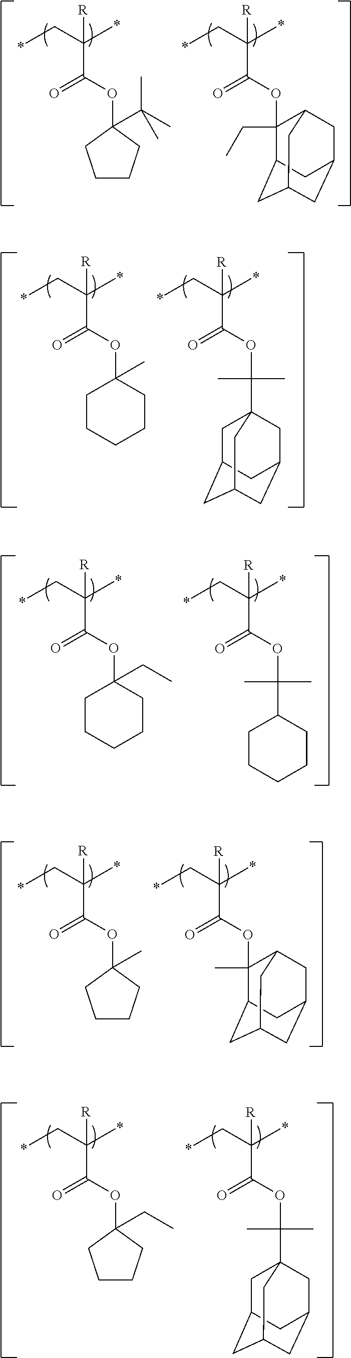

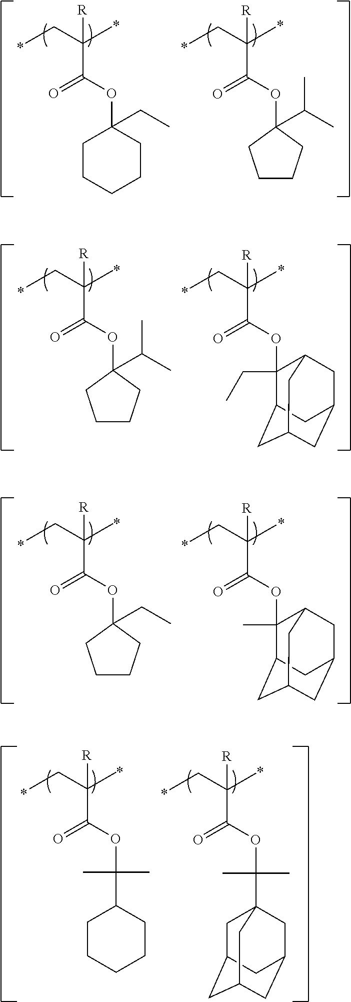

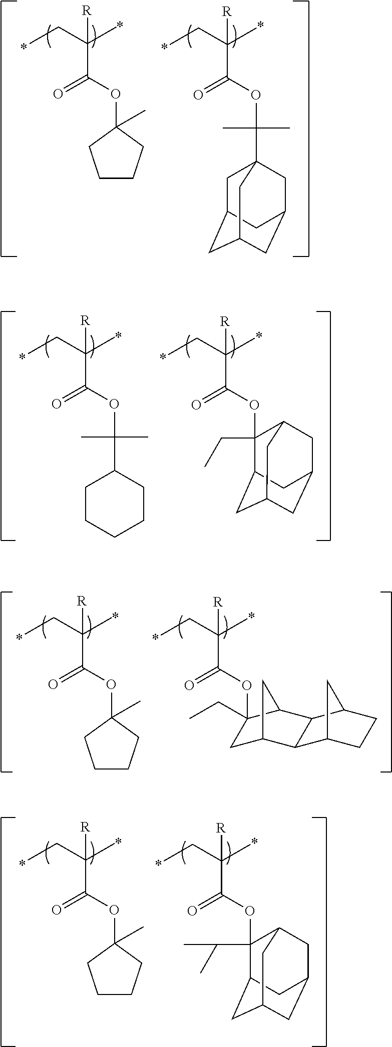

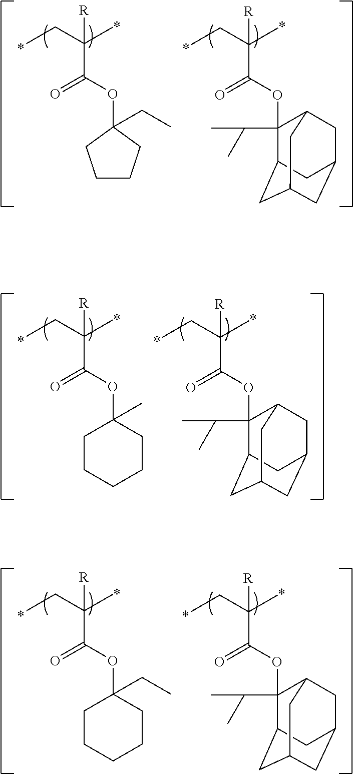

the content of the repeating unit having an acid-decomposable group (in the case of containing a plurality of kinds of repeating units having and acid-decomposable group, the total thereof) included in resin (A) is preferably 15 mol % or more, more preferably 20 mol % or more, still more preferably 25 mol % or more and particularly preferably 40 mol % or more, based on the total repeating units in resin (A). Among them, it is preferred that the resin (A) has a repeating unit represented by the Formula (AI) and the content of the repeating units represented by the Formula (AI) is 40 mol % or more based on the total repeating unit of the resin (A).

When the content of the repeating unit having an acid-decomposable group is 40 mol % or more bused on the total repeating unit of the resin (A), the glass transition temperature (Tg) of the resin (A) can be securely increased. Therefore, the effects of suppressing an increase in process cost described above are more reliable.

In addition, the content of the repeating unit having an acid-decomposable group is preferably 80 mol % or less, more preferably 70 mol % or less and still more preferably 65 mol % or less based on the total repeating unit of the resin (A).

Resin (A) may contain a repeating unit further having a lactone structure or a sultone structure.

As the group having a lactone structure or a sultone structure, any group may be used as long as the group has a lactone structure or a sultone structure, but a lactone structure having a 5- to 7-membered ring or a sultone structure having a 5- to 7-membered ring is preferred. A group in which another ring structure is condensed to a lactone structure having a 5- to 7-membered ring in the form of forming a bicyclo structure or a spiro structure, or a group in which another ring structure is condensed to a sultone structure having a 5- to 7-membered ring in the form of forming a bicyclo structure or a spiro structure is more preferred. It is more preferred that the group has a repeating unit having a lactone structure represented by any one of the following Formulas (LC1-1) to (LC1-21) or a sultone structure represented by any one of the following Formulas (SL1-1) to (SL1-3). Further, the lactone structure or sultone structure may be bonded directly to the main chain. A preferred lactone structure is (LC1-1), (LC1-4), (LC1-5), (LC1-6), (LC1-13), (LC1-14) and (LC1-17), and particularly preferably (LC1-4). By using such a specific lactone structure, LER and the development defect are improved.

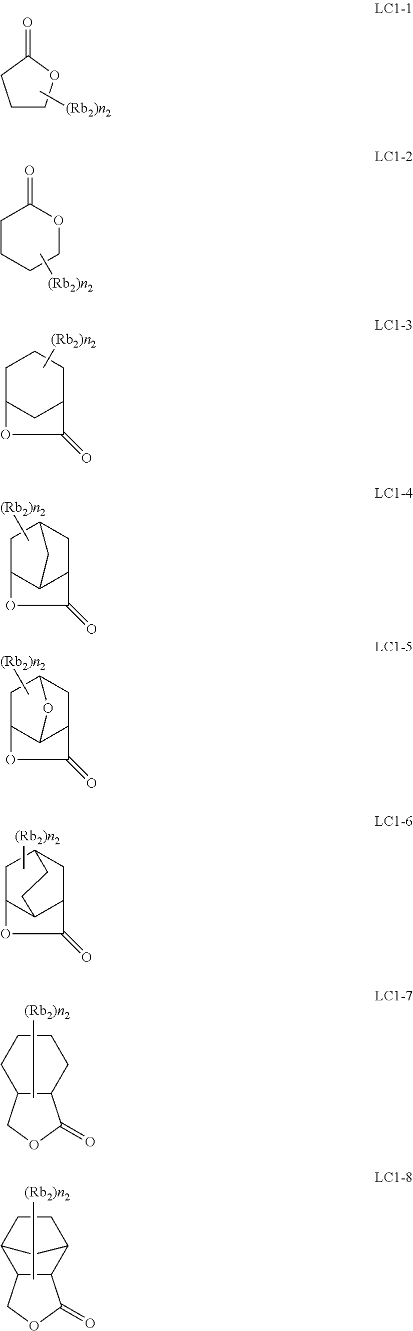

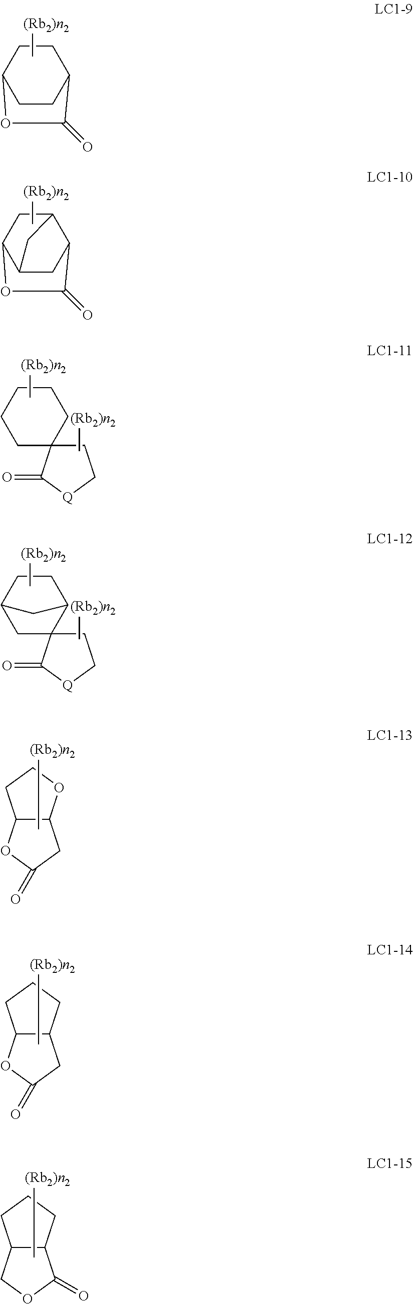

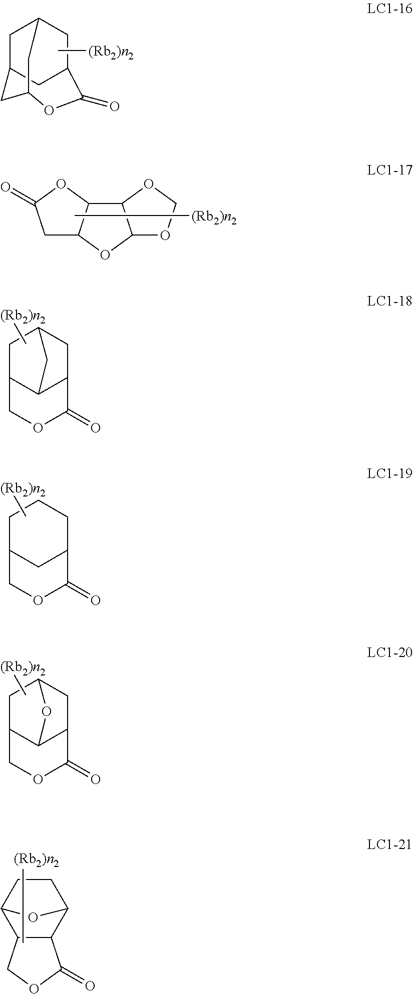

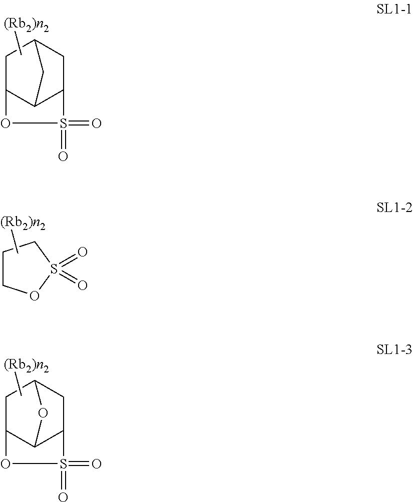

The lactone structure or sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group and the like. An alkyl group having 1 to 4 carbon atoms, a cyano group and an acid-decomposable group are more preferred. n₂ represents an integer of 0 to 4. When n₂ is 2 or more, a plurality of substituents (Rb₂) may be same or different, and the plurality of substituents (Rb₂) may be bonded to each other to form a ring.

The repeating unit having a lactone structure or a sultone structure usually has an optical isomer, and any optical isomer may be used. In addition, one kind of optical isomer may be used alone, or a plurality of optical isomers may be used in mixtures. When one kind of optical isomer is mainly used, the optical purity (ee) thereof is preferably 90% or more, and more preferably 95% or more.

Hereinafter, the repeating unit having a lactone structure or a sultone structure is preferably the repeating unit represented by the following Formula (III).

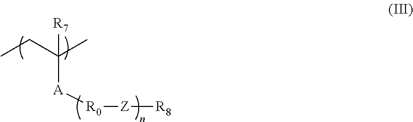

In Formula (III),

A represents an ester bond (a group represented by (—COO—) or an amide bond (a group represented by —CONH—).

When a plurality of R₀ is present, each R₀ independently represents an alkylene group, a cycloalkylene group, or a combination thereof.

When a plurality of Z is present, each Z independently represents a single bond, an ether bond, an ester bond, an amide bond, or an urethane bond

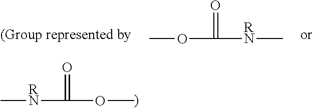

or an urea bond

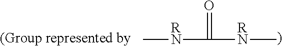

Here, each R independently represents a hydrogen atom, an alkyl group, a cycloalkyl group or an aryl group.

R₈ represents a monovalent organic group having a lactone structure or a sultone structure.

n is the repeating unit of the structure represented by —Rₒ—Z— and represents an integer of 0 to 5, preferably 0 or 1, and more preferably 0. When n is 0, —Rₒ-Z- is not present and n is a single bond.

R₇ represents a hydrogen atom, a halogen atom or an alkyl group.

The alkylene group or a cycloalkylene group of R₀ may have a substituent. Z is preferably an ether bond, an ester bond and particularly preferably an ester bond.

The alkyl group of R₇ is preferably an alkyl group having 1 to 4 carbon atoms, a methyl group, more preferably a methyl group or an ethyl group and particularly preferably a methyl group.

The alkylene group, the cycloalkylene group in R₀, the alkyl group in R₇ may be substituted, respectively, and examples of the substituent may include a halogen atom such as a fluorine atom, a chlorine atom, or a bromine atom; an alkoxy group such as a mercapto group, a hydroxyl group, a methoxy group, an ethoxy group, an isopropoxy group, a t-butoxy group, a benzyl group; or an acyloxy group such as an acetyloxy group, a propionyl group and the lile.

R₇ is preferably a hydrogen atom, a methyl group, a trifluoromethyl group, or a hydroxymethyl group.

Preferred chain alkylene group in R₀ is preferably a chain alkylene group having 1 to 10 carbon atoms and more preferably 1 to 5 carbon atoms, and may include, for example, a methylene group, an ethylene group, a propylene group and the like. Preferred cycloalkylene group is a cycloalkylene group having 3 to 20 carbon atoms and examples thereof may include a cyclohexylene group, a cyclopentylene group, a norbornylene group, an adamantylene group and the like. In order to exhibit the effects of the present invention, a chain alkylene group is more preferred, and a methylene group is particularly preferred.

The monovalent organic group having a lactone structure or a sultone structure represented by R, is not limited as long as it has a lactone structure or a sultone structure. Specific examples thereof may include a lactone structure or a sultone structure represented by any one of (LC1-1) to (LC1-21) and, (SL1-1) to (SL1-3). Among them, a structure represented by (LC1-4) is particularly preferred. In addition, n₂ in (LC1-1) to (LC1-21) is more preferably 2 or less.

Also, R₈ is preferably a monovalent organic group having unsubstituted lactone structure or sultone structure, or a monovalent organic group having unsubstituted lactone structure or sultone structure having a methyl group, a cyano group or an alkoxycarbonyl group as a substituent, and more preferably a monovalent organic group having a lactone structure (cyano lactone) having a cyano group as the substituent.

Specific examples of the repeating unit having a group having a lactone structure or a sultone structure are shown below, but the present invention is not limited thereto.

(In the formulas, Rx represents H, CH₃, CH₂OH or CF₃)

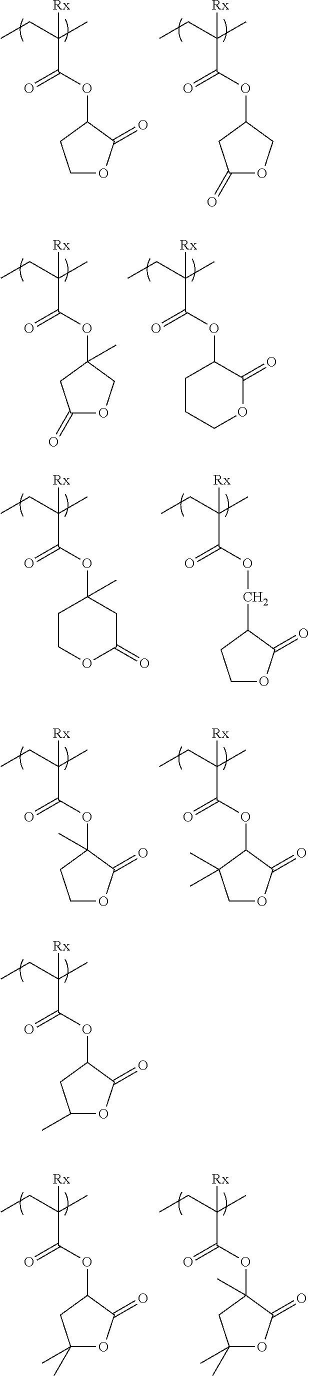

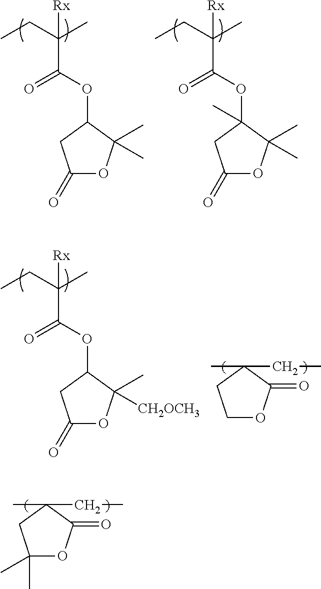

(In the formulas, Rx represents H, CH₃, CH₂OH or CF₃)

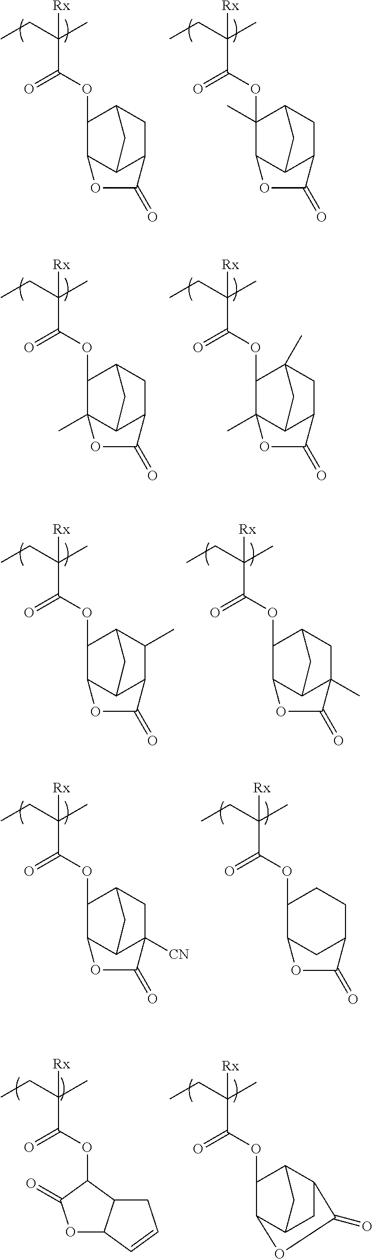

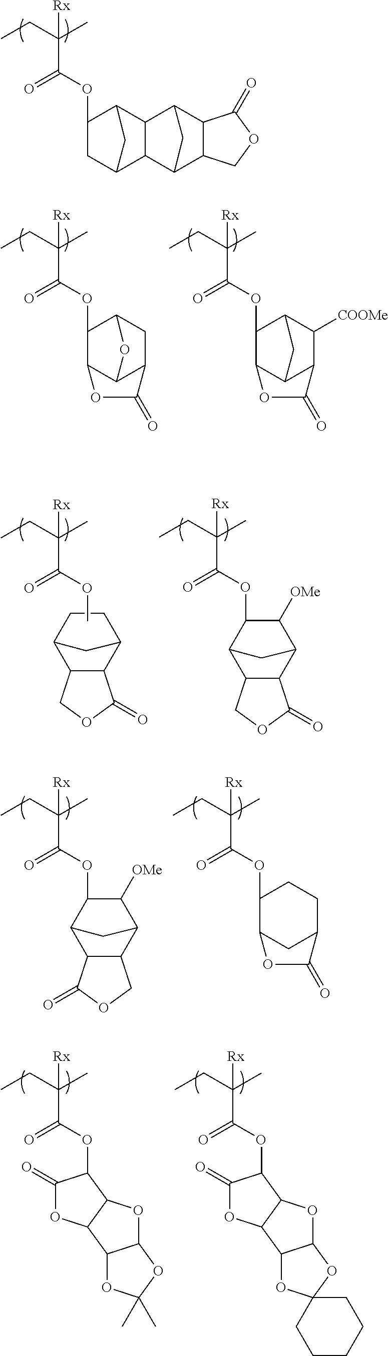

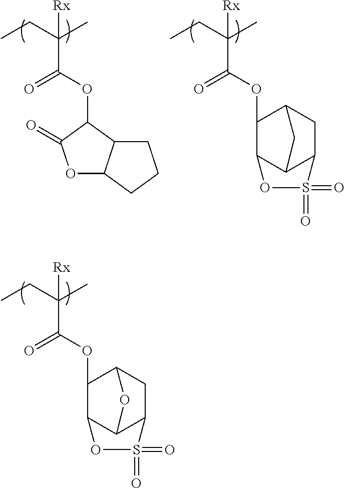

(In the formulas, Rx represents H, CH₃, CH₂OH or CF₃)

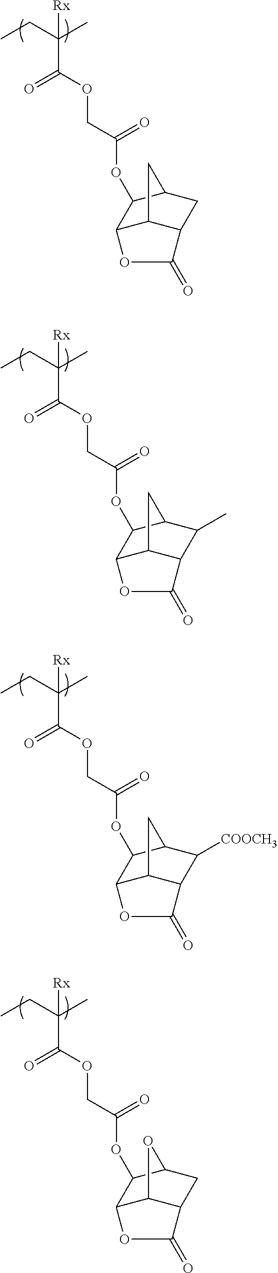

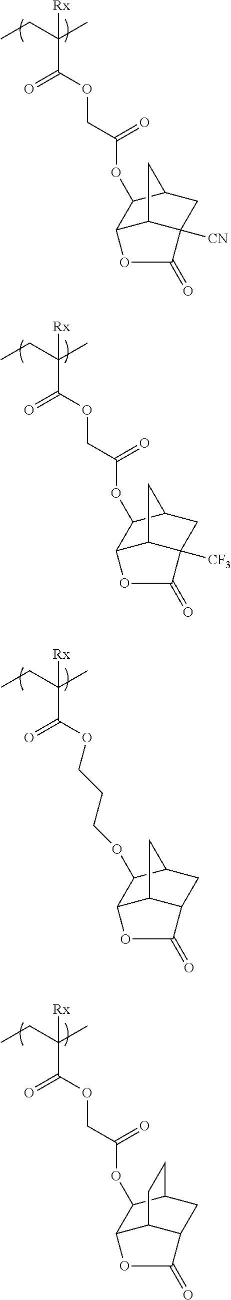

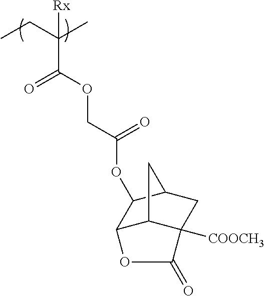

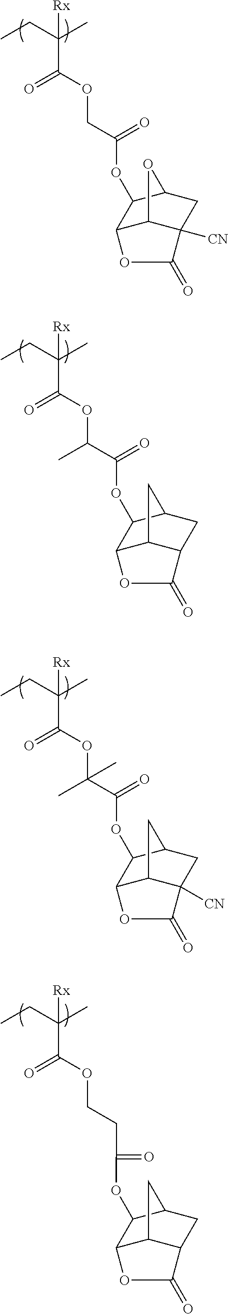

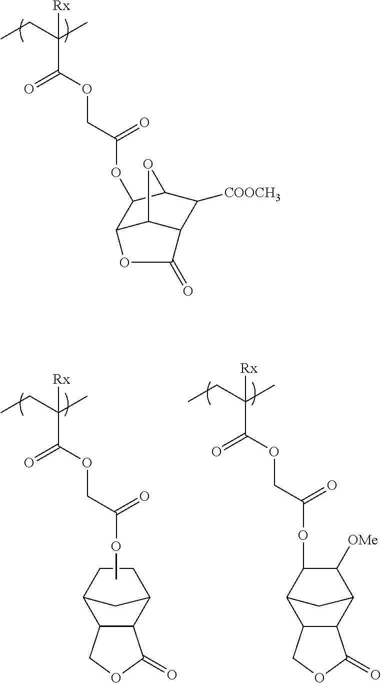

To enhance the effect of the present invention, it is also possible to use in combination of the repeating units having two or more lactone structures or sultone structures.

When the resin (A) contains a repealing unit having a lactone structure or a sultone structure, the content of the repeating unit having a lactone structure or a sultone structure is preferably 5 to 60 mol %, more preferably 5 to 55 mol % and still more preferably 10 to 50 mol %, based on the total repeating units of the resin (A).

Further, the resin (A) may have a repeating unit having a cyclic carbonate ester structure.

The repeating unit having a cyclic carbonate ester structure is preferably a repeating unit represented by the following Formula (A-1).

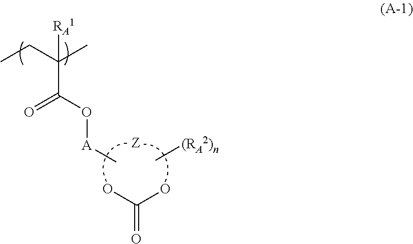

In Formula (A-1), R_{A}¹ represents a hydrogen atom or an alkyl group.

When R_{A}² are 2 or more, each R_{A}² independently represents a substituent.

A represents a single bond or a divalent linking group.

Z represents an atomic group forming a monocyclic or polycyclic structure such as the group represented by —O—C(═O)—O— in the formula.

n represents an integer of 0 or more.

Formula (A-1) will be described in detail below.

The alkyl group represented by R_{A}¹ may have a substituent such as a fluorine atom.

R_{A}¹ preferably represents a hydrogen atom, a methyl group or a trifluoromethyl group and more preferably a methyl group.

The substituent represented by R_{A}² is, for example, an alkyl group, a cycloalkyl group, a hydroxyl group, an alkoxy group, an amino group, or an alkoxycarbonyl amino group. Preferred is an alkyl group having 1 to 5 carton atoms, and examples thereof may include a straight alkyl group having 1 to 5 carbon atoms such as a methyl group, an ethyl group, a propyl group, and a butyl group; a branched alkyl group having 3 to 5 carbon atoms such as an isopropyl group, an isobutyl group, and a t-butyl group. The alkyl group may have a substituent such as a hydroxyl group.

n is an integer of 0 or more representing the number of substituents. n is, for example, preferably 0 to 4 and more preferably 0.

Examples of the divalent linking group represented by A may include an alkylene group, a cycloalkylene group, an ester bond, an amide bond, an ether bond, an urethane bond, an urea bond, or a combination thereof. The alkylene group is preferably an alkylene group having 1 to 10 carbon atoms and more preferably an alkylene group having 1 to 5 carbon atoms, and examples thereof may include a methylene group, an ethylene group, and a propylene group.

In one embodiment of the present invention, A is preferably a single bond or an alkylene group.

Examples of the monocyclic ring containing a —O—C(═O)—O—, represented by Z, may include a 5- to 7-membered ring in a cyclic carbonate ester represented by the following Formula (a) wherein n_{A}=2 to 4, preferably a 5- or 6-membered ring (n_{A}=2 or 3) and more preferably a 5-membered ring (n_{A}=2).

Examples of the polycyclic ring containing a —O—C(═O)—O—, represented by Z, may include a structure in which a cyclic carbonate ester represented by the following Formula (a) and two or more other ring structures are combined together to form a condensed ring, or a structure which forms forms a spiro ring. “Other ring structures” capable of forming a condensed ring or a spiro ring may be an alicyclic hydrocarbon group, or an aromatic hydrocarbon group, or a heterocyclic ring.

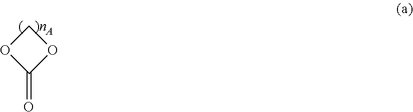

The monomer corresponding to the repeating unit represented by Formula (A-1) may be synthesized by publicly known methods in the related art, which are described in, for example, Tetrahedron Letters. Vol. 27, No. 32, p. 3741 (1986), Organic Letters, Vol. 4, No. 15, p. 2561 (2002), and the like.

The resin (A) may contain one type of the repeating unit represented by Formula (A-1) or two or more types thereof.

In the resin (A), the content of the repeating unit having a cyclic carbonate ester structure (preferably, the repeating unit represented by Formula (A-1)) is preferably 3 to 80 mol %, more preferably 3 to 60 mol %, particularly preferably 3 to 30 mol %, and most preferably 10 to 15 mol %, based on the total repeating units constituting the resin (A). By using such content, a developability, a low defectivity, a low LWR, a low PEB temperature dependence and a profile and the like as a resist may be improved.

Specific examples of the repeating unit represented by Formula (A-1) (repeating units (A-1a) to (A-1w)) are shown below, but the present invention is not limited thereto.

Further, R_{A}¹ in the following specific examples has the same meaning as R_{A}¹ in Formula (A-1).

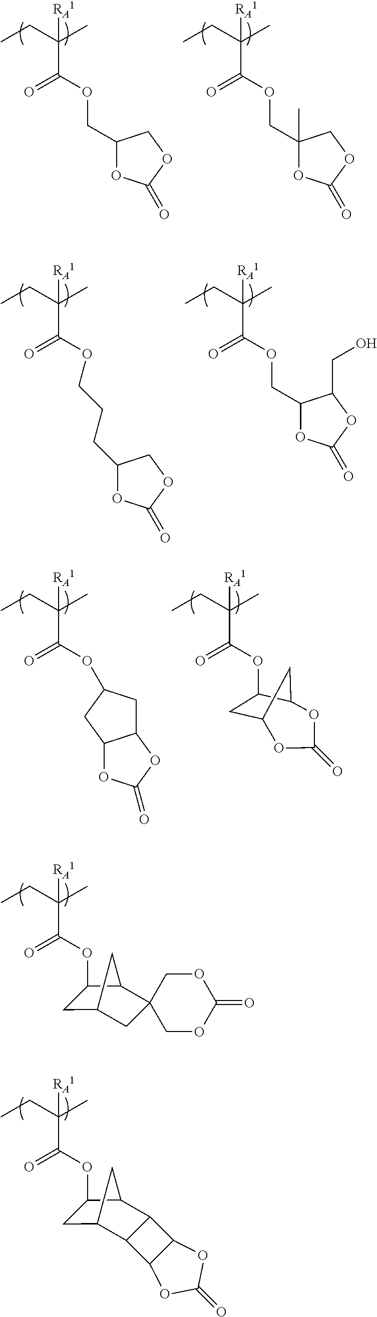

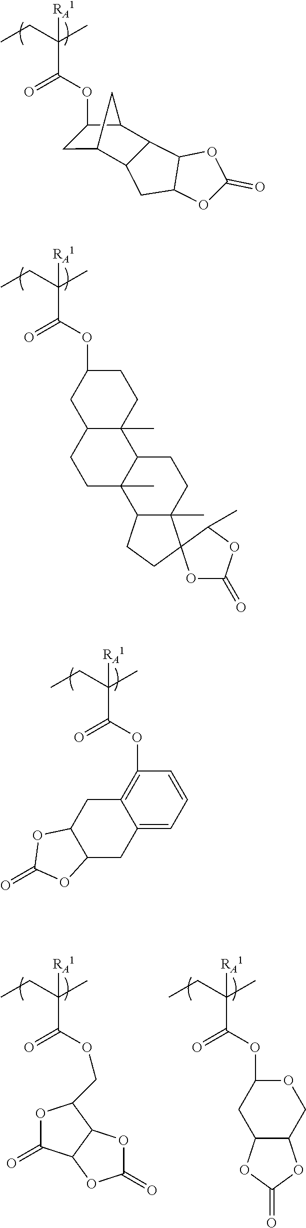

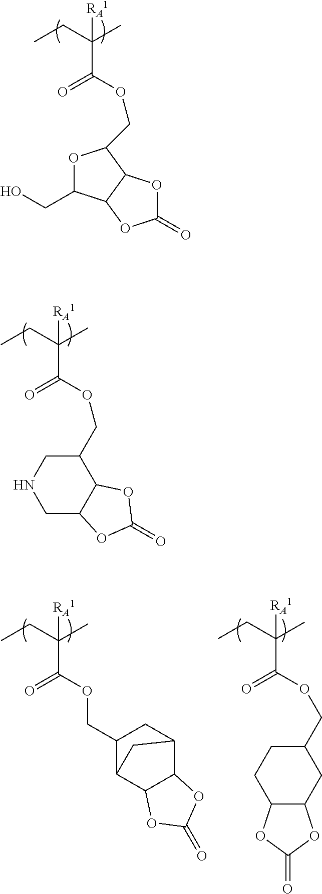

The resin (A) may have a repeating unit having a hydroxyl group or a cyano group. Thus, an adhesion of the substrate and an affinity to the developer are increased. The repeating unit having a hydroxyl group or a cyano group is preferably the repeating unit having an alicyclic hydrocarbon structure substituted with a hydroxyl group or a cyano group, and more preferably has no acid-decomposable group.

Also, the repeating unit having an alicyclic hydrocarbon structure substituted with a hydroxyl group or a cyano group may preferably be that different from the repeating unit having an acid-decomposable group (i.e., a stable repeating unit to an acid is preferred).

In the alicyclic hydrocarbon structure substituted with a hydroxyl group or a cyano group, the alicyclic hydrocarbon structure is preferably an adamantyl group, a diadamantyl group, or a norbornane group.

More preferably, a repeating unit represented by any one of the following Formulas (AIIa) to (AIIc) may be exemplified.

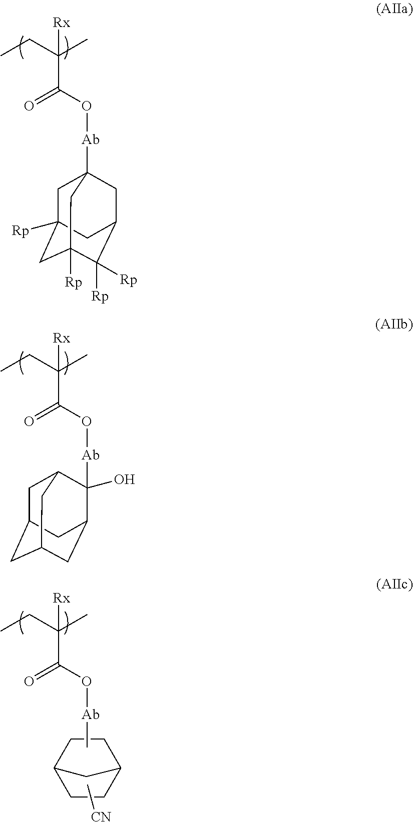

In the formulas, Rₓ represents a hydrogen atom, a methyl group, hydroxymethyl group, or a trifluoromethyl group.

Ab represents a single bond or a divalent linking group.

Examples of the divalent linking group represented by Ab may include an alkylene group, a cycloalkylene group, an ester bond, an amide bond, an ether bond, an urethane bond, an urea bond, or a combination thereof. The alkylene group is preferably an alkylene group having 1 to 10 carbon atoms, more preferably an alkylene group having 1 to 5 carbon atoms, and examples thereof may include a methylene group, an ethylene group, a propylene group, and the like.

In one embodiment of the present invention, Ab is preferably a single bond or an alkylene group.

Rp represents a hydrogen atom, a hydroxyl group or hydroxyalkyl group. A plurality of Rp's may be same as or different, but at least one of Rp's represents a hydroxyl group or a hydroxyalkyl group.

The resin (A) may or may not contain a repeating unit having a hydroxyl group or a cyano group, but when the resin (A) contains the repeating unit having a hydroxyl group or a cyano group, the content of the repeating unit having a hydroxyl group or a cyano group is preferably 1 to 40 mol %, more preferably 3 to 30 mol %, and still more preferably 5 to 25 mol %, based on the total repeating unit of the resin (A).

Specific examples of the repeating unit having a hydroxyl group or a cyano group are shown below, but the invention is not limited thereto.

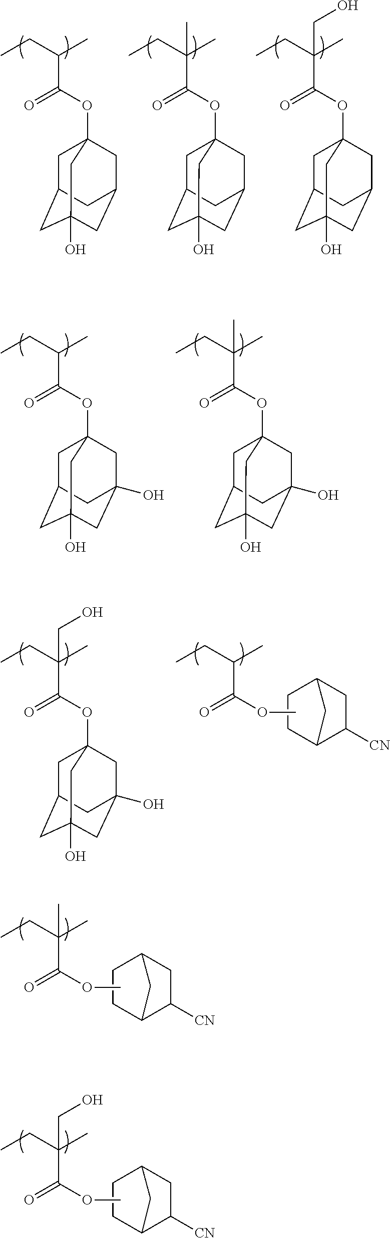

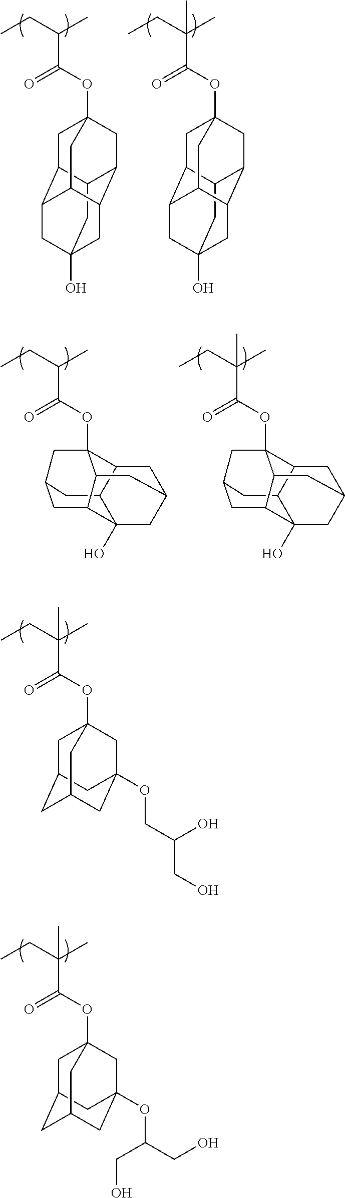

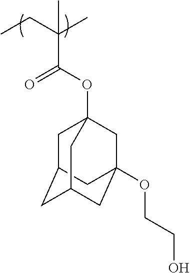

In addition, monomers or repeating Units corresponding thereto described following [0011] of International Publication WO 2011/122336 may also be appropriately used.

The resin (A) may have a repeating unit having an acid group. Examples of the acid group may include a carboxyl group, a sulfonamide group, a sulfonylimide group, a bissulfonyl imide groups, a naphthol structure, an aliphatic alcohol group substituted with an electron withdrawing group at α-position (for example, hexafluoroisopropanol group) and the like, and more preferably a group having a repeating unit having a carboxyl group. Resolution for use in contact holes increases by containing a repeating unit having an acid group. As the repeating unit having an acid group, any of a repeating unit in which an acid group is bonded directly to the main chain of the resin such as a repeating unit having an acrylic acid or a methacrylic acid, or a repeating unit in which an acid group is bonded to the main chain of the resin via a linking group, and further a repeating unit which is introduced into the terminal group of the polymer chain by using an polymerization initiator or a chain transfer agent having an acid group is preferred. The linking group may have a monocyclic or polycyclic hydrocarbon structure. Particularly preferred is a repeating unit having an acrylic acid or methacrylic acid.

The resin (A) may or may not contain a repeating unit having an acid group, but in the case of containing the repeating unit having an acid group, the content thereof is preferably 25 mol % or less, and more preferably 20 mol % or less, based on the total repeating units of the resin (A).

When the resin (A) contains a repeating unit having an acid group, the content of the repeating unit having an acid group in the resin (A) is usually 1 mol % or more.

Specific examples of the repeating unit having an acid group are shown below, but the invention is not limited thereto.

In the specific example, Rx represents H, CH₃, CH₂OH or CF₃.

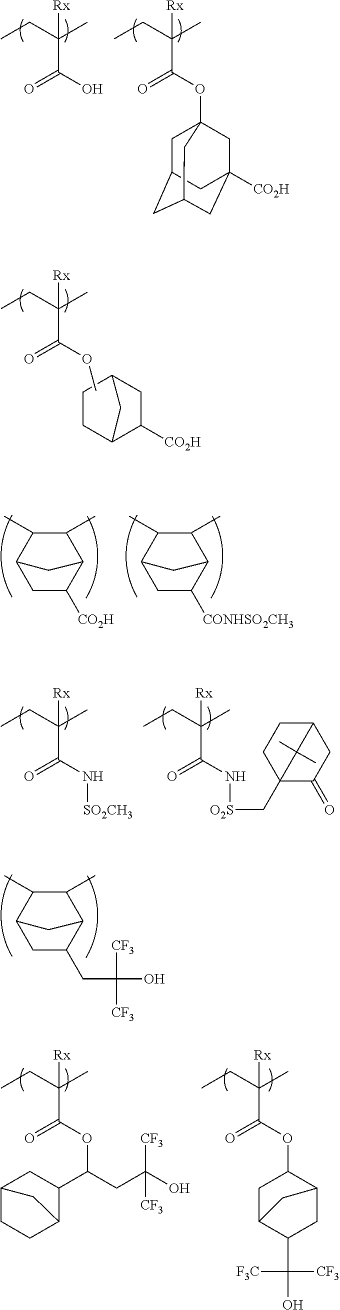

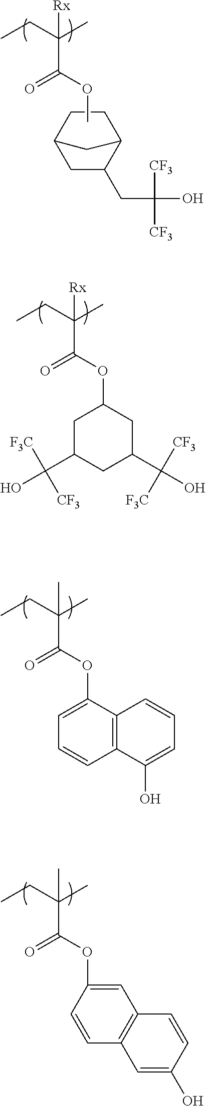

In the present invention, the resin (A) may have a repeating unit which further has an alicyclic hydrocarbon structure having no polar group (for example, the acid group, the hydroxyl group, and the cyano group) and does not exhibit an acid decomposability. Accordingly, elution of low molecular components from the resist film into the liquid for liquid immersion during the liquid immersion exposure may be reduced, and further, the solubility of the resin during the development using an organic solvent-containing developer may be appropriately adjusted. Examples of the repeating unit include a repeating unit represented by Formula (IV).

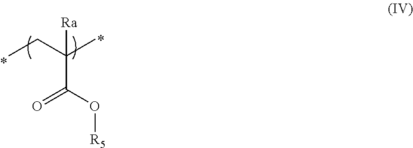

In Formula (IV), R₅ represents a hydrocarbon group having at least one cyclic structure and having no polar group.

Ra represents a hydrogen atom, an alkyl group or a —CH₂—O—Ra₂ group. In the formula, Ra₂ represents a hydrogen atom, an alkyl group or an acyl group. Ra is preferably a hydrogen atom, a methyl group, a hydroxymethyl group and a trifluoromethyl group, and particularly preferably a hydrogen atom and a methyl group.

The cyclic structure possessed by R₅ includes a monocyclic hydrocarbon group and a polycyclic hydrocarbon group. Preferred examples of the monocyclic hydrocarbon group may include a cyclopentyl group or a cyclohexyl group.

The polycyclic hydrocarbon group includes a ring-aggregated hydrocarbon group and a crosslinked cyclic hydrocarbon group, and examples of the ring-aggregated hydrocarbon group include a bicyclohexyl group, a perhydronaphthalenyl group and the like. Examples of the crosslinked cyclic hydrocarbon ring include a bicyclic hydrocarbon ring such as a pinane ring, a bornane ring, a norpinane ring, a norbornane ring and a bicyclooctane ring (a bicyclo[2.2.2]octane ring, a bicyclo[3.2.1]octane ring and the like), a tricyclic hydrocarbon ring such as a homobrendane ring, an adamantine ring, a tricyclo[5.2.1.0^{2,6}]decane ring and a tricyclo[4.3.1.1^{2,5}]undecane ring, a tetracyclic hydrocarbon ring such as a tetracyclo[4.4.0.1^{2,5}.1^{7,10}]dodecane ring and a perhydro-1,4-methano-5,8-methanonaphthalene ring, and the like. Furthermore, the crosslinked cyclic hydrocarbon ring also includes a condensed cyclic hydrocarbon ring, for example, a condensed ring obtained by condensing a plurality of 5- to 8-membered cycloalkane rings, such as a perhydroacenaphthene (decalin) ring, a perhydroanthracene ring, a perhydrophenanthrene ring, a perhydroacenaphthene ring, a perhydrofluorene ring, a perhydroindene ring, and a perhydrophenalene ring.

Preferred examples of the crosslinked cyclic hydrocarbon ring may include a norbornyl group, an adamantyl group, a bicyclooctanyl group, a tricyclo[5,2,1,0^{2,6}]decanyl group and the like. More preferred examples of the crosslinked cyclic hydrocarbon ring may include a norbornyl group and an adamantyl group.

The alicyclic hydrocarbon groups may have a substituent, and preferred examples of the substituent may include a halogen atom, an alkyl group, a hydroxyl group with a hydrogen atom being substituted, an amino group with a hydrogen atom being substituted and the like.

The resin (A) may or may not contain a repeating unit which has a polar group-free alicyclic hydrocarbon structure and does not exhibit acid decomposability, but when the resin (A) contains the repeating unit, the content of the repeating unit is preferably 1 to 50 mol %, more preferably 5 to 50 mol %, and still mote preferably 5 to 30 mol %, based on the total repeating units of the resin (A).

Specific examples of the repeating unit, which has a polar group-free alicyclic hydrocarbon structure and does not exhibit acid decomposability, will be shown below, but the present invention is not limited thereto. In the formula, Ra represents H, CH₃, CH₂OH or CF₃.

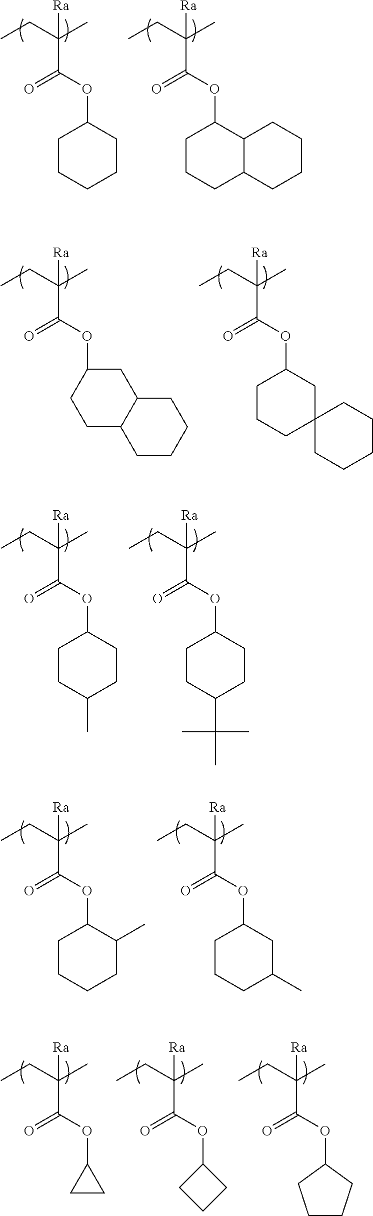

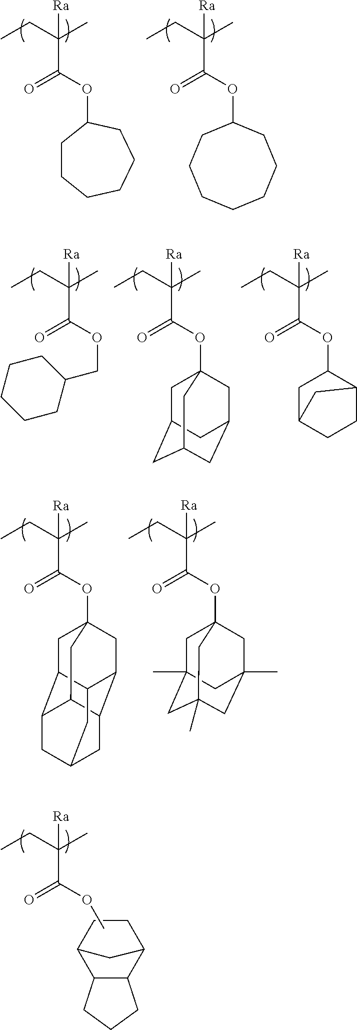

The resin (A) used in the composition of the present invention may have, in addition to the above-described repeating structural units, various repeating structural units for the purpose of controlling the dry etching resistance, suitability for a standard developer, adhesion to a substrate, and a resist profile, and resolution, heat resistance, sensitivity and the like, which are properties generally required for an actinic ray-sensitive or radiation-sensitive resin composition.

Examples of the repeating structural units may include repeating structural units corresponding to the monomers described below, but are not limited thereto.

Accordingly, the performance required for the resin used in the composition according to the present invention, particularly

(1) solubility in a coating solvent,

(2) film-forming property (glass transition temperature),

(3) alkali developability,

(4) film reduction (selection of a hydrophilic, hydrophobic or alkali-soluble group)

(5) adhesion of unexposed portion to the substrate, and

(6) dry etching resistance, and the like may be finely adjusted.

Examples of the monomer include a compound having one addition-polymerizable unsaturated bond selected from acrylate esters, methacrylate esters, acrylamides, methacrylamides, allyl compounds, vinyl ethers, vinyl esters and the like.

Other than these, an addition-polymerizable unsaturated compound that is copolymerizable with the monomers corresponding to the above-described various repeating structural units may be copolymerized.

In the resin (A) used in the composition of the present invention, the molar ratio of respective repeating structural units contained is appropriately set in order to control dry etching resistance, suitability for a standard developer, adhesion to a substrate, and resist profile of the actinic ray-sensitive or radiation-sensitive resin composition, and further resolution, heat resistance, sensitivity and the like which are performances generally required for the actinic ray-sensitive or radiation-sensitive resin composition.

In the present invention, the form of the resin (A) may be any of a random type, a block type, a comb type and a star type. The resin (A) may be synthesized, for example, by radical, cationic or anionic polymerization of an unsaturated monomer corresponding to the respective structure. Also, after the polymerization using an unsaturated monomer corresponding to the precursor of the respective structure, it is also possible to obtain the resin of interest by performing a polymer reaction.

When the composition of the present invention is for ArF exposure, from the viewpoint of transparency to ArF light, the resin (A) used in the composition of the present invention preferably substantially has no aromatic ring (specifically, the ratio of a repeating unit having an aromatic group in the resin is preferably 5 mol % or less, more preferably 3 mol % or less, and ideally 0 mol %, that is, the resin has no aromatic group), and the resin (A) preferably has a monocyclic or polycyclic alicyclic hydrocarbon structure.

Further, when the composition of the present invention includes a resin (D) to be described below, the resin (A) preferably contains no fluorine atom and no silicon atom from the viewpoint of compatibility with the resin (D) (specifically, in the resin, the ratio of the repeating units containing a fluorine atom or a silicon atom is preferably 5 mol % or less, more preferably 3 mol % or less, and ideally 0 mol %).

The resin (A) used in the composition of the present invention is preferably a resin in which all the repeating units consist of a (meth)acrylate-based repeating unit. In this case, a resin in which all the repeating units consist of a methacrylate-based repeating unit, a resin in which all the repeating units consist of an acrylate-based repeating unit, and a resin in which all the repeating units consist of a methacrylate-based repeating unit and an acrylate-based repeating unit may be used, but the acrylate-based repeating unit contains preferably 50 mol % or less of all the repeating units.

Specific examples of the resin (A) may include those mentioned in the examples to be described later, but further the following resins can be suitably applied. The composition ratio of each repeating unit of the following specific examples is shown in a molar ratio.

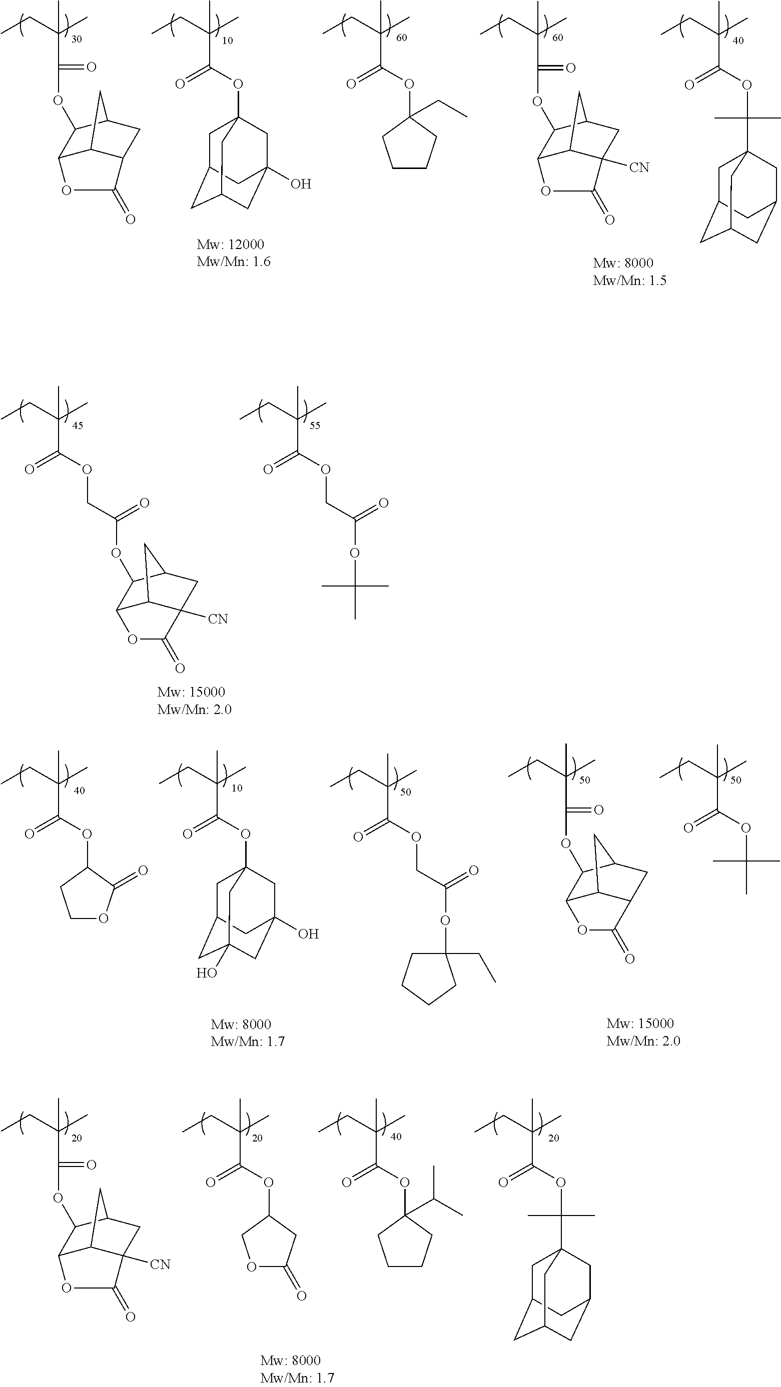

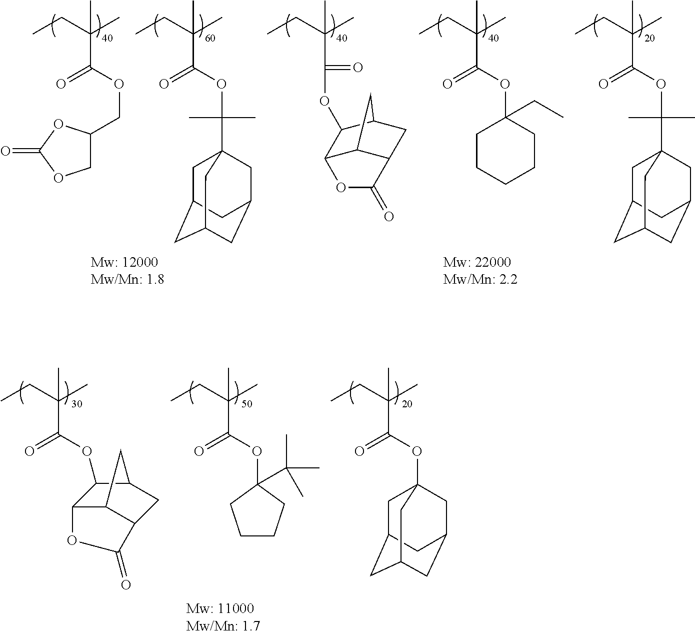

When KrF excimer laser light, electron beam, X-ray or high-energy beam having a wavelength of 50 nm or less (EUV and the like) is irradiated on the composition of the present invention, the resin (A) also has preferably a hydroxystyrene-based repeating unit. The resin (A) has more preferably a hydroxystyrene-based repeating unit, a hydroxystyrene-based repeating unit protected by an acid-decomposable group, and an acid-decomposable repeating unit such as (meth)acrylic acid tertiary alkyl ester.

Preferred examples of the hydroxystyrene-based repeating unit having an acid-decomposable group may include repeating units composed of t-butoxycarbonyloxystyrene, 1-alkoxyethoxystyrene, (meth)acrylic acid tertiary alkyl ester and the like, and repeating units composed of 2-alkyl-2-adamantyl(meth)acrylate and dialkyl(1-adamantyl)methyl (meth)acrylate are more preferred.

Such resins may include specifically resins having the repeating unit represented by the following Formula (A).

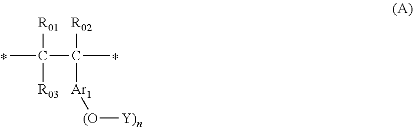

In the formula, each of R₀₁, R₀₂ and R₀₃ independently represents, for example, a hydrogen atom, an alkyl group, a cycloalkyl group, a halogen atom, a cyano group or an alkoxycarbonyl group. Ar₁ represents, for example, an aromatic ring group. Also, R₀₃ and Ar₁ are an alkylene group and both may combine with each other to form a 5- or 6-membered ring together with the —C—C-chain.

Each of nY's independently represents a hydrogen atom or a group capable of leaving by an action of an acid, provided that at least one of Y represents a group capable of leaving by the action of an acid.

n represents an integer of 1 to 4, preferably 1 to 2, and more preferably 1.

The alkyl group as R₀₁ to R₀₃ is, for example, an alkyl group having a carbon number of 20 or less and is preferably a methyl group, an ethyl group, a propyl group, an isopropyl group, an n-butyl group, a sec-butyl group, a hexyl group, a 2-ethylhexyl group, an octyl group or a dodecyl group. The alkyl group is more preferably an alkyl group having 8 or less carbon atoms. The alkyl group may have a substituent.

As the alkyl group contained in the alkoxycarbonyl group, the same alkyl group as in R₀₁ to R₀₃ is preferred.

The cycloalkyl group may be either a monocyclic cycloalkyl group or a polycyclic cycloalkyl group. The cycloalkyl group is preferably a monocyclic cycloalkyl group having 3 to 8 carbon atoms, such as cyclopropyl group, cyclopentyl group and cyclohexyl group. These cycloalkyl groups may have a substituent.

The halogen atom includes a fluorine atom, a chlorine atom, a bromine atom, and an iodine atom, with a fluorine atom being more preferred.

In a case where R₀₃ represents an alkylene group, this alkylene group is preferably an alkylene group having 1 to 8 carbon atoms, such as methylene group, ethylene group, propylene group, butylene group, hexylene group and octylene group.

The aromatic ring group as Art is preferably an aromatic ring group having 6 to 14 carbon atoms, and examples thereof include a benzene ring, a toluene ring, and a naphthalene ring. These aromatic rings may have a substituent.

Examples of the group Y capable of leaving by an action of acid may include groups represented by —C(R₃₆)(R₃₇)(R₃₈), —C(O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), and —CH(R₃₆)(Ar).

In the formulae, each of R₃₆ to R₃₉ independently represents an alkyl group, a cycloalkyl group, an aryl group, an aralkyl group or an alkenyl group. R₃₆ and R₃₇ may combine with each other to form a ring structure.

Each of R₀₁ and R₀₂ independently represents a hydrogen atom, an alkyl group, a cycloalkyl group, an aryl group, an aralkyl group or an alkenyl group.

Ar represents an aryl group.

The alkyl group as R₃₆ to R₃₉, R₀₁ or R₀₂ is preferably an alkyl group having 1 to 8 carbon atoms, and examples thereof include a methyl group, an ethyl group, a propyl group, an n-butyl group, a sec-butyl group, a hexyl group, and an octyl group.

The cycloalkyl group as R₃₆ to R₃₉, R₀₁ or R₀₂ may be a monocyclic cycloalkyl group or a polycyclic cycloalkyl group. The monocyclic cycloalkyl group is preferably a cycloalkyl group having 3 to 8 carbon atoms, and examples thereof may include a cyclopropyl group, a cyclobutyl group, a cyclopentyl group, a cyclohexyl group, and a cyclooctyl group. The polycyclic cycloalkyl group is preferably a cycloalkyl group having 6 to 20 carbon atoms, and examples thereof may include an adamantyl group, a norbornyl group, an isoboronyl group, a camphanyl group, a dicyclopentyl group, an α-pinel group, a tricyclodecanyl group, a tetracyclododecyl group, and an androstanyl group. Further, some of carbon atoms in the cycloalkyl group may be substituted with a heteroatom such as oxygen atom.

The aryl group as R₃₆ to R₃₉, R₀₁, R₀₂ or Ar is preferably an aryl group having 6 to 10 carbon atoms, and examples thereof may include a phenyl group, a naphthyl group, and an anthryl group.

The aralkyl group as R₃₆ to R₃₉, R₀₁ or R₀₂ is preferably an aralkyl group having 7 to 12 carbon atoms, and preferred examples thereof may include a benzyl group, a phenethyl group, and a naphthylmethyl group.

The alkenyl group as R₃₆ to R₃₉, R₀₁, or R₀₂ is preferably an alkenyl group having 2 to 8 carbon atoms, and examples thereof include a vinyl group, an allyl group, a butenyl group, and a cyclohexenyl group.

The ring that may be formed by combining R₃₆ and R₃₇ with each other may be either a monocyclic type or a polycyclic type. The monocyclic type is preferably a cycloalkane structure having 3 to 8 carbon atoms, and examples thereof include a cyclopropane structure, a cyclobutane structure, a cyclopentane structure, a cyclohexane structure, a cycloheptane structure, and a cyclooctane structure. The polycyclic type is preferably a cycloalkane structure having 6 to 20 carbon atoms, and examples thereof include an adamantane structure, a norbornane structure, a dicyclopentane structure, a tricyclodecane structure, and a tetracyclododecane structure. Further, some carbon atoms in the ring structure may be substituted with a heteroatom such as oxygen atom.

Each of the groups above may have a substituent. Examples of the substituent may include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The substituent has preferably 8 or less carbon atoms.

The group Y capable of leaving by an action of acid is more preferably a structure represented by the following formula (B):

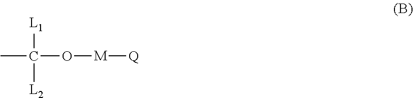

In the formula, each of L₁ and L₂ independently represents a hydrogen atom, an alkyl group, a cycloalkyl group, an aryl group or an aralkyl group.

M represents a single bond or a divalent linking group.

Q represents an alkyl group, a cycloakyl group, a cyclic aliphatic group, an aromatic ring group, an amino group, an ammonium group, a mercapto group, a cyano group or an aldehyde group. Also, the cyclic aliphatic group and the aromatic ring group may contain a heteroatom.

Further, at least two members of Q, M and L₁ may combine with each other to form a 5- or 6-membered ring.

The alkyl group as L₁ and L₂ is, for example, an alkyl group having 1 to 8 carbon atoms, and specific examples thereof may include a methyl group, an ethyl group, a propyl group, an n-butyl group, a sec-butyl group, a hexyl group, and an octyl group.

The cycloalkyl group as L₁ and L₂ is, for example, a cycloalkyl group having 3 to 15 carbon atoms, and specific examples thereof may include a cyclopentyl group, a cyclohexyl group, a norbornyl group, and an adamantyl group.

The aryl group as L₁ and L₂ is, for example, an aryl group having 6 to 15 carbon atoms, and specific examples thereof may include a phenyl group, a tolyl group, a naphthyl group, and an anthryl group.

The aralkyl group as L₁ and L₂ is, for example, an aralkyl group having 6 to 20 carbon atoms, and specific examples thereof may include a benzyl group and a phenethyl group.

The divalent linking group as M is, for example, an alkylene group (e.g., a methylene group, an ethylene group, a propylene group, a butylene group, a hexylene group, an octylene group), a cycloalkylene group (e.g., a cyclopentylene group or a cyclohexylene group), an alkenylene group (e.g., an ethenylene group, a propenylene group or a butenylene group), an arylene group (e.g., a phenylene group, a tolylene group, or a naphthylene group), —S—, —O—, —CO—, —SO₂—, —N(R₀)—, or a combination of two or more thereof. Here. R₀ is a hydrogen atom or an alkyl group. The alkyl group as R₀ is, for example, an alkyl group having 1 to 8 carbon atoms, and specific examples thereof may include a methyl group, an ethyl group, a propyl group, an n-butyl group, a sec-butyl group, a hexyl group, and an octyl group.

Examples of the alkyl group and cycloalkyl group as Q are the same as those of respective groups of as L₁ and L₂ as described above.

The cyclic aliphatic group and aromatic ring group as Q include, for example, the cycloalkyl group and the aryl group as L₁ and L₂. These cycloalkyl group and aryl group are preferably a group having 3 to 15 carbon atoms.

The heteroatom-containing cyclic aliphatic group or aromatic ring group as Q includes, for example, a group having a heterocyclic structure, such as thiirane, cyclothiolane, thiophene, furan, pyrrole, benzothiophene, benzofuran, benzopyrrole, triazine, imidazole, benzimidazole, triazole, thiadiazole, thiazole and pyrrolidone, but the ring is not limited thereto as long as it is a ring composed of carbon and a heteroatom or a ring composed of only a heteroatom.

Examples of the ring structure that may be formed by combining at least two members of Q, M and L₁ with each other may include a 5- or 6-membered ring structure where a propylene group or a butylene group is formed by the members above. Further, this 5- or 6-membered ring structure contains an oxygen atom.

Each of the groups represented by L₁, L₂, M and Q in Formula (2) may have a substituent. Examples of the substituent may include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The substituent has preferably 8 or less carbon atoms.

The group represented by -(M-Q) is preferably a group having 1 to 20 carbon atoms, more preferably a group having 1 to 10 carbon atoms, and still more preferably a group having 1 to 8 carbon atoms.

Specific examples of the repeating unit represented by Formula (P1) are illustrated below, but the present invention is not limited thereto.

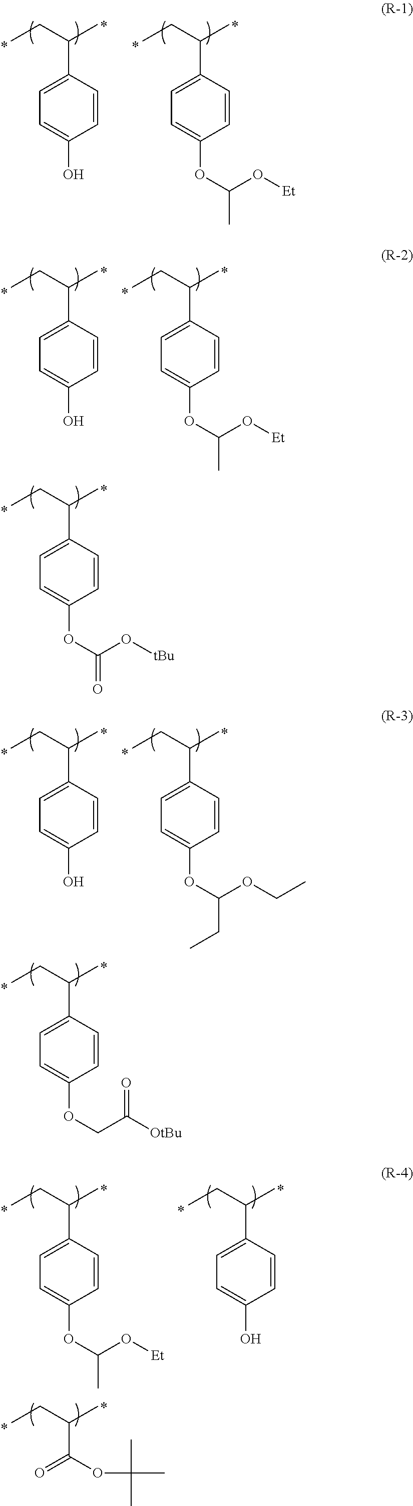

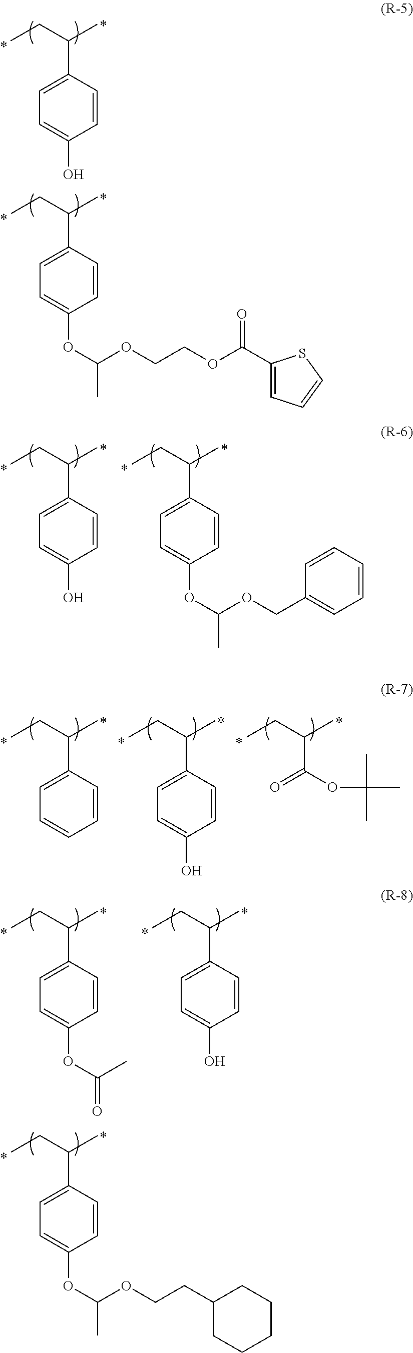

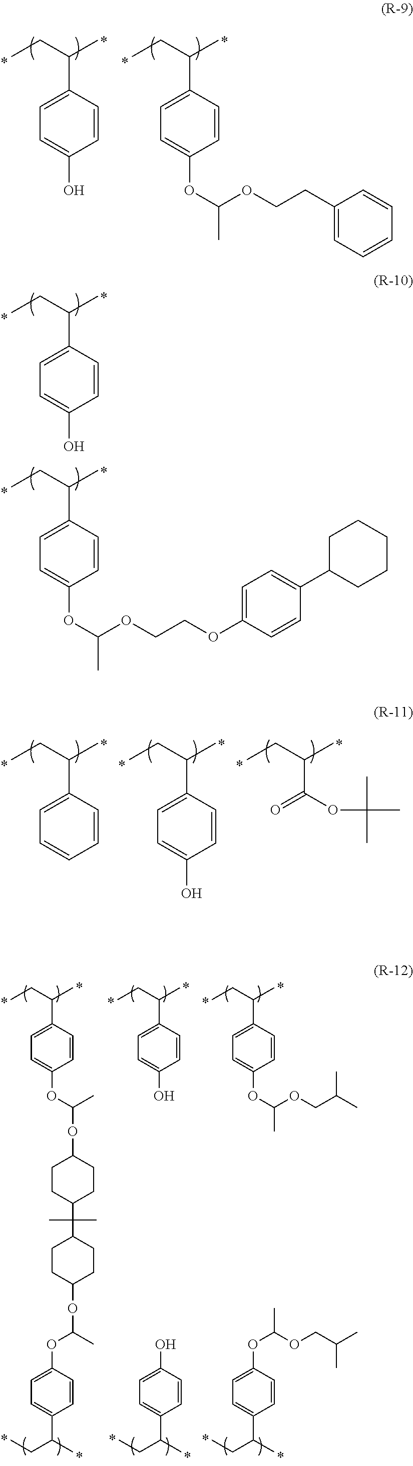

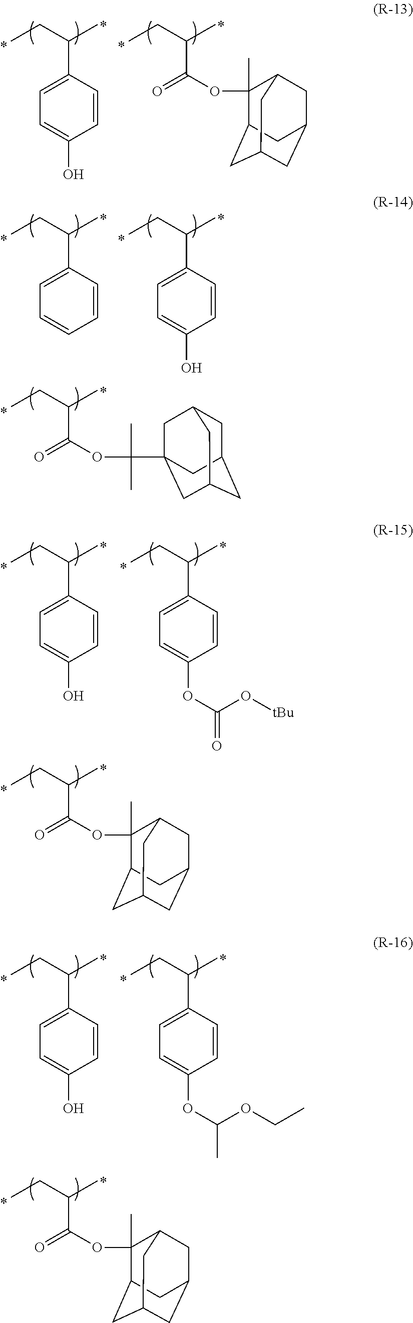

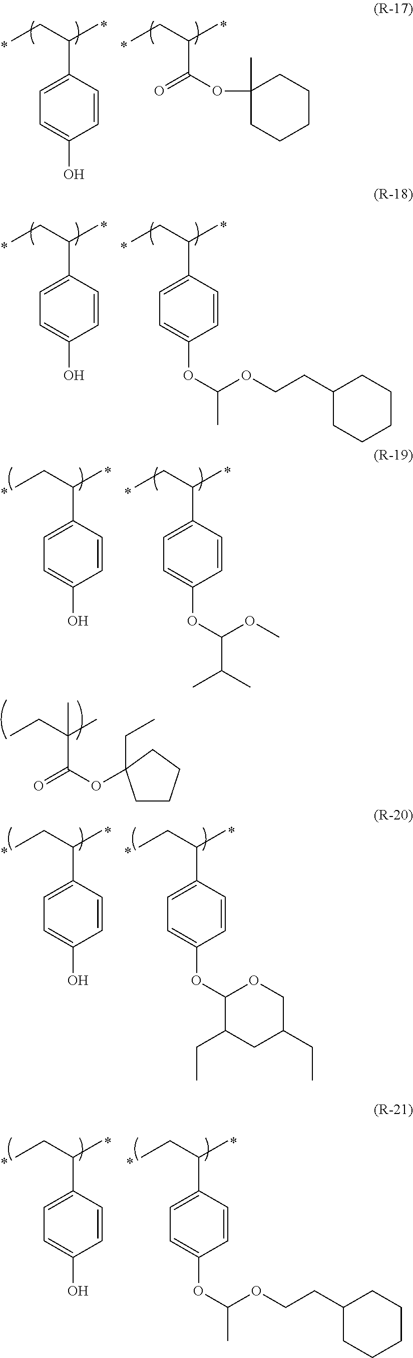

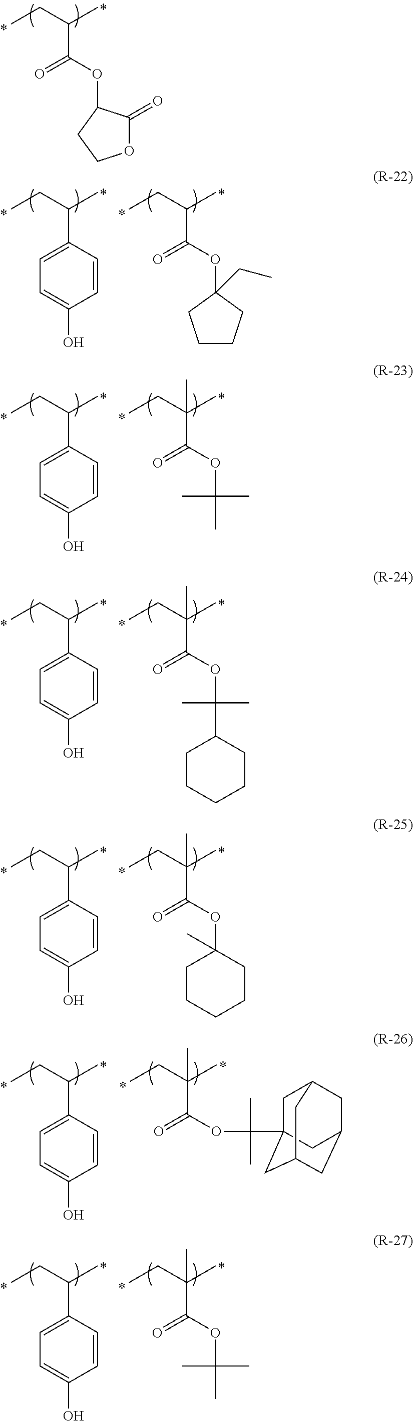

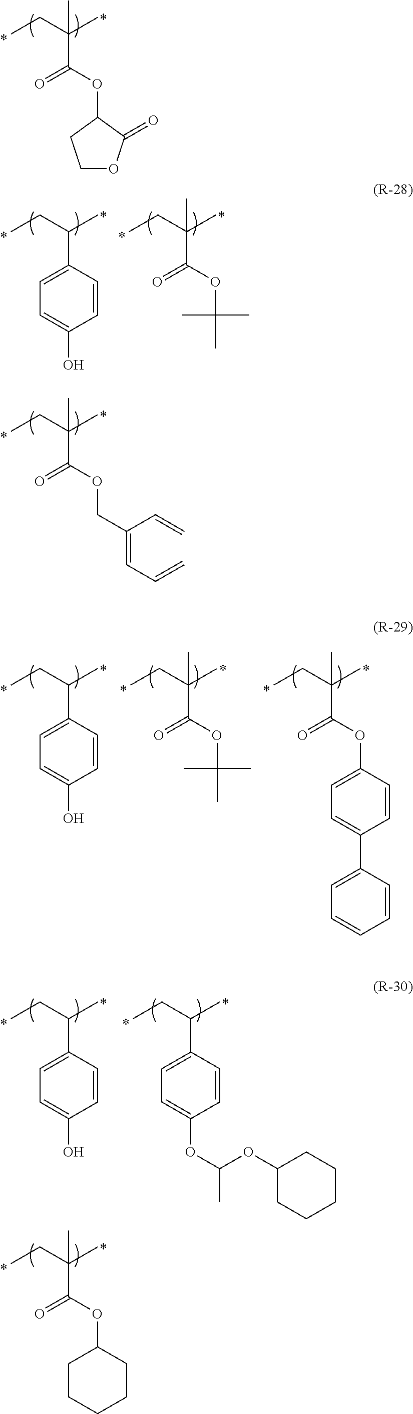

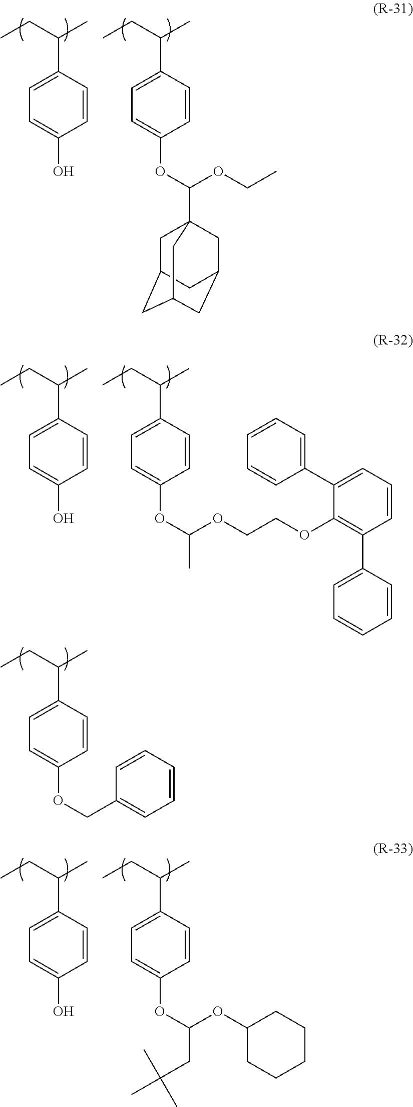

The composition ratio of each repeating unit of the following specific examples is in a molar ratio.

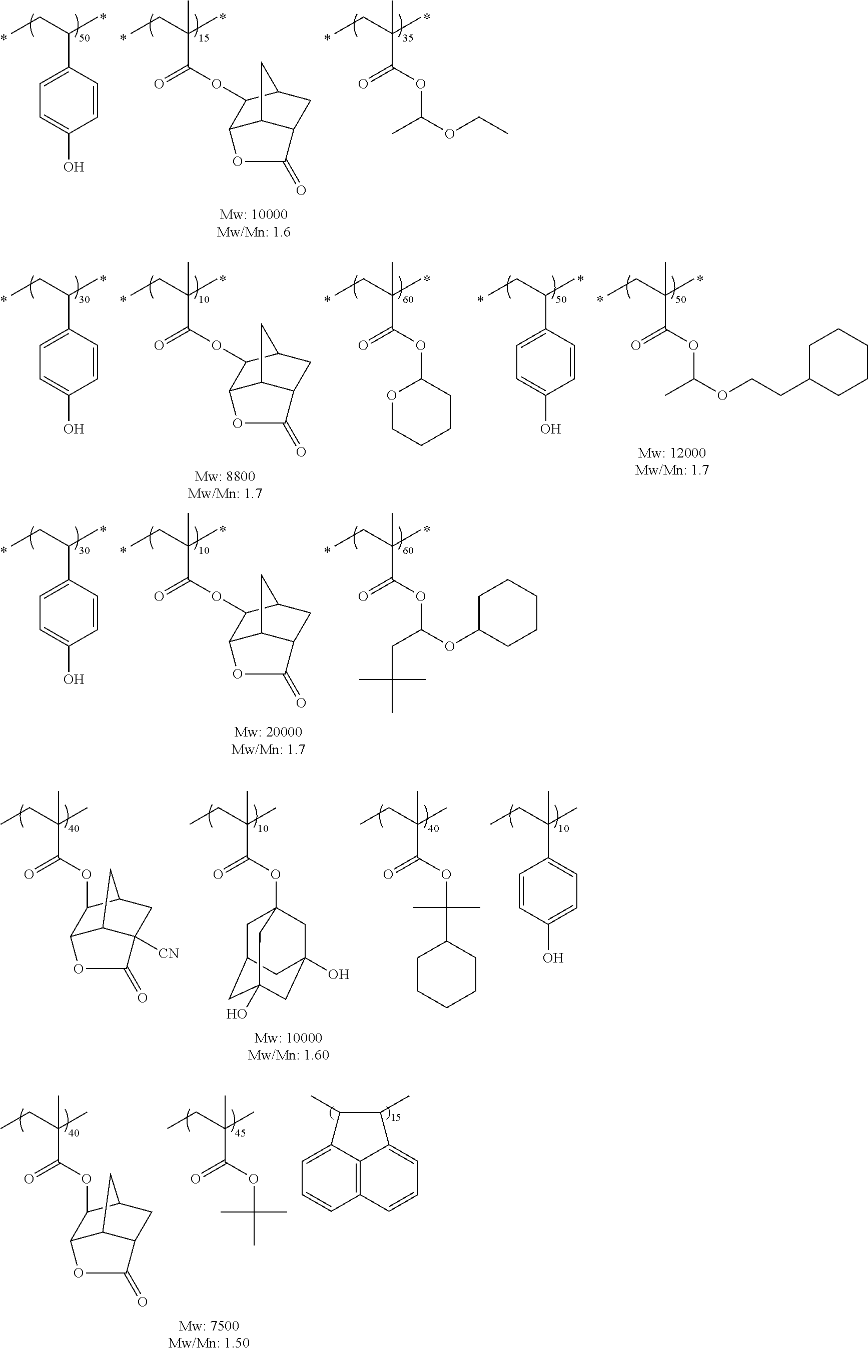

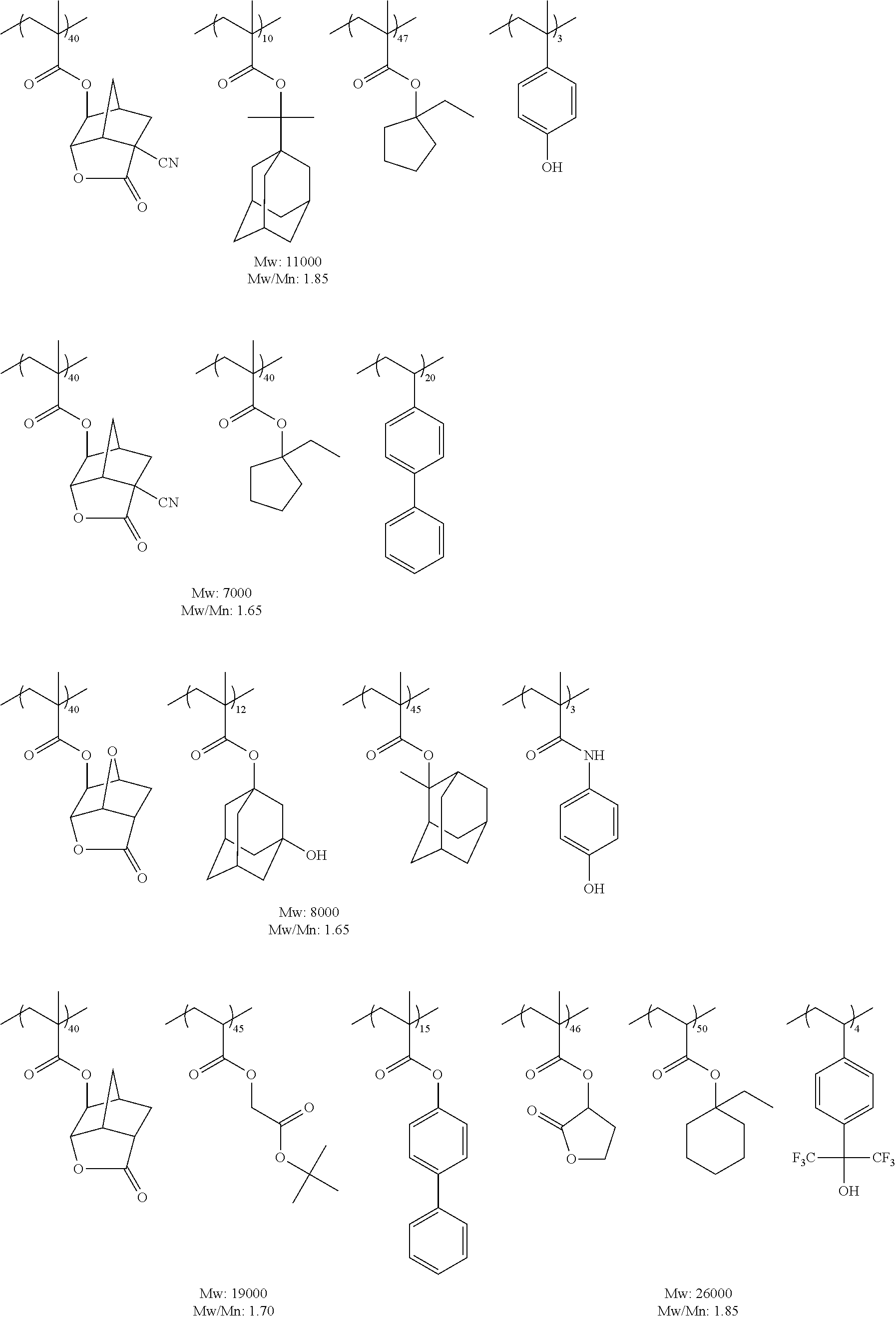

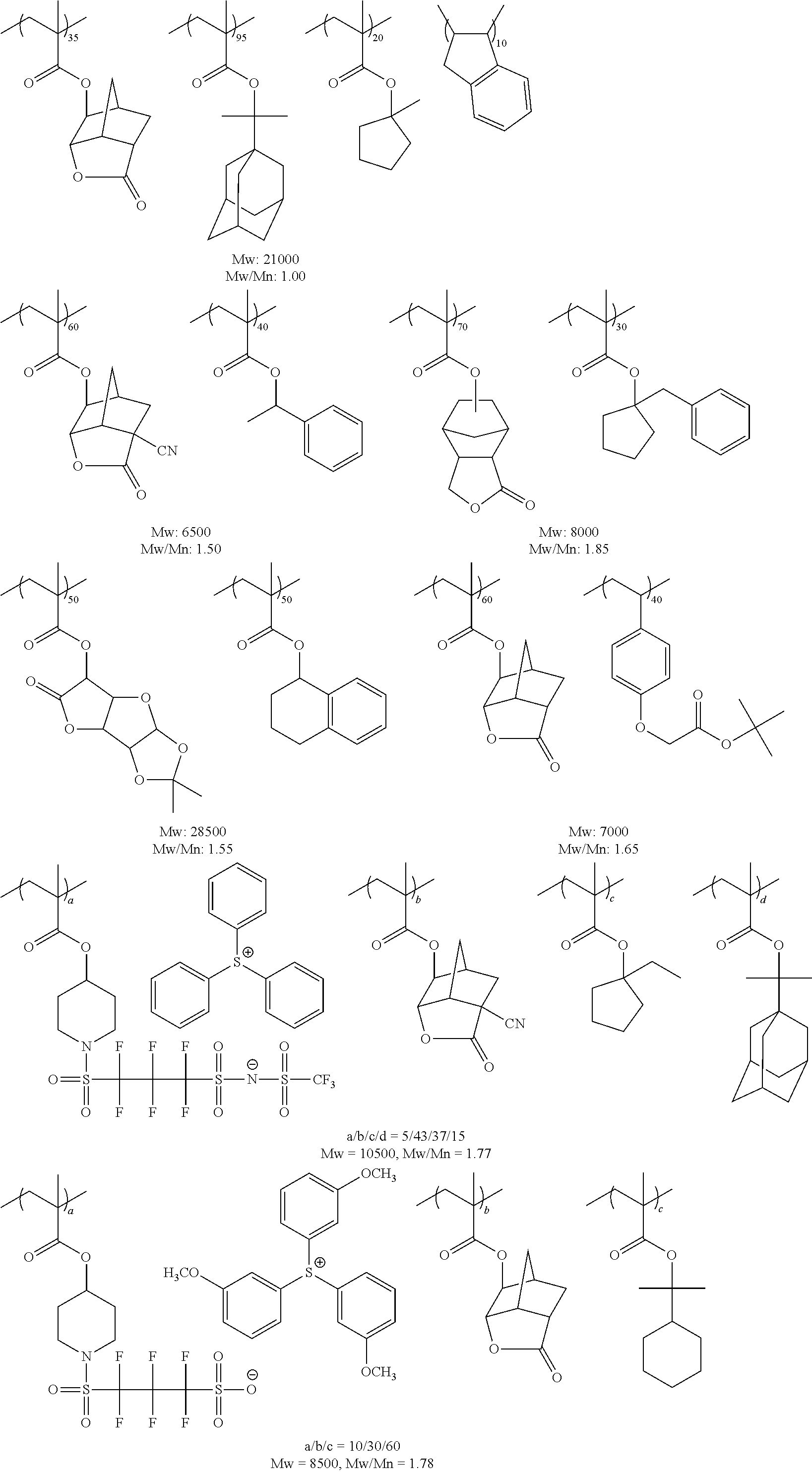

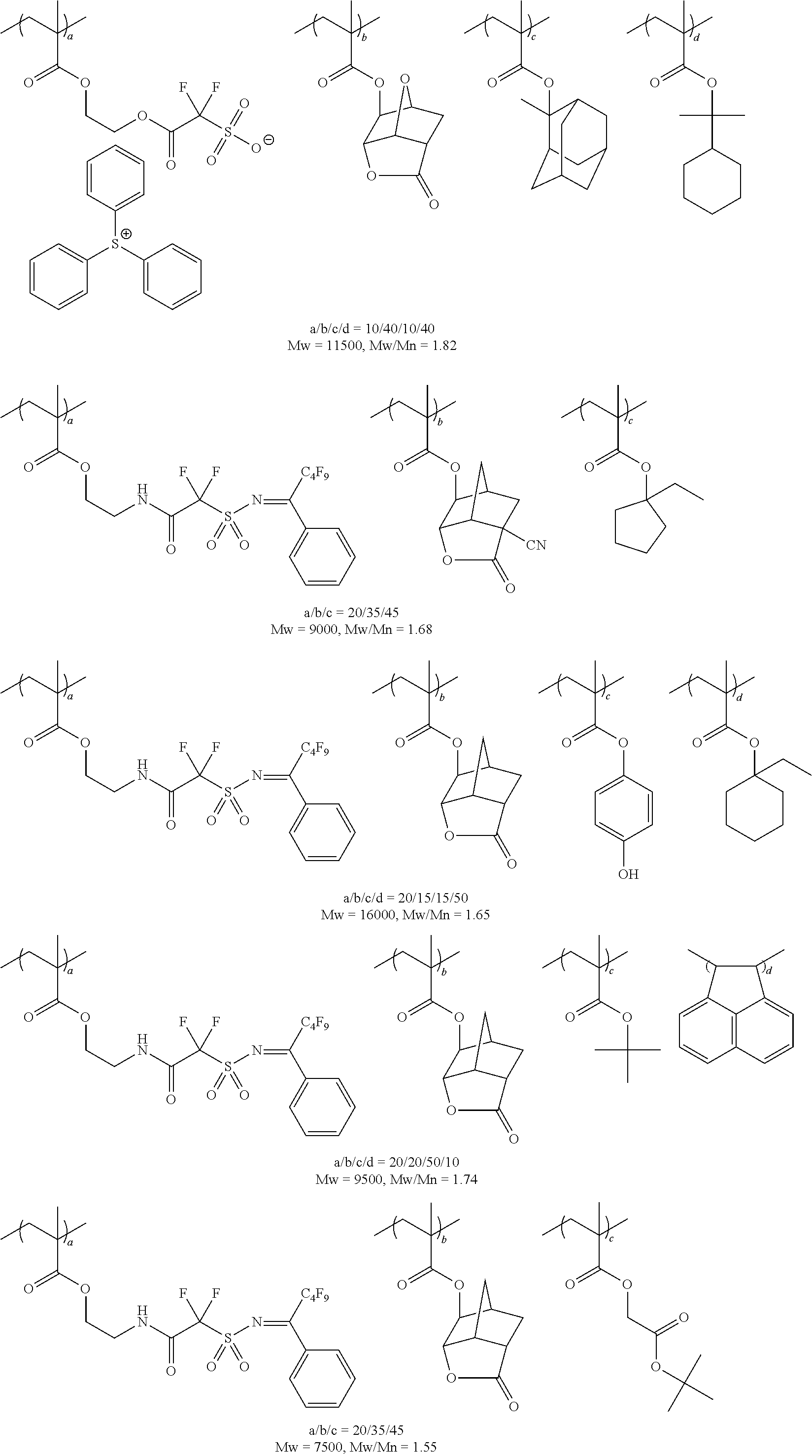

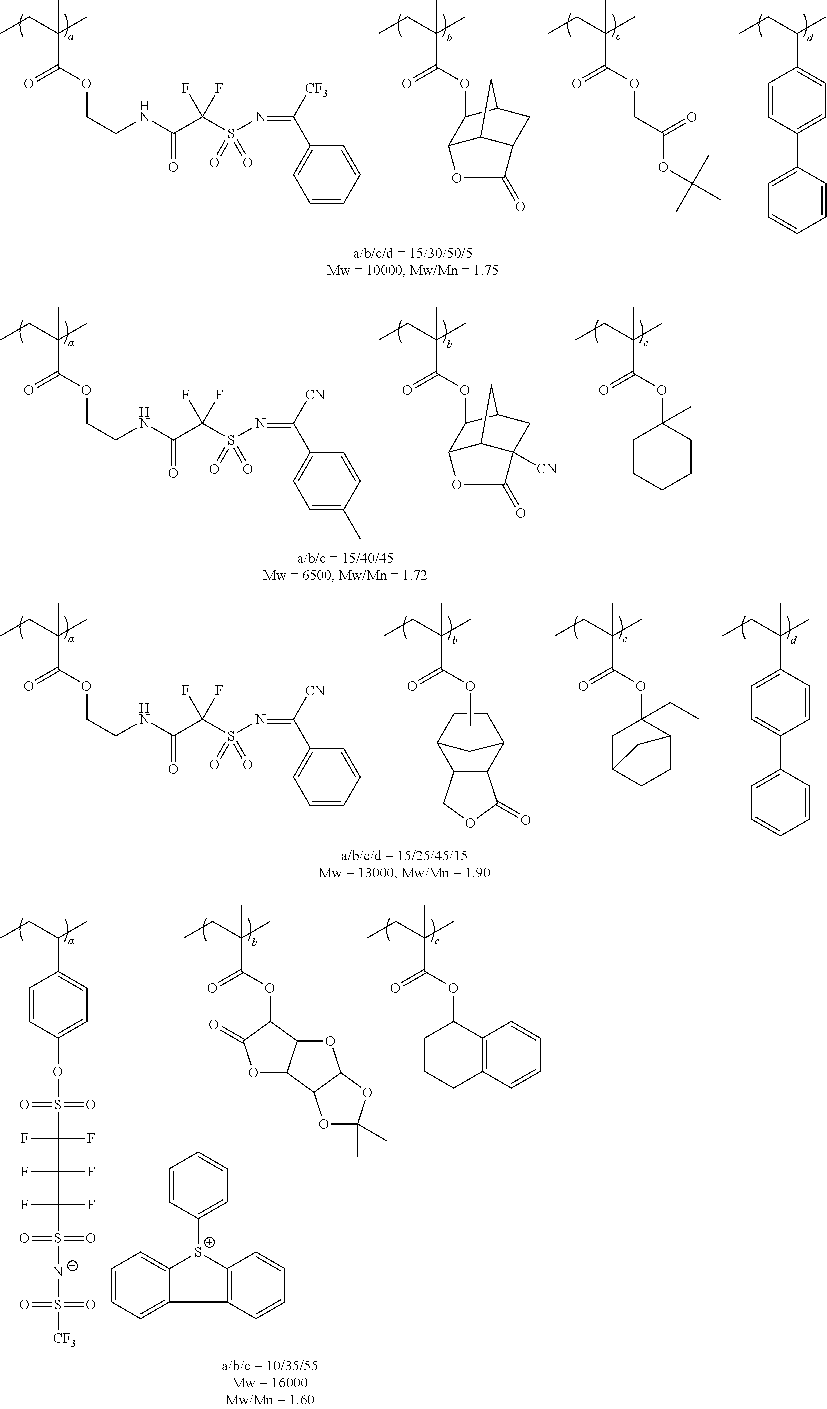

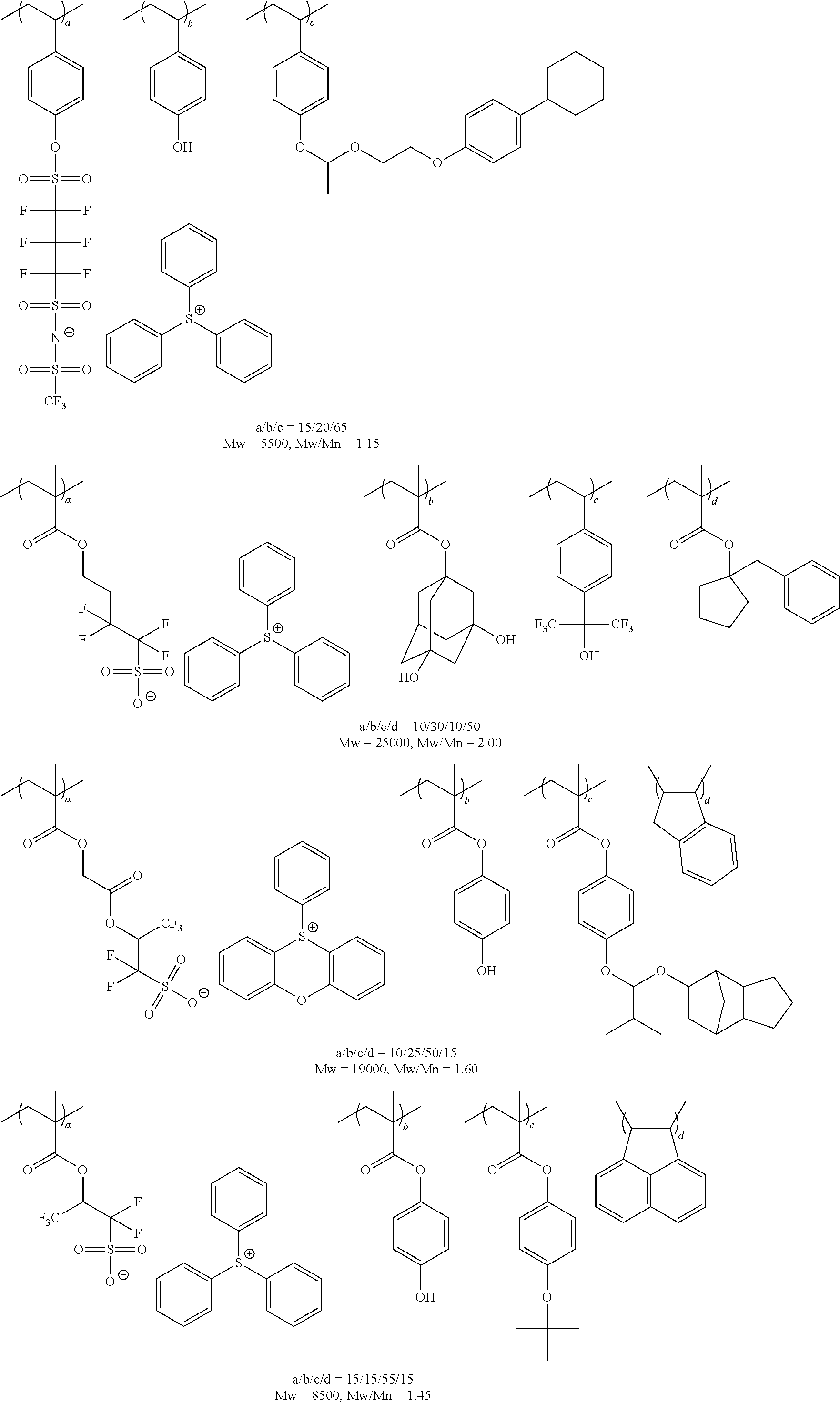

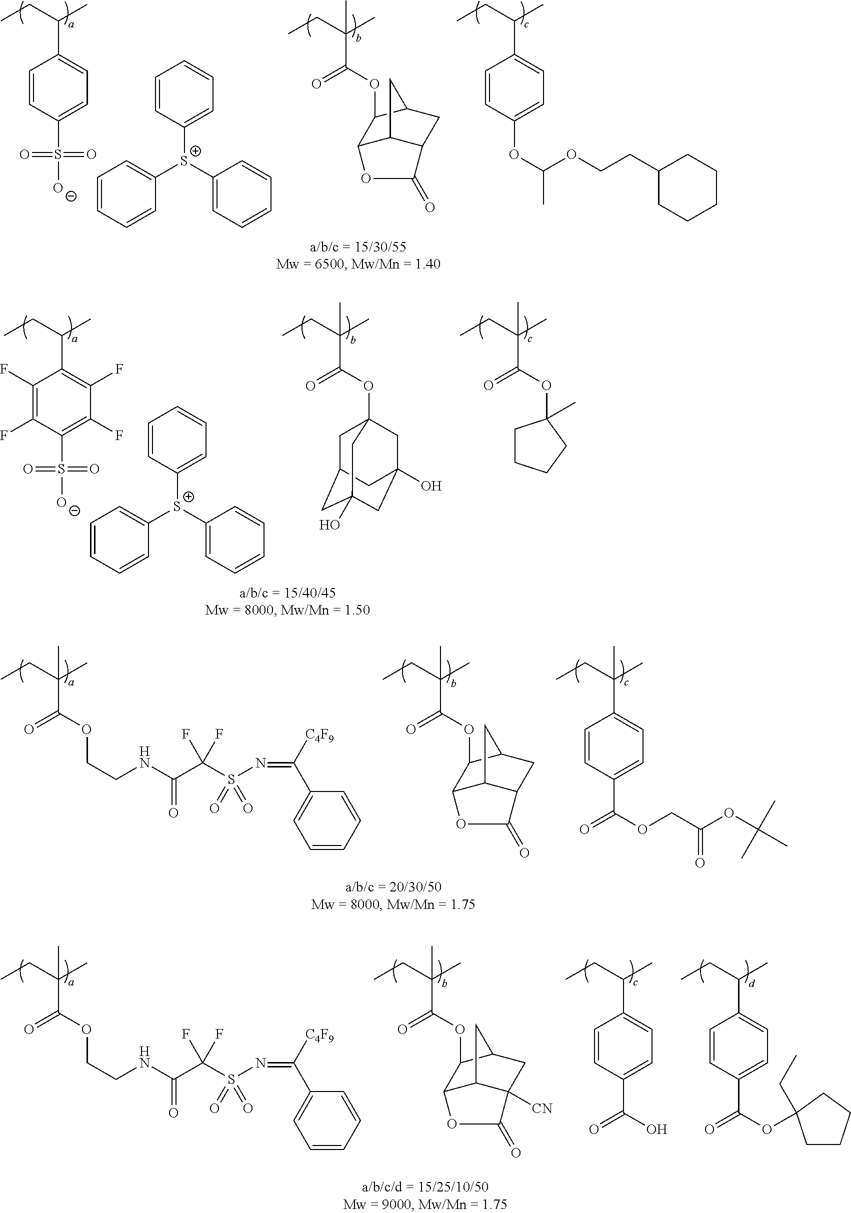

In the above specific examples, tBu represents a t-butyl group.

The resin (A) in the present invention may be synthesized by a conventional method (for example, radical polymerization, living radical polymerization, or anionic polymerization). Examples of a general synthesis method may include a batch polymerization method of dissolving monomer species and an initiator in a solvent and heating the solution to perform the polymerization, a dropping polymerization method of adding dropwise a solution containing monomer species and an initiator to a heated solvent over 1 to 10 hours, and the like, but the dropping polymerization method is preferred. Examples of a reaction solvent may include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and further a solvent capable of dissolving the composition of the present invention, which will be described below, such as propylene glycol monomethyl ether acetate, propylene glycol monomethyl ether, and cyclohexanone. The polymerization is more preferably performed by using the same solvent as the solvent used in the photosensitive composition of the present invention. Accordingly, generation of particles during storage may be suppressed.

The polymerization reaction is preferably performed under an inert gas atmosphere such as nitrogen and argon. As the polymerization initiator, a commercially available radical initiator (azo-based initiator, peroxide, etc.) is used to initiate the polymerization. The radical initiator is preferably an azo-based initiator, and an azo-based initiator having an ester group, a cyano group or a carboxyl group is preferred. Preferred examples of the initiator may include azobisisobutyronitrile, azobisdimethylvaleronitrile, dimethyl 2,2′-azobis(2-methylpropionate) and the like. The initiator is added additionally or in parts, if desired, and after the completion of reaction, the reaction product is poured in a solvent, and a desired polymer is recovered by a powder or solid recovery method, or the like. The reaction concentration is 5 to 50% by mass, and preferably 10 to 30% by mass. The reaction temperature is usually 10° C. to 150° C., preferably 30° C. to 120° C. and more preferably 60° C. to 100° C.

After the completion of reaction, the reaction solution is allowed to cool to room temperature and purified. The purification may be performed by a conventional method, such as a liquid-liquid extraction method of applying water-washing or combining water-washing with an appropriate solvent to remove residual monomers or oligomer components, a purification method in a solution state, such as ultrafiltration of removing only those having a molecular weight not more than a specific molecular weight by virtue of extraction, a reprecipitation method of adding dropwise a resin solution in a poor solvent to solidify the resin in the poor solvent to remove residual monomers and the like, and a purification method in a solid state, such as washing of the resin slurry separated by filtration with a poor solvent.

For example, the resin is precipitated as a solid by contacting the reaction solution with a solvent (poor solvent) in which the resin is sparingly soluble or insoluble and which is in a volumetric amount of 10 times or less and preferably from 10 to 5 times the reaction solution.

The solvent (precipitation or reprecipitation solvent) used at the time of operating precipitation or reprecipitation from the polymer solution may be sufficient if the solvent is a poor solvent for the polymer, and the solvent may be appropriately selected from a hydrocarbon, a halogenated hydrocarbon, a nitro compound, ether, ketone, ester, carbonate, alcohol, carboxylic acid, water, and a mixed solvent including these solvents, according to the kind of the polymer, and may be used. Among these solvents, a solvent including at least alcohol (particularly, methanol or the like) or water is preferred as the precipitation or reprecipitation solvent.

The amount of the precipitation or reprecipitation solvent used may be appropriately selected in consideration of the efficiency, yield and the like, but in general, the amount is 100 to 10,000 parts by mass, preferably 200 to 2,000 parts by mass, and more preferably 300 to 1,000 parts by mass, based on 100 parts by mass of the polymer solution.

The temperature during the precipitation or reprecipitation may be appropriately selected in consideration the efficiency or operability but is usually 0 to 50° C., and preferably in the vicinity of room temperature (for example, approximately 20 to 35° C.). The precipitation or reprecipitation operation may be performed by a publicly known method such as batch system and continuous system using a commonly-used mixing vessel such as stirring tank.

The precipitated or reprecipitated polymer is usually subjected to commonly-used solid-liquid separation such as filtration and centrifugation, and then dried and used. The filtration is performed by using a solvent-resistant filter element, and preferably under pressure. The drying is performed under normal pressure or reduced pressure (preferably under reduced pressure) at a temperature of approximately 30 to 100° C. and preferably at a temperature of approximately 30 to 50° C.

Furthermore, in the present invention, after the resin is precipitated once and separated, this resin is dissolved in the solvent (C1) and filtered using a filter as described above. This filtrate is preferably re-precipitated by contacting with a solvent (poor solvent) that is sparingly soluble or insoluble to the resin. That is, the present invention may be the method which comprises, after the completion of the radical polymerization reaction, allowing the polymer to contact with the sparingly soluble or insoluble solvent to precipitate a resin (process a), separating the resin from the solution (process b), dissolving the resin in the solvent (C1) to prepare the resin solution A (process c), filtering the resin solution A through a filter (process d), allowing the sparingly soluble or insoluble solvent to contact with the filtrate in the process d in less than 10 times of the volume quantity (preferably 5 times or less the volume quantity) of the resin solution A, to thereby precipitate a solid resin solid (process d) and separate the precipitated resin (process e).

Also, as described above, in order to suppress aggregation of the resin after the preparation of the composition, it is preferred to apply a process in which a resin solution A before being subjected to the process (d) is heated at 30° C. to 90° C. for 30 minutes to 12 hours, for example, as described in Japanese Patent Application Laid-Open No. 2009.037108.

In the present invention, the weight average molecular weight of the resin (A) in terms of a standard polystyrene in accordance with the GPC method as described above is 7,000 or more, preferably from 7,000 to 200,000, more preferably 7,000 to 50,000, still more preferably 7.000 to 40,000, and particularly preferably 7,000 to 30,000. If the weight average molecular weight is smaller than 7000, the solubility in the organic developer is excessively high and so it is likely that a fine pattern cannot be formed

The polydispersity (molecular weight distribution) is usually in a range of 1.0 to 3.0, preferably 1.0 to 2.6, more preferably 1.0 to 2.0, and particularly preferably 1.4 to 2.0. The smaller the molecular weight distribution is, the better the resolution and resist shape are, and the smoother the side wall of the resist pattern is, and thus roughness is excellent.

In the actinic ray-sensitive or radiation-sensitive resin composition of the present invention, the blending ratio of the resin (A) in the entire composition is preferably 30 to 99% by mass and more preferably 60 to 95% by mass based on the total solid content of the composition.

Furthermore, in the present invention, the resin (A) may be used either alone or in combination of a plurality thereof. When a plurality of resin (A) is used in combination, a resin solution containing a resin (A) and the solvent (C1) is filtered using a filter and at least one of the plurality of resin (A) is obtained from the filtrate in this process

[2] Compound (B) Capable of Generating an Acid Upon Irradiation with Actinic Ray or Radiation

The composition of the present invention, typically, also contains a compound (B) capable of generating an acid upon irradiation with an actinic ray or radiation (hereinafter, also referred to as an “acid generator”). The compound (B) capable of generating an acid upon irradiation with an actinic ray or radiation is preferably a compound capable of generating an organic acid upon irradiation with an actinic ray or radiation.

The compound (B) capable of generating an acid upon irradiation with an actinic ray or radiation may be in the form of a low-molecular compound, or in the form of being incorporated into a portion of a polymer. In addition, the form of a low molecular compound and the form of being incorporated into a portion of a polymer may be used in combination.

When the compound (B) capable of generating an acid upon irradiation with an actinic ray or radiation is in the form of a low molecular compound, the molecular weight is preferably 3,000 or less, more preferably 2,000 or less, and still more preferably 1,000 or less.

When the compound (B) capable of generating an acid upon irradiation with an actinic ray or radiation is in the form of being incorporated into a portion of a polymer, the compound (B) may be incorporated into a portion of the above-described acid-decomposable resin, or may be incorporated into a resin different from the acid-decomposable resin.

In the present invention, the compound (B) capable of generating an acid upon irradiation with an actinic ray or radiation is preferably in the form of a low molecular compound.

The acid generator may be appropriately selected from a photo-initiator for cationic photopolymerization, a photo-initiator for radical photopolymerization, a photodecoloring agent for dyes, a photodiscoloring agent, or a publicly known compound capable of generating an acid upon irradiation with an actinic ray or radiation, which is used for microresist or the like, and a mixture thereof, and be used.

Examples thereof may include a diazonium salt, a phosphonium salt, a sulfonium salt, an iodonium salt, imidosulfonate, oxime sulfonate, diazodisulfone, disulfone, and o-nitrobenzyl sulfonate.

Among the acid generators, examples of preferred compounds may include compounds represented by the following Formulas (ZI), (ZII) and (ZIII).

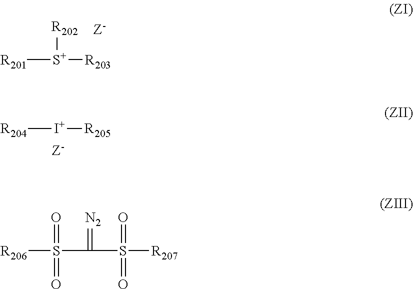

In Formula (ZI), each of R₂₀₁, R₂₀₁ and R₂₀₃ independently represents an organic group.

The carbon number of the organic group as R₂₀₁, R₂₀₂ and R₂₀₃ is generally 1 to 30, and preferably 1 to 20.

Furthermore, two of R₂₀₁ to R₂₀₃ may be bonded to each other to form a ring structure, and the ring may include an oxygen atom, a sulfur atom, an ester bond, an amide bond or a carbonyl group therein. Examples of the group formed by bonding of two of R₂₀₁ to R₂₀₃ may include an alkylene group (for example, a butylene group and a pentylene group).

Z⁻ represents a non-nucleophilic anion.

Examples of the non-nucleophilic anion as Z⁻ may include sulfonate anion, carboxylate anion, sulfonylimide anion, bis(alkylsulfonyl)imide anion, tris(alkylsulfonyl)methyl anion and the like.

The non-nucleophilic anion is an anion having an extremely low ability of causing a nucleophilic reaction and capable of suppressing the decomposition with time due to an intramolecular nucleophilic reaction. Accordingly, the stability of the resist composition with time is enhanced.

Examples of the sulfonate anion may include an aliphatic sulfonate anion, an aromatic sulfonate anion, a camphorsulfonate anion and the like.

Examples of the carboxylate anion may include an aliphatic carboxylate anion, an aromatic carboxylate anion, an aralkylcarboxylate anion and the like.

The aliphatic moiety in the aliphatic sulfonate anion and the aliphatic carboxylate anion may be an alkyl group or a cycloalkyl group, preferably an alkyl group having 1 to 30 carbon atoms and a cycloalkyl alkyl group having 3 to 30 carbon atoms, and examples thereof may include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a noradecyl group, an eicosyl group, a cyclopropyl group, a cyclopentyl group, a cyclohexyl group, an adamantyl group, a norbornyl group, a bornyl group.

The aromatic group in the aromatic sulfonate anion and the aromatic carboxylate anion is preferably an aryl group having from 6 to 14 carbon atoms, for example, a phenyl group, a tolyl group, and a naphthyl group.

The alkyl group, the cycloalkyl group and the aryl group in the aliphatic sulfonate anion and the aromatic sulfonate anion may have a substituent. Examples of the substituent of the alkyl group, the cycloalkyl group and the aryl group in the aliphatic sulfonate anion and the aromatic sulfonate anion may include a nitro group, a halogen atom (a fluorine atom, a chlorine atom, a bromine atom and an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) and the like. Examples of the aryl group and the ring structure, which each group has, further include, as the substituent, an alkyl group (preferably having 1 to 15 carbon atoms) and a cycloalkyl group (preferably having 3 to 15 carbon atoms).

The aralkyl group in the aralkylcarboxylate anion is preferably an aralkyl group having 7 to 12 carbon atoms, for example, a benzyl group, a phenethyl group, a naphthylmethyl group, and a naphthylethyl group.

The alkyl group, the cycloalkyl group, the aryl group and the aralkyl group in the aliphatic carboxylate anion, the aromatic carboxylate anion and the aralkylcarboxylate anion may have a substituent. Examples of the substituent include the halogen atom, the alkyl group, the cycloalkyl group, the alkoxy group, the alkylthio group and the like in the aromatic sulfonate anion.

Examples of the sulfonylimide anion may include saccharin anion.

The alkyl group in the bis(alkylsulfonyl)imide anion and the tris(alkylsulfonyl)methide anion is preferably an alkyl group having 1 to 5 carbon atoms, for example, a methyl group, an ethyl group, a propyl group, an isopropyl group, an n-butyl group, an isobutyl group, a sec-butyl group, a pentyl group, and a neopentyl group.

Two alkyl groups in the bis(alkylsulfonyl)imide anion may be linked to each other to form an alkylene group (preferably having 2 to 4 carbon atoms), and the alkylene group may be bonded to an imide group and two sulfonyl groups to form a ring. Examples of a substituent, which an alkylene group formed by linking two alkyl groups in the alkyl group and the bis(alkylsulfonyl)imide anion with each other may have, may include a halogen atom, an alkyl group substituted with a halogen atom, an alkoxy group, an alkylthio group, an alkyloxysulfonyl group, an aryloxysulfonyl group, a cycloalkylaryloxysulfonyl group and the like, and an alkyl group substituted with a fluorine atom is preferred.

Examples of the other non-nucleophilic anions may include fluorinated phosphate (for example, PF₆⁻), fluorinated boron (for example, BF₄⁻), fluorinated antimony (for example, SbF₆⁻) and the like.

The non-nucleophilic anion of Z⁻ is preferably an aliphatic sulfonate anion in which at least an α-position of sulfonic acid is substituted with a fluorine atom, an aromatic sulfonate anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having 4 to 8 carbon atoms and a benzenesulfonate anion having a fluorine atom, and still more preferably a nonafluorobutanesulfonate anion, a perfluorooctanesulfonate anion, a pentafluorobenzenesulfonate anion and a 3,5-bis(trifluoromethyl)benzenesulfonate anion.

The acid generator is preferably a compound capable of generating an acid represented by the following Formula (V) or (VI) upon irradiation with an actinic ray or radiation. Since the acid generator is the compound capable of generating an acid represented by the following Formula (V) or (VI), the compound has a cyclic organic group, and thus the resolution and roughness performance may be more excellent.

The non-nucleophilic anion may be an anion capable of generating an organic acid represented by the following Formula (V) or (VI).

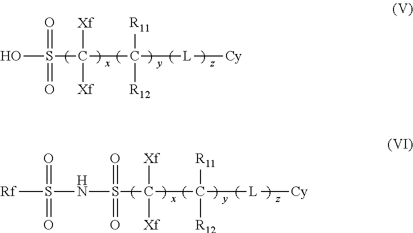

In the formulas,

Each Xf independently represents a fluorine atom or an alkyl group substituted with at least one fluorine atom.

Each of R₁₁ and R₁₂ independently represents a hydrogen atom, a fluorine atom or an alkyl group.

Each L independently represents a divalent linking group.

Cy represents a cyclic organic group.

Rf is a group including a fluorine atom.

x represents an integer of 1 to 20.

y represents an integer of 0 to 10.

z represents an integer of 0 to 10.

Xf represents a fluorine atom or an alkyl group substituted with at least one fluorine atom. The carbon number of the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. More specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉, and more preferably a fluorine atom or CF₃. In particular, it is preferred that both Xfs are a fluorine atom.

Each of R₁₁ and R₁₂ independently represcnts a hydrogen atom, a fluorine atom or an alkyl group. The alkyl group may have a substituent (preferably a fluorine atom) and preferably has 1 to 4 carbon atoms. The alkyl group is more preferably a perfluoroalkyl group having 1 to 4 carbon atoms. Specific examples of the alkyl group having a substituent of R₁₁ and R₁₂ may include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, and among them. CF₃ is preferred.

L represents a divalent linking group. Examples of the divalent linking group may include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms) or a divalent linking group formed by combining a plurality of these groups, and the like. Among them, —COO—, —OCO—, —CONH—, —NHCO—, —CO—, —O—, —SO₂—, —COO-alkylene group-, —OCO-alkylene group-, —CONH-alkylene group- or —NHCO-alkylene group- is preferred, and —COO—, —OCO—, —CONH—, —SO₂—, —COO-alkylene group- or —OCO-alkylene group- is more preferred.

Cy represents a cyclic organic group. Examples of the cyclic organic group may include an alicyclic group, an aryl group and a heterocyclic group.

The alicyclic group may be monocyclic or polycyclic. Examples of the monocyclic alicyclic group may include a monocyclic cycloalkyl group such as a cyclopentyl group, a cyclohexyl group and a cyclooctyl group. Examples of the polycyclic alicyclic group may include a polycyclic cycloalkyl group such as a norbornyl group, a tricyclodecanyl group, a tetracyclodecanyl group, a tetracyclododecanyl group and an adamantyl group. Among them, an alicyclic group with a bulky structure having 7 or more carbon atoms, such as a norbornyl group, a tricyclodecanyl group, a tetracyclodecanyl group, a tetracyclododecanyl group and an adamantyl group, is preferred from the viewpoint of restraining diffusion in film during a PEB (post-exposure baking) process and enhancing the MEEF (Mask Error Enhancement Factor).

The aryl group may be monocyclic or polycyclic. Examples of the aryl group may include a phenyl group, a naphthyl group, a phenanthryl group and an anthryl group. Among them, a naphthyl group having relatively low light absorbance at 193 nm is preferred.

The heterocyclic group may be monocyclic or polycyclic, but a polycyclic heterocyclic group may further suppress the diffusion of an acid. In addition, the heterocyclic group may have aromaticity or may not have aromaticity. Examples of the heterocyclic ring having aromaticity may include a furan ring, a thiophene ring, a benzofuran ring, a benzothiophene ring, a dibenzofuran ring, a dibenzothiophene ring and a pyridine ring. Examples of the heterocyclic ring having no aromaticity may include a tetrahydropyran ring, a lactone ring, a sultone ring and a decahydroisoquinoline ring. The heterocyclic ring in the heterocyclic group is particularly preferably a furan ring, a thiophene ring, a pyridine ring or a decahydroisoquinoline ring. Furthermore, examples of the lactone ring or the sultone ring may include the above-described lactone structure or a sultone structure exemplified in the resin (A).

The cyclic organic group may have a substituent. Examples of the substituent may include an alkyl group (may be straight or branched, and preferably has 1 to 12 carbon atoms), a cycloalkyl group (may be monocyclic, polycyclic or spirocyclic, and preferably has 3 to 20 carbon atoms), an aryl group (preferably has 6 to 14 carbon atoms), a hydroxyl group, an alkoxy group, an ester group, an amide group, a urethane group, a ureido group, a thioether group, a sulfonamide group and a sulfonate ester group. Furthermore, the carbon constituting the cyclic organic group (the carbon contributing to ring formation) may be carbonyl carbon.

x is preferably 1 to 8, and among them, preferably 1 to 4, and particularly preferably 1. y is preferably 0 to 4, and more preferably 0. z is preferably 0 to 8, and among them, preferably 0 to 4.

Examples of the group having a fluorine atom, which is represented by Rf, may include an alkyl group having at least one fluorine atom, a cycloalkyl group having at least one fluorine atom, and an aryl group having at least one fluorine atom.

The alkyl group, the cycloalkyl group and the aryl group may be substituted with a fluorine atom, or may be substituted with another substituent including a fluorine atom. When Rf is a cycloalkyl group having at least one fluorine atom or an aryl group having at least one fluorine atom, examples of the another substituent including a fluorine atom include an alkyl group substituted with at least one fluorine atom.

Further, the alkyl group, the cycloakyl group and the aryl group may be further substituted with a substituent including no fluorine atom. Examples of the substituent may include those including no fluorine atom among those for Cy described above.

Examples of the alkyl group having at least one fluorine atom, which is represented by Rf, may include the same as those described above as the alkyl group substituted with at least one fluorine atom, which is represented by Xf. Examples of the cycloalkyl group having at least one fluorine atom, which is represented by Rf, may include a perfluorocyclopentyl group and a perfluorocyclohexyl group. Examples of the aryl group having at least one fluorine atom, which is represented by Rf, may include a perfluorophenyl group.

In addition, the non-nucleophilic anion is also preferably an anion represented by any one of the following Formulas (B-1) to (B-3).

First, an anion represented by the following Formula (B-1) will be described.

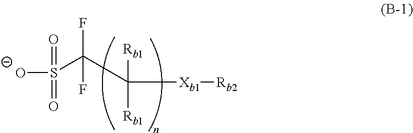

In Formula (B-1), each R_{b1} independently represents a hydrogen atom, a fluorine atom or a trifluoromethyl group (CF₃).

n represents an integer of 1 to 4.

n is preferably an integer of 1 to 3, and more preferably 1 or 2.

X_{b1} represents a single bond, an ether bond, an ester bond (—OCO— or —COO—), or a sulfonate ester bond (—OSO₂— or —SO₃—).

X_{b1} is preferably an ester bond (—OCO— or —COO—), or a sulfonate ester bond (—OSO₂— or —SO₃—).

R_{b2} represents a substituent having 6 or more carbon atoms.

The substituent having 6 or more carbon atoms for R_{b2} is preferably a bulky substituent, and examples thereof include an alkyl group, an alicyclic group, an aryl group, a heterocyclic group and the like, which have 6 or more carbon atoms.

The alkyl group having 6 or more carbon atoms for R_{b2} may be straight or branched and is preferably a straight or branched alkyl group having 6 to 20 carbon atoms, and examples thereof may include a straight or branched hexyl group, a straight or branched heptyl group, a straight or branched octyl group, and the like. From the viewpoint of being bulky, the branched alkyl group is preferred.

The alicyclic group having 6 or more carbon atoms for R_{b2} may be monocyclic or polycyclic. Examples of the monocyclic alicyclic group may include a monocyclic cycloalkyl group such as a cyclohexyl group and a cyclooctyl group. Examples of the polycyclic alicyclic group may include a polycyclic cycloalkyl group such as a norbornyl group, a tricyclodecanyl group, a tetracyclodecanyl group, a tetracyclododecanyl group and an adamantyl group. Among them, an alicyclic group with a bulky structure having 7 or more carbon atoms, such as a norbornyl group, a tricyclodecanyl group, a tetracyclodecanyl group, a tetracyclododecanyl group and an adamantyl group, is preferred from the viewpoint of restraining diffusion in the film during a PEB (post-exposure baking) process and enhancing the MEEF (Mask Error Enhancement Factor).

The aryl group having 6 or more carbon atoms for R_{b2} may be monocyclic or polycyclic. Examples of the aryl group may include a phenyl group, a naphthyl group, a phenanthryl group and an anthryl group. Among them, a naphthyl group having relatively low light absorbance at 193 nm is preferred.

The heterocyclic group having 6 or more carbons for R_{b2} may be monocyclic or polycyclic, but a polycyclic heterocyclic group may further suppress the diffusion of an acid. Furthermore, the heterocyclic group may have aromaticity or may not have aromaticity. Examples of the heterocyclic ring having aromaticity may include a benzofuran ring, a benzothiophene ring, a dibenzofuran ring and a dibenzothiophene ring. Examples of the heterocyclic ring having no aromaticity may include a tetrahydropyran ring, a lactone ring and a decahydroisoquinoline ring. The heterocyclic ring in the heterocyclic group is particularly preferably a benzofuran ring or a decahydroisoquinoline ring. Further, examples of the lactone ring may include the above-described lactone structure exemplified in the resin (A).

The substituent having 6 or more carbon atoms for R_{b2} may further have a substituent. Examples of the further substituent may include an alkyl group (may be straight or branched, and preferably has 1 to 12 carbon atoms), a cycloalkyl group (may be any one of monocyclic, polycyclic or spirocyclic, and preferably has 3 to 20 carbon atoms), an aryl group (preferably has 6 to 14 carbon atoms), a hydroxyl group, an alkoxy group, an ester group, an amide group, a urethane group, a ureido group, a thioether group, a sulfonamide group and a sulfonato eater group. Furthermore, the carbon constituting the above-described alicyclic group, aryl group or heterocyclic group (the carbon contributing to ring formation) may be carbonyl carbon.

Specific examples of the anion represented by Formula (B-1) are as follows, but the present invention is not limited thereto.

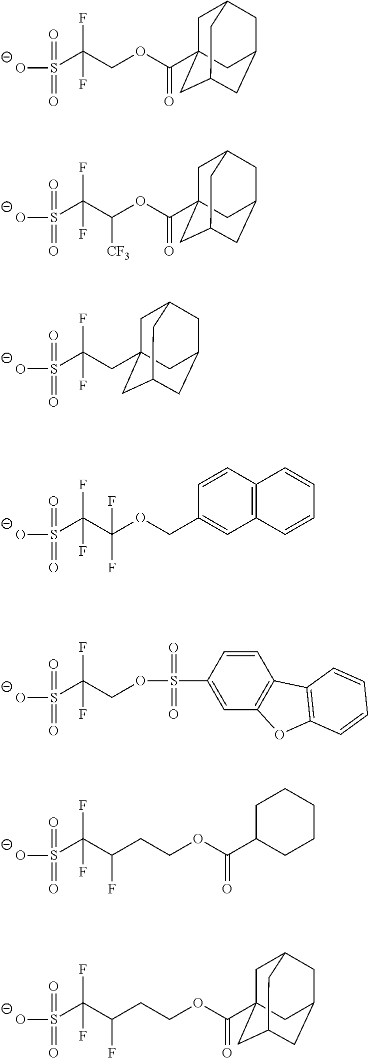

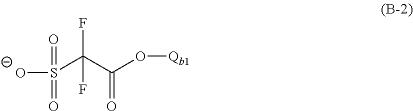

In Formula (B-2),

Q_{b1} represents a group having a lactone structure, a group having a sultone structure or a group having a cyclic carbonate structure.

Examples of the lactone structure and the sultone structure for Q_{b1} may include the same lactone structure and the same sultone structure as in the repeating unit having the lactone structure and the sultone structure, which are previously described in the paragraph of resin (P). Specifically, examples thereof may include the lactone structure represented by any one of Formulas (LC1-1) to (LC1-17), or the sultone structure represented by any one of Formulas (SL1-1) to (SL1-3).

The lactone structure or the sultone structure may be directly bonded to an oxygen atom of the ester group in Formula (B-2), but the lactone structure or the sultone structure may be bonded to an oxygen atom of an ester group through an alkylene group (for example, a methylene group and an ethylene group). In that case, a group having the lactone structure or the sultone structure may be an alkyl group having the lactone structure or the sultone structure as a substituent.

The cyclic carbonate structure for Q_{b1} is preferably a 5- to 7-membered cyclic carbonate structure.

The cyclic carbonate structure may be directly bonded to an oxygen atom of the ester group in Formula (B-2), but the cyclic carbonate structure may be bonded to an oxygen atom of an ester group through an alkylene group (for example, a methylene group and an ethylene group). In that case, a group having the cyclic carbonate structure may be an alkyl group having a cyclic carbonate structure as a substituent.

Specific examples of the anion represented by Formula (B-2) are as follows, but the present invention is not limited thereto.

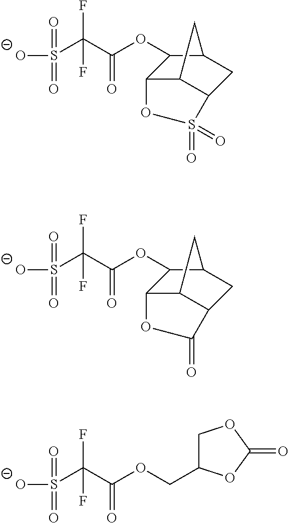 [SMILES: O=C(OC1C2CC3C1OS(=O)(=O)C3C2)C(F)(F)S(=O)(=O)[O-] ; O=C1OC2C3CC(CC13)C2OC(=O)C(F)(F)S(=O)(=O)[O-] ; O=C1OCC(COC(=O)C(F)(F)S(=O)(=O)[O-])O1]

Subsequently, an anion represented by the following Formula (B-3) will be described.

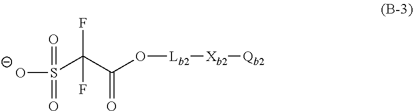

In Formula (B-3),

L_{b2} represents an alkylene group having 1 to 6 carbon atoms, and an alkylene having 1 to 4 carbon atoms is preferred.

X_{b2} represents an ether bond or an ester bond (—OCO— or —COO—).

Q_{b2} represents an alicyclic group or a group containing an aromatic ring.

The alicyclic group for Q_{b2} may be monocyclic or polycyclic. Examples of the monocyclic alicyclic group may include a monocyclic cycloalkyl group such as a cyclopentyl group, a cyclohexyl group and a cyclooctyl group. Examples of the polycyclic alicyclic group may include a polycyclic cycloalkyl group such as a norbornyl group, a tricyclodecanyl group, a tetracyclodecanyl group, a tetracyclododecanyl group and an adamantyl group. Among them, an alicyclic group with a bulky structure having 7 or more carbon atoms, such as a norbornyl group, a tricyclodecanyl group, a tetracyclodecanyl group, a tetracyclododecanyl group, and an adamantyl group, is preferred.

The aromatic ring in the group containing an aromatic ring for Q_{b2} is preferably an aromatic ring having 6 to 20 carbon atoms, examples thereof may include a benzene ring, a naphthalene ring, a phenanthrene ring, an anthracene ring and the like, and among them, a benzene ring or a naphthalene ring is more preferred. The aromatic ring may be substituted with at least one fluorine atom, and examples of the aromatic ring substituted with at least one fluorine atom may include a perfluorophenyl group and the like.

The aromatic ring may be directly bonded to X_{b2}, but may be bonded to X_{b2} through an alkylene group (for example, a methylene group and an ethylene group). In that case, a group containing the aromatic ring may be an alkyl group having the aromatic ring as a substituent.

Specific examples of the anion represented by Formula (B-3) are as follows, but the present invention is not limited thereto.

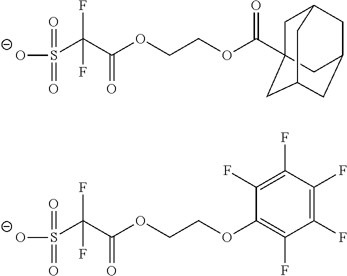 [SMILES: O=C(OCCOC(=O)C(F)(F)S(=O)(=O)[O-])C12CC3CC(CC(C3)C1)C2 ; O=C(OCCOc1c(F)c(F)c(F)c(F)c1F)C(F)(F)S(=O)(=O)[O-]]

Examples of the organic group represented by R₂₀₁, R₂₀₂ and R₂₀₃ may include corresponding groups in the compounds (ZI-4), (ZI-2), (ZI-3) and (ZI-4) to be described below.

Meanwhile, a compound having a plurality of structures represented by Formula (ZI) may be used. For example, it is possible to use a compound having a structure in which at least one of R₂₀₁ to R₂₀₃ in a compound represented by Formula (ZI) is bonded to at least one of R₂₀₁ to R₂₀₃ in another compound represented by Formula (ZI) through a single bond or a linking group.

In addition, examples of a preferred (ZI) component include compounds (ZI-1), (ZI-2), (ZI-3) and (ZI-4) to be described below.

Compound (ZI-1) is an arylsulfonium compound in which at least one of R₂₀₁ to R₂₀₃ in Formula (ZI) is an aryl group, that is, a compound having arylsulfonium as a cation.

In the arylsulfonium compound, all of R₂₀₁ to R₂₀₃ may be an aryl group or some of R₂₀₁ to R₂₀₃ may be an aryl group, with the remaining being an alkyl group or a cycloalkyl group.

Examples of the arylsulfonium compound may include a triarylsulfonium compound, a diarylalkylsulfonium compound, an aryldialkylsulfonium compound, a diarylcycloalkylsulfonium compound and an aryldicycloalkylsulfonium compound.

The aryl group in the arylsulfonium compound is preferably a phenyl group and a naphthyl group, and more preferably a phenyl group. The aryl group may be an aryl group having a heterocyclic structure having an oxygen atom, a nitrogen atom, a sulfur atom and the like. Examples of the heterocyclic structure may include a pyrrole residue, a furan residue, a thiophene residue, an indole residue, a benzofuran residue, a benzothiophene residue and the like. When the arylsulfonium compound has two or more aryl groups, each aryl group may be same as or different.

The alkyl group or the cycloalkyl group, which the arylsulfonium compound has, if necessary, is preferably a straight or branched alkyl group having 1 to 15 carbon atoms and a cycloalkyl group having 3 to 15 carbon atoms. Examples thereof may include a methyl group, an ethyl group, a propyl group, an n-butyl group, a sec-butyl group, a t-butyl group, a cyclopropyl group, a cyclobutyl group, and a cyclohexyl group.

The aryl group, the alkyl group and the cycloalkyl group of R₂₀₁ to R₂₀₃ may have, as a substituent, an alkyl group (for example, having from 1 to 15 carbon atoms), a cycloalkyl group (for example, having from 3 to 15 carbon atoms), an aryl group (for example, having from 6 to 14 carbon atoms), an alkoxy group (for example, having from 1 to 15 carbon atoms), a halogen atom, a hydroxyl group or a phenylthio group. The substituent is preferably a straight or branched alkyl group having 1 to 12 carbon atoms, a cycloalkyl group having 3 to 12 carbon atoms, and a straight, branched or cyclic alkoxy group having 1 to 12 carbon atoms, and more preferably an alkyl group having 1 to 4 carbon atoms and an alkoxy group having 1 to 4 carbon atoms. The substituent may be substituted with any one of three R₂₀₁ to R₂₀₃ or may be substituted with all of the three. Furthermore, when R₂₀₁ to R₂₀₃ are an aryl group, the substituent is preferably substituted at the p-position of the aryl group.

Subsequently, compound (ZI-2) will be described.

Compound (ZI-2) is a compound in which each of R₂₀₁ to R₂₀₃ in Formula (ZI) independently represcnts an organic group having no aromatic ring. Here, the aromatic ring also includes an aromatic ring containing a heteroatom.

The organic group containing no aromatic ring as R₂₀₁′ to R₂₀₃′ has generally 1 to 30 carbon atoms, and preferably 1 to 20 carbon atoms.

Each of R₂₀₁′ to R₂₀₃′ independently represents preferably an alkyl group, a cycloalkyl group, an allyl group or a vinyl group, more preferably a straight or branched 2-oxoalkyl group, a 2-oxocycloalkyl group and an alkoxycarbonylmethyl group, and particularly preferably a straight or branched 2-oxoalkyl group.

Preferred examples of the alkyl group and the cycloalkyl group of R₂₀₁′ to R₂₀₃′ may include a straight or branched alkyl group having 1 to 10 carbon atoms (for example, a methyl group, an ethyl group, a propyl group, a butyl group, and a pentyl group) and a cycloalkyl group having 3 to 10 carbon atoms (a cyclopentyl group, a cyclohexyl group, and a norbornyl group). More preferred examples of the alkyl group may include a 2-oxoalkyl group and an alkoxycarbonylmethyl group. More preferred examples of the cycloalkyl group may include a 2-oxocycloalkyl group.

The 2-oxoalkyl group may be either straight or branched, and preferred examples thereof include a group having >C═O at the 2-position of the aforementioned alkyl group.

Preferred examples of the 2-oxocycloalkyl group may include a group having >C═O at the 2-position of the aforementioned cycloalkyl group.

Preferred examples of the alkoxy group in the alkoxycarbonylmethyl group may include an alkoxy group having 1 to 5 carbon atoms (a methoxy group, an ethoxy group, a propoxy group, a butoxy group, and a pentoxy group).

R₂₀₁′ to R₂₀₃′ may be further substituted with a halogen atom, an alkoxy group (for example, having 1 to 5 carbon atoms), a hydroxyl group, a cyano group or a nitro group.

Subsequently, the compound (ZI-3) will be described.

The compound (ZI-3) is a compound represented by the following Formula (ZI-3), and a compound having a phenacylsulfonium salt structure.

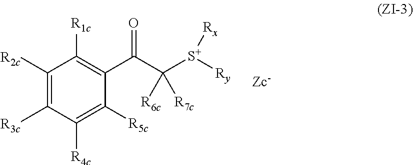

In Formula (ZI-3), each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Each of R_{6c} and R_{7c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more of R_{1c} to R_{5c}, R_{5c} and R_{6c}, R_{6c} and R_{7c}, R_{5c} and Rₓ and Rₓ and R_{y} may be bonded to each other to form a ring structure, respectively, and the ring structure may include an oxygen atom, a sulfur atom, a ketone group, an ester bond and an amide bond.

Examples of the ring structure may include an aromatic or non-aromatic hydrocarbon ring, an aromatic or non-aromatic heterocyclic ring, or a polycyclic condensed ring formed by combining two or more of these rings. The ring structure includes a 3- to 10-membered ring and is preferably a 4- to 8-membered ring, and more preferably a 5- or 6-membered ring.

Examples of the group formed by bonding of any two or more of R_{1c} to R_{5c}, R_{6c} and R_{7c}, and Rₓ and R_{y} may include a butylene group, a pentylene group and the like.

The group formed by bonding of R_{5c} and R_{6c} and R_{5c} and Rₓ is preferably a single bond or an alkylene group, and examples of the alkylene group may include a methylene group, an ethylene group and the like.

Zc⁻ represents a non-nucleophilic anion, and examples thereof may include the non-nucleophilic anion which is the same as Z⁻ in Formula (ZI).

The alkyl group as R_{1c} to R_{7c} may be either straight or branched, examples thereof may include an alkyl group having 1 to 20 carbon atoms, and preferably a straight or branched alkyl group having 1 to 12 carbon atoms (for example, a methyl group, a straight or branched propyl group, a straight or branched butyl group, and a straight or branched pentyl group), and examples of the cycloalkyl group may include a cycloalkyl group having 3 to 10 carbon atoms (for example, a cyclopentyl group and a cyclohexyl group).

The aryl group as R_{1c} to R_{5c} is preferably an aryl group having 5 to 15 carbon atoms, and examples thereof may include a phenyl group and a naphthyl group.

The alkoxy group as R_{1c} to R_{5c} may be straight, branched or cyclic and examples thereof may include an alkoxy group having 1 to 10 carbon atoms, preferably a straight or branched alkoxy group having 1 to 5 carbon atoms (for example, a methoxy group, an ethoxy group, a straight or branched propoxy group, a straight or branched butoxy group, and a straight or branched pentoxy group), and a cyclic alkoxy group having 3 to 10 carbon atoms (for example, a cyclopentyloxy group and a cyclohexyloxy group).

Specific examples of the alkoxy group in the alkoxycarbonyl group as R_{1c} to R_{5c} are the same as the specific examples of the alkoxy group as R_{1c} to R_{5c}.

Specific examples of the alkyl group in the alkylcarbonyloxy group and the alkylthio group as R_{1c} to R_{5c} are the same as the specific examples of the alkyl group as R_{1c} to R_{5c}.

Specific examples of the cycloalkyl group in the cycloalkylcarbonyloxy group as R_{1c} to R_{5c} are the same as the specific examples of the cycloalkyl group as R_{1c} to R_{5c}.

Specific examples of the aryl group in the aryloxy group and the arylthio group as R_{1c} to R_{5c} are the same as the specific examples of the aryl group as R_{1c} to R_{5c}.

Any one of R_{1c} to R_{5c} is preferably a straight or branched alkyl group, a cycloalkyl group, or a straight, branched or cyclic alkoxy group, and the sum of carbon numbers of R_{1c} to R_{5c}, is more preferably from 2 to 15. Accordingly, the solvent solubility is more enhanced, and thus, generation of particles during storage is suppressed.

Examples of the ring structure which may be formed by any two or more of R_{1c} to R_{5c} bonded to each other may include preferably a 5- or 6-membered ring, and particularly preferably a 6-membered ring (for example, a phenyl ring).

Examples of the ring structure which may be formed by R_{5c} and R_{6c} bonded to each other may include a 4-membered or greater ring (particularly preferably a 5- or 6-membered ring) formed together with the carbonyl carbon atom and the carbon atom in Formula (ZI-3) by R_{5c} and R_{6c} bonded to each other to form a single bond or an alkylene group (a methylene group, an ethylene group or the like).

The aryl group as R_{6c} to R_{7c} preferably has 5 to 15 carbon atoms, and examples thereof include a phenyl group and a naphthyl group.

An aspect in which both R_{6c} and R_{7c} are an alkyl group is preferred. In particular, an aspect in which each of R_{6c} and R_{7c} is a straight or branched alkyl group having 1 to 4 carbon atoms is preferred, and an aspect in which both are a methyl group is particularly preferred.

Furthermore, when R_{6c} and R_{7c} are bonded to each other to form a ring, the group formed by bonding of R_{6c} and R_{7c} is preferably an alkylene group having 2 to 10 carbon atoms, and examples thereof may include an ethylene group, a propylene group, a butylene group, a pentylene group, a hexylene group and the like. Further, the ring formed by bonding of R_{6c} and R_{7c} may have a heteroatom such as oxygen atom in the ring.

Examples of the alkyl group and the cycloalkyl group as Rₓ and R_{y} may include the alkyl group and the cycloalkyl group in R_{1c} to R_{7c}.

Examples of the 2-oxoalkyl group and the 2-oxocycloalkyl group as Rₓ and R_{y} may include a group having >C═O at the 2-position of the alkyl group and the cycloalkyl group as R_{1c} to R_{7c}.

Examples of the alkoxy group in the alkoxycarbonylalkyl group as Rₓ and R_{y} may include the same alkoxy group as R_{1c} to R_{5c} and examples of the alkyl group may include an alkyl group having 1 to 12 carbon atoms, and preferably a straight alkyl group having 1 to 5 carbon atoms (for example, a methyl group and an ethyl group).

The allyl group as Rₓ and R_{y} is not particularly limited, but is preferably an unsubstituted allyl group, or an allyl group substituted with a monocyclic or polycyclic cycloalkyl group (preferably a cycloalkyl group having from 3 to 10 carbon atoms).

The vinyl group as Rₓ and R_{y} is not particularly limited, but is preferably an unsubstituted vinyl group, or a vinyl group substituted with a monocyclic or polycyclic cycloalkyl group (preferably a cycloalkyl group having 3 to 10 carbon atoms).

Examples of the ring structure which may be formed by R_{5c} and Rₓ bonded to each other may include a 5-membered or greater membered ring (particularly preferably a 5-membered ring) formed together with a sulfur atom and a carbonyl carbon atom in Formula (ZI-3) by R_{5c} and Rₓ bonded to each other to form a single bond or an alkylene group (a methylene group, an ethylene group and the like).

Examples of the ring structure which may be formed by Rₓ and R_{y} bonded to each other may include a 5- or 6-membered ring, particularly preferably a 5-membered ring (that is, a tetrahydrothiophene ring), which is formed together with a sulfur atom in Formula (ZI-3) by divalent Rₓ and R_{y} (for example, a methylene group, an ethylene group, a propylene group and the like).

Each of Rₓ and R_{y} is an alkyl group or a cycloalkyl group having preferably 4 or more carbon atoms, more preferably 6 or more carbon atoms, and still more preferably 8 or more carbon atoms.

Each of R_{1c} to R_{7c} and Rₓ and R_{y} may further have a substituent, and examples of the further substituent may include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group and the like.

In Formula (ZI-3), it is more preferred that each of R_{1c}, R_{2c}, R_{4c} and R_{5c} independently represents a hydrogen atom and R_{3c} represents a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkythio group or an arylthio group.

A cation of the compound represented by Formula (ZI-2) or (ZI-3) in the present invention includes the following specific examples.

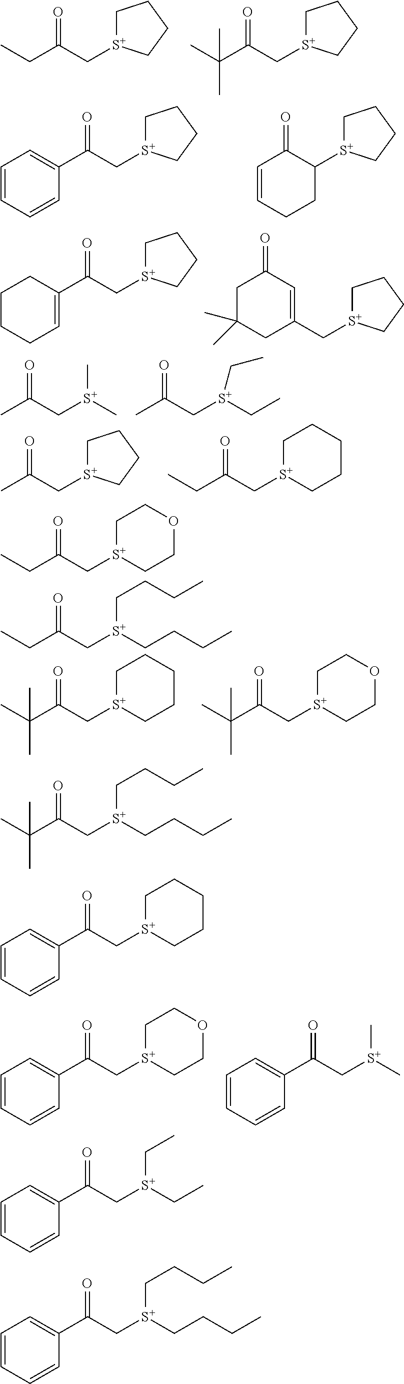

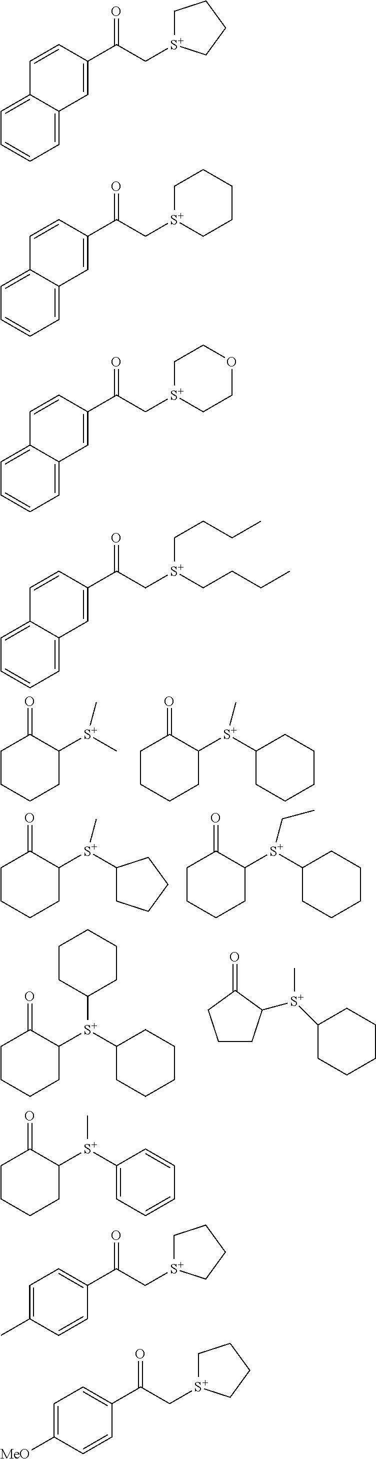

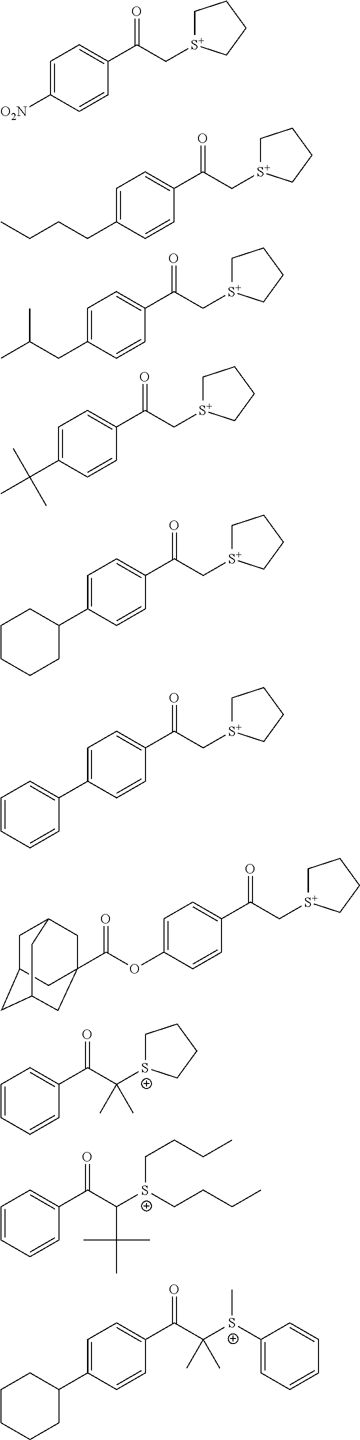

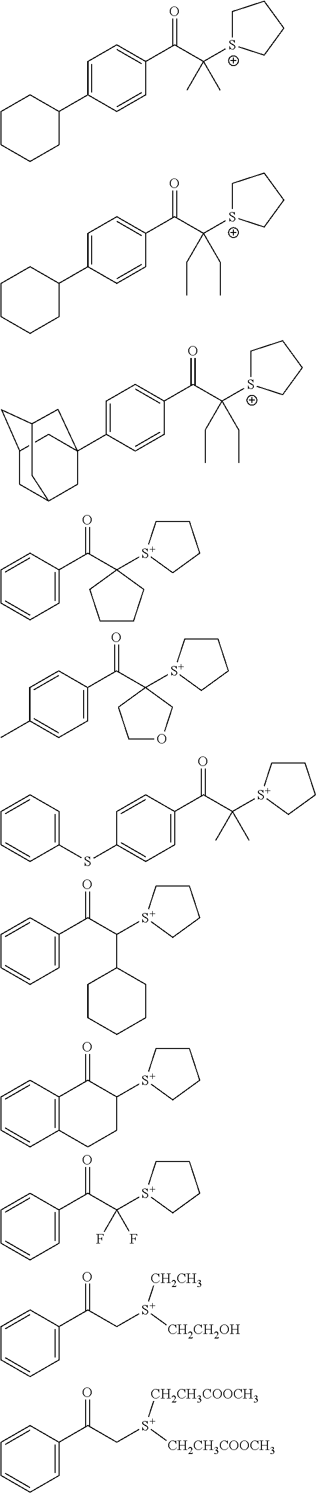

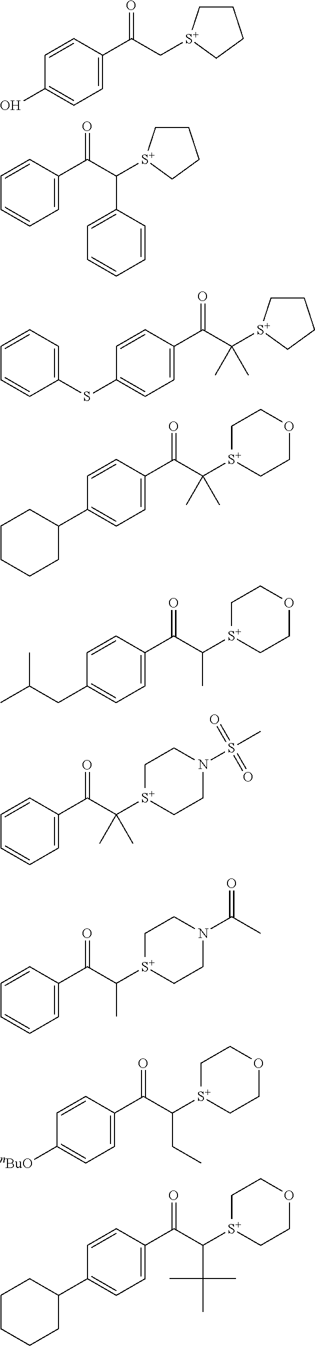

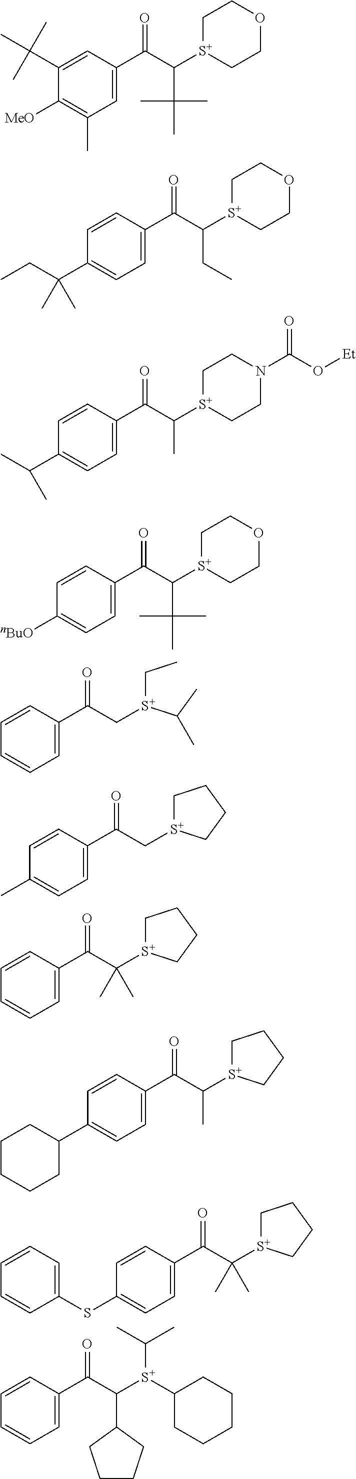

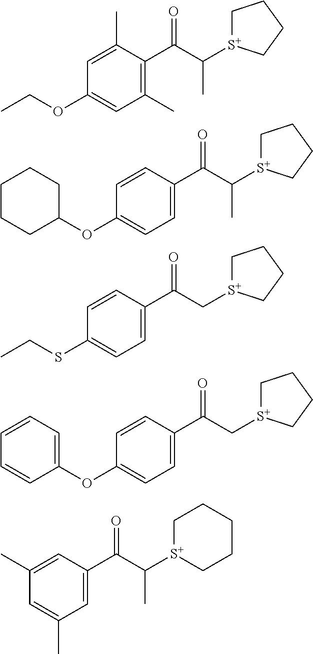 [SMILES: CCOc1cc(C)c(C(=O)C(C)[S+]2CCCC2)c(C)c1 ; CC(C(=O)c1ccc(OC2CCCCC2)cc1)[S+]1CCCC1 ; CCSc1ccc(C(=O)C[S+]2CCCC2)cc1 ; O=C(C[S+]1CCCC1)c1ccc(Oc2ccccc2)cc1 ; Cc1cc(C)cc(C(=O)C(C)[S+]2CCCCC2)c1]

Subsequently, compound (ZI-4) will be described.

Compound (ZI-4) is represented by the following Formula (ZI-4).

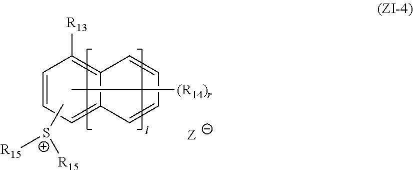

In Formula (ZI 4),

R₁₃ represents a hydrogen atom, a fluorine atom, a hydroxyl group, an alkyl group, a cycloalkyl group, an alkoxy group, an alkoxycarbonyl group or a group having a cycloalkyl group. These groups may have a substituent.

When a plurality of R₁₄ is present, each R₁₄ independently represents a hydroxyl group, an alkyl group, a cycloalkyl group, an alkoxy group, an alkoxycarbonyl group, an alkylcarbonyl group, an alkylsulfonyl group, a cycloalkylsulfonyl group or a group having a cycloalkyl group. These groups may have a substituent.

Each R₁₅ independently represents an alkyl group, a cycloalkyl group or a naphthyl group. Two of R₁₅ may be bonded to each other to form a ring. These groups may have a substituent.

l represents an integer of 0 to 2.

r represents an integer of 0 to 8.

Z⁻ represents a non-nucleophilic anion, and examples thereof may include the same as the non-nucleophilic anion of Z⁻ in Formula (ZI).

In Formula (ZI-4), the alkyl group of R₁₃, R₁₄ and R₁₅ is preferably a straight or branched alkyl group having 1 to 10 carbon atoms, and more preferably a methyl group, an ethyl group, an n-butyl group, and a t-butyl group.

Examples of the cycloalkyl group of R₁₃, R₁₄ and R₁₅ may include a monocyclic or polycyclic cycloalkyl group (preferably a cycloalkyl group having 3 to 20 carbon atoms), and particularly preferably cyclopropyl, cyclopentyl, cylcohexyl, cycloheptyl, and cyclooctyl.

The alkoxy group of R₁₃ and R₁₄ is preferably a straight or branched alkoxy group having 1 to 10 carbon atoms, and more preferably a methoxy group, an ethoxy group, an n-propoxy group, and an n-butoxy group.

The alkoxycarbonyl group of R₁₁ and R₁₄ is preferably a straight or branched alkoxycarbonyl group having from 2 to 11 carbon atoms, and more preferably a methoxycarbonyl group, an ethoxycarbonyl group, and an n-butoxycarbonyl group.

Examples of the group having a cycloalkyl group of R₁₃ and R₁₄ may include a monocyclic or polycyclic cycloalkyl group (preferably a cycloalkyl group having 3 to 20 carbon atoms), and examples thereof include a monocyclic or polycyclic cycloalkyloxy group and an alkoxy group having a monocyclic or polycyclic cycloalkyl group. These groups may further have a substituent.

Each of the mono- or polycycloalkyloy groups represented by R₁₃ and R₁₄ preferably has a total carbon number of 7 or more, more preferably a total carbon number of 7 to 15. It is preferred to have a monocycloalkyl group. The monocycloalkyloxy group having a total carbon number of 7 or more refers to a monocycloalkyloxy group comprised of a cycloalkyloxy group, such as a cyclopropyloxy group, a cyclobutyloxy group, a cyclopentyloxy group, a cyclohexyloxy group, a cycloheptyloxy group, a cyclooctyloxy group or a cyclododecanyloxy group, optionally substituted with an alkyl group such as methyl, ethyl, propyl, butyl, pentyl, hexyl, heptyl, octyl, dodecyl, 2-ethylhexyl, isopropyl, sec-butyl, t-butyl or isoamyl, a hydroxyl group, a halogen atom (fluorine, chlorine, bromine or iodine), a nitro group, a cyano group, an amido group, a sulfonamido group, an alkoxy group such as methoxy, ethoxy, hydroxyethoxy, propoxy, hydroxypropoxy or butoxy, an alkoxycarbonyl group such as methoxycarbonyl or ethoxycarbonyl, an acyl group such as formyl, acetyl or benzoyl, an acyloxy group such as acetoxy or butyryloxy, a carboxyl group or the like, wherein the sum of carbon atoms thereof including those of any substituents introduced in the cycloalkyl group is 7 or greater.

Examples of the polycycloalkyloxy group having a total carbon number of 7 or more may include a norbornyloxy group, a tricyclodecanyloxy group, a tetracyclodecanyloxy group, an adamantyloxy group or the like.

Each of the alkoxy groups with a mono- or polycycloalkyl group represented by R₁₃ and R₁₄ preferably has a total carbon number of 7 or more, more preferably a total carbon number of 7 to 15. The alkoxy group with a monocycloalkyl group is preferred. The alkoxy group with a monocycloalkyl group, which has a total carbon number of 7 or more, refers to an alkoxy group, such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy or isoamyloxy, substituted with any of the above-mentioned optionally substituted monocycloalkyl groups, wherein the sum of carbon atoms thereof including those of substituents is 7 or greater. Examples thereof may include a cyclohexylmethoxy group, a cyclopentylethoxy group, a cyclohexylethoxy group or the like, and preferably a cyclohexylmethoxy group.

Examples of the alkoxy group with a polycycloalkyl group, which has a total carbon number of 7 or more, may include a norborylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group or the like, and preferably a norbornylmethoxy group and a norbornylethoxy group.

Examples of the alkyl group in the alkylcarbonyl group represented by R₁₄ may include the same specific examples as previously described with respect to the alkyl groups represented by R₁₃ to R₁₅.

Each of the alkylsulfonyl group and cycloalkylsulfonyl group represented by R₁₄ may be straight, branched or cyclic, and preferably has 1 to 10 carbon atoms, and examples thereof may include a methanesulfonyl group, an ethanesulfonyl group, an n-propanesulfonyl group, an n-butanesulfonyl group, a cyclopentanesufonyl group, a cyclohexanesulfonyl group and the like.

Each of these groups may have a substituent. Examples of the substituent may include a halogen atom (e.g., a fluorine atom), a hydroxyl group, a carboxyl group, a cyano group, a nitro group, an alkoxy group, an akoxyalkyl group, an alkoxycarbonyl group, an alkoxycarbonyloxy group or the like.

Examples of the alkoxy group may include a straight, branched or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group or a cyclohexyloxy group.

Examples of the alkoxyalkyl group may include a straight, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group or a 2-ethoxyethyl group.

Examples of the alkoxycarbonyl group may include a straight, branched or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group or a cyclohexyloxycarbonyl group.

Examples of the alkoxycarbonyloxy group may include a straight, branched or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group or a cyclohexyloxycarbonyloxy group.

Examples of the ring structure which may be formed by two R₁₅'s bonded to each other may include a 5- or 6-membered ring formed together with the sulfur atom in Formula (ZI-4) by two R₁₅'s, and particularly preferably a 5-membered ring (that is, a tetrahydrothiophene ring), and may be condensed with an aryl group or a cycloalkyl group. The divalent R₁₃ may have a substituent, and examples of the substituent may include a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group and the like. As for the substituent on the ring structure, a plurality of substituents may be present, and the substituents may be bonded to each other to form a ring (an aromatic or non-aromatic hydrocarbon ring, an aromatic or non-aromatic heterocyclic ring, a polycyclic condensed ring formed by combining two or more of these rings or the like).

In Formula (ZI-4), R₁₅ is preferably a methyl group, an ethyl group, a naphthyl group, a divalent group capable of forming a tetrahydrothiophene ring structure together with the sulfur atom by two R₁₅'s bonded to each other, and the like.

The substituent which may be possessed by R₁₃ and R₁₄ is preferably a hydroxyl group, an alkoxy group, an alkoxycarbonyl group or a halogen atom (particularly a fluorine atom).

l is preferably 0 or 1, and more preferably 1.

r is preferably 0 to 2.

A cation of the compound represented by Formula (ZI-4) in the present invention may include the following specific examples.

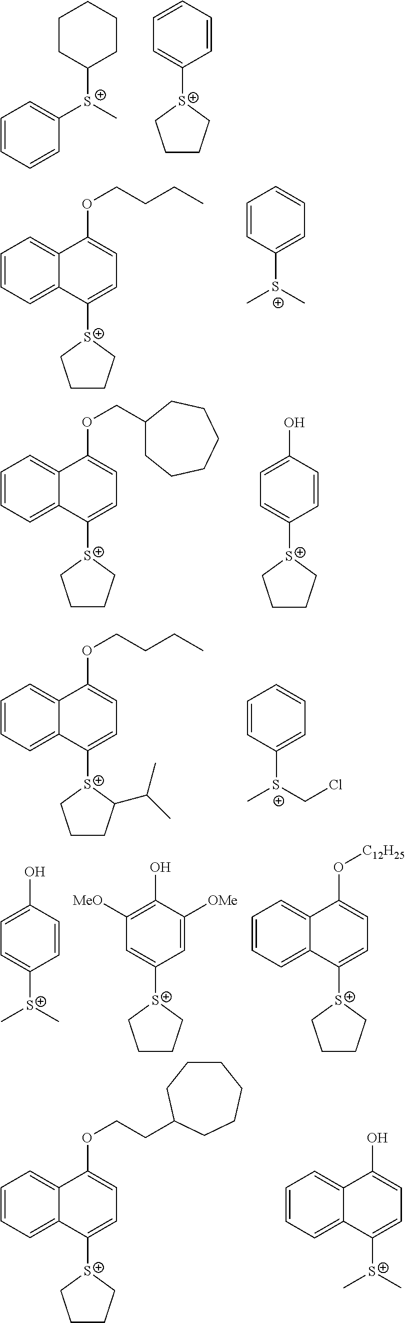

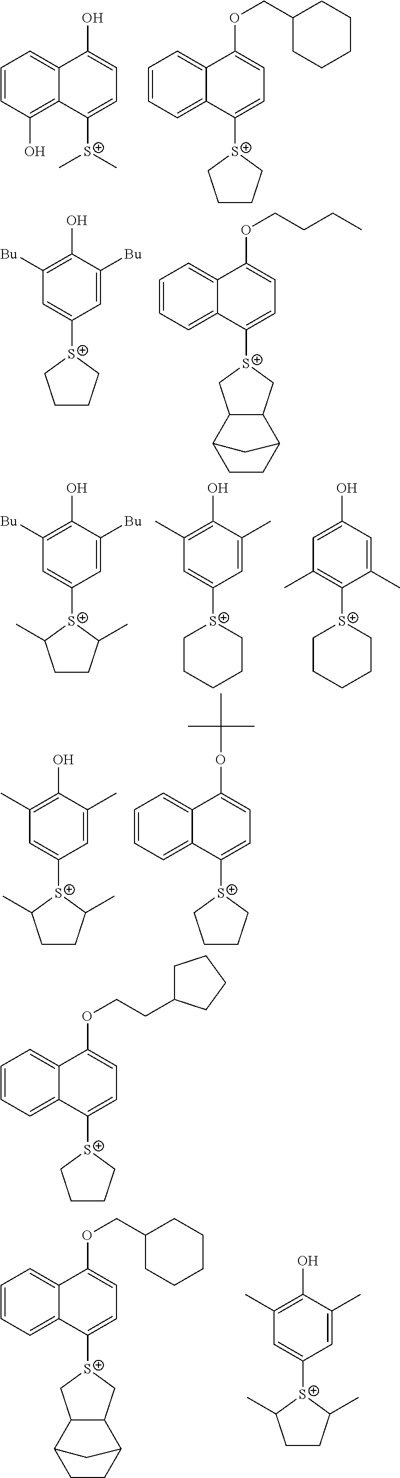

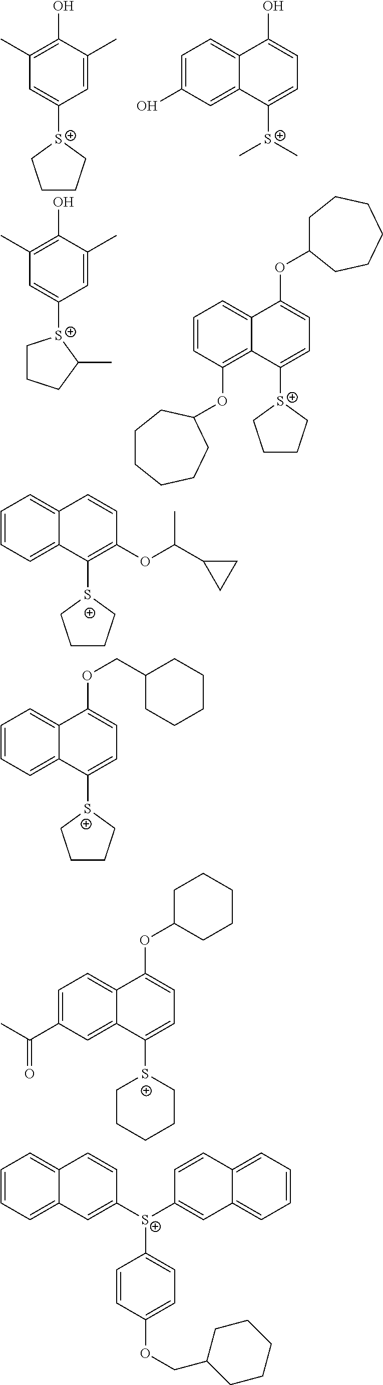

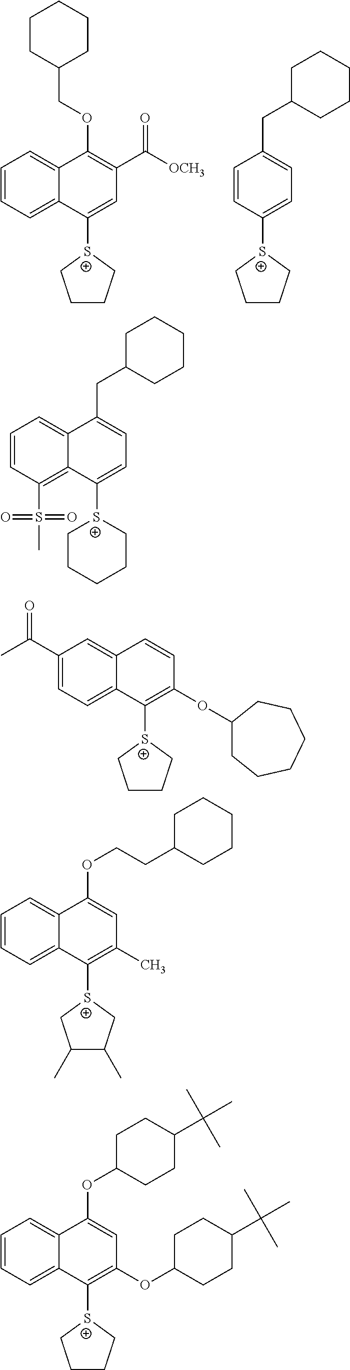 [SMILES: COC(=O)c1cc([S+]2CCCC2)c2ccccc2c1OCC1CCCCC1 ; c1cc([S+]2CCCC2)ccc1CC1CCCCC1 ; CS(=O)(=O)c1cccc2c(CC3CCCCC3)ccc([S+]3CCCCC3)c12 ; CC(=O)c1ccc2c([S+]3CCCC3)c(OC3CCCCCC3)ccc2c1 ; Cc1cc(OCCC2CCCCC2)c2ccccc2c1[S+]1CC(C)C(C)C1 ; CC(C)(C)C1CCC(Oc2cc(OC3CCC(C(C)(C)C)CC3)c3ccccc3c2[S+]2CCCC2)CC1]

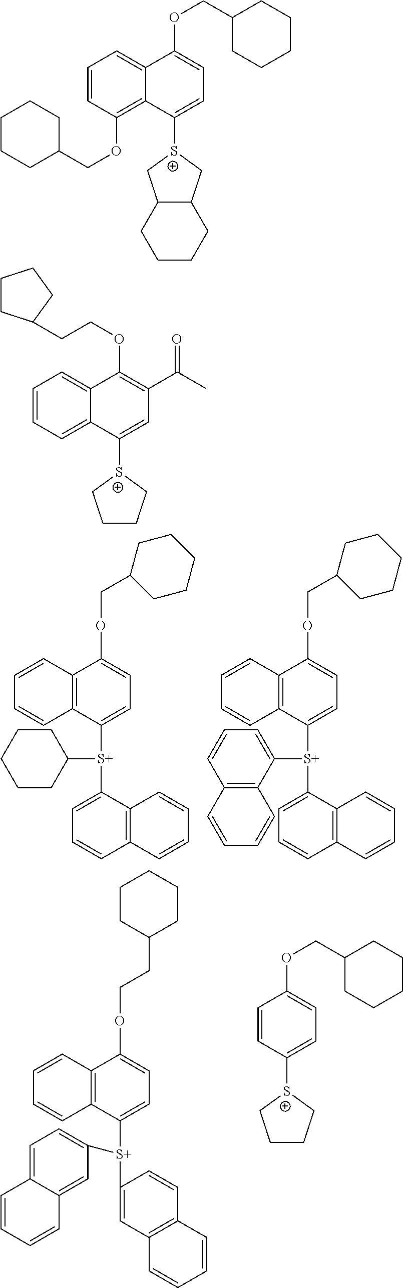 [SMILES: c1cc(OCC2CCCCC2)c2c([S+]3CC4CCCCC4C3)ccc(OCC3CCCCC3)c2c1 ; CC(=O)c1cc([S+]2CCCC2)c2ccccc2c1OCCC1CCCC1 ; c1ccc2c([S+](c3ccc(OCC4CCCCC4)c4ccccc34)C3CCCCC3)cccc2c1 ; c1ccc2c([S+](c3cccc4ccccc34)c3ccc(OCC4CCCCC4)c4ccccc34)cccc2c1 ; c1ccc2cc([S+](c3ccc4ccccc4c3)c3ccc(OCCC4CCCCC4)c4ccccc34)ccc2c1 ; c1cc([S+]2CCCC2)ccc1OCC1CCCCC1]

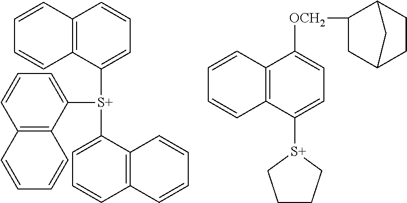

Subsequently, Formulas (ZII) and (ZIII) will be described.

In Formulas (ZII) and (ZIII).

Each of R₂₀₄ to R₂₀₇ independently represents an aryl group, an alkyl group or a cycloalkyl group.

The aryl group of R₂₀₄ to R₂₀₇, is preferably a phenyl group or a naphthyl group, and more preferably a phenyl group. The aryl group of R₂₀₄ to R₂₀₇ may be an aryl group having a heterocyclic structure having an oxygen atom, a nitrogen atom, a sulfur atom or the like. Examples of the structure of the aryl group having a heterocyclic structure may include pyrrole, furan, thiophene, indole, benzofuran, benzothiophene and the like.

The alkyl group and the cycloalkyl group in R₂₀₄ to R₂₀₇ are preferably a straight or branched alkyl group having 1 to 10 carbon atoms (for example, a methyl group, an ethyl group, a propyl group, a butyl group, and a pentyl group) and a cycloalkyl group having 3 to 10 carbon atoms (a cyclopentyl group, a cyclohexyl group, and a norbornyl group), respectively.

The aryl group, the alkyl group and the cycloalkyl group of R₂₀₄ to R₂₀₇ may have a substituent. Examples of the substituent which may be possessed by the aryl group, the alkyl group and the cycloalkyl group of R₂₀₄ to R₂₀₇ may include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, a phenylthio group and the like.

Z⁻ represents a non-nucleophilic anion, and examples thereof may include the same as the non-nucleophilic anion of Z⁻ in Formula (ZI).

Examples of the acid generator may further include compounds represented by the following Formulas (ZIV), (ZV) and (ZVI).

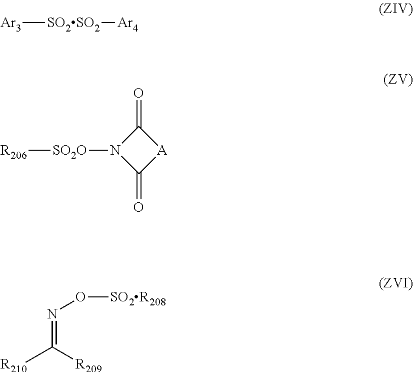

In Formulas (ZIV) to (ZVI),

Each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as specific examples of the aryl group as R₂₀₁, R₂₀₂ and R₂₀₃ in Formula (ZI-1).

Specific examples of the alkyl group and cycloalkyl group of R₂₀₈, R₂₀₉, and R₂₁₀ are the same as specific examples of the alkyl group and cycloalkyl group as R₂₀₁, R₂₀₂ and R₂₀₃ in Formula (ZI-2).

Examples of the alkylene group of A may include an alkylene group having 1 to 12 carbon atoms (for example, a methylene group, an ethylene group, a propylene group, an isopropylene group, a butylene group, and an isobutylene group), examples of the alkenylene group of A may include an alkenylene group having 2 to 12 carbon atoms (for example, an ethenylene group, a propenylene group, and a butenylene group), and examples of the arylene group of A may include an arylene group having 6 to 10 carbon atoms (for example, a phenylene group, a tolylene group, and a naphthylene group).

Among the acid generators, the compounds represented by Formulas (ZI) to (ZIII) are more preferred.

Further, the acid generator is preferably a compound capable of generating an acid having either a sulfonic acid group or an imide group, more preferably a compound capable of generating a monovalent perfluoroalkanesulfonic acid, or a compound capable of generating an aromatic sulfonic acid substituted with a monovalent fluorine atom or a fluorine atom-containing group, or a compound capable of generating an imide acid substituted with a monovalent fluorine atom or a fluorine atom-containing group, and still more preferably a sulfonium salt of fluoro-substituted alkanesulfonic acid, fluorine-substituted benzenesulfonic acid, fluorine-substituted imide acid or fluorine-substituted methide acid. The acid generator which may be used is particularly preferably a fluoro-substituted alkanesulfonic acid, a fluoro-substituted benzenesulfonic acid, or a fluoro-substituted imide acid, in which the acid generated has a pKa of −1 or less, and the sensitivity is enhanced.

Among the acid generators, particularly preferred examples will be described below.

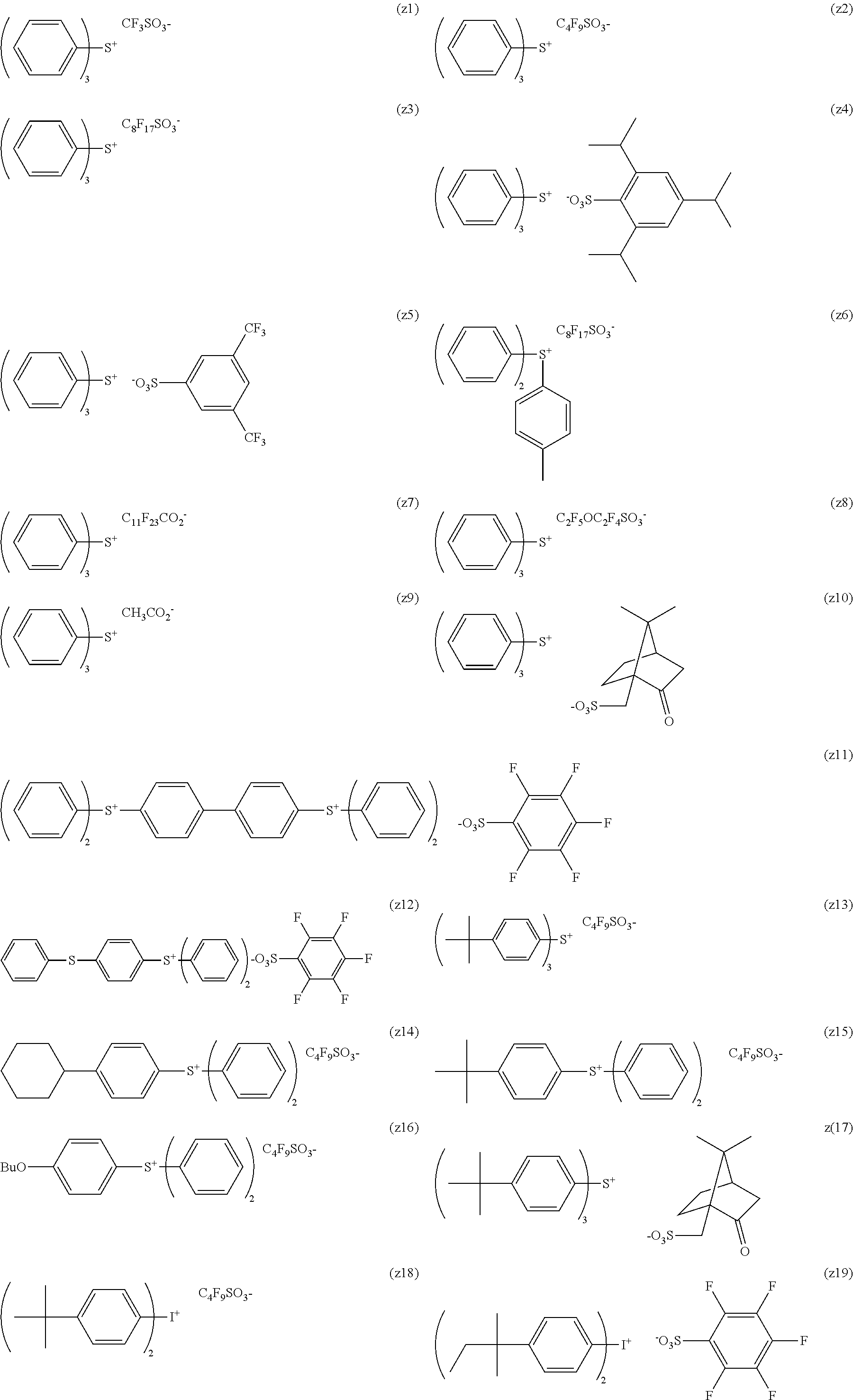

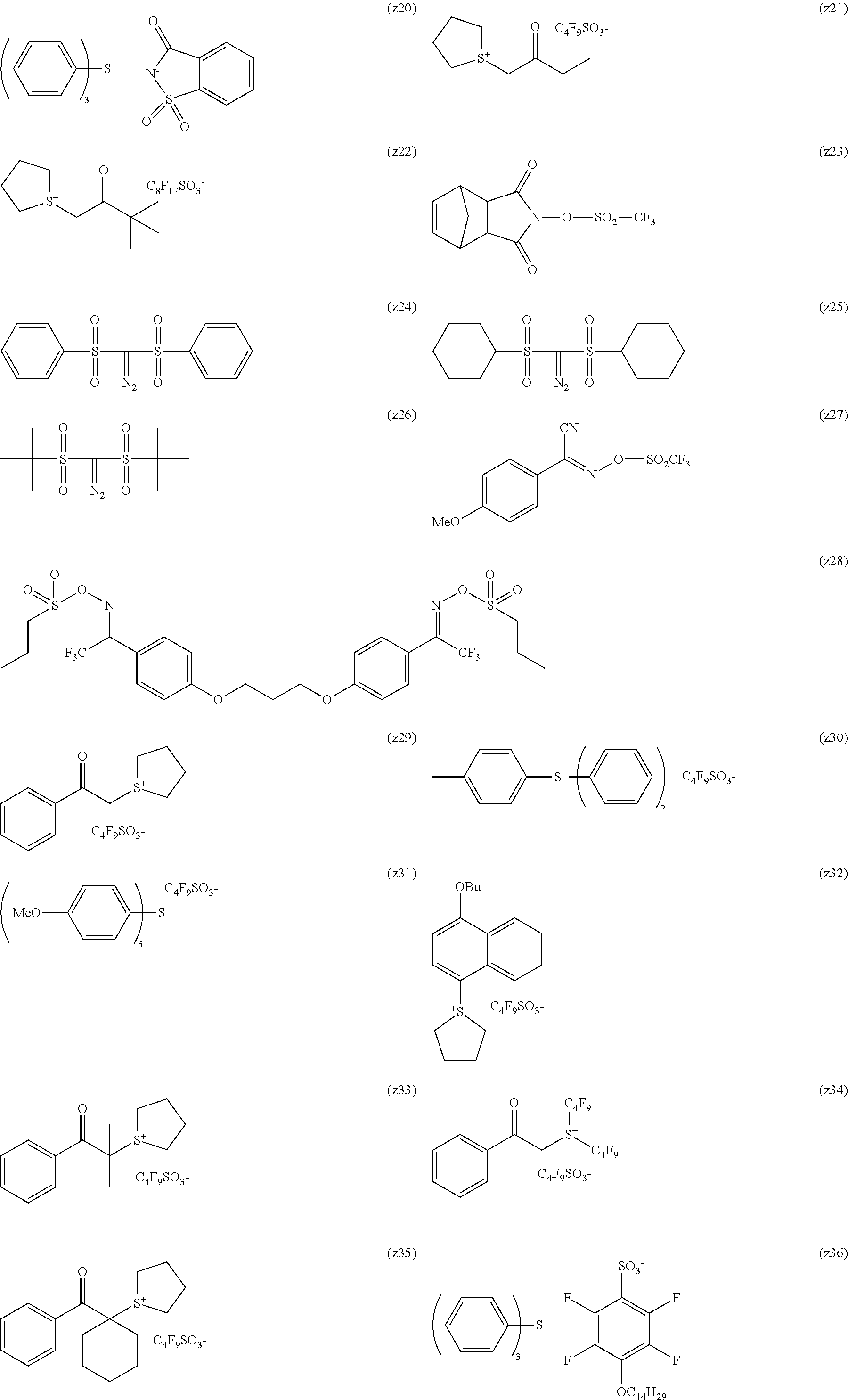

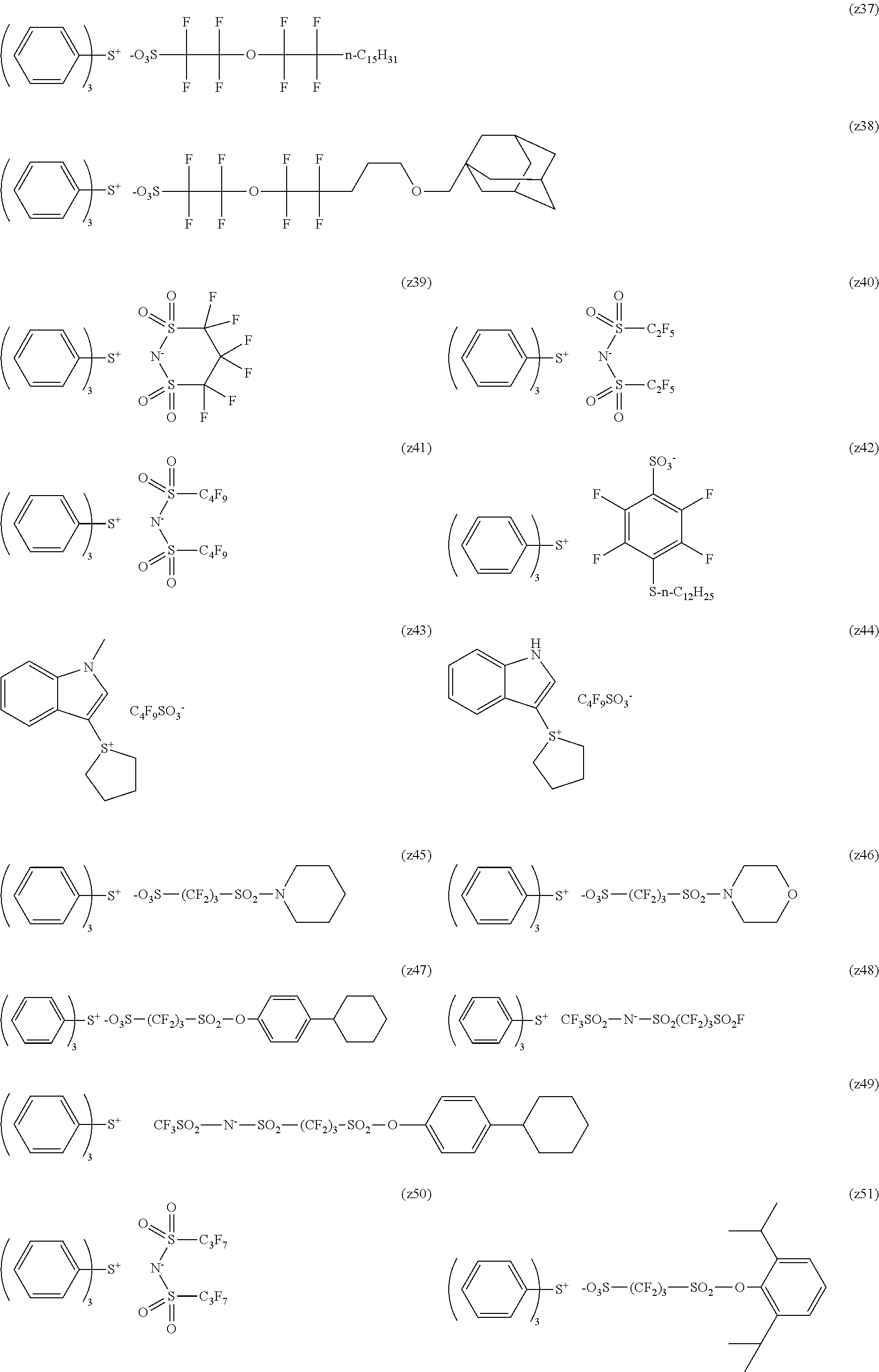

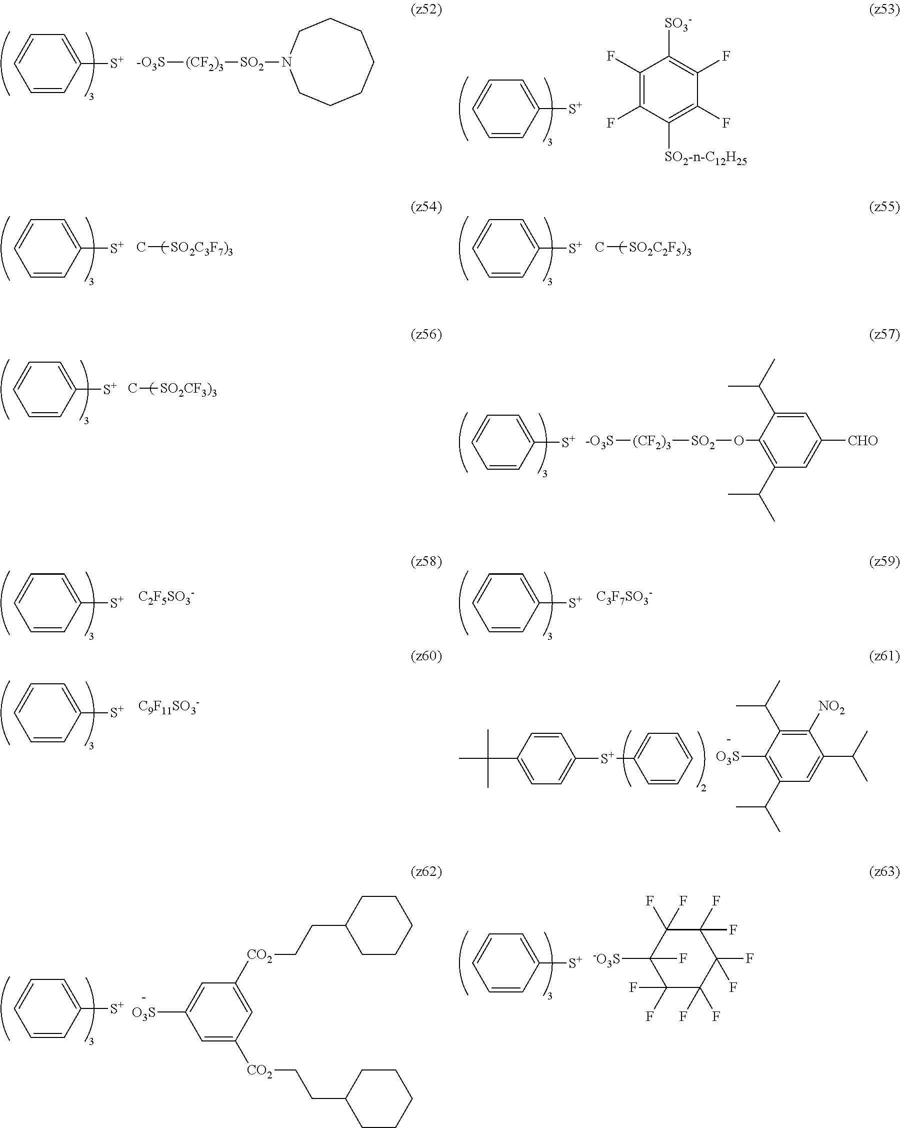

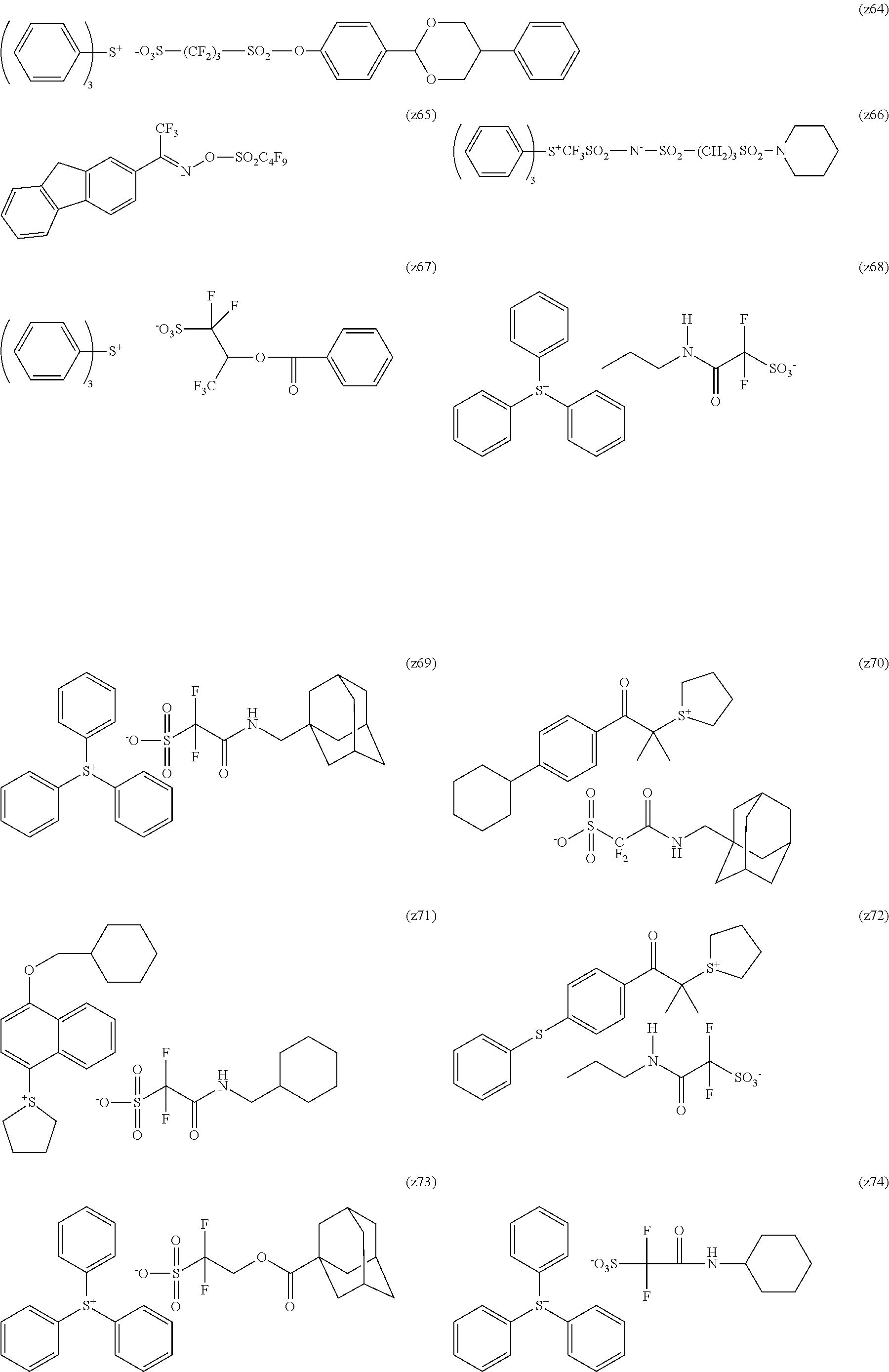

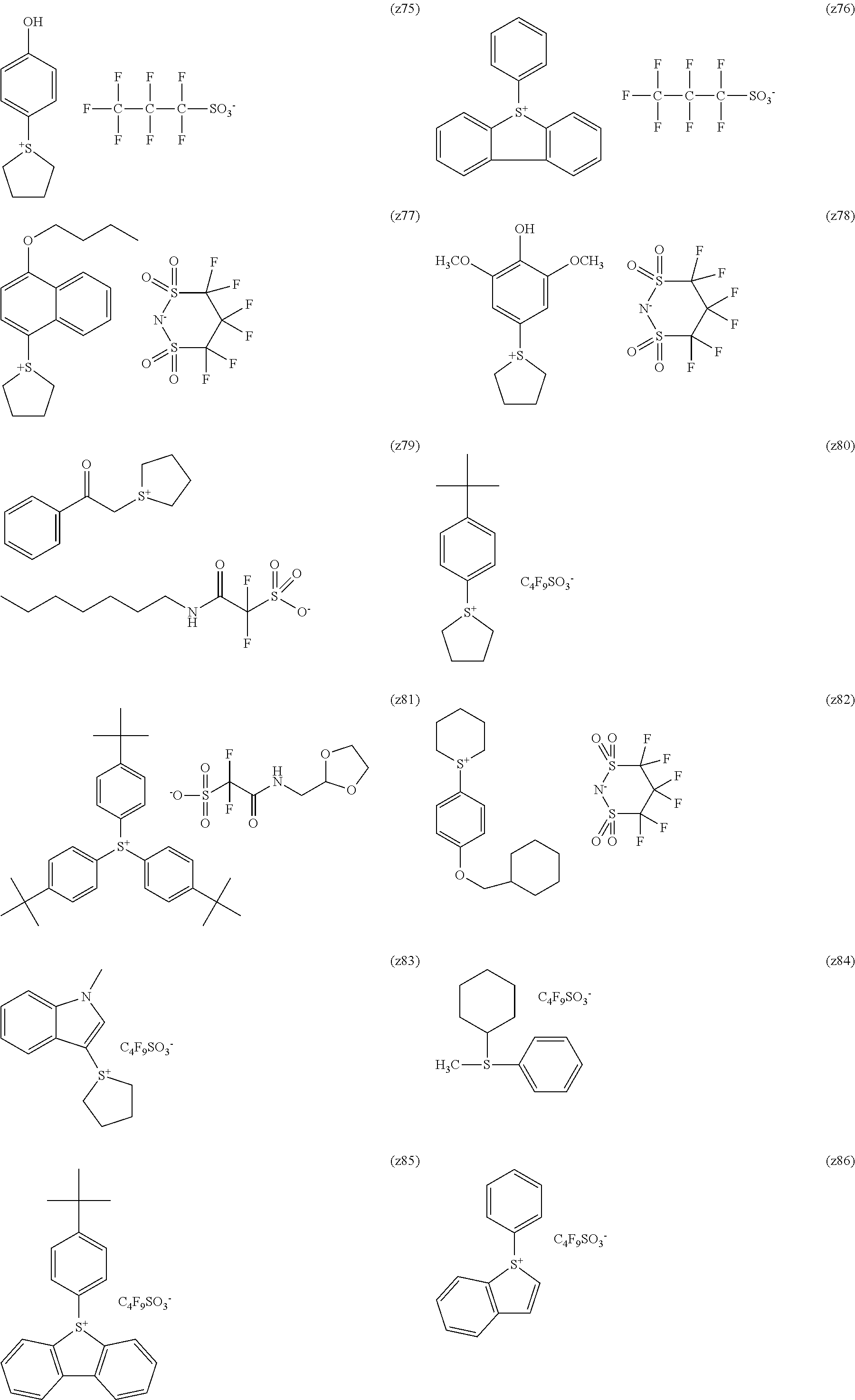

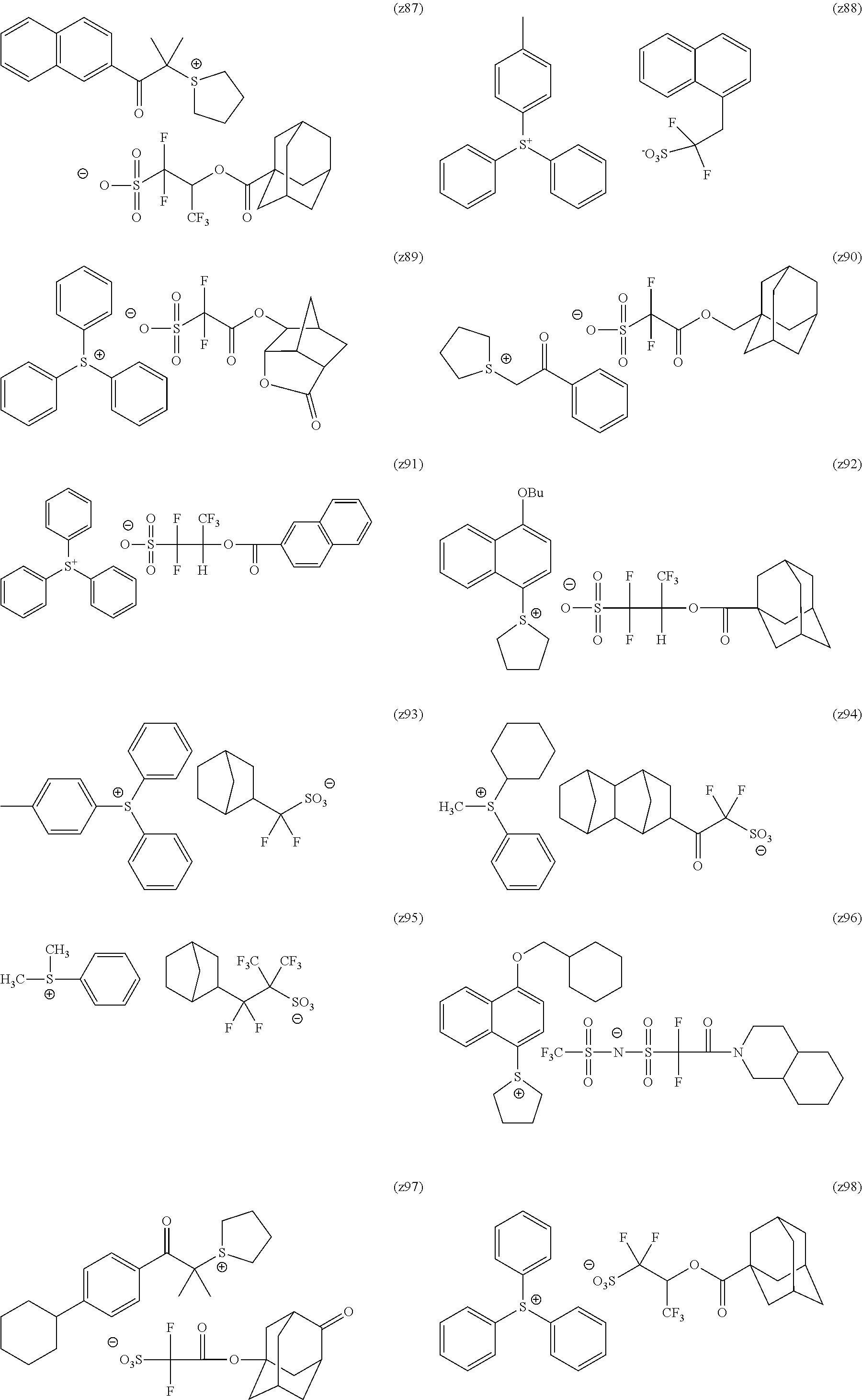

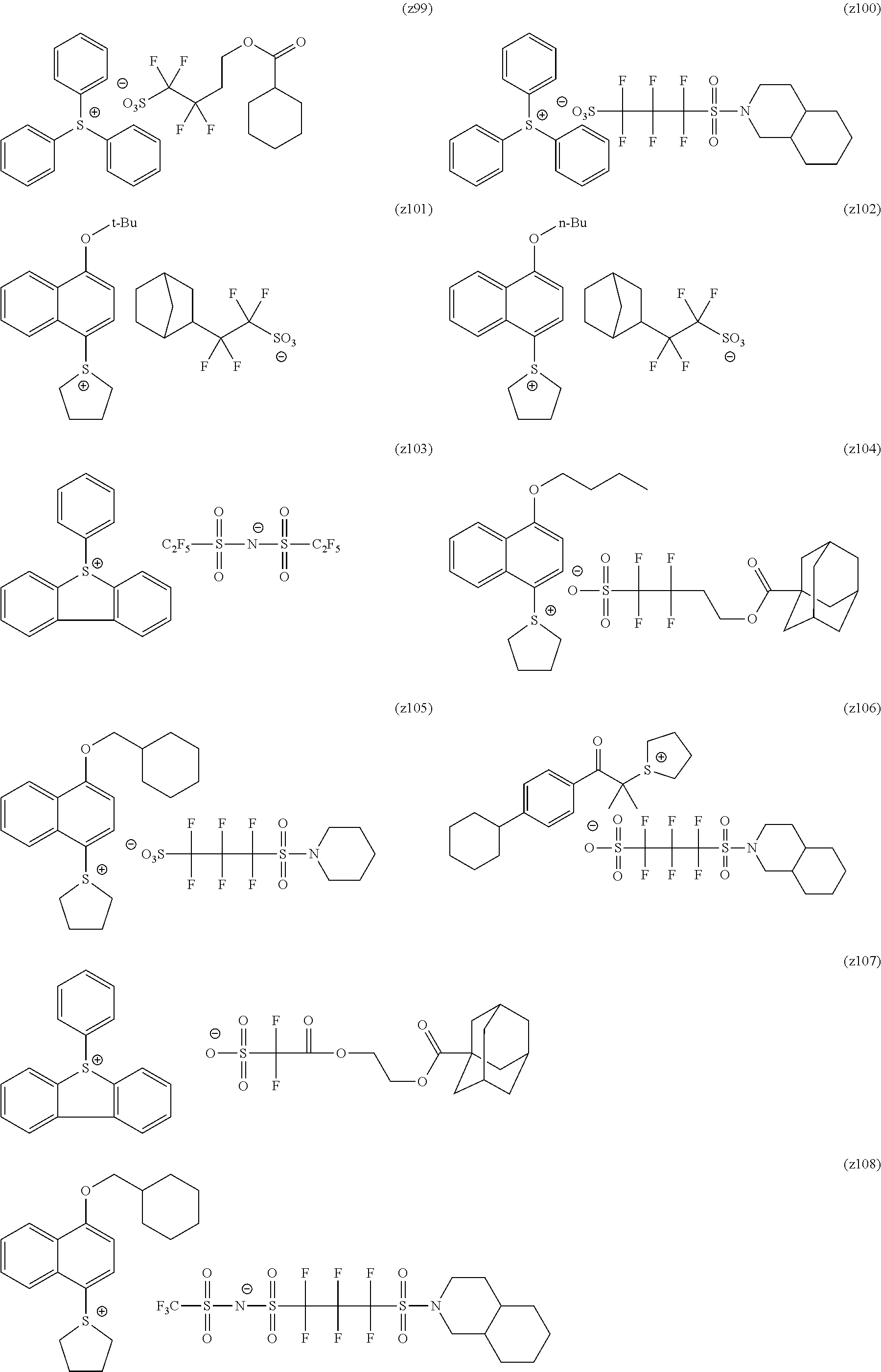

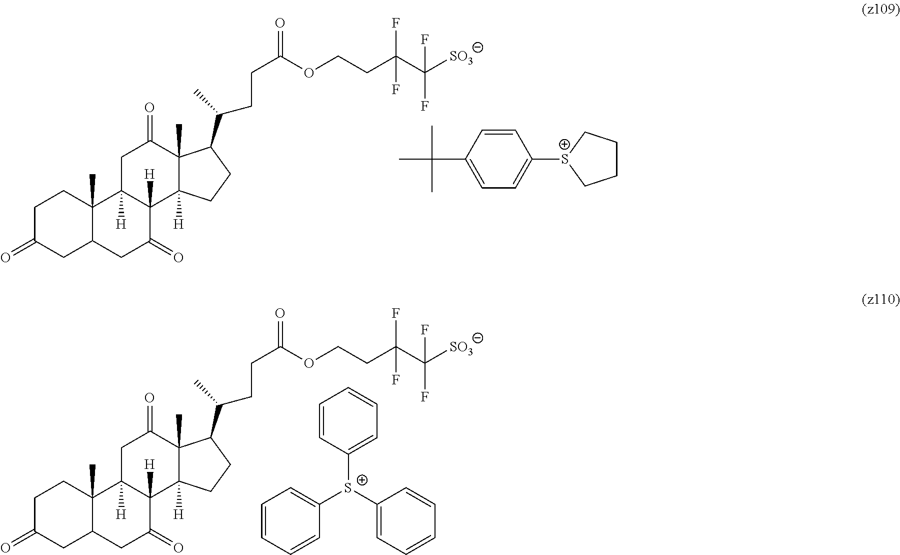

In addition, particularly preferred examples of compound (B) having the anion represented by any one of Formulas (B-1) to (B-3) will be described below, but the present invention is not limited thereto.

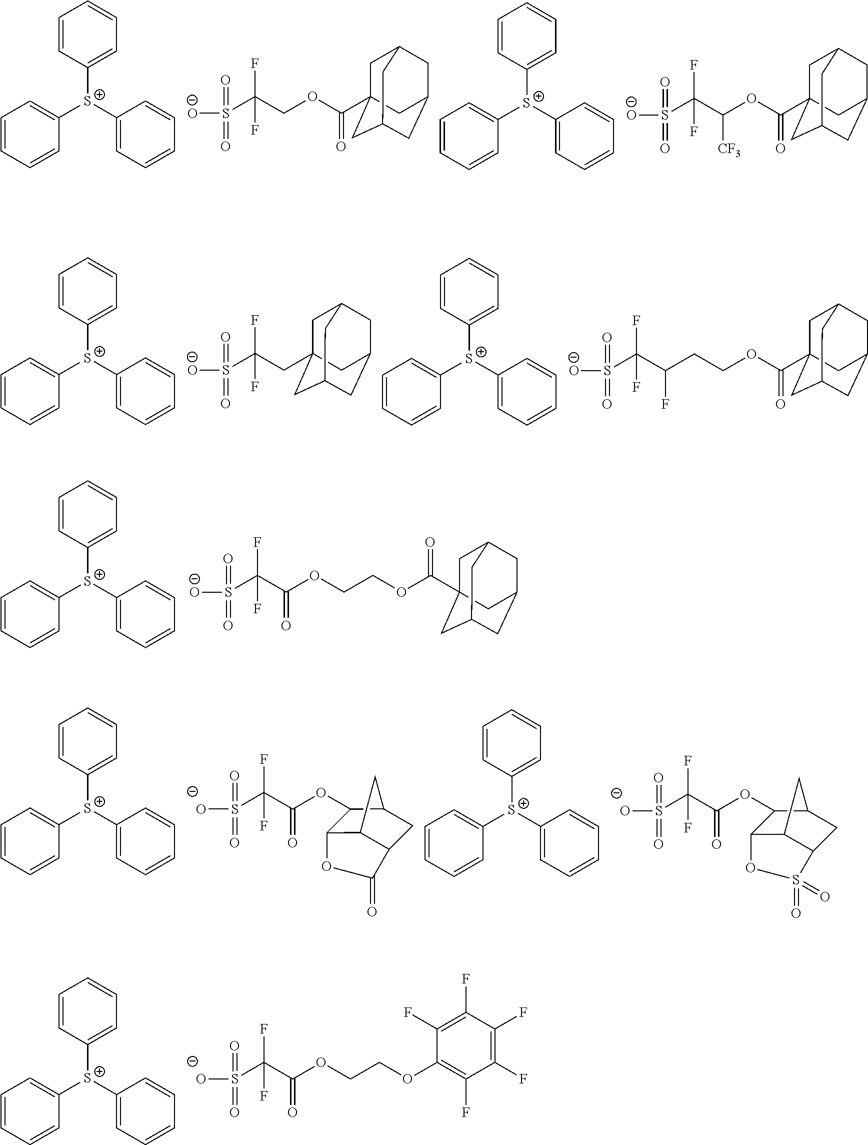

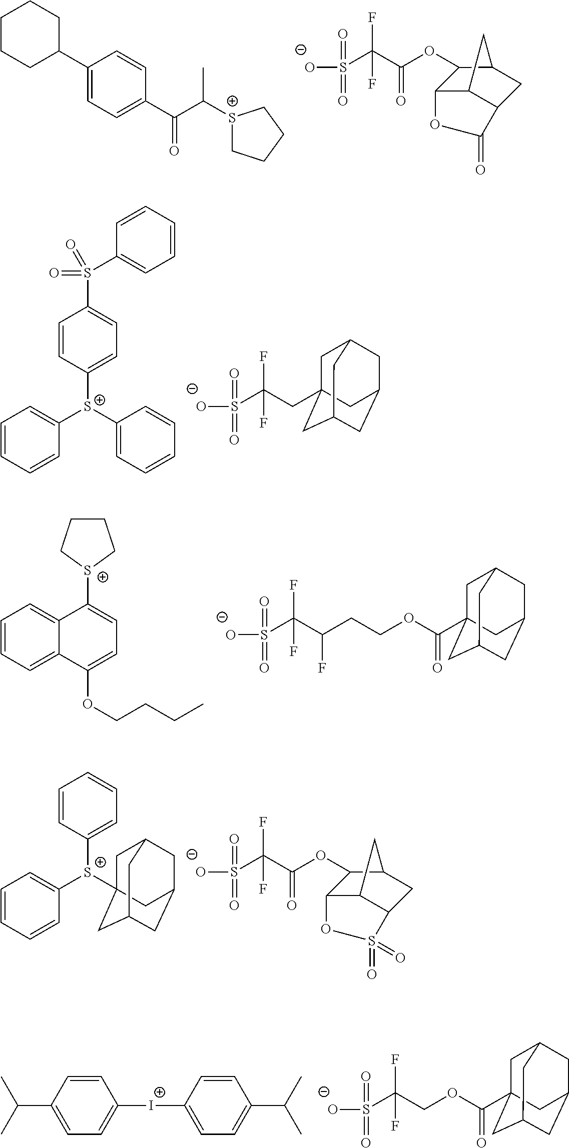

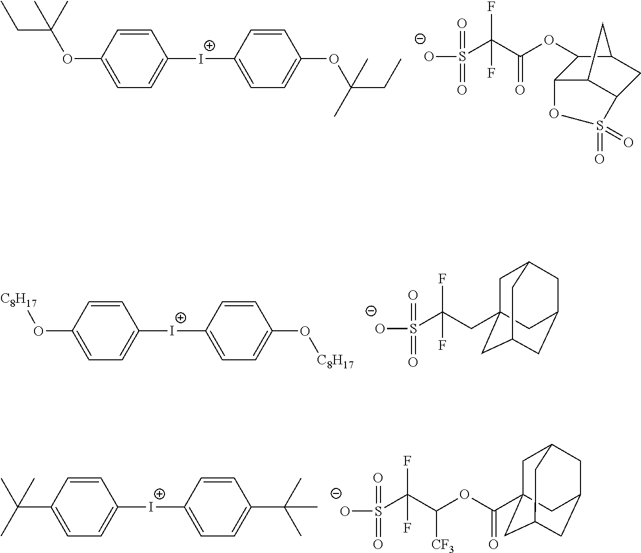

The acid generator may be synthesized by a publicly known method, and may be synthesized in accordance with the method described in, for example, Japanese Patent Application Laid-open No. 2007-161707, [0200] to [0210] of Japanese Patent Application Laid-open No. 2010-100595, [0051] to [0058] of International Publication No. 2011/093280, [0382] to [0385] of International Publication No. 2008/153110, Japanese Patent Application Laid-open No. 2007-161707 and the like.

The acid generator may be used either alone or in combination of two or more thereof.

The content of the compound capable of generating an acid upon irradiation with an actinic ray or radiation (except for the case represented by Formula (ZI-3) or (ZI-4)) in the composition is preferably 0.1 to 30% by mass, more preferably 0.5 to 25% by mass, still more preferably 3 to 20% by mass, and particularly preferably 3 to 15% by mass, based on the total solid content of the actinic ray-sensitive or radiation-sensitive resin composition (1).

Furthermore, when the acid generator is represented by Formula (ZI-3) or (ZI-4), the content thereof is preferably 5 to 35% by mass, more preferably from 8 to 30% by mass, still more preferably from 9 to 30% by mass, and particularly preferably from 9 to 25% by mass, based on the total solid content of the composition.

[3] Solvent (C2)

The actinic ray-sensitive or radiation-sensitive resin composition contains the solvent (C2), provided that the solvent (C2) is different from the solvent (C1) as described above.

Examples of the solvent (C2) which may be used at the time of preparing the actinic ray-sensitive or radiation-sensitive resin composition may include an organic solvent such as alkylene glycol monoalkyl ether carboxylate, alkylene glycol monoalkyl ether, alkyl ester lactate, alkyl alkoxypropionate, cyclic lactone (preferably having 4 to 10 carbon atoms), a monoketone compound (preferably having 4 to 10 carbon atoms) which may have a ring, alkylene carbonate, alkyl alkoxyacetate and alkyl pyruvate.

Specific examples of these solvents may include those described in [0441] to [0455] of U.S. Patent Application Publication No. 2008/0187860.

As the solvent (C2) in the present invention, a mixed solvent of a solvent containing a hydroxyl group and a solvent containing no hydroxyl group in the structure may be used.

As a solvent containing a hydroxyl group and a solvent containing no hydroxyl group, the above-mentioned compounds may be appropriately selected, and the solvent containing a hydroxyl group is preferably alkylene glycol monoalkyl ether, alkyl lactate and the like, and more preferably propylene glycol monomethyl ether (PGME, another name 1-methoxy-2-propanol) or ethyl lactate. Further, the solvent containing no hydroxyl group is preferably alkylene glycol monoalkyl ether acetate, alkyl alkoxypropionate, a monoketone compound which may contain a ring, cyclic lactone, alkyl acetate and the like, and among them, particularly preferably propylene glycol monomethyl ether acetate (PGMEA, another name 1-methoxy-2-acetoxypropane), ethyl ethoxypropionate, 2-heptanone, γ-butyrolactone, cyclohexanone or butyl acetate, and most preferably propylene glycol monomethyl ether acetate, ethylethoxy propionate or 2-heptanone.

The mixing ratio (by mass) of the solvent containing a hydroxyl group to the solvent containing no hydroxyl group is 1/99 to 99/1, preferably 10/90 to 90/10, and more preferably 20/80 to 60/40. A mixed solvent in which the solvent containing no hydroxyl group is contained in an amount of 50% by mass or more is particularly preferred in view of coating uniformity.

The solvent (C2) preferably contains propylene glycol monomethyl ether acetate, and is preferably a propylene glycol monomethyl ether acetate sole solvent, or a mixed solvent of two kinds or more containing propylene glycol monomethyl ether acetate.

[4] Hydrophobic Resin (D)

Particularly when applied to liquid immersion exposure, the actinic ray-sensitive or radiation-sensitive resin composition according to the present invention may contain a hydrophobic resin (hereinafter, also referred to as a “hydrophobic resin (D)” or simply referred to as a “resin (D)”). Further, the hydrophobic resin (D) is preferably different from the resin (A).

Accordingly, when the hydrophobic resin (D) is unevenly distributed on the film top layer and the immersion medium is water, the static/dynamic contact angle of the resist film surface against water may be enhanced, thereby enhancing an immersion liquid follow-up property.

It is preferred that the hydrophobic resin (D) is designed to be unevenly distributed at the interface as previously described, but unlike a surfactant, the hydrophobic resin (D) does not need to have a hydrophilic group in the molecule thereof, and may not contribute to the mixing of polar/non-polar materials homogeneously.

From the viewpoint of uneven distribution on the film top layer, the hydrophobic resin (D) has preferably one or more of “a fluorine atom”, “a silicon atom” and “a CH₃ partial structure contained in a side chain moiety of a resin”, and more preferably two or more thereof.

When the hydrophobic resin (D) includes a fluorine atom and/or a silicon atom, the fluorine atom and/or the silicon atom in the hydrophobic resin (D) may be included in the main chain of the resin, and may be included in the side chain thereof.

When the hydrophobic resin (D) includes a fluorine atom, the hydrophobic resin (D) is preferably a resin having an alkyl group having a fluorine atom, a cycloalkyl group having a fluorine atom, or an aryl group having a fluorine atom as a partial structure having a fluorine atom.

The alkyl group (having preferably 1 to 10 carbon atoms, and more preferably 1 to 4 carbon atoms) having a fluorine atom is a straight or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is an aryl group in which at least one hydrogen atom in an aryl group such as a phenyl group and a naphthyl group is substituted with a fluorine atom, and may further have a substituent other than a fluorine atom.

Preferred examples of the alkyl group having a fluorine atom, the cycloalkyl group having a fluorine atom and the aryl group having a fluorine atom include groups represented by the following Formulas (F2) to (F4), but the present invention is not limited thereto.

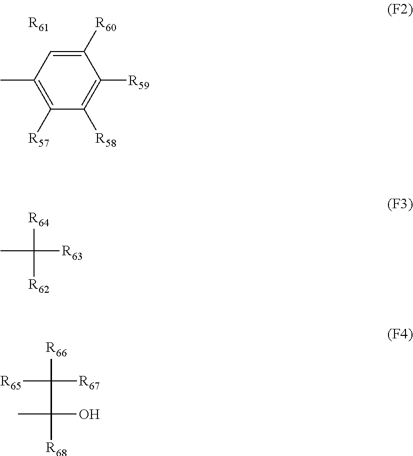

In Formulas (F2) ad (F4),

Each of R₅₇ to R₆₈ independently represents a hydrogen atom, a fluorine atom or an alkyl group (straight or branched). However, each of at least one of R₅₇ to R₆₁, at least one of R₆₂ to R₆₄ and at least one of R₆₅ to R₆₈ independently represents a fluorine atom or an alkyl group (preferably having 1 to 4 carbon atoms) in which at least one hydrogen atom is substituted with a fluorine atom.

All of R₅₇ to R₆₁ and R₆₅ to R₆₇ are preferably a fluorine atom. R₆₂, R₆₃ and R₆₈ are preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be bonded to each other to form a ring.

Specific examples of the group represented by Formula (F2) may include a p-fluorophenyl group, a pentafluorophenyl group, a 3,5-di(trifluoromethyl)phenyl group and the like.

Specific examples of the group represented by Formula (F3) may include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. A hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred, and a hexafluoroisopropyl group and a heptafluoroisopropyl group are more preferred.

Specific examples of the group represented by Formula (F4) may include —C(CF₃)₂OH, —C(C₂F)₂OH. —C(CF₃)(CH₃)OH, —CH(CF₃)OH and the like, and —C(CF₃)₂OH is preferred.

The partial structure including a fluorine atom may be banded directly to the main chain and further may be bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more thereof.

Hereinafter, specific examples of the repeating unit having a fluorine atom will be described, but the present invention is not limited thereto.

In the specific examples, X₁ represents a hydrogen atom, —CH₃, —F or —CF₃. X₂ represents —F or —CF₃.

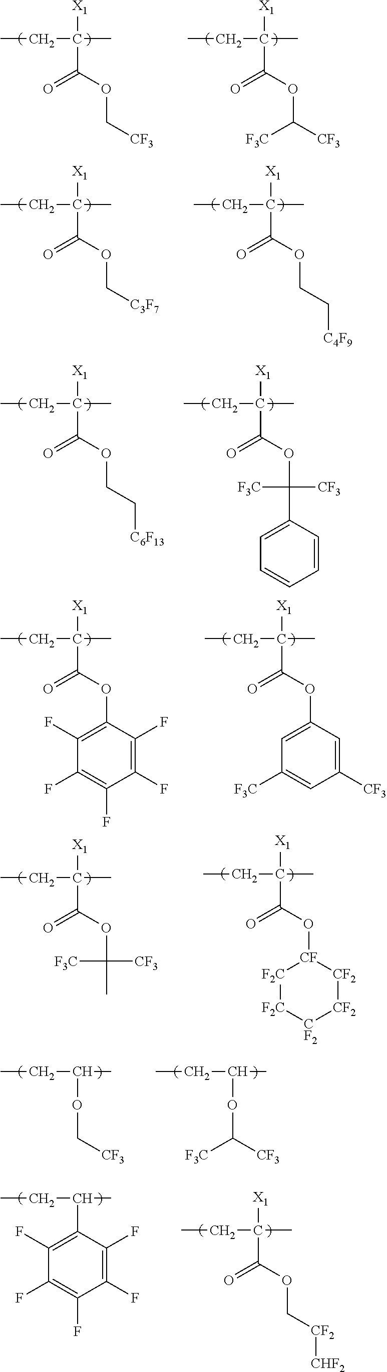

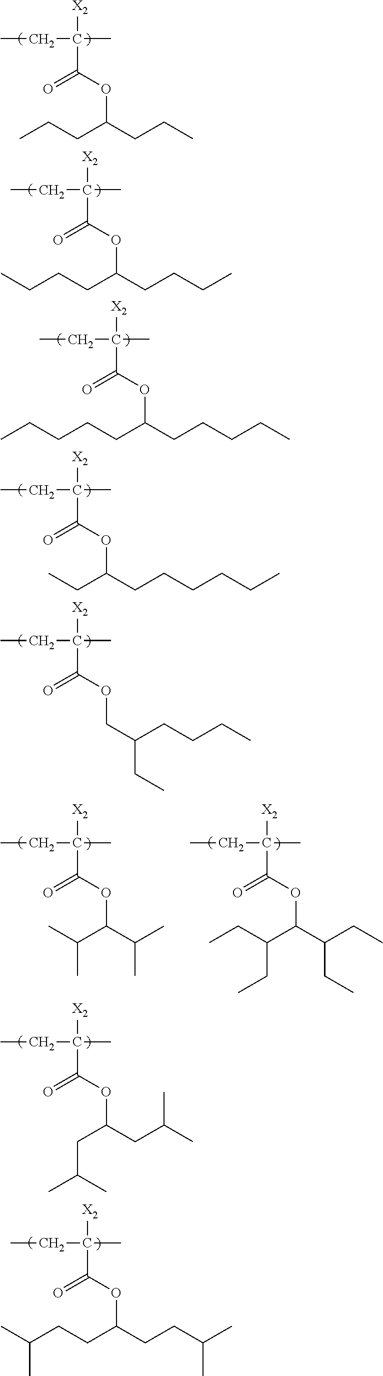

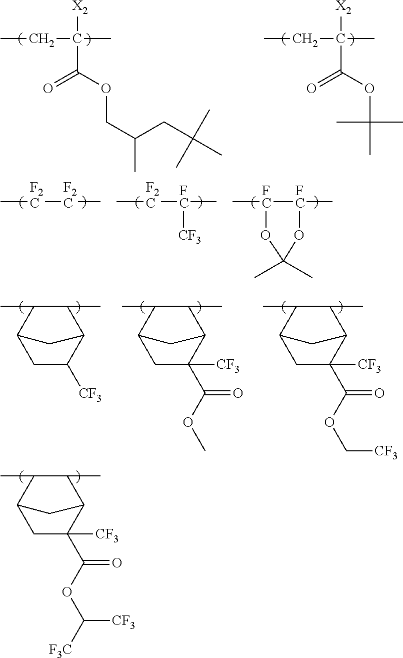

The hydrophobic resin (D) may contain a silicon atom. The hydrophobic resin (D) is preferably a resin having an alkylsilyl structure (preferably a trialkylsilyl group) or a cyclic siloxane structure as a partial structure having a silicon atom.

Specific examples of the alkylsilyl structure or the cyclic siloxane structure may include groups represented by the following Formulas (CS-1) to (CS-3) and the like.

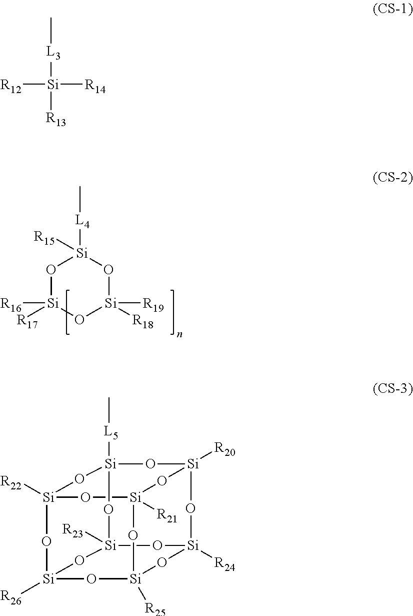

In Formulas (CS-1) to (CS-3),

Each of R₁₂ to R₂₆ independently represents a straight or branched alkyl group (preferably having 1 to 20 carbon atoms) or a cycloalkyl group (preferably having 3 to 20 carbon atoms).

Each of L₃ to L₅ represents a single bond or a divalent linking group. Examples of the divalent linking group may include a sole group or a combination of two or more groups (preferably having a total carbon number of 12 or less), selected from the group consisting of an alkylene group, a phenylene group, an ether bond, a thioether bond, a carbonyl group, an ester bond, an amide bond, a urethane bond and an urea bond.

n represents an integer of 1 to 5. n is preferably an integer of 2 to 4.

Hereinafter, specific examples of the repeating unit having a group represented by Formulas (CS-1) to (CS-3) will be shown, but the present invention is not limited thereto. Meanwhile, in the specific examples, X₁ represents a hydrogen atom, —CH₃, —F, or —CF₃.

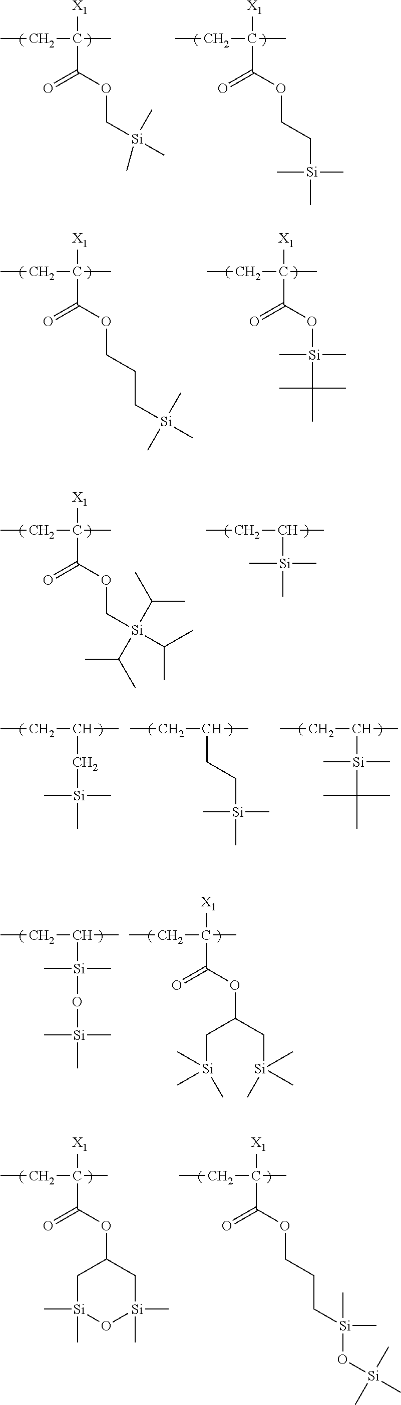

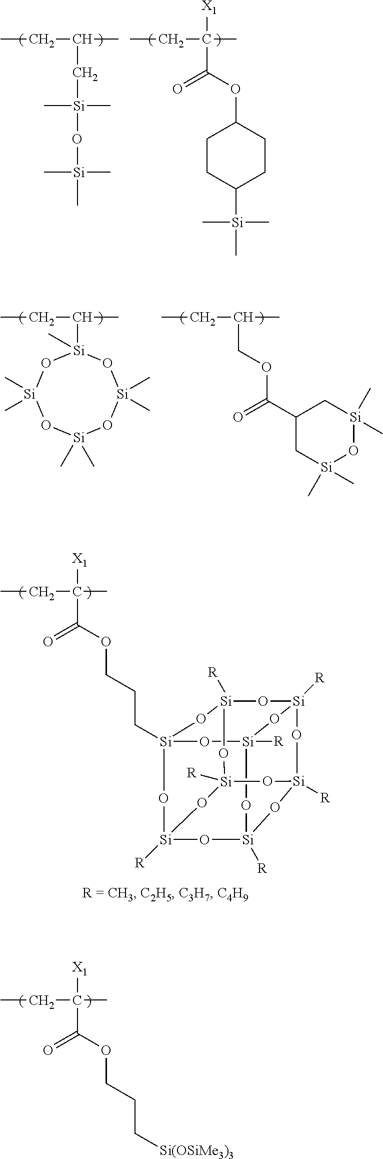

Further, as described above, it is preferred that hydrophobic resin (D) also includes a CH₃ partial structure in the side chain moiety thereof.

Here, the CH₃ partial structure (hereinafter, simply referred to as a “side chain CH₃ partial structure”), which the side chain moiety in the resin (I)) has, includes a CH₃ partial structure that an ethyl group, a propyl group and the like have.

Meanwhile, a methyl group (for example, an α-methyl group of the repeating unit having a methacrylic acid structure) directly bonded to the main chain of the resin (D) slightly contributes to the surface uneven distribution of the resin (D) due to the effects of the main chain and thus is not included in the CH₃ partial structure in the present invention.

More specifically, when resin (D) includes a repeating unit derived from a monomer having a polymerizable moiety having a carbon-carbon double bond, such as, for example, a repeating unit represented by the following Formula (M) and when R₁₁ to R₁₄ are a CH₃ “as it is”, the CH₃ is not included in the CH₃ partial structure in the present invention that the side chain moiety has.

Meanwhile, the CH₃ partial structure present through any atom from the C—C main chain is assumed to correspond to a CH₃ partial structure in the present invention. For example, when R₁₁ is an ethyl group (CH₂CH₃), R₁₁ is assumed to have “one” of the CH₃ partial structures in the present invention.

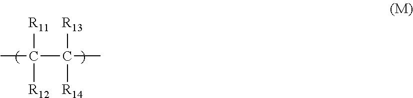

In Formula (M),

Each of R₁₁ to R₁₄ independently represents a side chain moiety.

Examples of R₁₁ to R₁₄ in the side chain moiety may include a hydrogen atom, a monovalent organic group and the like.

Examples of the monovalent organic group for R₁₁ to R₁₄ may include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group and the like, and these groups may further have a substituent.

The hydrophobic resin (D) is preferably a resin having a repeating unit having a CH₃ partial structure at the side chain moiety thereof, and more preferably has at least one repeating unit (x) of a repeating unit represented by the following Formula (II) and a repeating unit represented by the following Formula (III) as the repeating unit.

Hereinafter, the repeating unit represented by Formula (II) will be described in detail

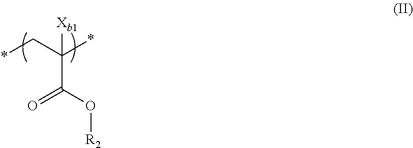

In Formula (II), X_{b1} represents a hydrogen atom, an alkyl group, a cyano group or a halogen atom, and R₂ represents an organic group which is stable against an acid and has one or more CH₃ partial structures. Here, more specifically, the organic group which is stable against an acid is preferably an organic group which does not have “a group capable of decomposing by the action of an acid to generate a polar group” previously described with respect to the resin (A).

The alkyl group of X_{b1} is preferably an alkyl group having 1 to 4 carbon atoms, and examples thereof include a methyl group, an ethyl group, a propyl group, a hydroxymethyl group, a trifluoromethyl group and the like, but a methyl group is preferred.

X_{b1} is preferably a hydrogen atom or a methyl group.

Examples of R₂ may include an alkyl group, a cycloalkyl group, an alkenyl group, a cycloalkenyl group, an aryl group and an aralkyl group, which have one or more CH₃ partial structures. The aforementioned cycloalkyl group, alkenyl group, cycloalkenyl group, aryl group and aralkyl group may further have an alkyl group as a substituent.

R₂ is preferably an alkyl group or an alkyl-substituted cycloalkyl group, which has one or more CH₃ partial structures.

As R₂, the organic group, which has one or more CH partial structures and is stable against an acid, preferably has 2 to 10 CH₃ partial structures, and more preferably 2 to 8 CH₃ partial structures.

The alkyl group having one or more CH₃ partial structures in R₂ is preferably a branched alkyl group having 3 to 20 carbon atoms.

The cycloalkyl group having one or more CH₃ partial structures in R₂ may be monocyclic or polycyclic. Specific examples thereof may include groups having a monocyclo, bicyclo, tricyclo and tetracyclo structure having 5 or more carbon atoms, and the like. The carbon number thereof is preferably 6 to 30, and particularly preferably 7 to 25.

The alkenyl group having one or more CH₃ partial structures in R₂ is preferably a straight or branched alkenyl group having 1 to 20 carbons, and more preferably a branched alkenyl group.

The aryl group having one or more CH₃ partial structures in R₂ is preferably an aryl group having 6 to 20 carbon atoms, and examples thereof may include a phenyl group and a naphthyl group, and preferably a phenyl group.

The aralkyl group having one or more CH₃ partial structures in R₂ is preferably an aralkyl group having 7 to 12 carbon atoms, and examples thereof may include a benzyl group, a phenethyl group, a naphthylmethyl group and the like.

Preferred specific examples of the repeating unit represented by Formula (II) will be described below. Meanwhile, the present invention is not limited thereto.

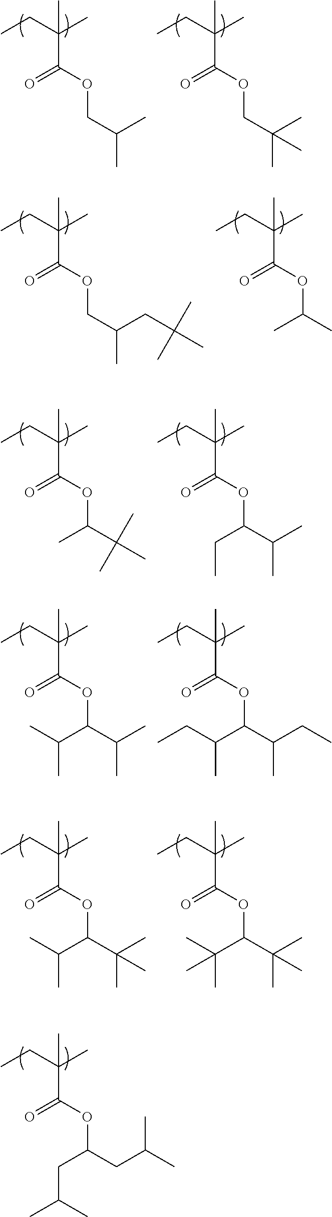

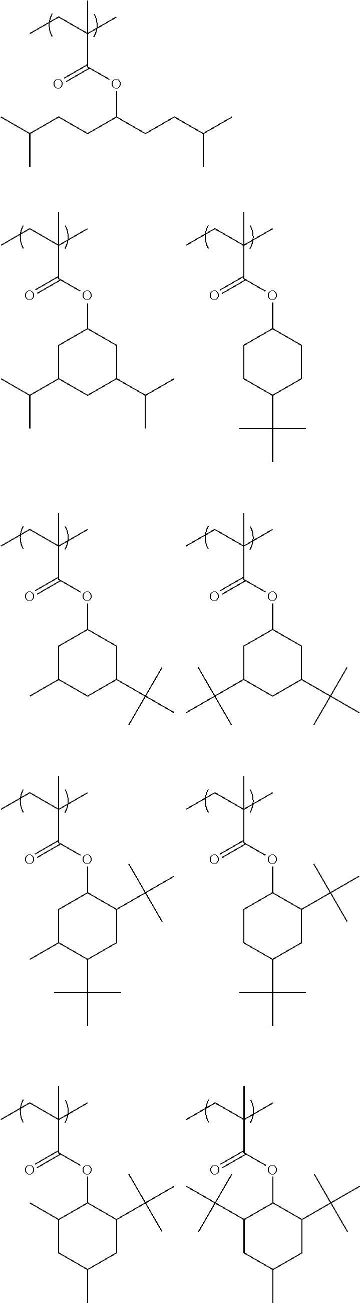

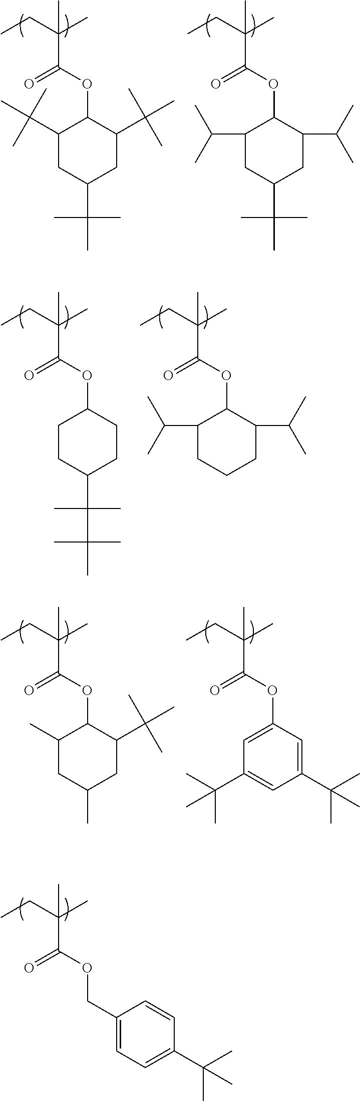

The repeating unit represented by Formula (II) is preferably a repeating unit that is stable against an acid (non-acid-decomposable). Specifically, a repeating unit having no group capable of decomposing by the action of an acid to generate a polar group is preferred.

Hereinafter, the repeating unit represented by Formula (III) will be described in detail.

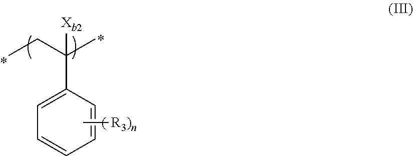

In Formula (III), X_{b2} represents a hydrogen atom, an alkyl group, a cyano group or a halogen atom. R₃ represents an organic group which is stable against an acid and has one or more CH₃ partial structures, and n represents an integer of 1 to 5.

The alkyl group of X_{b2} is preferably an alkyl group having 1 to 4 carbon atoms, and examples thereof may include a methyl group, an ethyl group, a propyl group, a hydroxymethyl group, a trifluoromethyl group or the like, but a hydrogen atom is preferred.

X_{b2} is preferably a hydrogen atom.

Since R₃ is an organic group which is stable against an acid, more specifically, R₃ is preferably an organic group which does not have “a group capable of decomposing by the action of an acid to generate a polar group” described in the resin (A).

Examples of R₃ may include an alkyl group having one or more CH₃ partial structures.

The organic group as R₃, which has one or more CH₃ partial structures and is stable against an acid, preferably has 1 to 10 CH₃ partial structures, more preferably 1 to 8 CH₃ partial structures, and still more preferably 1 to 4 CH₃ partial structures.

The alkyl group having one or more CHI partial structures in R₃ is preferably a branched alkyl group having 3 to 20 carbon atoms.

n represents an integer of 1 to 5, more preferably an integer of 1 to 3, and still more preferably 1 or 2.

Preferred specific examples of the repeating unit represented by Formula (III) will be described below, but the present invention is not limited thereto.

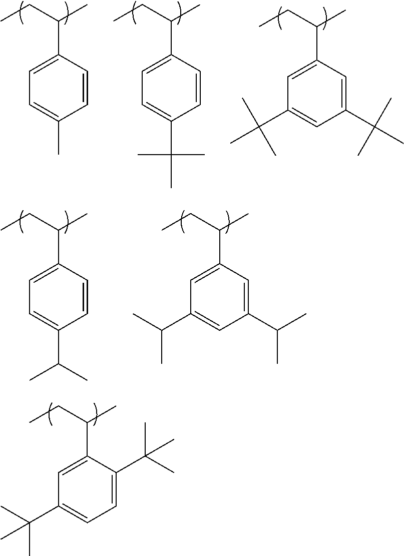

The repeating unit represented by Formula (III) is preferably a repeating unit that is stable against an acid (non-acid-decomposable), and specifically, is preferably a repeating unit having no group capable of decomposing by the action of an acid to generate a polar group.

When the resin (D) includes a CH₃ partial structure in the side chain moiety thereof and particularly has no fluorine atom and silicon atom, a content of at least one repeating unit (x) of the repeating unit represented by Formula (II) and the repeating unit represented by Formula (III) is preferably 90 mol % or more, and more preferably 95 mol % or more, based on all the repeating units of the resin (D). The content is usually 100 mol % or less based on all the repeating units of the resin (D).

The resin (D) contains at least one repeating unit (x) of the repeating unit represented by Formula (II) and the repeating unit represented by Formula (III) in an amount of 90 mol % or more based on all the repeating units of the resin (D), thereby increasing the surface free energy of the resin (D). As a result, it is difficult for the resin (D) to be unevenly distributed on the surface of the resist film, and thus the static/dynamic contact angle of the resist film against water may be certainly enhanced, thereby enhancing an immersion liquid follow-up property.

In addition, even when the hydrophobic rosin (D) includes (i) a fluorine atom and/or a silicon atom and even when the hydrophobic resin (D) includes (ii) a CH₃ partial structure in the side chain moiety thereof, the hydrophobic resin (D) may have at least one group selected from the group consisting of following (x) to (z).

(x) an acid group,

(y) a group having a lactone structure, an acid anhydride group or an acid imide group, and

(z) a group capable of decomposing by the action of an acid

Examples of the acid group (x) may include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group and the like.

Preferred examples of the acid group include a fluorinated alcohol group (preferably hexafluoroisopropanol), a sulfonimide group and a bis(alkylcarbonyl)methylene group.

Examples of the repeating unit having the acid group (x) may include a repeating unit, in which the acid group is directly bonded to the main chain of the resin, such as repeating unit by an acrylic acid or a methacrylic acid, or a repeating unit in which the acid group is bonded to the main chain of the resin through a linking group or the like. Furthermore, the repeating unit may also be introduced into the terminal of the polymer chain by using a polymerization initiator or a chain transfer agent each having an acid group at the time of polymerization, and all of these cases are preferred. The repeating unit having the acid group (x) may have at least one of a fluorine atom and a silicon atom.

The content of the repeating unit having the acid group (x) is preferably 1 to 50 mol %, more preferably 3 to 35 mol %, and still more preferably 5 to 20 mol %, based on all the repeating units in the hydrophobic resin (D).

Specific examples of the repeating unit having the acid group (x) will be shown below, but the present invention is not limited thereto. In Formulas, Rx represents a hydrogen atom, CH₃, CF₃ or CH₂OH.

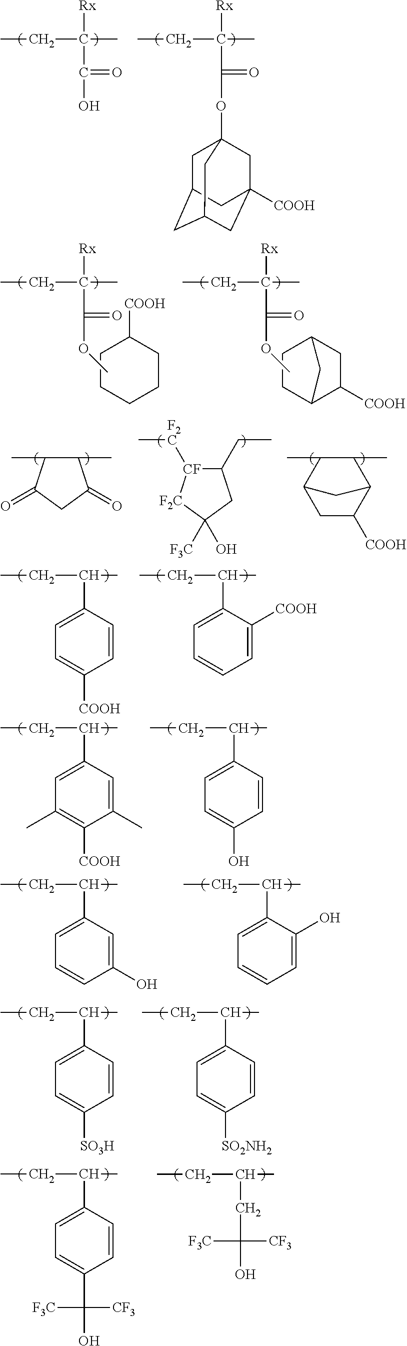

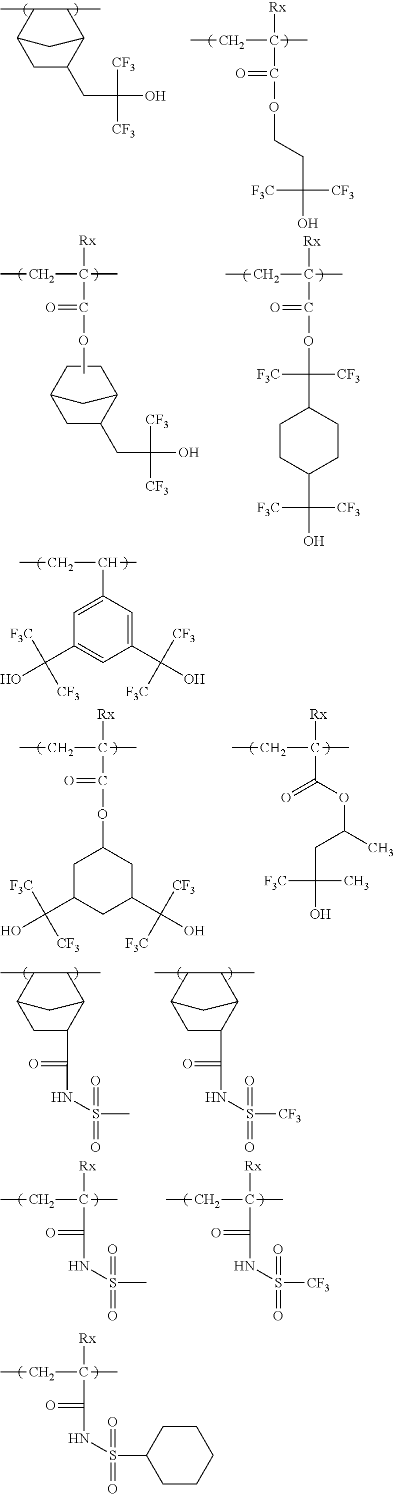

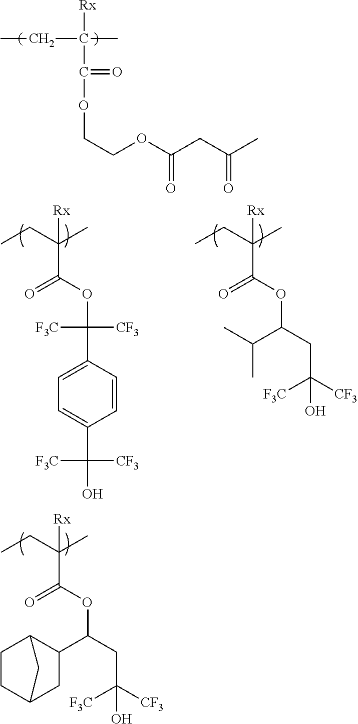

As (y) the group having a lactone structure, the acid anhydride group or the acid imide group, a group having a lactone structure is particularly preferred.

Examples of the repeating unit including these groups may include a repeating unit in which the group is directly bonded to the main chain of the resin, such as a repeating unit by an acrylate ester or a methacrylate ester. Or, the repeating unit may be a repeating unit in which the group is bonded to the main chain of the resin through a linking group. Or, the repeating unit may be introduced into the end of the resin by using a polymerization initiator or a chain transfer agent having the group at the time of polymerization.

Examples of the repeating unit having a group having a lactone structure are the same as those of the repeating unit having a lactone structure, which is previously described in the paragraph of the acid-decomposable resin (A).

The content of the repeating unit having a group having a lactone structure, an acid anhydride group or an acid imide group is preferably 1 to 100 mol %, more preferably 3 to 98 mol %, and still more preferably 5 to 95 mol %, based on all the repeating units in the hydrophobic resin (D).

Examples of the repeating unit having (z) a group capable of decomposing by the action of an acid in the hydrophobic resin (D) are the same as those of the repeating unit having an acid-decomposable group, which is exemplified in the resin (A). The repeating unit having (z) a group capable of decomposing by the action of an acid may have at least one of a fluorine atom and a silicon atom. In the hydrophobic resin (D), the content of the repeating unit having (z) a group capable of decomposing by the action of an acid is preferably 1 to 80 mol %, more preferably 10 to 80 mol %, and still more preferably 20 to 60 mol %, based on all the repeating units in the resin (D).

The hydrophobic resin (D) may further have a repeating unit represented by the following Formula (III).

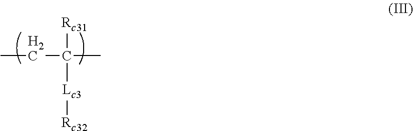

In Formula (III),

R_{c31} represents a hydrogen atom, an alkyl group (which may be substituted with a fluorine atom or the like), a cyano group or a —CH₂—O—Ra_{C2} group. In the formula, Rac₂ represents a hydrogen atom, an alkyl group or an acyl group. R_{c31} is preferably a hydrogen atom, a methyl group, a hydroxymethyl group and a trifluoromethyl group, and particularly preferably a hydrogen atom and a methyl group.

R_{c32} represents a group having an alkyl group, a cycloalkyl group, an alkenyl group, a cycloalkenyl group or an aryl group. These groups may be substituted with a group including a fluorine atom or a silicon atom.

L_{c3} represents a single bond or a divalent linking group.

In Formula (III), the alkyl group of R_{c32} is preferably a straight or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group, and these groups may have a substituent.

R_{c32} is preferably an unsubstituted alkyl group or an alkyl group substituted with a fluorine atom.

The divalent linking group of L_{c3} is preferably an alkylene group (preferably having 1 to 5 carbon atoms), an ether bond, a phenylene group or an ester bond (a group represented by —COO—).

The content of the repeating unit represented by Formula (III) is preferably 1 to 100 mol %, more preferably 10 to 90 mol %, and still more preferably 30 to 70 mol/o, based on all the repeating units in the hydrophobic resin.

It is also preferred that the hydrophobic resin (D) further has a repeating unit represented by the following Formula (CII-AB).

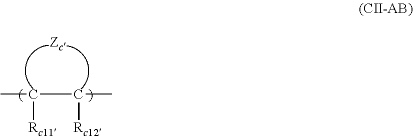

In Formula (CII-AB),

each of R_{c11}′ and R_{c12}′ independently represents a hydrogen atom, a cyano group, a halogen atom or an alkyl group.

Z_{c}′ includes two carbon atoms (C—C) to which Z_{c}′ is bonded and represents an atomic group for forming an alicyclic structure.

The content of the repeating unit represented by Formula (CII-AB) is preferably 1 to 100 mol %, more preferably 10 to 90 mol %, and still more preferably 30 to 70 mol %, based on all the repeating units in the hydrophobic resin.

Hereinafter, specific examples of the repeating units represented by Formulas (III) and (CII-AB) will be described below, but the present invention is not limited thereto. In the formulas. Ra represents H, CH₃, CH₂OH, CF₃ or CN.

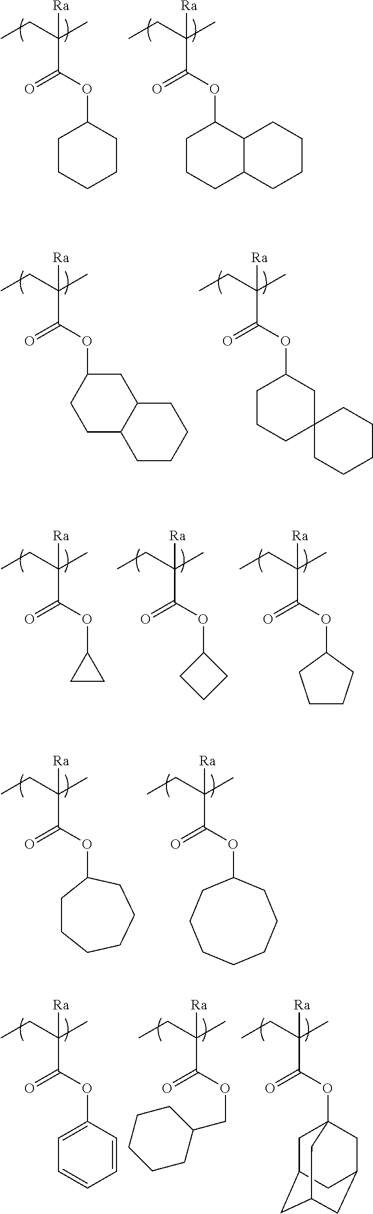

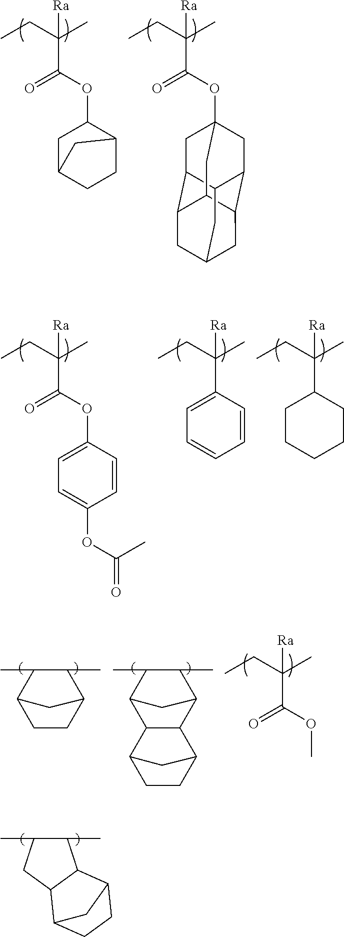

When the hydrophobic resin (D) has a fluorine atom, the content of the fluorine atom is preferably 5 to 80% by mass, and more preferably 10 to 80% by mass, based on the weight average molecular weight of the hydrophobic resin (D). Furthermore, the repeating unit including a fluorine atom is preferably 10 to 100 mol %, and more preferably 30 to 100 mol %, based on all the repeating units included in the hydrophobic resin (D).

When the hydrophobic resin (D) has a silicon atom, the content of the silicon atom is preferably from 2 to 50% by mass, and more preferably 2 to 30% by mass, based on the weight average molecular weight of the hydrophobic resin (D). Further, the repeating unit including a silicon atom is preferably 10 to 100 mol %, and more preferably 20 to 100 mol %, based on all the repeating units included in the hydrophobic resin (D).

Meanwhile, particularly when the resin (D) includes a CH₃ partial structure in the side chain moiety thereof, the form that the resin (D) contains substantially no fluorine atom and silicon atom is also preferred, and in this case, specifically, the content of the repeating unit having a fluorine atom or a silicon atom is preferably 5 mol % or less, more preferably 3 mol % or less, and still more preferably 1 mol % or less, based on all the repeating units in the resin (D), and is ideally 0 mol %, that is, containing no fluorine atom and silicon atom. In addition, it is preferred that the resin (D) is substantially composed of only a repeating unit composed of only an atom selected from a carbon atom, an oxygen atom, a hydrogen atom, a nitrogen atom and a sulfur atom. More specifically, the repeating unit composed only of an atom selected from a carbon atom, an oxygen atom, a hydrogen atom, a nitrogen atom and a sulfur atom is present in an amount of preferably 95 mol % or more, more preferably 97 mol % or more, still more preferably 99 mol % or more, and ideally 100 mol %, based on all the repeating units of the resin (D).

The weight average molecular weight of the hydrophobic resin (D) in terms of standard polystyrene in accordance with the GPC method is preferably 1,000 to 100,000, more preferably 1,000 to 50,000, and still more preferably 2,000 to 15,000.

Furthermore, the hydrophobic resin (D) may be used either alone or in combination of a plurality thereof.

The content of the hydrophobic resin (D) in the composition is preferably 0.01 to 10% by mass, more preferably from 0.05 to 8% by mass, and still more preferably from 0.1 to 7% by mass, based on the total solid content in the composition of the present invention.

In the hydrophobic resin (D), similarly to the resin (A), it is natural that the content of impurities such as metal is small, and the content of residual monomers or oligomer components is preferably 0.01 to 5% by mass, more preferably 0.01 to 3% by mass, and still more preferably 0.05 to 1% by mass. Accordingly, it is possible to obtain an actinic ray-sensitive or radiation-sensitive resin composition free from extraneous substances in liquid and change in sensitivity and the like with time. Further, from the viewpoint of resolution, resist shape, side wall of resist pattern, roughness and the like, the molecular weight distribution (Mw/Mn, also referred to as polydispersity) is in a range of preferably 1 to 3, more preferably 1 to 3, and still more preferably 1 to 2.

As for the resin (D), various commercially available products may be used, and the resin (D) may be synthesized by a conventional method (for example, radical polymerization). Examples of a general synthesis method include a batch polymerization method of dissolving monomer species and an initiator in a solvent and heating the solution, thereby performing the polymerization, a dropping polymerization method of adding dropwise a solution containing monomer species and an initiator to a heated solvent over 1 to 10 hours, and the like, and a dropping polymerization method is preferred.

The reaction solvent, polymerization initiator, reaction conditions (temperature, concentration and the like) and purification method after reaction are the same as those described in the resin (A), but in the synthesis of the hydrophobic resin (D), the reaction concentration is preferably 30 to 50% by mass.

Hereinafter, specific examples of the hydrophobic resin (D) will be shown. In addition, the molar ratio (corresponding to each repeating unit sequentially from the left), the weight average molecular weight and the polydispersity of the repeating unit in each resin are shown in the following Tables.

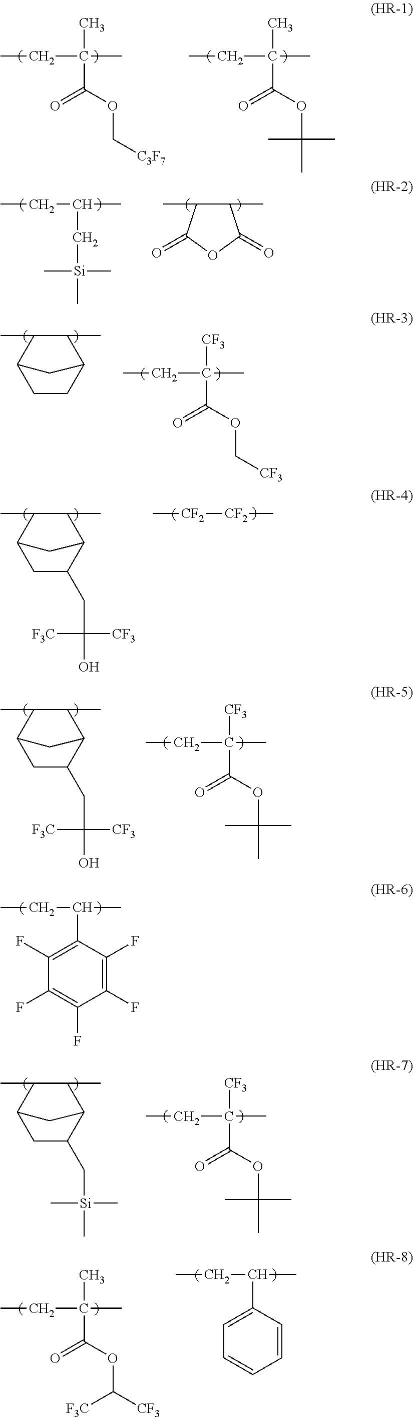

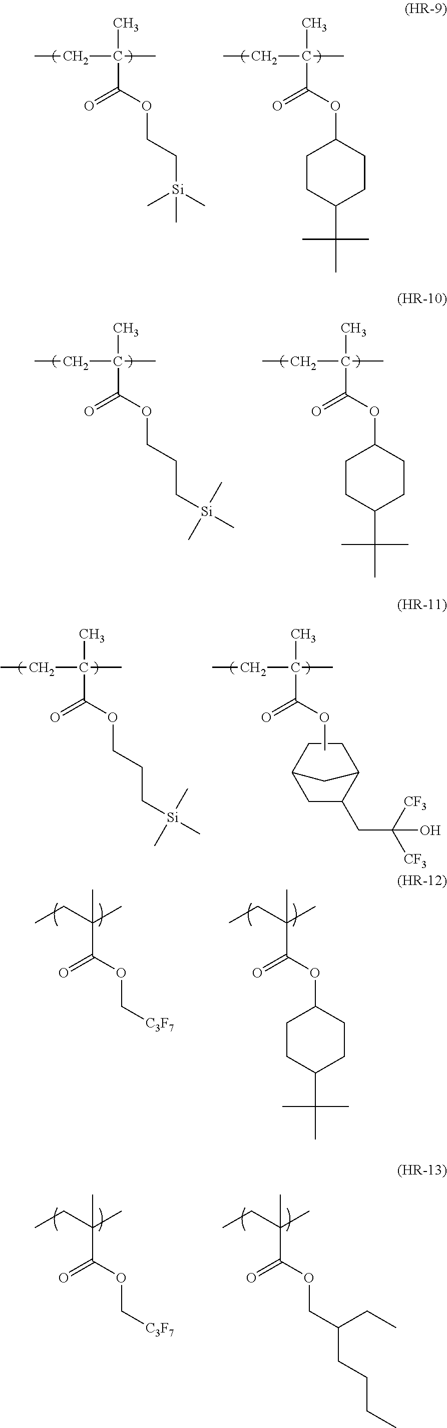

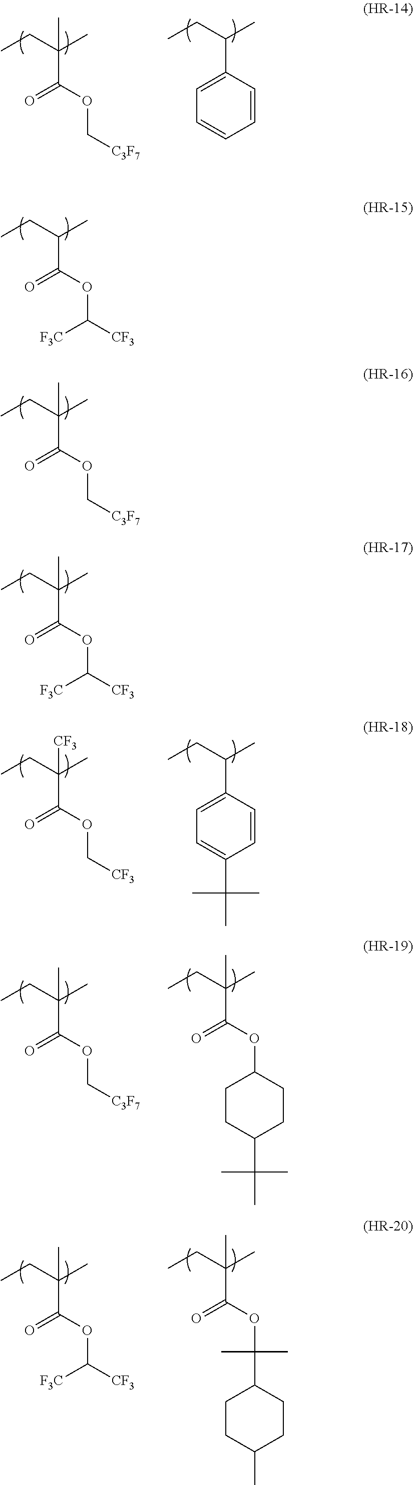

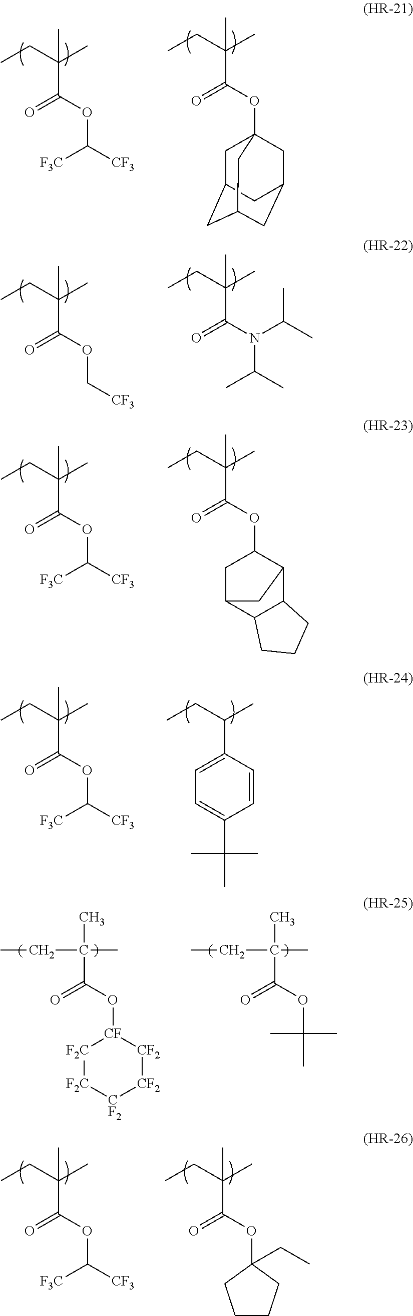

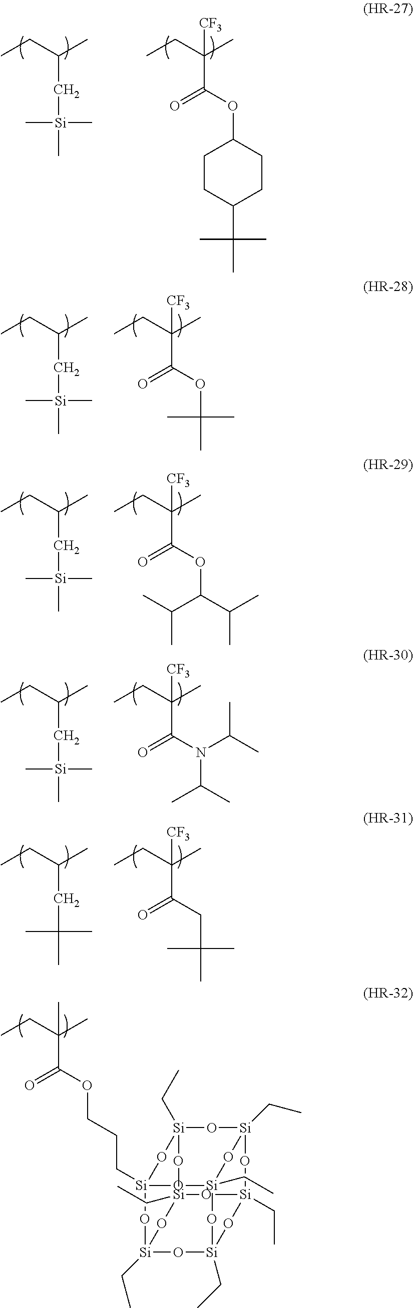

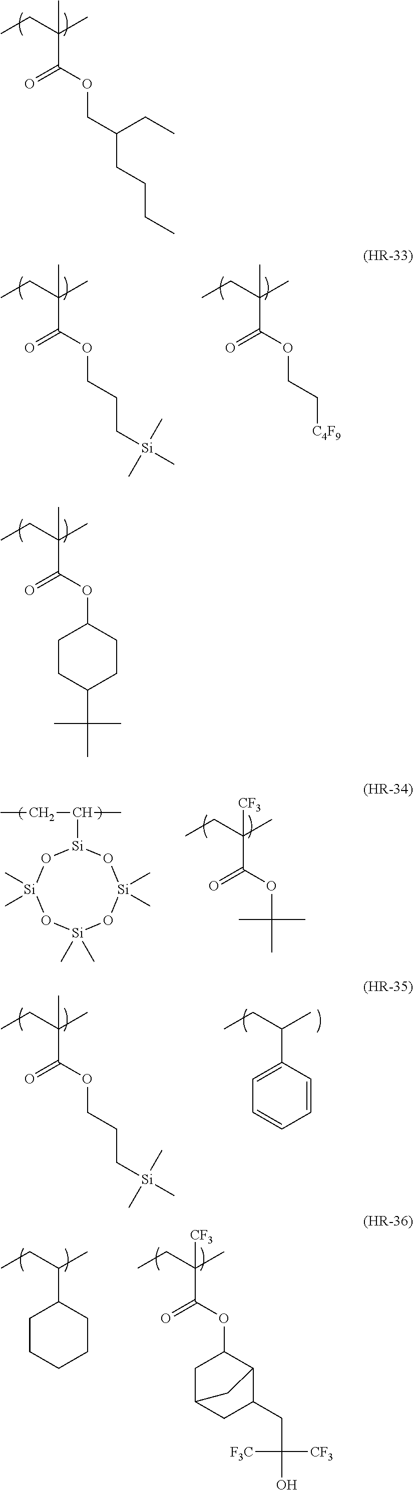

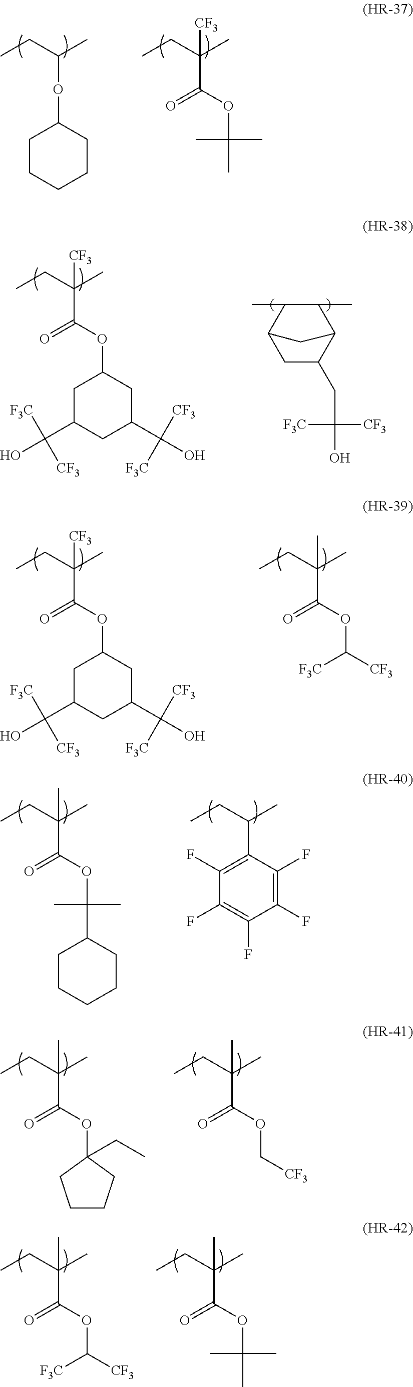

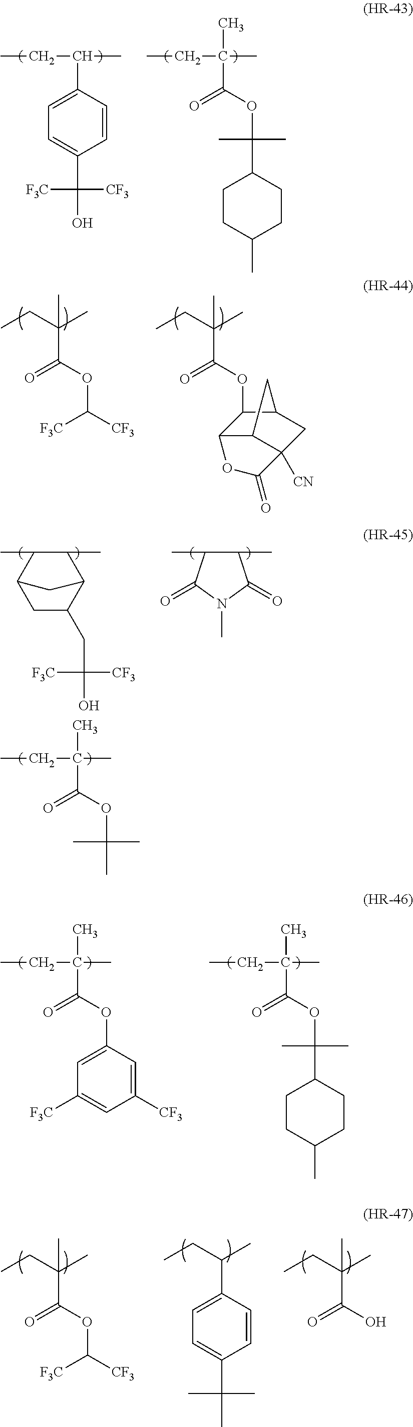

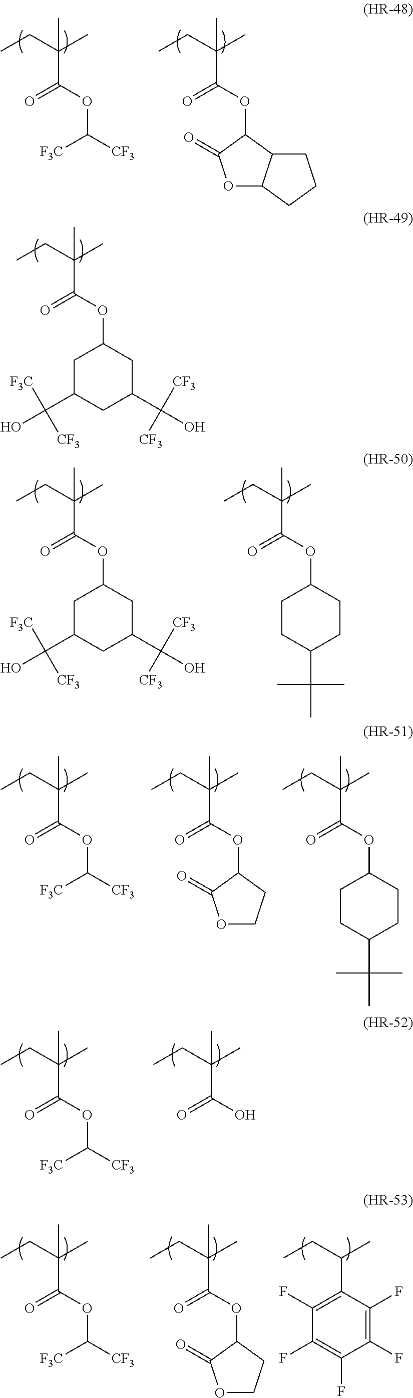

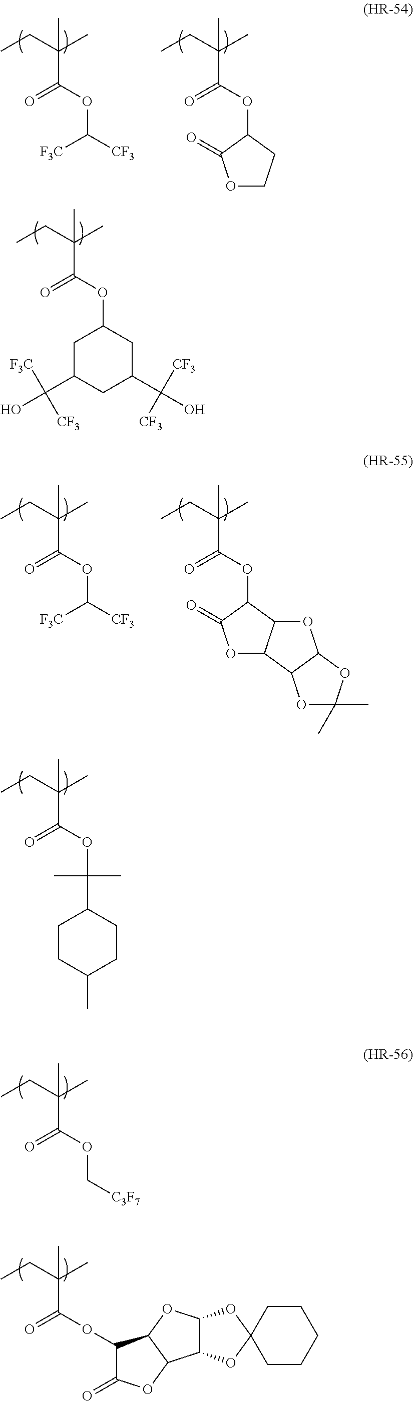

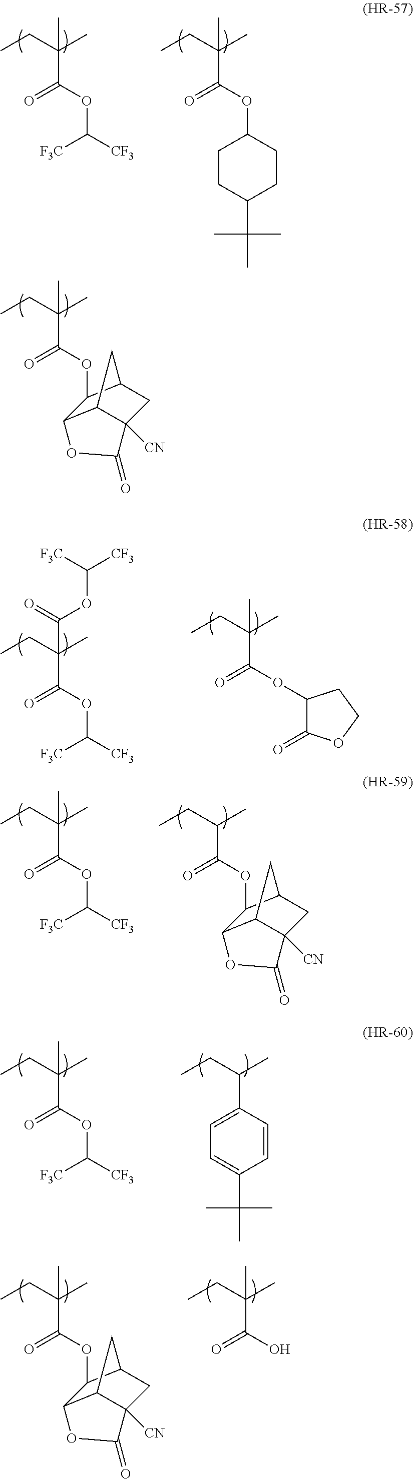

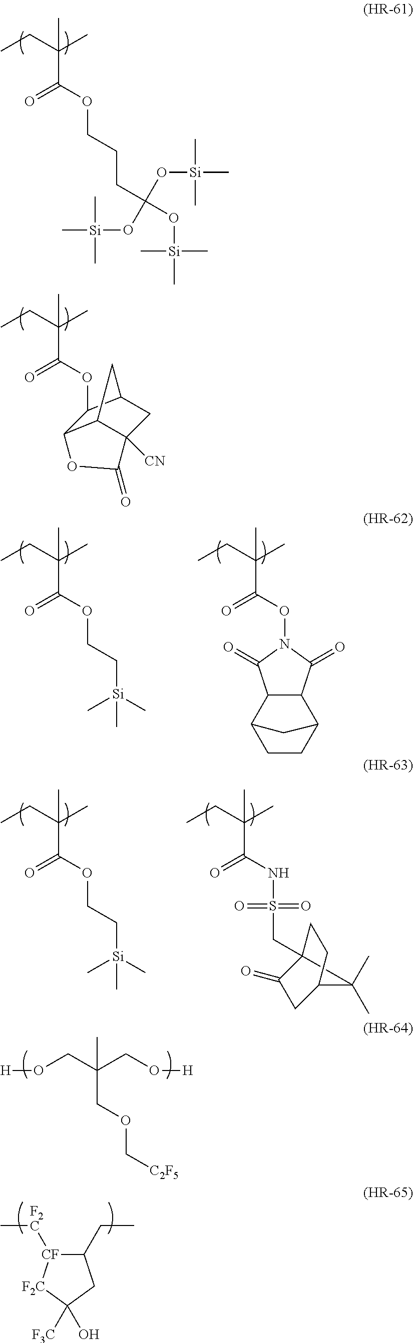

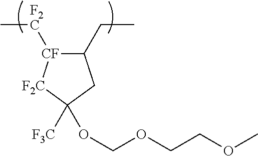

TABLE 2

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

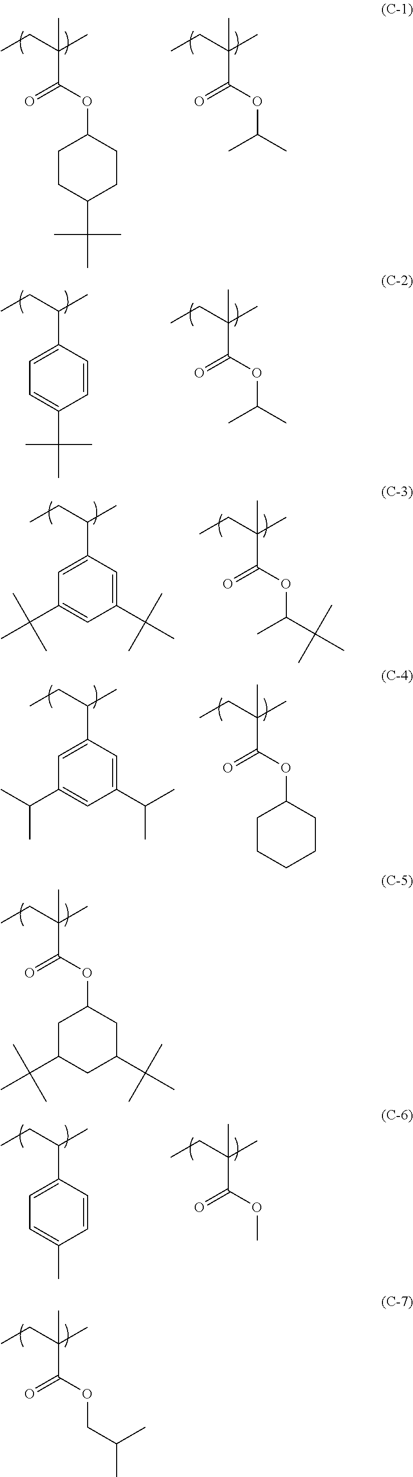

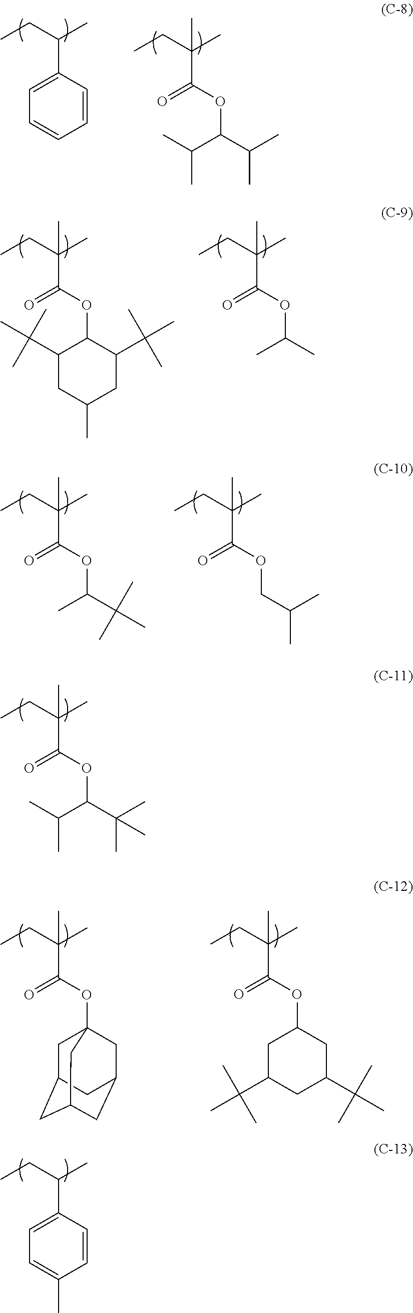

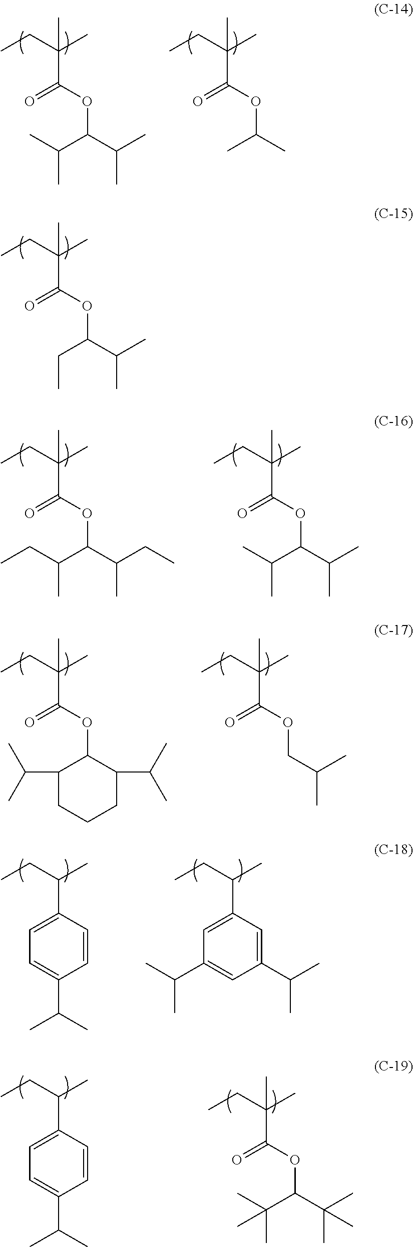

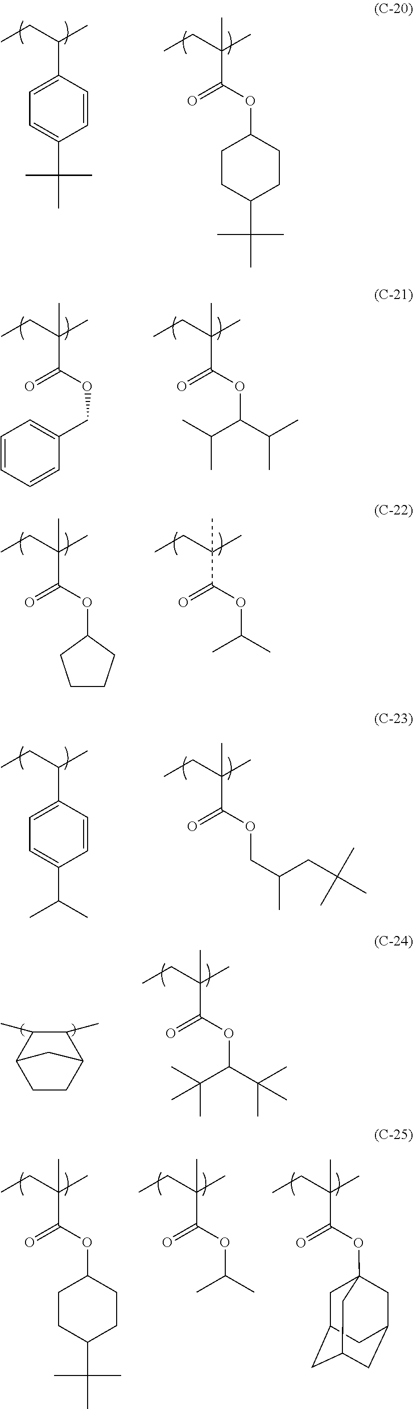

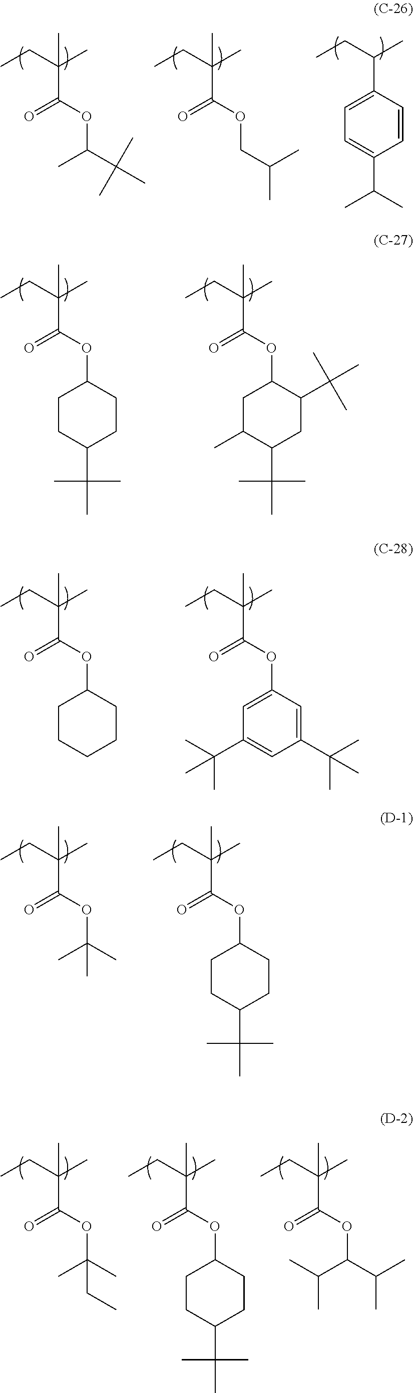

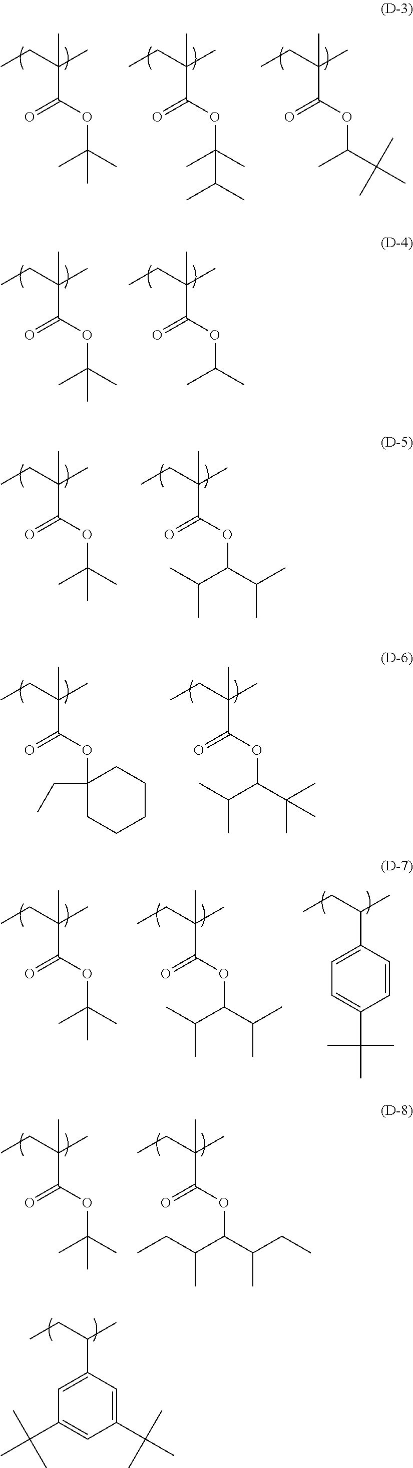

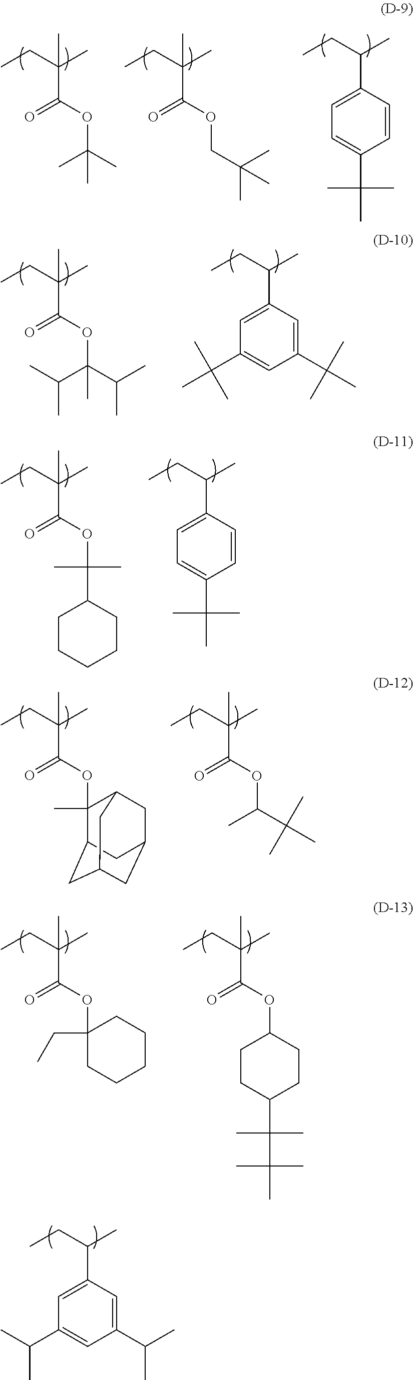

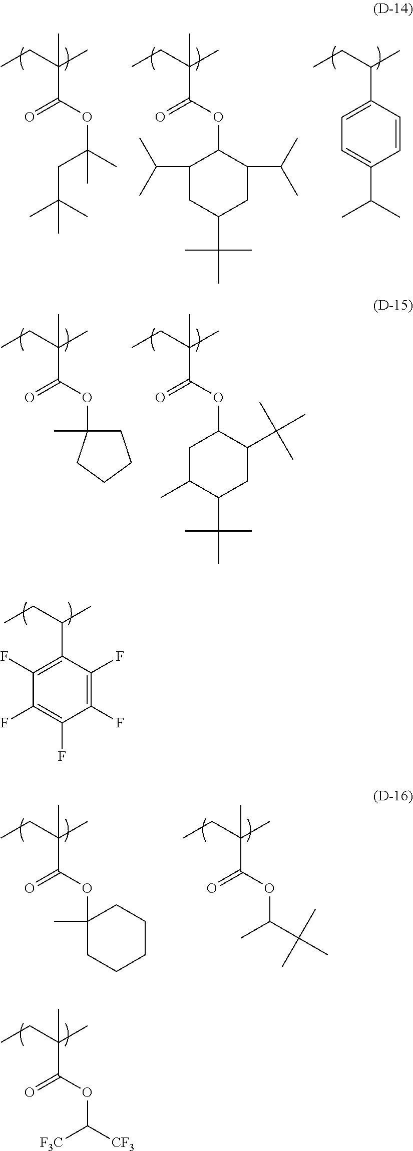

TABLE 3

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 4

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5] Basic Compound (N)

The actinic ray-sensitive or radiation-sensitive resin composition in the present invention may contain a basic compound (N) in order to reduce the change in performance over time from exposure to healing.

Preferred examples of the basic compound (N) may include the compound having a structure represented by the following Formulas (A′) to (E′).

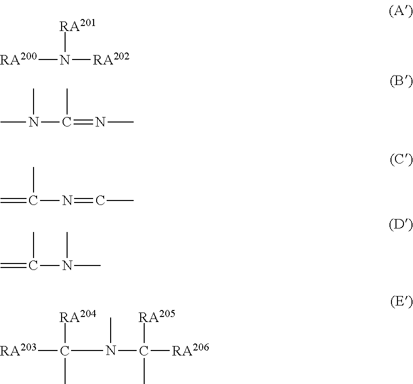

In Formulas (A′) to (E′).

Each of RA²⁰⁰, RA²⁰¹ and RA²⁰² may be same or different and represents a hydrogen atom, an alkyl group (preferably having 1 to 20 carbon atoms), a cycloalkyl group (preferably having 3 to 20 carbon atoms) or an aryl group (having 6 to 20 carbon), wherein RA²⁰¹ and RA²⁰² may combine to each other to form a ring. Each of RA²⁰³, RA²⁰⁴, RA²⁰⁵ and R²⁰⁶ may be same or different and represents an alkyl group (having preferably 1 to 20 carbon atoms).

The alkyl group may have a substituent. The alkyl group having a substituent is preferably an aminoalkyl group having 1 to 20 carbon atoms, a hydroxyalkyl group having 1 to 20 carbon atoms or a cyanoalkyl group having 1 to 20 carbon atoms.

The alkyl group in Formulas (A′) to (E′) is more preferably unsubstituted.

Preferred specific examples of the basic compound (N) may include guanidine, aminopyrrolidine, pyrazole, pyrazoline, piperazine, aminomorpholine, aminoalkylmorpholine, piperidine and the like, and more preferred examples of the compound include a compound having an imidazole structure, a diazabicyclo structure, an onium hydroxide structure, an onium carboxylate structure, a trialkylamine structure, an aniline structure or a pyridine structure, an alkylamine derivative having a hydroxyl group and/or an ether bond, an aniline derivative having a hydroxyl group and/or an ether bond and the like.

Examples of the compound having an imidazole structure may include imidazole, 2,4,5-triphenylimidazole, benzimidazole and the like. Examples of the compound having a diazabicyclo structure may include 1,4-diazabicyclo[2,2,2]octane, 1,5-diazabicyclo[4,3,0]non-5-ene, 1,8-diazabicyclo[5,4,0]undec-7-ene and the like. Examples of the compound having an onium hydroxide structure may include triarylsulfonium hydroxide, phenacylsulfonium hydroxide, a sulfonium hydroxide having a 2-oxoalkyl group, specifically, triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. Examples of the compound having an onium carboxylate structure may include a compound, in which the anion moiety of a compound having an onium hydroxide structure has been converted into carboxylate, such as acetate, adamantane-1-carboxylate, perfluoroalkylcarboxylate and the like. Examples of the compound having a trialkylamine structure may include tri(n-butyl)amine, tri(n-octyl)amine and the like. Examples of the compound having an aniline structure may include 2,6-diisopropylaniline, N,N-dimethylaniline, N,N-dibutylaniline, N,N-dihexylaniline and the like. Examples of the alkylamine derivative having a hydroxyl group and/or an ether bond may include ethanolamine, diethanolamine, triethanolamine, tris(methoxyethoxyethyl)amine and the like. Examples of the aniline derivative having a hydroxyl group and/or an ether bond may include N,N-bis(hydroxyethyl)aniline and the like.

Examples of the preferred basic compound may further include an amine compound having a phenoxy group, an ammonium salt compound having a phenoxy group, an amine compound having a sulfonic acid ester group, and an ammonium salt compound having a sulfonic acid ester group.

It is preferred that the amine compound having a phenoxy group, the ammonium salt compound having a phenoxy group, the amine compound having a sulfonic acid ester group, and the ammonium salt compound having a sulfonic acid ester group have at least one alkyl group bonded to a nitrogen atom. Further, it is preferred that the alkyl chain has an oxygen atom therein to form an oxyalkylene group. The number of the oxyalkylene groups is one or more, preferably 3 to 9, and more preferably 4 to 6, in the molecule. Among the oxyalkylene groups, the structures of —CH₂CH₂O—, —CH(CH₃)CH₂O— or —CH₂C H₂O— are preferred.

Specific examples of the amine compound having a phenoxy group, the ammonium salt compound having a phenoxy group, the amine compound having a sulfonic acid ester group, and the ammonium salt compound having a sulfonic acid ester group may include compounds (C1-1) to (C3-3) as exemplified is [0066] of U.S. Patent Application Publication No. 2007/0224539, but are not limited thereto.

Further, a nitrogen-containing organic compound having a group capable of leaving by the action of an acid may also be used as a kind of basic compound. Examples of the compound may include a compound represented by the following Formula (F). In addition, the compound represented by the following Formula (F) exhibits an effective basicity in the system as a result of elimination of the group capable of leaving by the action of an acid.

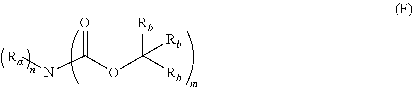

In Formula (F), each Rₐ independently represents a hydrogen atom, an alkyl group, a cycloalkyl group, an aryl group or an aralkyl group. Further, when n=2, each of two Ra's may be same or different, and two Ra's may combine with each other to form a divalent heterocyclic hydrocarbon group (preferably having 20 or less carbon atoms) or a derivative thereof.

Each R_{b} independently represents a hydrogen atom, an alkyl group, a cycloalkyl group, an aryl group or an aralkyl group. However, in —C(R_{b})(R_{b})(R_{b}), when one or more R_{b} are a hydrogen atom, at least one of the remaining R_{b} is a cyclopropyl group or a 1-alkoxy alkyl group.

At least two R_{b} may combine with each other to form an alicyclic hydrocarbon group, an aromatic hydrocarbon group, a heterocyclic hydrocarbon group or a derivative thereof. n represents an integer of 0 to 2, m represents an integer of 1 to 3, and n+m3.

Specific examples of the compound represented by Formula (F) are shown below.

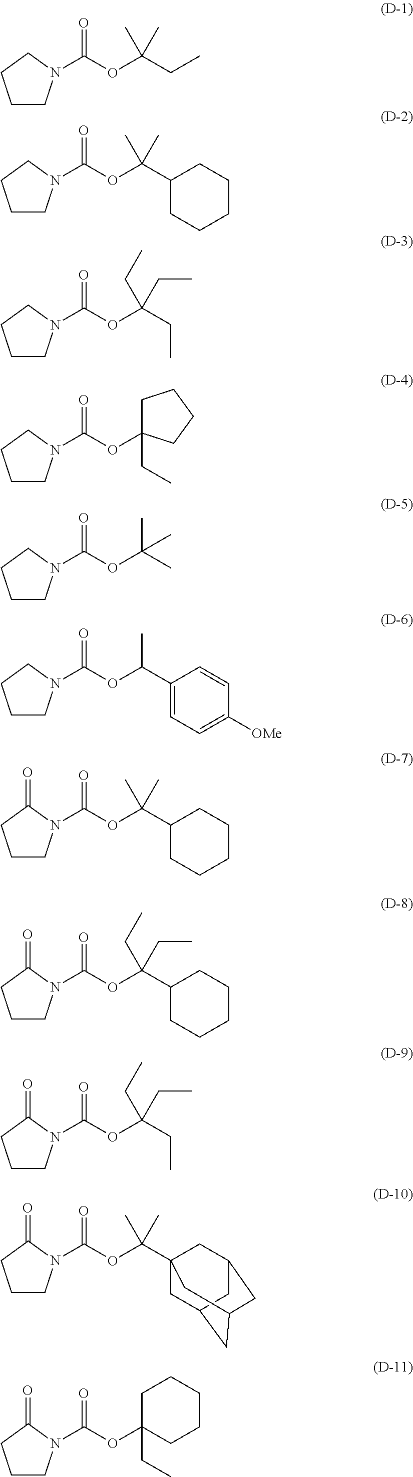

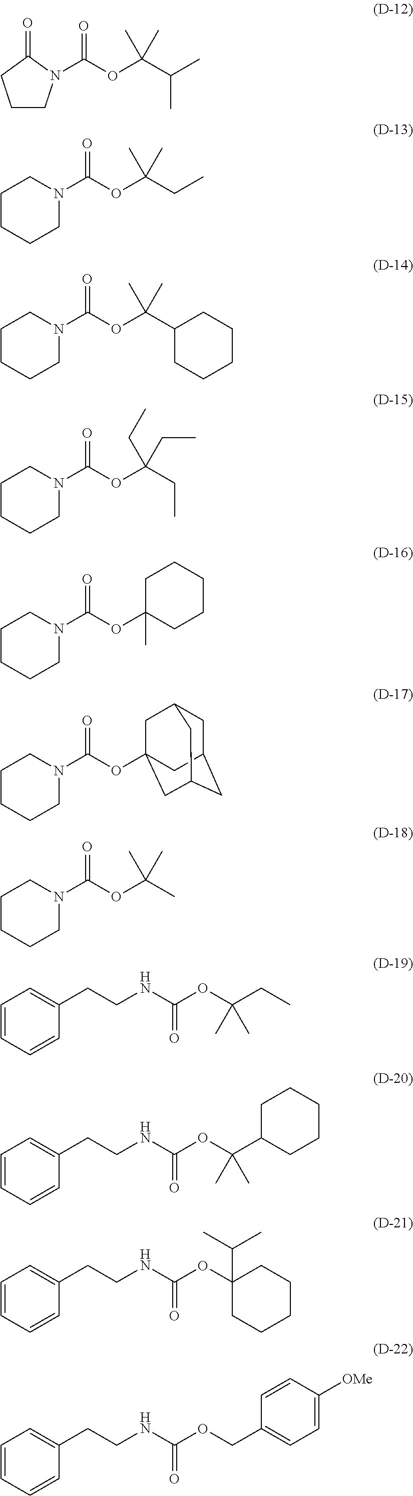

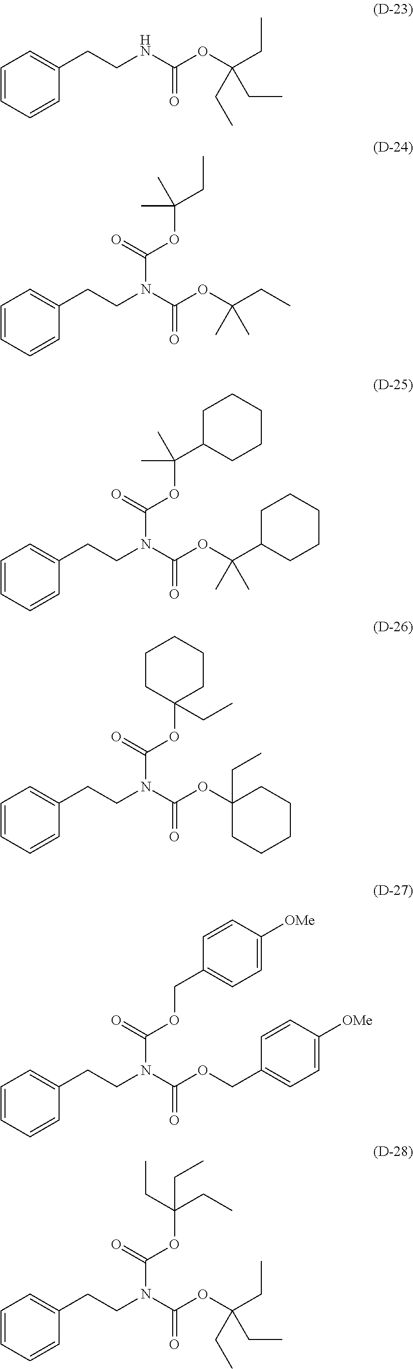

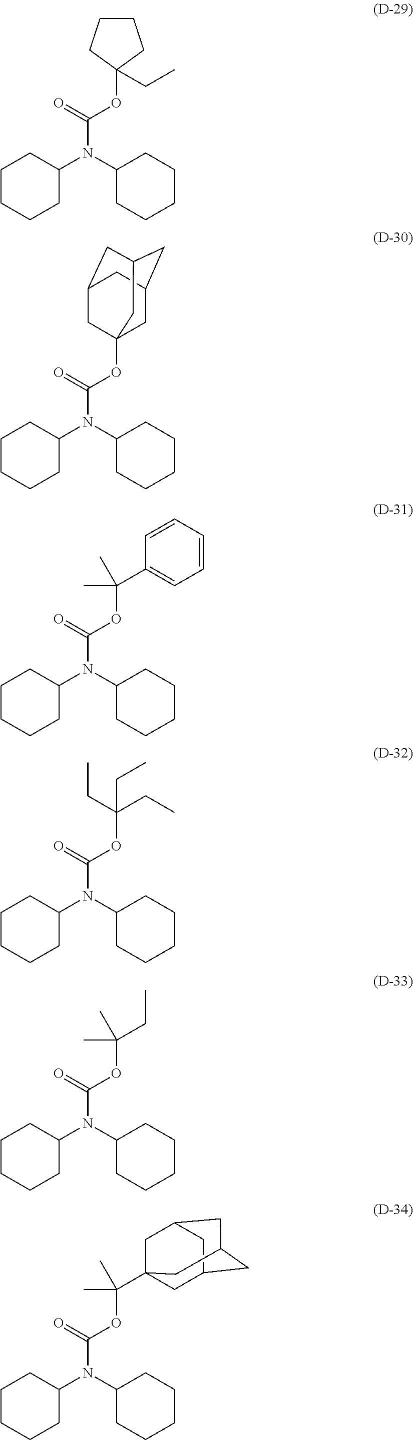

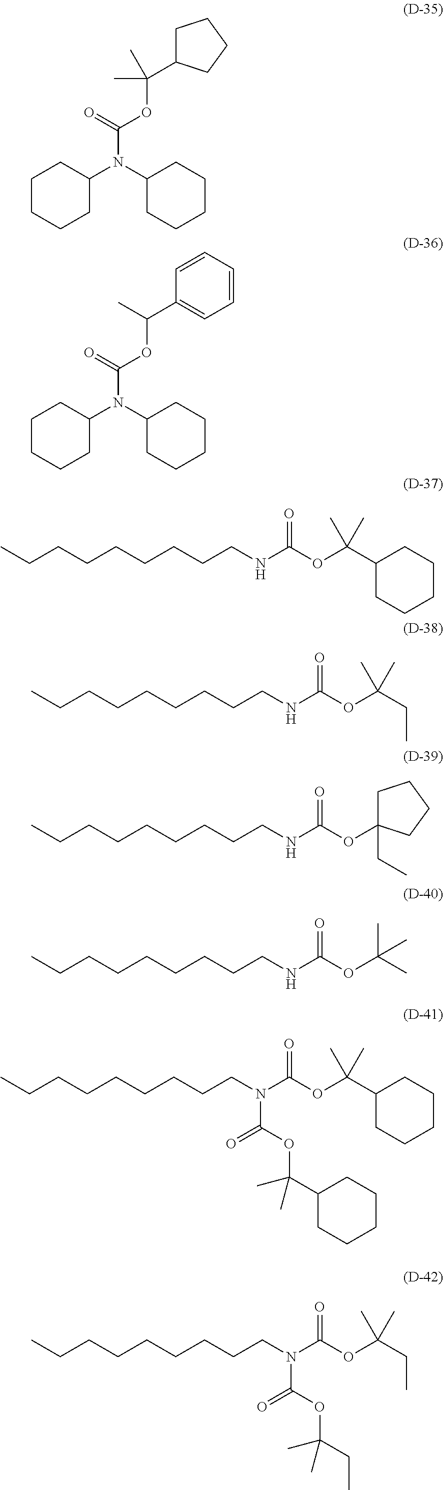

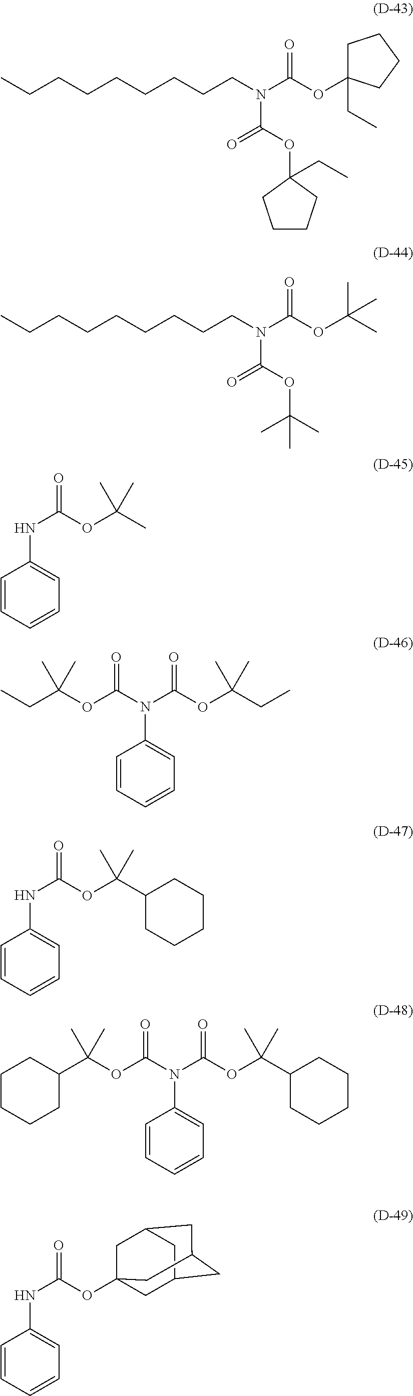

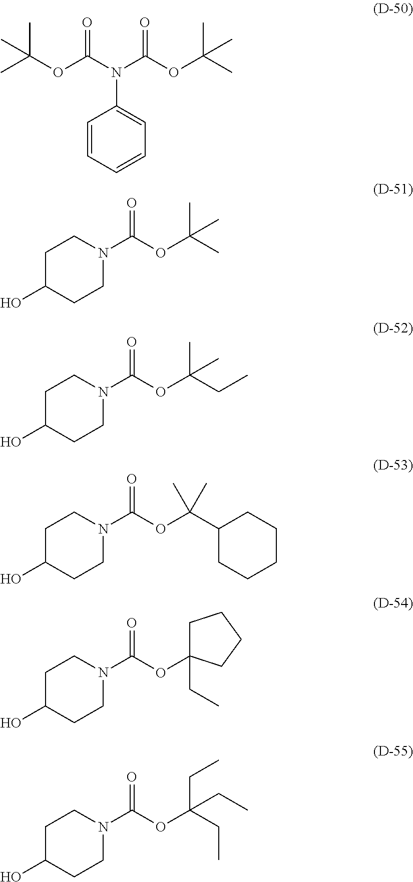

The compounds represented by Formula (F) may also be used as commercially available compounds and may be synthesized from commercially available amines in accordance with the methods as described in Protective Groups in Organic Synthesis, 4th edition and like. As a general method, for example, it is possible to be synthesized according to the method described in Japanese Patent Application Laid-Open No. 2009-199021.

The basic compound (N) can also be used as compounds having an amine oxide structure. Specific examples of this compound may include triethylamine pyridine N-oxide, tributylamine N-oxide, triethanolamine N-oxide, tris(methoxyethyl)amine N-oxide, tris(2-(methoxymethoxy)ethyl)amine=oxide, 2,2′,2″-nitrilotriacetic ethyl propionate N-oxide. N-2-(2-methoxyethoxy)methoxyethyl morpholine N-oxide, and further amine oxide compounds exemplified in Japanese Patent Application Laid-Open No. 2008-102383.

As the basic compound (N), a compound capable of decomposing upon irradiation with actinic ray or radiation to generate an acid anion having a basic structure in the molecule, such as the compound (A-1) to (A-44) described in U.S. Patent Application Publication No. 2010/0233629A and the compounds (A-1) to (A-23) described in U.S. Patent Application Publication No. 2012/0156617 can also be used. In these compounds, and particularly preferably used compounds are shown below.

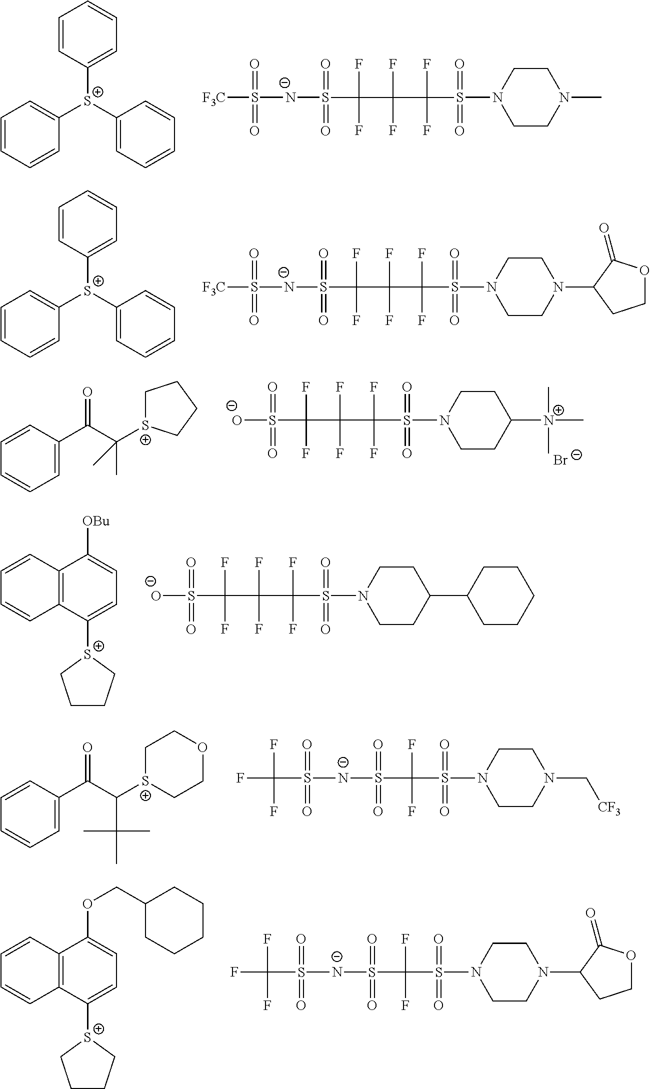

The compounds of the present invention may include an onium salt represented by the following Formula (6A) or (6B) as a basic compound. The onium salt is expected to control the diffusion of the generated acid in relation to the acid strength of the photo-acid generating agent commonly used in the resist composition.

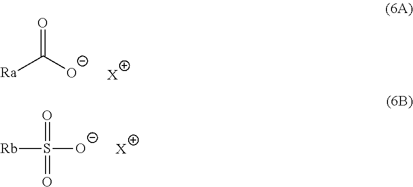

In Formula (6A),

Ra represents an organic group, but, the group in which a fluorine atom is substituted to the carbon atom directly bonded to the carboxylic acid group in the formula is excluded.

X⁺ represents an onium cation.

In Formula (6B),

Rb represents an organic group, but, the group in which fluorine atom is substituted to the carbon atom directly bonded to the sulfnic acid groups in the formula is excluded.

X⁺ represents an onium cation.

The organic groups represented by Ra and Rb are preferably those in which atoms directly bonded to a carboxylic acid group or a sulfonic acid group in the formula is a carbon atom. However, in this case, in order to make a relatively weaker acid than the acid generated from the abovementioned photoacid generator, a fluorine atom is not be substituted on the carbon atom bonded directly to a sulfonic acid group or a carboxylic acid group.

Examples of the organic group represented by Ra and Rb may include an alkyl group having 1 to 20 carbon atoms, a cycloalkyl group having 3 to 20 carbon atoms, an aryl group having 6 to 30 carbon atoms, an aralkyl group having 7 to 30 carbon atoms or a heterocyclic group having a carbon number of 3 to 30, and the like. In these groups, some or all of hydrogen atoms may be substituted.

The substituent which the alkyl group, the cycloalkyl group, the aryl group, the aralkyl group and the heterocyclic group may have include, for example, a hydroxyl group, a halogen atom, an alkoxy group, a lactone group, an alkylcarbonyl group and the like.

Examples of the onium cation represented by X⁺ in Formulas (6A) and (6B) may include a sulfonium cation, an ammonium cation, an iodonium cation, a phosphonium cation, a diazonium cation and the like. Among them, a sulfonium cation is more preferred.

Examples of the sulfonium cation may include preferably an aryl sulfonium cation having at least one aryl group, and more preferably a triaryl sulfonium cation. The aryl group may have a substituent. The aryl group is preferably a phenyl group.

Examples of the sulfonium cation and iodonium cation may include preferably a sulfonium cation structure site in the compounds (ZI-1), (ZI-2), (ZI-3) and (ZI-4) as the above-described compound (B).

The specific structure of the onium salt represented by Formula (6A) or (6B) is shown below.

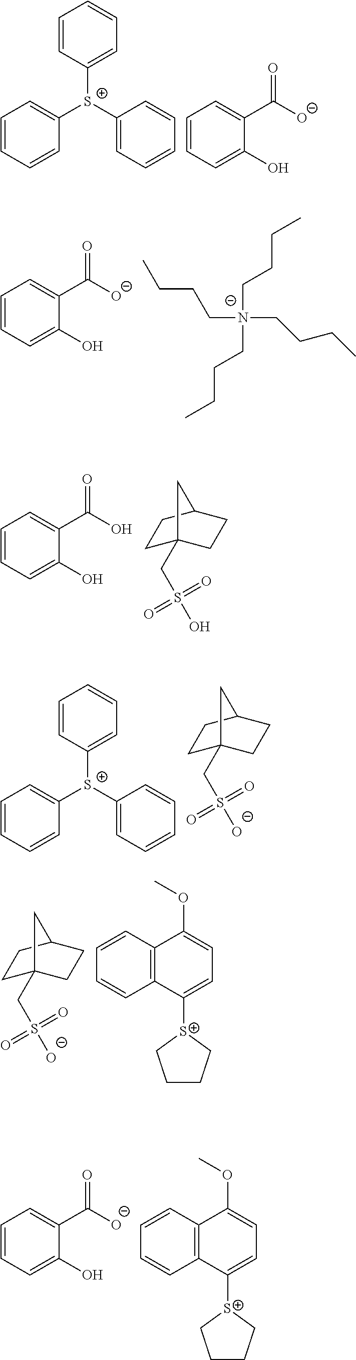

In addition, the chemically amplified resist composition of the present invention may also preferably use a compound having both an onium salt structure and an acid anion structure in one molecule (hereinafter, referred to as betaine compound), such as compounds included in Formula (I) of Japanese Patent Laid-open No. 2012-189977, compounds represented by Formula (I) of Japanese Patent Laid-open No. 2013-6827, compounds represented by Formula (I) of Japanese Patent Laid-open No. 2013-8020, and compounds represented by Formula (I) of Japanese Patent Laid-open No. 2012-252124. The onium salt structure includes sulfonium, iodonium, or ammonium structures, and preferably a sulfonium or iodonium salt structure. Further, the acid anion structure is preferably a sulfonate anion or a carboxylate anion. Example of the compounds may be exemplified below.

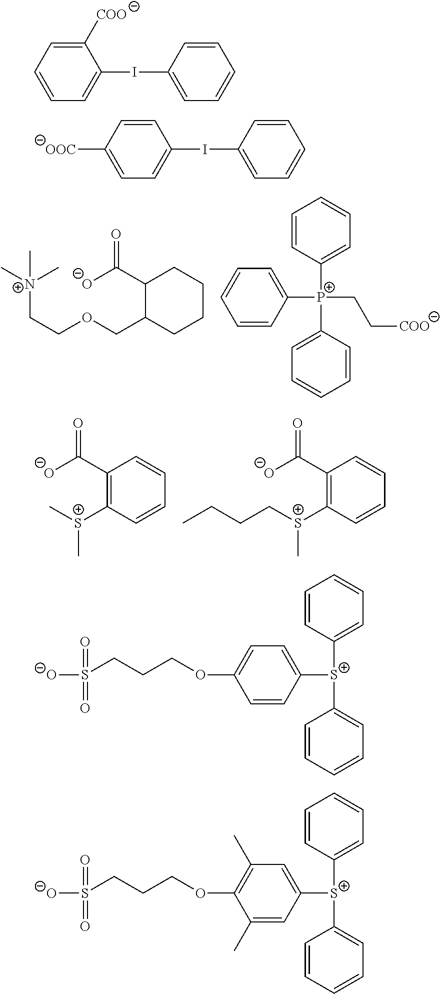

The molecular weight of the basic compound (N) is preferably 250 to 2,000, and more preferably 400 to 1,000. From the viewpoint of more reduction in LWR and uniformity of local pattern dimension, the molecular weight of the basic compound is preferably 400 or more, more preferably 500 or more, and still more preferably 600 or more.

The basic compound (N) may be used either alone or in combination of two or more thereof.

The actinic ray-sensitive or radiation-sensitive resin composition in the present invention may or may not contain a basic compound (N). However, in the case of containing the basic compound (N), the amount of the basic compound used is usually 0.001% by mass to 10% by mass, and preferably 0.01% by mass to 5% by mass, based on the total solid content of the actinic ray-sensitive or radiation-sensitive resin composition.

[7] Surfactant (F)

The actinic ray-sensitive or radiation-sensitive resin composition in the present invention may or may not contain a surfactant, but when the composition contains a surfactant, it is more preferred that the composition contains any one of fluorine and/or silicone-based surfactants (a fluorine-based surfactant, a silicone-based surfactant and a surfactant having both a fluorine atom and a silicon atom), or two or more thereof.

The actinic ray-sensitive or radiation-sensitive resin composition in the present invention contains a surfactant, thereby imparting a resist pattern with adhesion and reduced development defects due to improved sensitivity and resolution when using an exposure light source with a wavelength of 250 nm or less, particularly 220 nm or less.

Examples of the fluorine-based and/or silicone-based surfactants may include surfactants described in [0276] of U.S. Patent Application Publication No. 2008/0248425, such as F-Top EF301 and EF303 (manufactured by Shin-Akita Chemical Co., Ltd.), Fluorad FC430, 431 and 4430 (manufactured by Sumitomo-3M Co., Ltd.), Megafac F171, F173, F176, F189, P113, F110, F177, F120 and R08 (manufactured by DIC Corporation). Surflon S-382. SC101, 102, 103, 104, 105 and 106 and KH-20 (manufactured by Asahi Glass Co., Ltd.), Troysol S-366 (manufactured by Troy Chemical Corp.), GF-300 and GF-150 (manufactured by TOAGOSEI Chemical Industry Co., Ltd.), Surflon S-393 (manufactured by Seimi Chemical Co., Ltd.), F-Top EF121, EF122A, EF122B, RF122C, EF125M, EF135M, EF351, EF352, EF801, EF802 and EF601 (manufactured by JEMCO Inc.), PF636, PF656, PF6320 and PF6520 (manufactured by OMNOVA Solutions, Inc.), FTX-204G, 208G, 218G, 230G, 204D, 208D, 212D, 218D and 222D (manufactured by NEOS Corporation) and the like. In addition, polysiloxane polymer KP-341 (manufactured by Shin-Etsu Chemical Co., Ltd.) may also be used as the silicone-based surfactant.

Furthermore, in addition to those publicly known surfactants described above, it is possible to use a surfactant using a polymer having a fluoro-aliphatic group derived from a fluoro-aliphatic compound which is prepared by a telomerization method (also referred to as a telomer method) or an oligomerization method (also referred to as an oligomer method) as the surfactant. The fluoro-aliphatic compound nay be synthesized by the method described in Japanese Patent Application Laid-Open No. 2002-90991.

Examples of a surfactant corresponding to the above-described surfactant may include Megafac F178, F-470, F-473, F-475, F-476 and F-472 (manufactured by DIC Corporation), a copolymer of an acrylate having a C₆Fi₃ group (or methacrylate) with a (poly(oxyalkylene))acrylate (or methacrylate), a copolymer of an acrylate having a C₃F₇ group (or methacrylate) with a (poly(oxyethylene))acrylate (or methacrylate) and a (poly(oxypropylene))acrylate (or methacrylate), and the like.

Further, in the present invention, it is also possible to use a surfactant other than the fluorine-based and/or silicone-based surfactant, described in [0280] of U.S. Patent Application Publication No. 2008/0248425.

These surfactants may be used either alone or in combination of several thereof.

When the actinic ray-sensitive or radiation-sensitive resin composition contains a surfactant, the amount of surfactant used is preferably 0.0001 to 2% by mass, and more preferably 0.0005 to 1% by mass, based on the total amount of the actinic ray-sensitive or radiation-sensitive resin composition (excluding the solvent).

Meanwhile, by adjusting the amount of surfactant added to 10 ppm or less based on the total amount of actinic ray-sensitive or radiation-sensitive resin composition (excluding the solvent), the surface uneven distribution of the hydrophobic rein is increased, and accordingly, the surface of the resist film may be made to be more hydrophobic, thereby enhancing the water follow-up property at the time of liquid immersion exposure.

[7] Other Addivitives (G)

The actinic ray-sensitive or radiation-sensitive resin composition in the present invention may or may not contain a carboxylic acid onium salt. Examples of the carboxylic acid onium salt may include those described in [0605] and [0606] of U.S. Patent Application Publication No. 2008/0187860.

These carboxylic acid onium salts may be synthesized by reacting sulfonium hydroxide, iodonium hydroxide, ammonium hydroxide and carboxylic acid with silver oxide in an appropriate solvent.

When the actinic ray-sensitive or radiation-sensitive resin composition contains a carboxylic acid onium salt, the content thereof is generally 0.1 to 20% by mass, preferably 0.5 to 10% by mass, and more preferably 1 to 7% by mass, based on the total solid content of the composition.

The actinic ray-sensitive or radiation-sensitive resin composition of the present invention may further contain an acid multiplication agent, a dye, a plasticizer, a photosensitizer, a light absorber, an alkali-soluble resin, a dissolution inhibitor, a compound for accelerating solubility in a developer (for example, a phenol compound having a molecular weight of 1,000 or less, or an alicyclic or aliphatic compound having a carboxyl group) and the like, if necessary.

The phenol compound having a molecular weight of 1,000 or less may be easily synthesized by a person skilled in the art by referring to the methods described in, for example, Japanese Patent Application Laid-Open No. H14-122938, Japanese Patent Application Laid-Open No. 142-28531, U.S. Pat. No. 4,916,210, European Patent No. 219294 and the like.

Specific examples of the alicyclic or aliphatic compound having a carboxyl group may include a carboxylic acid derivative having a steroid structure, such as cholic acid, deoxycholic acid and lithocholic acid, an adamantanecarboxylic acid derivative, adamantanedicarboxylic acid, cyclohexanecarboxylic acid, cyclohexanedicarboxylic acid and the like, but are not limited thereto.

From the viewpoint of enhancing the resolution, the actinic ray-sensitive or radiation-sensitive resin composition in the present invention is used preferably in a film thickness of 30 to 250 nm, and more preferably in a film thickness of 30 to 200 nm. Such a film thickness may be achieved by setting a solid concentration, in the composition to an appropriate range to have an appropriate viscosity, thereby enhancing coatability and film-formation property.

The solid content concentration of the actinic ray-sensitive or radiation-sensitive resin composition in the present invention is usually 1.0 to 10% by mass, preferably 2.0 to 5.7% by mass, and more preferably 2.0 to 5.3% by mass. By setting the solid content concentration to the above-described range, the resist solution may be uniformly applied on a substrate and a resist pattern having excellent line width roughness may be formed. The reason is not clear, but it is thought that by setting the solid content concentration to 10% by mass or less and preferably 5.7% by mass or less, aggregation of materials, particularly, a photo-acid generator, in the resist solution is suppressed, and as a result, a uniform resist film may be formed.

The solid content concentration is a weight percentage of the weight of other resist components excluding the solvent, based on the total weight of the actinic ray-sensitive or radiation-sensitive resin composition.

The actinic ray-sensitive or radiation-sensitive resin composition in the present invention is prepared by dissolving the aforementioned components in a predetermined organic solvent, preferably in the mixed solvent.

Furthermore, at the time of the preparation, it is preferred to perform a process of reducing metal impurities in the composition to ppb level by using an ion exchange membrane, a process of filtering the impurities such as various particles by using an appropriate filter, a process of deacration and the like. Details of these processes are described in Japanese Patent Laid-Open Nos. 2012-88574, 2010-189563, 2001-12529, 2001-350266, 2002-99076, 115-307263 and 2010-164980, International Publication WO2006/121162A, Japanese Patent laid-Open Nos. 2010-243866 and 2010-020297.

In particular, the filters that are suitable to use in the process of filtering are preferably those made of polytetrafluoroethylene, polyethylene, or nylon having pore size of 0.1 μm or less, more preferably 0.05 μm or less, and more preferably 0.03 μm or less.

In addition, the composition of the present invention has preferably a low water content ratio. Specifically, the water content ratio is preferably 2.5% by mass or less and more preferably 1.0% by mass or less, and still more preferably 0.3% by mass or less based on the total weight of the composition.

### EXAMPLES

### Synthesis Example

### Resin (A-1)

102.3 parts by mass of cyclohexanone was heated at 80° C. under nitrogen flow. While the liquid was stirred, a mixed solution of 22.2 parts by mass of a monomer represented by the following Formula M-1, 22.8 parts by mass of a monomer represented by the following Formula M-2, 6.6 parts by mass of a monomer represented by the following Formula M-3, 189.9 parts by mass of cyclohexanone, and 2.40 parts by mass of 2,2′-dimethyl azobisisobutyrate [V-601, manufactured by Wako Pure Chemical Industries, Ltd.] was added dropwise thereto over 5 hours. After the completion of the dropwise addition, the solution was further stirred at 80° C. for 2 hours. The reaction solution was allowed to cool, then subjected to reprecipitation with a large amount of hexane/ethyl acetate (mass ratio 9:1), and filtered to obtain a solid, and the solid was vacuum dried to obtain 41.1 parts by mass of Resin (A−1) of the present invention.

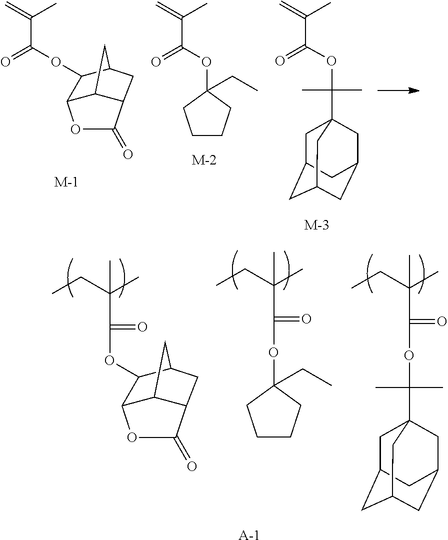

The weight average molecular weight (Mw; in terms of polystyrene) obtained from the GPC (carrier: tetrahydrofuran (THF)) of the obtained resin was Mw=9500 with a polydispersity Mw/Mn=1.60. The composition ratio measured by ¹³C-NMR was 40/50/10.

<Resin (A)>

Hereinafter, Resins (A-2) to (A-9) were synthesized in the same manner as above. The composition ratio (molar ratio; corresponding in order from the left) of the repeating unit, mass average molecular weight (Mw) and polydispersity (Mw/Mn) in the resins (A-2) to (A-9) including the resin (A-1) will be shown below.

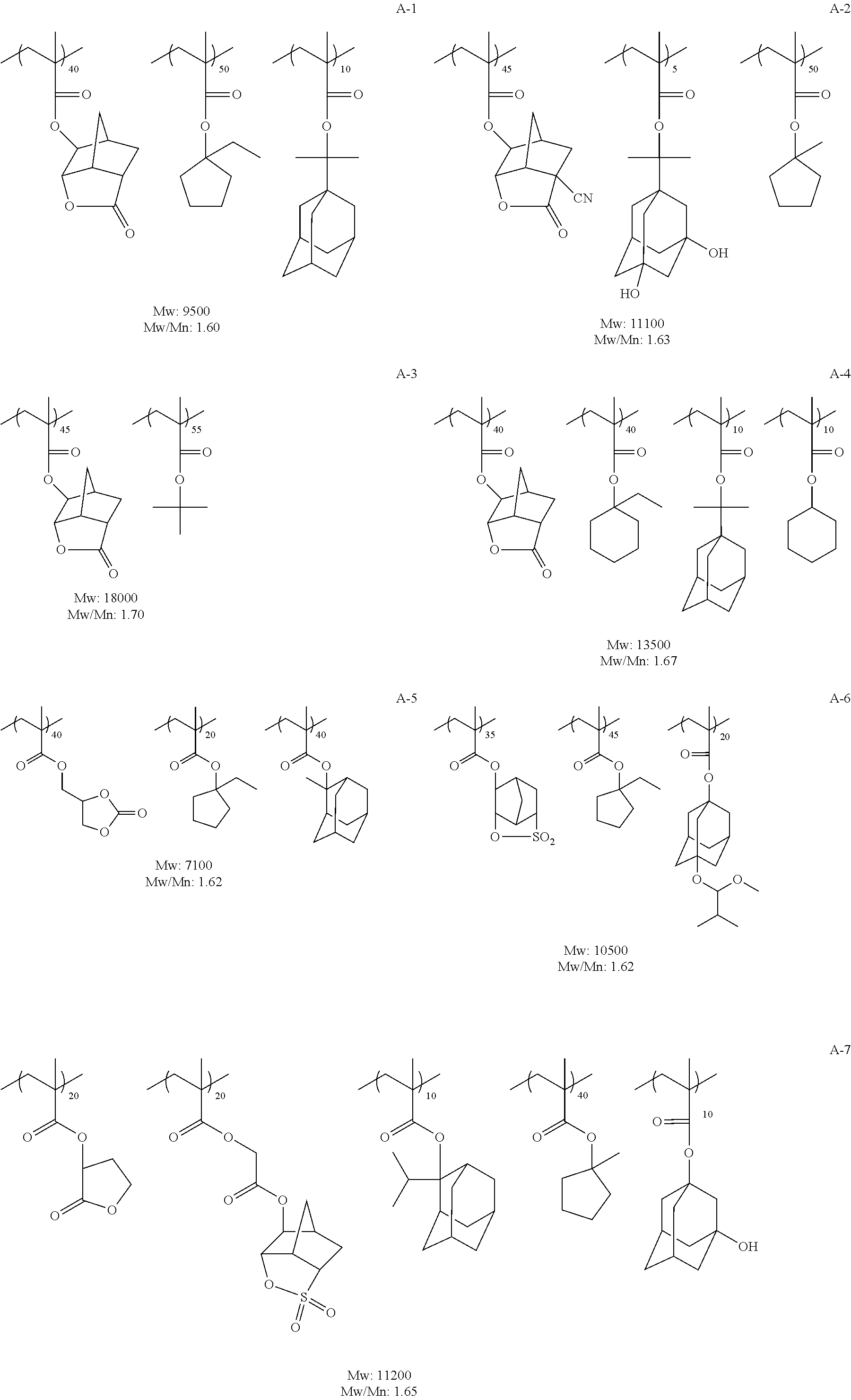

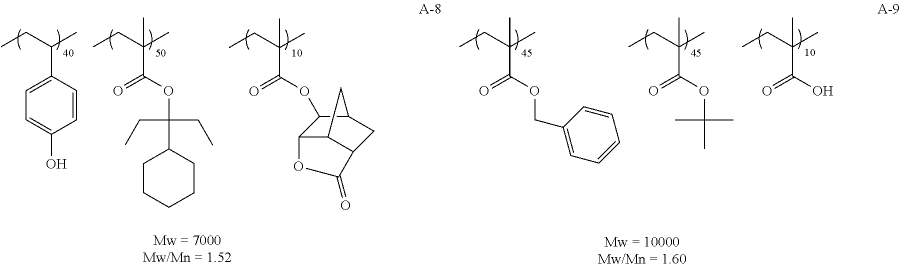

<Hydrophobic Resin>

Hereinafter, Resins (D-1) to (D-5) were synthesized in the same manner as above. The composition ratio (molar ratio; corresponding in order from the left) of the repeating unit, mass average molecular weight (Mw) and polydispersity (Mw/Mn) in the resins (D-1) to (D-5) will be shown below.

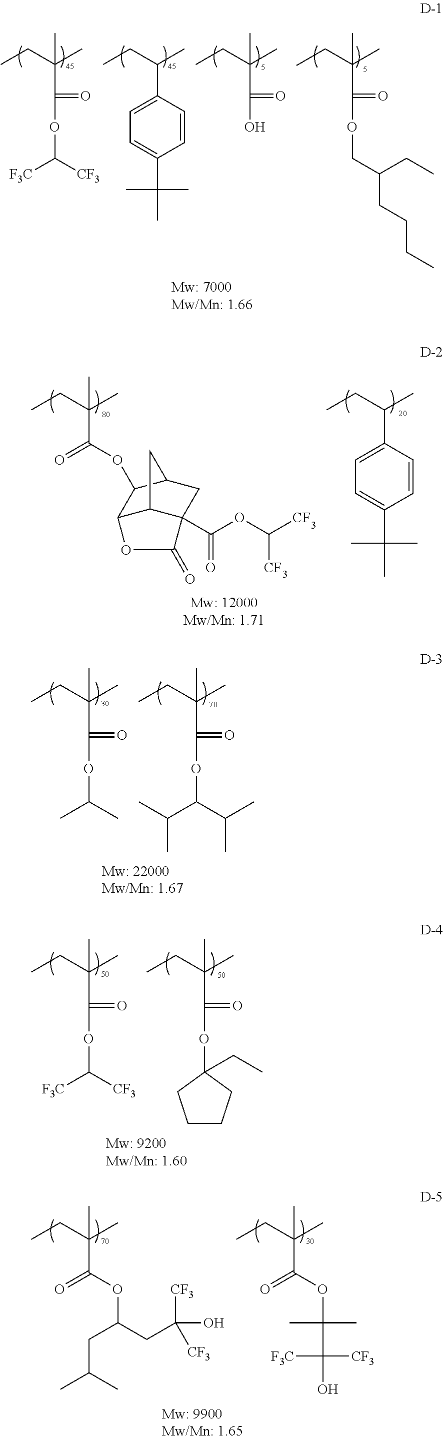

<Acid Generator>

The following compounds were used as the acid generator.

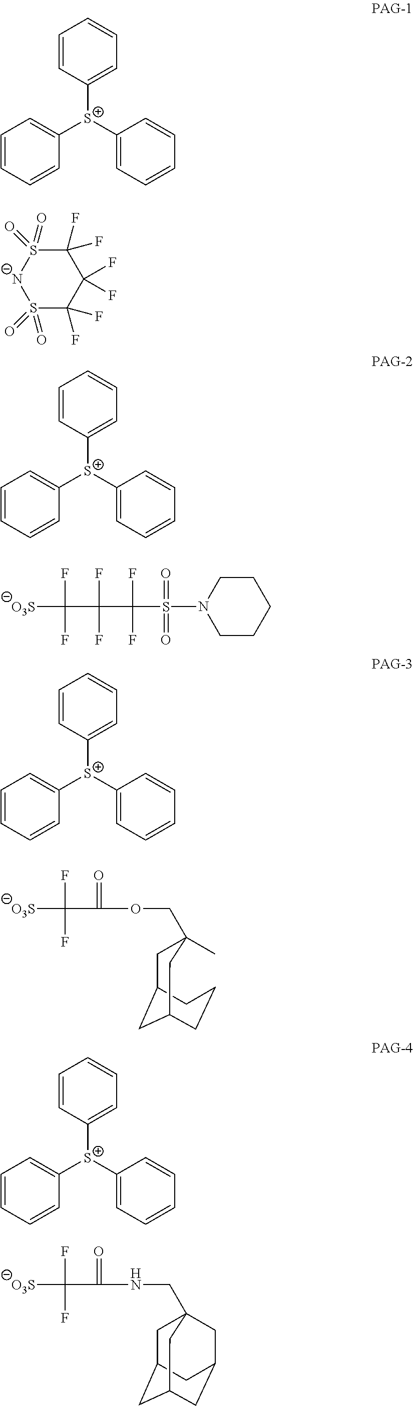

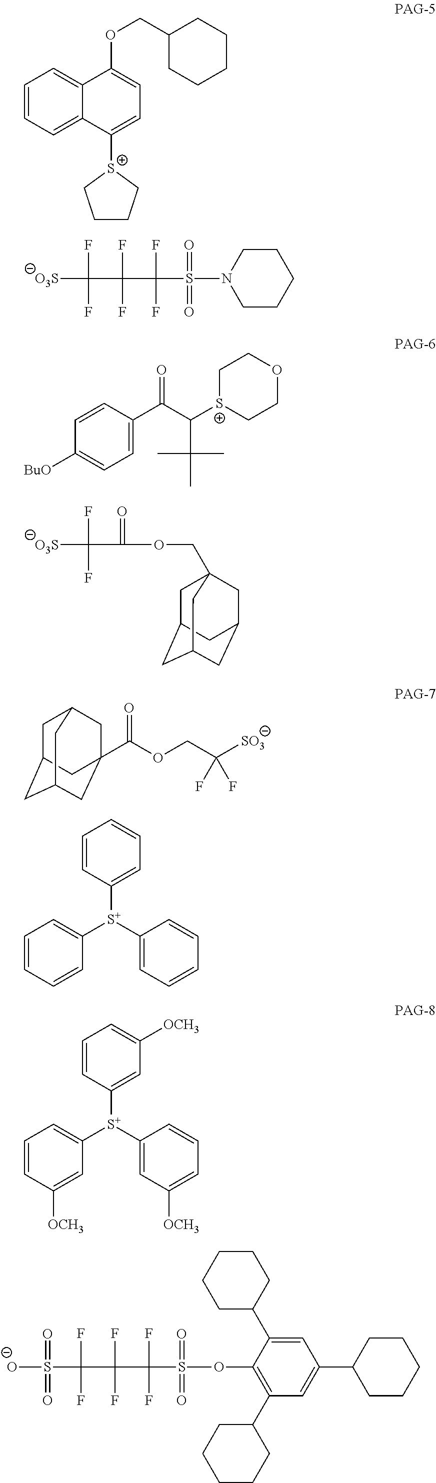

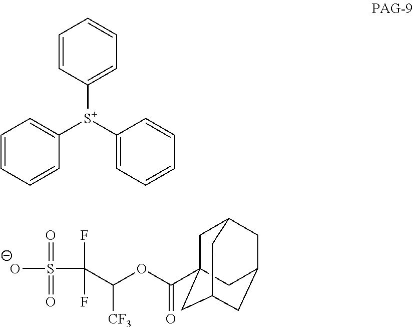 [SMILES: c1ccc([S+](c2ccccc2)c2ccccc2)cc1 ; O=C(OC(C(F)(F)F)C(F)(F)S(=O)(=O)[O-])C12CC3CC(CC(C3)C1)C2]

<Basic Compound (N)>

The following compounds were used as the basic compound.

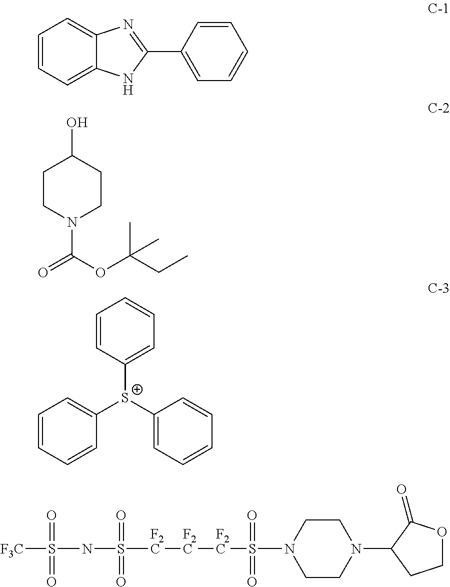

<Surfactant>

The followings were used as the surfactant.

W-1: Megafac F176 (manufactured by DIC Corporation; fluorine-based)

W-2: PolyFox PF-6320 (manufactured by OMNOVA Solutions Inc.; fluorine-based)

<Solvent (C1), Solvent (C2), Organic-Based Developer>

The followings were used as the solvent (C1), solvent (C2), organic-based developer.

SG-1: Propylene glycol monomethyl ether acetate

SG-2: Ethyl lactate

SG-3: Butyl acetate

SG-4: 2-Heptanone (methyl amyl ketone)

SG-5: Ethyl-3-ethoxy propionate

SG-6: Propylene glycol monomethyl ether

SG-7: Methyl 3-methoxy propionate

SG-8: Cyclohexanone

SG-9: Ethyl acetate

SG-10: Propyl acetate

SG-11: Isopropyl acetate

SG-12: Isobutyl acetate

SG-13: Pentyl acetate

SG-14: Isopentyl acetate

SG-15: Methyl 3-ethoxy propionate

SG-16: Propylene glycol monomethyl ether propionate

SG-17: γ-butyrolactone

SG-18: 3-Methoxy-1-butanol

<Rinse Liquid>

The followings were used as the rinse liquid.

SR-1: 4-methyl-2-pentanol

SR-2: 1-hexanol

### Examples 1 to 36 and Comparative Examples 1 to 10

### Formation and evaluation of the resist pattern

### Purification of resin

10 parts by mass of the resin (A) shown in Tables 6 and 7 which were obtained by the above synthesis examples, were dissolved in 90 parts by mass of the solvent (C1) shown in the same tables, filtered at a flow rate of 100 mL/min using a filter shown in the same tables. A large amount of hexane was added to the filtrate to thereby re-precipitate the resin. The solid obtained by filtration or evaporation of the solvent was vacuum dried to purify the resin (A).

Further, in Example 36, purification of the resin was performed twice by changing the type of filter.

(Preparation of Resist Composition)

The resin (A) purified as described above and the other components shown in Table 5 were dissolved in the solvent shown in the same table to have a total solid content of 3.5% by mass, and each was filtered through a polyethylene filter having a pore size of 0.03 μm to prepare an actinic ray-sensitive or radiation-sensitive resin composition (resist composition) (I-1) to (I-7) shown in each Examples and Comparative Examples.

(Formation of the Resist Film)

An organic antireflection film ARC29SR (manufactured by Nissan Chemical Industries, Ltd.) was applied on a silicon wafer and baked at 205° C. for 60 seconds to form an antireflection film having a film thickness of 95 nm. The actinic ray-sensitive or radiation-sensitive resin composition (I-1) to (I-7) was applied thereon and baked (PB: prebake) at 100° C. over 60 seconds to form a resist film having a film thickness of 80 nm.

(Formation of Resist Pattern)

The obtained wafer was subjected to pattern exposure by using an ArF excimer laser liquid immersion scanner (manufactured by ASML Co., Ltd.; XT1700i, NA 1.20, C-Quad, outer sigma 0.950, inner sigma 0.800, XY deflection) through a halftone mask of line-and-space pattern having a pitch of 100 am and a mask size of 50 nm. As the liquid for liquid immersion, ultrapure water was used. Thereafter, heating (PER: Post Exposure Bake) was performed at 100° C. for 60 seconds. The water was then developed by performing paddling using the developer described in Tables 6 and 7 for 30 seconds (with respect to Examples in which the rinse liquid is described in Tables 6 and 7, rinsed by performing paddling using this rinse liquid for 30 seconds) to obtaine a 1:1 line-and-space pattern with a line width of 50 nm.

(Evaluation of Resist Pattern)

For the resulting respective patterns, the defect distribution on the wafer was detected with UVision3+(manufactured by AMAT) and the shape of the defects was observed using SEMVisionG4 (manufactured by AMAT). FIG. 1 is a diagram showing an example of a SEM image of the residue defects.

By counting the number of residue defects as shown in FIG. 1 in the wafer with 300 mm diameter (12 inches diameter), the residue defects were evaluated.

TABLE 5

| | | | | | Basic | | | | | | | |
|---|---|---|---|---|---|---|---|---|---|---|---|---|
| | Resin | | Acid generator | | compound | | Resin | | | | Solvent | Mass |
| Composition | (A) | (g) | (B) | (g) | (N) | (g) | (D) | (g) | Surfactant | (g) | (C2) | ratio |
| I-1 | A-1 | 10 | PAG-1 | 0.80 | C-2 | 0.17 | D-5 | 0.14 | W-1 | 0.003 | SG-1 | 100 |
| I-2 | A-2 | 10 | PAG-2/PAG-5 | 0.30/1.00 | C-1 | 0.14 | D-2 | 0.20 | none | — | SG-16 | 100 |
| I-3 | A-3 | 10 | PAG-3 | 0.85 | C-2 | 0.14 | D-3 | 0.20 | W-2 | 0.003 | SG-1/SG-8 | 80/20 |
| I-4 | A-4 | 10 | PAG-7/PAG-6 | 0.25/1.00 | C-3 | 0.45 | D-3/D-4 | 0.10/0.30 | none | — | SG-1/SG-6 | 90/10 |
| I-5 | A-5 | 10 | PAG-7 | 0.88 | C-1/C-3 | 0.06/0.25 | D-4 | 0.10 | W-1 | 0.003 | SG-2 | 100 |
| I-6 | A-6 | 10 | PAG-4 | 1.20 | C-1 | 0.16 | D-4 | 0.15 | W-1 | 0.003 | SG-1 | 100 |
| I-7 | A-7 | 10 | PAG-3 | 0.78 | C-2 | 0.17 | D-1 | 0.06 | none | — | SG-1/SG-8/SG-17 | 85/10/5 |

TABLE 6

| | | | Process (1) | | | Process (2) | | Process (6) | |
|---|---|---|---|---|---|---|---|---|---|
| | Composition | Resin | | SP value | | Solvent (C2) | SP value | | SP value |
| | Structure (1) | (A) | Solvent (C1) | (cal/cm³)^{1/2} | Filter | (molar ratio) | (cal/cm³)^{1/2} | Developer | (cal/cm³)^{1/2} |
| Ex. 1 | I-1 | A-1 | SG-3 | 8.73 | Nylon 40 nm/Ion clean AN | SG-1 | 9.21 | SG-3 | 8.73 |
| Ex. 2 | I-1 | A-1 | SG-11 | 8.74 | Nylon 40 nm/Ion clean SL | SG-1 | 9.21 | SG-3 | 8.73 |
| Ex. 3 | I-1 | A-1 | SG-7 | 9.46 | Nylon 40 nm | SG-1 | 9.21 | SG-3 | 8.73 |
| Ex. 4 | I-1 | A-1 | SG-4 | 8.77 | Nylon 40 nm | SG-1 | 9.21 | SG-4 | 8.77 |
| Ex. 5 | I-1 | A-1 | SG-5 | 9.14 | Nylon 40 nm | SG-1 | 9.21 | SG-5 | 9.14 |
| C. Ex. 1 | I-1 | A-1 | none | — | none | SG-1 | 9.21 | SG-3 | 8.73 |
| Ex. 6 | I-2 | A-2 | SG-3 | 8.73 | PE 50 nm | SG-16 | 9.08 | SG-3 | 8.73 |
| Ex. 7 | I-2 | A-2 | SG-14 | 8.58 | Nylon 20 nm | SG-16 | 9.08 | SG-3 | 8.73 |
| Ex. 8 | I-2 | A-2 | SG-7 | 9.46 | PE 50 nm | SG-16 | 9.08 | SG-3 | 8.73 |
| Ex. 9 | I-2 | A-2 | SG-12 | 8.65 | PE 10 nm | SG-16 | 9.08 | SG-4 | 8.77 |
| Ex. 10 | I-2 | A-2 | SG-3 | 8.73 | Nylon 40 nm/PE 10 nm | SG-16 | 9.08 | SG-5 | 9.14 |
| C. Ex. 2 | I-2 | A-2 | SG-16 | 9.08 | PE 50 nm | SG-16 | 9.08 | SG-3 | 8.73 |
| Ex. 11 | I-3 | A-3 | SG-8 | 10.01 | PE 50 nm | SG-1/SG-8 (80/20) | 9.37 | SG-5 | 9.14 |
| Ex. 12 | I-3 | A-3 | SG-9 | 8.98 | PE 10 nm | SG-1/SG-8 (80/20) | 9.37 | SG-3 | 8.73 |
| Ex. 13 | I-3 | A-3 | SG-10 | 8.84 | Nylon 40 nm/PE 10 nm | SG-1/SG-8 (80/20) | 9.37 | SG-3 | 8.73 |
| Ex. 14 | I-3 | A-3 | SG-15 | 9.28 | Nylon 40 nm/Ion clean AN | SG-1/SG-8 (80/20) | 9.37 | SG-3 | 8.73 |
| Ex. 15 | I-3 | A-3 | SG-5 | 9.14 | Nylon 40 nm/Ion clean SL | SG-1/SG-8 (80/20) | 9.37 | SG-4 | 8.77 |
| C. Ex. 3 | I-3 | A-3 | SG-8 | 10.01 | Nylon 20 nm | SG-1/SG-8 (80/20) | 9.37 | SG-4 | 8.77 |
| Ex. 16 | I-4 | A-4 | SG-13 | 8.65 | Nylon 40 nm/PE 10 nm | SG-1/SG-6 (90/10) | 9.44 | SG-3 | 8.73 |
| Ex. 17 | I-4 | A-4 | SG-15 | 9.28 | Nylon 40 nm/Ion clean AN | SG-1/SG-6 (90/10) | 9.44 | SG-3 | 8.73 |
| Ex. 18 | I-4 | A-4 | SG-9 | 8.98 | Nylon 40 nm/Ion clean SL | SG-1/SG-6 (90/10) | 9.44 | SG-3 | 8.73 |
| Ex. 19 | I-4 | A-4 | SG-4 | 8.77 | Nylon 20 nm | SG-1/SG-6 (90/10) | 9.44 | SG-3 | 8.73 |
| Ex. 20 | I-4 | A-4 | SG-5 | 9.14 | PE 50 nm | SG-1/SG-6 (90/10) | 9.44 | SG-3 | 8.73 |
| C. Ex. 4 | I-4 | A-4 | none | — | none | SG-1/SG-6 (90/10) | 9.44 | SG-3 | 8.73 |

| | \|SP_{C1} − SP_{C2}\| | \|SP_{C1} − SP_{DEV}\| | | Residue defect |
|---|---|---|---|---|
| | (cal/cm³)^{1/2} | (cal/cm³)^{1/2} | Rinse liquid | (number) |
| Ex. 1 | 0.47 | 0.00 | — | 2 |
| Ex. 2 | 0.47 | 0.01 | — | 6 |
| Ex. 3 | 0.25 | 0.72 | — | 26 |
| Ex. 4 | 0.44 | 0.00 | — | 16 |
| Ex. 5 | 0.06 | 0.00 | — | 3 |
| C. Ex. 1 | * | * | — | 182 |
| Ex. 6 | 0.34 | 0.00 | — | 1 |
| Ex. 7 | 0.50 | 0.16 | — | 7 |
| Ex. 8 | 0.38 | 0.72 | — | 47 |
| Ex. 9 | 0.43 | 0.12 | — | 6 |
| Ex. 10 | 0.34 | 0.41 | — | 9 |
| C. Ex. 2 | 0.00 | 0.34 | — | 69 |
| Ex. 11 | 0.64 | 0.87 | — | 45 |
| Ex. 12 | 0.39 | 0.24 | SR-1 | 23 |
| Ex. 13 | 0.53 | 0.10 | — | 16 |
| Ex. 14 | 0.09 | 0.55 | SR-2 | 38 |
| Ex. 15 | 0.22 | 0.38 | — | 33 |
| C. Ex. 3 | 0.64 | 1.24 | — | 98 |
| Ex. 16 | 0.79 | 0.08 | — | 6 |
| Ex. 17 | 0.16 | 0.55 | — | 31 |
| Ex. 18 | 0.46 | 0.24 | — | 12 |
| Ex. 19 | 0.67 | 0.03 | — | 15 |
| Ex. 20 | 0.30 | 0.41 | — | 36 |
| C. Ex. 4 | * | * | — | 153 |

TABLE 7

| | | | | | | | | Process (6) | |
|---|---|---|---|---|---|---|---|---|---|
| | | | Process (1) | | | Process (2) | | | SP value |
| | Composition | Resin | Solvent | SP value | | Solvent (C2) | SP value | | (cal/ |
| | Structure (1) | (A) | (C1) | (cal/cm³)^{1/2} | Filter | (molar ratio) | (cal/cm³)^{1/2} | Developer | cm³)^{1/2} |
| Ex. 21 | I-5 | A-5 | SG-5 | 9.14 | Nylon 20 nm | SG-2 | 12.13 | SG-3 | 8.73 |
| Ex. 22 | I-5 | A-5 | SG-3 | 8.73 | Nylon 40 nm | SG-2 | 12.13 | SG-3 | 8.73 |
| Ex. 23 | I-5 | A-5 | SG-1 | 9.21 | PE 50 nm | SG-2 | 12.13 | SG-3 | 8.73 |
| Ex. 24 | I-5 | A-5 | SG-16 | 9.08 | Nylon 40 nm/Ion clean SL | SG-2 | 12.13 | SG-3 | 8.73 |
| Ex. 25 | I-5 | A-5 | SG-5 | 9.14 | Nylon 40 nm | SG-2 | 12.13 | SG-3 | 9.14 |
| C. Ex. 5 | I-5 | A-5 | SG-2 | 12.13 | PE 50 nm | SG-2 | 12.13 | SG-3 | 8.73 |
| Ex. 26 | I-6 | A-6 | SG-10 | 8.84 | PE 10 nm | SG-2 | 9.21 | SG-3 | 8.73 |
| Ex. 27 | I-6 | A-6 | SG-11 | 8.74 | Nylon 40 nm/Ion clean AN | SG-1 | 9.21 | SG-3 | 8.73 |
| Ex. 28 | I-6 | A-6 | SG-3 | 8.73 | PE 50 nm | SG-1 | 9.21 | SG-3 | 8.73 |
| Ex. 29 | I-6 | A-6 | SG-14 | 8.58 | Nylon 40 nm/Ion clean SL | SG-1 | 9.21 | SG-3 | 8.73 |
| Ex. 30 | I-6 | A-6 | SG-16 | 9.08 | Nylon 20 nm | SG-1 | 9.21 | SG-3 | 8.73 |
| C. Ex. 6 | I-6 | A-6 | SG-1 | 9.21 | PE 50 nm | SG-1 | 9.21 | SG-3 | 8.73 |
| C. Ex. 7 | I-6 | A-6 | SG-6 | 11.52 | PE 50 nm | SG-1 | 9.21 | SG-3 | 8.73 |
| C. Ex. 8 | I-6 | A-6 | SG-8 | 10.01 | Nylon 40 nm | SG-1 | 9.21 | SG-3 | 8.73 |
| C. Ex. 9 | I-6 | A-6 | SG-18 | 11.00 | Nylon 20 nm | SG-1 | 9.21 | SG-5 | 9.14 |
| Ex. 31 | I-7 | A-7 | SG-3 | 8.73 | Nylon 40 nm/Ion clean AN | SG-1/SG-8/SG-17 (85/10/5) | 9.33 | SG-3 | 8.73 |
| Ex. 32 | I-7 | A-7 | SG-4 | 8.77 | Nylon 20 nm | SG-1/SG-8/SG-17 (85/10/5) | 9.33 | SG-4 | 8.77 |
| Ex. 33 | I-7 | A-7 | SG-5 | 9.14 | PE 50 nm | SG-1/SG-8/SG-17 (85/10/5) | 9.33 | SG-3 | 8.73 |
| Ex. 34 | I-7 | A-7 | SG-12 | 8.65 | Nylon 40 nm/Ion clean SL | SG-1/SG-8/SG-17 (85/10/5) | 9.33 | SG-3 | 8.73 |
| Ex. 35 | I-7 | A-7 | SG-9 | 8.98 | Nylon 40 nm/PE 10 nm | SG-1/SG-8/SG-17 (85/10/5) | 9.33 | SG-3 | 8.73 |
| Ex. 36 | I-7 | A-7 | SG-5 | 9.14 | PE 50 nm | SG-1/SG-8/SG-17 (85/10/5) | 9.33 | SG-3 | 8.73 |
| | | | SG-3 | 8.73 | Nylon 40 nm/Ion clean AN | | | | |
| C. Ex. | I-7 | A-7 | none | — | none | SG-1/SG-8/SG-17 (85/10/5) | 9.33 | SG-3 | 8.73 |
| 10 | | | | | | | | | |

| | \|SP_{C1} − SP_{C2}\| | \|SP_{C1} − SP_{DEV}\| | | Residue defect |
|---|---|---|---|---|
| | (cal/cm³)^{1/2} | (cal/cm³)^{1/2} | Rinse liquid | (number) |
| Ex. 21 | 2.99 | 0.41 | — | 8 |
| Ex. 22 | 3.40 | 0.00 | — | 2 |
| Ex. 23 | 2.92 | 0.47 | — | 9 |
| Ex. 24 | 3.05 | 0.34 | — | 12 |
| Ex. 25 | 2.99 | 0.00 | SR-1 | 4 |
| C. Ex. 5 | 0.00 | 3.40 | — | 159 |
| Ex. 26 | 0.37 | 0.10 | — | 17 |
| Ex. 27 | 0.47 | 0.01 | — | 6 |
| Ex. 28 | 0.47 | 0.00 | — | 2 |
| Ex. 29 | 0.63 | 0.16 | — | 9 |
| Ex. 30 | 0.13 | 0.34 | — | 21 |
| C. Ex. 6 | 0.00 | 0.47 | — | 88 |
| C. Ex. 7 | 2.32 | 2.79 | — | 92 |
| C. Ex. 8 | 0.80 | 1.28 | — | 102 |
| C. Ex. 9 | 1.79 | 1.85 | — | 105 |
| Ex. 31 | 0.60 | 0.00 | — | 2 |
| Ex. 32 | 0.56 | 0.00 | — | 3 |
| Ex. 33 | 0.19 | 0.41 | — | 39 |
| Ex. 34 | 0.68 | 0.09 | — | 8 |
| Ex. 35 | 0.36 | 0.24 | — | 28 |
| Ex. 36 | 0.19 | 0.41 | — | 1 |
| | 0.60 | 0.00 | | |
| C. Ex. 10 | * | * | — | 96 |

In Tables 6 and 7, details of the filter are described below. In the above Tables 6 and 7, examples in which two type of filters are described mean that two-stage filters combined of 2 types of filters were used.

Nylon 40 nm: Nyloin 6,6-made filter (pore size: 40 nm) manufactured by Japan Pall Corporation

Nylon 20 nm: Nyloin 6,6-made filter (pore size: 20 nm) manufactured by Japan Pall Corporation

PE 50 nm: Polyethylene-based resin-made filter (pore size: 50 nm) manufactured by Japan Entegris, Inc.

PE 10 nm: Polyethylene-based resin-made filter (pore size: 10 nm) manufactured by Japan Entegris. Inc.

Ion Clean AN: filter of the porous membrane polyolefin film having anion exchange groups manufactured by Japan Pall Corporation

Ion Clean SL: filter of the porous membrane polyolefin film having anion exchange groups manufactured by Japan Pall Corporation

It could be seen that the absolute value of the difference between the solubility parameters with the developer was 1.0 (cal/cm³)^{1/2} or less and the residue defects were greatly decreased by pre-filtering the resin with a filter by using the other solvent (C1) that is different from the solvent (C2) used in the resist composition.

This is considered that because a component sparingly soluble to the solvent (C2) used in the resist composition and a component which is sparingly soluble to the solvent (C1) are different, a plurality of components which may lead to residual components were removed by pre-filtering with different solvents.

Also, it is considered that, by using the solvent in which the absolute value of the difference between the solubility parameters with the developer was 1.0 (cal/cm³)^{1/2} or less, a residual component could be removed and the components which are sparingly soluble to the developer were removed.

Further, it could be seen that when the absolute value of the difference between the solubility parameters of the solvent (C1) and solvent (C2) was 0.40 (cal/cm³)^{1/2} or more, the residue defects were further reduced.

In Example 1, after exposure of the mask pattern of line and space, development could be performed in both the alkaline developer and butyl acetate to form a pattern with a pitch of ½ of the mask pattern, with reference to Example 7, etc. of U.S. Pat. No. 8,227,183.

In Example 1, the evaluation was performed in the same manner except that a small amount of tri-n-octyl amine was added to the developer (butyl acetate) of the process (6). In this example, it was possible to perform a good pattern formation.

### Examples 37 to 40 and Comparative Examples 11 and 12

### Formation and Evaluation of Resist Pattern

(Purification of Resin)

10 parts by mass of the resin (A) shown in Table 9 which was obtained by the above synthesis example, was dissolved in 90 parts by mass of the solvent (C1) shown in the same table, filtered at a flow rate of 100 mL/min using a filter shown in the same table. A large amount of hexane was added to the filtrate to thereby re-precipitate the resin. The solid obtained by filteration or evaporation of the solvent was vacuum dried to purify the resin (A).

Further, in Example 36, purification of the resin was performed twice by changing the type of filter.

(Preparation of Resist Composition)

The resin (A) purified as described above and the other components shown in Table 8 were dissolved in the solvent shown in the same Table to have a total solid content of 1.6% by mass, and each was filtered through a polyethylene filter having a pore size of 0.05 μm to prepare an actinic ray-sensitive or radiation-sensitive resin composition (resist composition) (I-8) and (I-9) shown in each Examples and Comparative Examples.

(Formation of the Resist Film)

The actinic ray-sensitive or radiation-sensitive resin composition solution was applied on a Si wafer of 8 inches treated in advance with hexamethyldisilazane (HMDS), using a spin coater-Mark8 manufactured by Tokyo Electron, and dried on a hot plate at 100° C. for 60 seconds to obtain a resist film having a film thickness of 50 nm.

(Formation of Resist Pattern)

The applied wafer of the resist film was subjected to pattern exposure by using an EUV exposure apparatus (manufactured by Exitech Ltd.; Micro Exposure Tool, NA0.3, Quadrupole, outer sigma 0.68, inner sigma 0.36) through an exposure mask (line/space=1/1). After irradiation, the wafer was heated on a hot plate at 110° C. for 60 seconds. Subsequently, the wafer was developed by performing paddling using the organic-based developer described in Table 9 below, rotated at a rotational speed of 4000 rpm for 30 seconds and baked at 90° C. for 60 seconds to obtain a 1:1 line-and-space pattern with a line width of 50 nm.

(Evaluation of Resist Pattern)

Using a scanning electron microscope (manufactured by Hitachi Ltd.; S-938011), the shape of the resulting resist pattern was evaluated to obtain an irradiation energy when developing a 1:1 line-and-space pattern with a line width of 50 nm. After exposure by the radiation energy and the above-described development, 1000 photos were taken while shifting the observation points to one micron, and tested residue defects on the pattern. In the wafer with a diameter of 150 mm (diameter of 8 inches), the number of residue defects as shown in FIG. 1 were counted. As this value is small, performance is good.

TABLE 8

| | | | Acid | | Basic | | | | | |
|---|---|---|---|---|---|---|---|---|---|---|
| | Resin | | generator | | compound | | | | Solvent | Mass |
| Composition | (A) | (g) | (B) | (g) | (N) | (g) | Surfactant | (g) | (C2) | ratio |
| I-8 | A-8 | 10 | PAG-8 | 3.00 | C-3 | 0.90 | W-1 | 0.003 | SG-1/SG-6 | 60/40 |
| I-9 | A-9 | 10 | PAG-9 | 3.00 | C-3 | 0.90 | W-1 | 0.003 | SG-1/SG-6 | 60/40 |

TABLE 9

| | Com- | | Process (1) | | | Process (2) | | Process (6) | | | | |
|---|---|---|---|---|---|---|---|---|---|---|---|---|
| | position | | | SP value | | | SP value | | SP value | | \|SP_{C1} − | Residue |
| | Structure | Resin | Solvent | (cal/ | | Solvent (C2) | (cal/ | Devel- | (cal/ | \|SP_{C1} − SP_{C2}\| | SP_{DEV}\| | defect |
| | (I) | (A) | (C1) | cm³)^{1/2} | Filter | (molar ratio) | cm³)^{1/2} | oper | cm³)^{1/2} | (cal/cm³)^{1/2} | (cal/cm³)^{1/2} | (number) |
| Ex. 37 | I-8 | A-8 | SG-3 | 8.73 | Nylon | SG-1/SG-6 | 10.13 | SG-3 | 8.73 | 1.40 | 0.00 | 3 |
| | | | | | 40 nm | (60/40) | | | | | | |
| Ex. 38 | I-8 | A-8 | SG-11 | 8.74 | Nylon | SG-1/SG-6 | 10.13 | SG-3 | 8.73 | 1.39 | 0.01 | 2 |
| | | | | | 40 nm | (60/40) | | | | | | |
| C. Ex. | I-8 | A-8 | none | — | none | SG-1/SG-6 | 10.13 | SG-3 | 8.73 | * | * | 9 |
| 11 | | | | | | (60/40) | | | | | | |
| Ex. 39 | I-9 | A-9 | SG-3 | 8.73 | PE | SG-1/SG-6 | 10.13 | SG-3 | 8.73 | 1.40 | 0.00 | 1 |
| | | | | | 50 nm | (60/40) | | | | | | |
| Ex. 40 | I-9 | A-9 | SG-12 | 8.65 | Nylon | SG-1/SG-6 | 10.13 | SG-3 | 8.73 | 1.49 | 0.09 | 2 |
| | | | | | 20 nm | (60/40) | | | | | | |
| C. Ex. | I-9 | A-9 | none | — | none | SG-1/SG-6 | 10.13 | SG-3 | 8.73 | * | * | 8 |
| 12 | | | | | | (60/40) | | | | | | |

In Table 9, details of the filter are as described above.

It could be seen that the absolute value of the difference between the solubility parameters with the developer was 1.00 (cal/cm³)^{1/2} or less and the residue defects were greatly decreased by pre-filtering the resin with a filter by using the other solvent (C1) that is different from the solvent (C2) used in the resist composition.

This is considered that because a component sparingly soluble to the solvent (C2) used in the resist composition and a component which is sparingly soluble to the solvent (C1) are different, a plurality of components which may lead to residual components were removed by pre-filtering with different solvents.

Also, it is considered that, by using the solvent in which the absolute value of the difference between the solubility parameters with the developer was 1.00 (cal/cm³)^{1/2} or less, a residual component could be removed and the components which are sparingly soluble to the developer were removed.

### INDUSTRIAL APPLICABILITY

According to the present invention, there is provide a pattern forming method which can reduce the residue defects and performs development using an organic developer, an actinic ray-sensitive or radiation-sensitive resin composition for organic solvent development used therefor and a method for manufacturing the same, a method of manufacturing an electronic device, and an electronic device.

Although the present invention has been described with reference to detailed and specific aspects, it is obvious to those skilled in the art that various changes or modifications can be made without departing from the spirit and scope of the present invention.

The present application is based on Japanese Patent Application (Patent Application No. 2013-053283) filed on Mar. 15, 2013, the content of which is incorporated herein by reference.

What is claimed is:

1. A pattern forming method comprising:
(1) filtering, by using a filter, a resin solution containing (A) a resin capable of increasing its polarity by an action of an acid to decrease solubility in a developer including an organic solvent, and (C1) a solvent;
(2) preparing an actinic ray-sensitive or radiation-sensitive resin composition which contains the resin (A) obtained from the filtrating (1) and a solvent (C2) that is different from the solvent (C1);
(3) filtering the actinic ray-sensitive or radiation-sensitive resin composition by using a filter;
(4) forming a film by using a filtrate obtained by the filtering (3);
(5) exposing the film; and
(6) performing development using a developer containing an organic solvent to form a negative pattern,
wherein an absolute value of the difference between solubility parameter (SP_{c1}) of the solvent (C1) and solubility parameter (SP_{DEV}) of the developer (C1), |SP_{C1}−SP_{DEV}|, is 1.00 (cal/cm³)^{1/2} or less.

2. The pattern forming method according to claim 1,
wherein the absolute value |SP_{C1}−SP_{DEV}| is 0.40 (cal/cm³)^{1/2} or less.

3. The pattern forming method according to claim 1,
wherein the solvent (C1) and the developer are the same.

4. The pattern forming method according to claim 1,
wherein, when the filtering (1) is performed once, the absolute value of the difference between the solubility parameter (SP_{C1}) of the solvent (C1) and the solubility parameter (SP_{C2}) of the solvent (C2), |SP_{C1}−SP_{C2}|, is 0.40 (cal/cm³)^{1/2} or more; and
when the filtering (1) is performed twice or more, in at least one of two or more filtering (1), the absolute value of the difference between the solubility parameter (SP_{C1}) of the solvent (C1) and the solubility parameter (SP_{C2}) of the solvent (C2), |SP_{C1}−SP_{C2}|, is 0.40 (cal/cm³)^{1/2} or more.

5. The pattern forming method according to according to claim 1,
wherein the solvent (C1) is one or more solvents selected from the group consisting of butyl acetate, methyl amyl ketone, ethyl 3-ethoxy propionate, ethyl acetate, propyl acetate, isopropyl acetate, isobutyl acetate, pentyl acetate, isopentyl acetate, and methyl 3-methoxy propionate.

6. The pattern forming method according to claim 1,
wherein the resin (A) includes a repeating unit represented by Formula (AI): 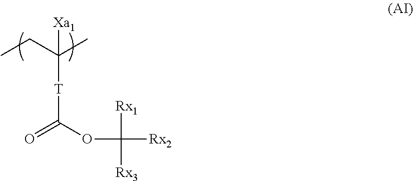
wherein in Formula (AI),
Xa₁ represents a hydrogen atom, an alkyl group, a cyano group or a halogen atom,
T represents a single bond or a divalent linking group,
each of Rx₁ to Rx₃ independently represents an alkyl group or a cycloalkyl group, and
two of Rx₁ to Rx₃ may combine with each other to form a ring structure.

7. The pattern forming method according to claim 1,
wherein the resin (A) is a resin including a repeating unit having a lactone structure or a sultone structure.

8. The pattern forming method according to claim 1,
wherein the resin (A) is a resin including a repeating unit having a cyclic carbonate ester structure.

9. The pattern forming method according to claim 1,
wherein the filter in the filtering (1) is a filter containing a polyamide-based resin filter or a polyethylene-based resin filter.

10. The pattern forming method according to claim 1,
wherein a pore size of the filter in the filtering (1) is 0.1 μm or less.

11. An actinic ray-sensitive or radiation-sensitive resin composition, comprising:
(A) a resin capable of increasing its polarity by an action of an acid to decrease solubility in a developer including an organic solvent; and
(C2) a solvent,
wherein the resin (A) is obtained from a filtrate which is obtained by filtering, by using a filter, a resin solution containing the resin (A) and a solvent (C1) that is different from the solvent (C2), and
the solvent (C1) is one or more solvents selected from the group consisting of butyl acetate, methyl amyl ketone, ethyl 3-ethoxy propionate, ethyl acetate, propyl acetate, isopropyl acetate, isobutyl acetate, pentyl acetate, isopentyl acetate, and methyl 3-methoxy propionate.

12. The actinic ray-sensitive or radiation-sensitive resin composition according to claim 11,
wherein the filter is a filter containing a polyamide-based resin filter or a polyethylene-based resin filter.

13. The actinic ray-sensitive or radiation-sensitive resin composition according to claim 11,
wherein a pore size of the filter is 0.1 μm or less.

14. The actinic ray-sensitive or radiation-sensitive resin composition according to claim 11,
wherein the resin (A) includes a repeating unit represented by Formula (AI): 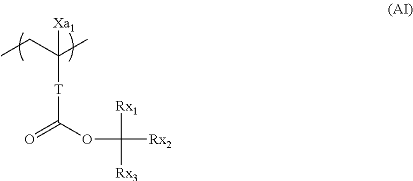
wherein in Formula (AI),
Xa₁ represents a hydrogen atom, an alkyl group, a cyano group or a halogen atom,
T represents a single bond or a divalent linking group,
each of Rx₁ to Rx₃ independently represcnts an alkyl group or a cycloalkyl group, and
two of Rx₁ to Rx₃ may combine with each other to form a ring structure.

15. The actinic ray-sensitive or radiation-sensitive resin composition according to claim 11,
wherein the resin (A) is a resin including a repeating unit having a lactone structure or a sultone structure.

16. The actinic ray-sensitive or radiation-sensitive resin composition according to claim 11,
wherein the resin (A) is a resin including a repeating unit having a cyclic carbonate ester structure.

17. A method of preparing an actinic ray-sensitive or radiation-sensitive resin composition for organic solvent development, comprising:
(1) filtering, by using a filter, a resin solution containing (A) a resin capable of increasing its polarity by an action of an acid to decrease solubility in a developer including an organic solvent, and (C1) a solvent;
(2) preparing an actinic ray-sensitive or radiation-sensitive resin composition for organic solvent development, containing the resin (A) obtained from a filtrate in the filtering (1) and a solvent (C2) that is different from the solvent (C1); and
(3) filtering the actinic ray-sensitive or radiation-sensitive resin composition for organic solvent development by using a filter, and
the solvent (C1) is one or more solvents selected from the group consisting of butyl acetate, methyl amyl ketone, ethyl 3-ethoxy propionate, ethyl acetate, propyl acetate, isopropyl acetate, isobutyl acetate, pentyl acetate, isopentyl acetate, and methyl 3-methoxy propionate.

18. The method of preparing an actinic ray-sensitive or radiation-sensitive resin composition for organic solvent development according to claim 17,
wherein the filter is a filter containing a polyamide-based resin filter or a polyethylene-based resin filter.

19. The method of preparing an actinic ray-sensitive or radiation-sensitive resin composition for organic solvent development according to claim 17,
wherein a pore size of the filter is 0.1 μm or less.

20. The method of preparing an actinic ray-sensitive or radiation-sensitive resin composition for organic solvent development according to claim 17,
wherein the resin (A) includes a repeating unit represented by Formula (AI): 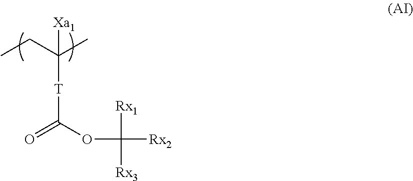
wherein in Formula (AI),
Xa₁ represents a hydrogen atom, an allyl group, a cyano group or a halogen atom,
T represents a single bond or a divalent linking group,
each of Rx₁ to Rx₃ independently represents an alkyl group or a cycloalkyl group, and
two of Rx₁ to Rx₃ may combine with each other to form a ring structure.

21. The method of preparing an actinic ray-sensitive or radiation-sensitive resin composition for organic solvent development according to claim 17,
wherein the resin (A) is a resin including a repeating unit having a lactone structure or a sultone structure.

22. The method of preparing an actinic ray-sensitive or radiation-sensitive resin composition for organic solvent development according to claim 17,
wherein the resin (A) is a resin including a repeating unit having a cyclic carbonate ester structure.

23. A method of manufacturing an electronic device comprising the pattern forming method according to claim 1.
